(19) United States
(12) Patent Application Publication
(10) Pub. No.: US 2026/0028503 A1
(43) Pub. Date: Jan. 29, 2026

(54) RESIST COMPOSITION AND PATTERNING PROCESS

(71) Applicant: Shin-Etsu Chemical Co., Ltd., Tokyo (JP)

(72) Inventors: Shun Kikuchi, Joetsu-shi (JP); Satoshi Kusama, Joetsu-shi (JP); Kousuke Ohyama, Joetsu-shi (JP); Masaki Ohashi, Joetsu-shi (JP)

(73) Assignee: Shin-Etsu Chemical Co., Ltd., Tokyo (JP)

(21) Appl. No.: 19/270,858

(22) Filed: Jul. 16, 2025

(30) Foreign Application Priority Data
Jul. 23, 2024 (JP) 2024-117420
Jul. 2, 2025 (JP) 2025-112254

(51) Int. Cl. C09D 167/06; G03F 7/00; G03F 7/004; G03F 7/039; G03F 7/09

(52) U.S. Cl. CPC C09D 167/06; G03F 7/0045; G03F 7/0397; G03F 7/094; G03F 7/70033

(57) ABSTRACT

A resist composition comprising a hypervalent iodine compound, an onium salt, a carboxy-containing compound, and a solvent is provided. When processed by photolithography using high-energy radiation, the resist composition exhibits a high sensitivity and resolution. The non-chemically-amplified resist composition exhibits a high sensitivity and maximum resolution when processed by photolithography using high-energy radiation, typically EB and EUV lithography, and a patterning process using the same.

### CROSS-REFERENCE TO RELATED APPLICATION

This non-provisional application claims priority under 35 U.S.C. § 119(a) on Patent Application Nos. 2024-117420 and 2025-112254 filed in Japan on Jul. 23, 2024 and Jul. 2, 2025, respectively, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives 20 forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. Particularly in the case of line-and-space patterns, chances of collapse and disconnection of patterns increase outstandingly as the pattern size becomes smaller. Minimizing such chances leads to an improvement in maximum resolution.

Patent Document 2 discloses a negative resist composition comprising a tin compound. Based on tin element having high EUV absorption, this resist composition is improved in stochastics and achieves a high sensitivity and high resolution. The so-called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

Citation List

| | |
|---|---|
| Patent Document 1: | JP-A 2018-005224 (U.S. Pat. No. 10,323,113) |
| Patent Document 2: | JP-A 2021-503482 |
| Non-Patent Document 1: | SPIE Vol. 5039 p1 (2003) |
| Non-Patent Document 2: | SPIE Vol. 6520 p65203L-1 (2007) |

### DISCLOSURE OF INVENTION

An object of the invention is to provide a non-chemically-amplified resist composition which exhibits a high sensitivity and maximum resolution when processed by photolithography using high-energy radiation, typically EB and EUV lithography, and a patterning process using the same.

The inventors have found that a resist composition based on a hypervalent iodine compound, a carboxy-containing compound, and an onium salt forms a resist film having a satisfactory sensitivity and resolution and is thus quite useful in precise micropatterning.

In one aspect, the invention provides a resist composition comprising a hypervalent iodine compound, an onium salt compound, a carboxy-containing compound, and a solvent. The hypervalent iodine compound is at least one compound selected from hypervalent iodine compounds having the formulae (1) to (4).

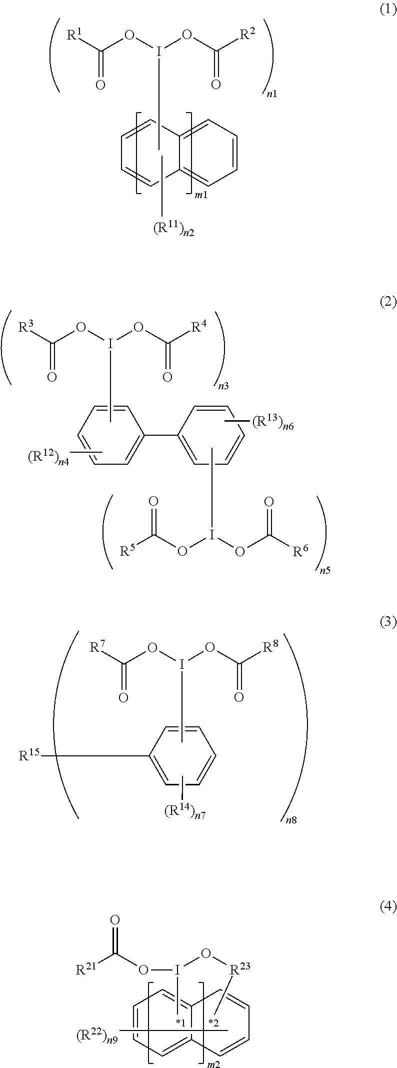

Herein m1 is 0, 1 or 2; when m1=0, n1 is 1, 2 or 3, n2 is 0, 1, 2, 3, 4 or 5 and 1≤n1+n2≤6; when m1=1, n1 is 1, 2 or 3, n2 is 0, 1, 2, 3, 4, 5, 6 or 7 and 1≤n1+n2≤8; when m1=2, n1 is 1, 2 or 3, n2 is 0, 1, 2, 3, 4, 5, 6, 7, 8 or 9 and 1≤n1+n2≤10;
n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
m2 is 0, 1 or 2; when m2=0, n9 is 0, 1, 2, 3 or 4; when m2=1, n9 is 0, 1, 2, 3, 4, 5 or 6; when m2=2, n9 is 0, 1, 2, 3, 4, 5, 6, 7 or 8;
R¹ to R⁸ are each independently halogen or a C₁-C₁₀ hydrocarbyl group which may contain a heteroatom, R¹ and R², R³ and R⁴, R⁵ and R⁶, or R⁷ and R¹ may bond together to form a ring with the carbon atoms to which they are attached and the intervenient atoms,
R¹¹ to R¹⁴ are each independently halogen or a C₁-C₄₀ hydrocarbyl group which may contain a heteroatom; when n2 is 2 or more, a plurality of R¹¹ may be identical or different and a plurality of R¹¹ may bond together to form a ring with the carbon atoms on the aromatic ring to which they are attached; when n4 is 2 or more, a plurality of R¹² may be identical or different and a plurality of R¹² may bond together to form a ring with the carbon atoms on the aromatic ring to which they are attached; when n6 is 2 or more, a plurality of R¹³ may be identical or different and a plurality of R¹³ may bond together to form a ring with the carbon atoms on the aromatic ring to which they are attached; when n7 is 2 or more, a plurality of R¹⁴ may be identical or different and a plurality of R¹⁴ may bond together to form a ring with the carbon atoms on the aromatic ring to which they are attached;
R¹⁵ is a C₁-C₄₀ (n8)-valent hydrocarbon group or C₂-C₄₀ (n8)-valent heterocyclic group; when n8=2, R¹⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R¹⁴ and R¹⁵ may bond together to form a ring with the carbon atoms to which they are attached and the intervenient atoms,
R²¹ is halogen or a C₁-C₁₀ hydrocarbyl group which may contain a heteroatom,
R²² is halogen or a C₁-C₄₀ hydrocarbyl group which may contain a heteroatom, when n9 is 2 or more, a plurality of R²² may be identical or different and a plurality of R²² may bond together to form a ring with the carbon atoms on the aromatic ring to which they are attached;
R²³ is carbonyl or a C₁-C₁₀ hydrocarbylene group which may contain a heteroatom,
* 1 and *2 each designate a point of attachment to a carbon atom on the aromatic ring in the formula, *1 and *2 being attached to adjoining carbon atoms on the aromatic ring.

The onium salt compound consists of a sulfonium cation having the formula (5-1) or iodonium cation having the formula (5-2) and a halide ion, nitrate ion, hydrogensulfate ion, hydrogencarbonate ion, tetraphenylborate ion or anion having any one of the formulae (5-3) to (5-9).

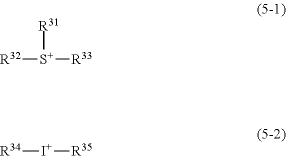

Herein R³¹ to R³⁵ are each independently halogen or a C₁-C₃₀ hydrocarbyl group which may contain a heteroatom, R³¹ and R³² may bond together to form a ring with the sulfur atom to which they are attached,

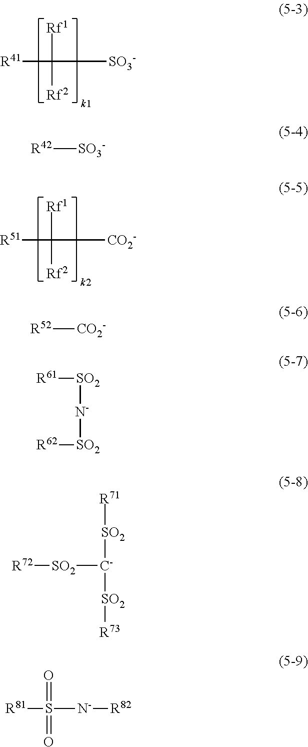

wherein k1 and k2 are each independently 1, 2, 3 or 4,
Rf¹ and Rf² are each independently hydrogen, fluorine, or a C₁-C₆ fluorinated alkyl group, excluding that all Rf¹ and Rf² are hydrogen at the same time,
R⁴¹ is hydrogen, halogen, hydroxy or a C₁-C₅₀ hydrocarbyl group which may contain a heteroatom,
R⁴² is hydrogen, halogen, hydroxy or a C₁-C₅₀ hydrocarbyl group which may contain a heteroatom, exclusive of the group wherein hydrogen bonded to the carbon atom at α- or β-position relative to the sulfo group is substituted by fluorine or fluoroalkyl,
R⁵¹ is hydrogen, halogen, hydroxy or a C₁-C₅₀ hydrocarbyl group which may contain a heteroatom,
R⁵² is hydrogen, halogen, hydroxy or a C₁-C₅₀ hydrocarbyl group which may contain a heteroatom, exclusive of the group wherein hydrogen bonded to the carbon atom at α- or β-position relative to the carboxy group is substituted by fluorine or fluoroalkyl,
R⁶¹ and R⁶² are each independently a C₁-C₅₀ hydrocarbyl group which may contain a heteroatom,
R⁷¹ to R⁷³ are each independently a C₁-C₅₀ hydrocarbyl group which may contain a heteroatom,
R⁸¹ is fluorine or a C₁-C₁₀ fluorinated hydrocarbyl group which may contain hydroxy, ether bond or ester bond, R⁸² is hydrogen or a C₁-C₂₀ hydrocarbyl group which may contain hydroxy, ether bond or ester bond, R⁸¹ and R⁸² may bond together to form a ring with the atom to which they are attached.

In a preferred embodiment, the carboxy-containing compound is a polymer comprising repeat units having the formula (6) or a compound having the formula (7).

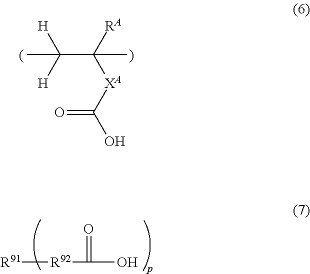

Herein R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone,
p is 1, 2, 3 or 4,
R⁹¹ is a C₁-C₄₀ p-valent hydrocarbon group or C₂-C₄₀ p-valent heterocyclic group; when p=2, R⁹¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R⁹² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R⁹² may be identical or different.

Preferably, the polymer comprising repeat units having formula (6) is free of an acid labile group.

In another aspect, the invention provides a laminate comprising a substrate and a resist film formed thereon from the resist composition defined herein.

The laminate may further comprise an underlying film between the substrate and the resist film.

In a preferred embodiment, the resist film is formed by a ligand exchange between the hypervalent iodine compound and the carboxy-containing compound.

In a further aspect, the invention provides a pattern forming process comprising the steps of applying the resist composition defined herein onto a substrate or a substrate having an underlying film deposited thereon to form a resist film thereon, exposing the resist film to i-line, KrF excimer laser, ArF excimer laser, EB or EUV, and developing the exposed resist film in a developer.

### Advantageous Effects of Invention

The resist composition exhibits both high sensitivity and resolution when processed by photolithography using i-line, KrF excimer laser, ArF excimer laser, EB or EUV and is quite useful in micropatterning.

### DESCRIPTION OF EMBODIMENTS

The terms “a” and “an” herein do not denote a limitation of quantity, but rather denote the presence of at least one of the referenced item. As used herein, Me stands for methyl, Ac for acetyl, the notation (Cₙ-Cₘ) means a group containing from n to m carbon atoms per group. Both the broken line ( [symbol] ) and the asterisk (*) designate a point of attachment or valence bond.

The abbreviations and acronyms have the following meaning.

UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### Resist Composition

One embodiment of the invention is a resist composition based on a hypervalent iodine compound, a carboxy-containing compound, and an onium salt compound.

### Hypervalent Iodine Compound

The hypervalent iodine compound is a three-coordinate hypervalent iodine compound having the formula (1), (2), (3) or (4).

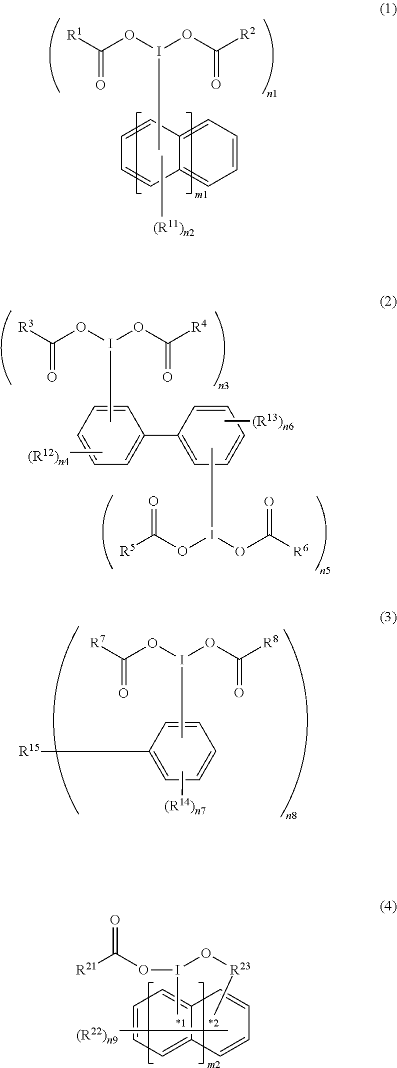

In formula (1), m1 is 0, 1 or 2. When m1=0, n1 is 1, 2 or 3, n2 is 0, 1, 2, 3, 4 or 5 and 1≤n1+n2≤6. When m1=1, n1 is 1, 2 or 3, n2 is 0, 1, 2, 3, 4, 5, 6 or 7 and 1≤n1+n2≤8. When m1=2, n1 is 1, 2 or 3, n2 is 0, 1, 2, 3, 4, 5, 6, 7, 8 or 9 and 1≤n1+n2≤10. In formulae (2) and (3), n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, and n8 is 1, 2, 3 or 4. In formula (4), m2 is 0, 1 or 2. When m2=0, n9 is 0, 1, 2, 3 or 4. When m2=1, n9 is 0, 1, 2, 3, 4, 5 or 6. When m2=2, n9 is 0, 1, 2, 3, 4, 5, 6, 7 or 8.

In formulae (1) to (3), R¹ to R⁸ are each independently halogen or a C₁-C₁₀ hydrocarbyl group which may contain a heteroatom. R¹ and R², R³ and R⁴, R⁵ and R⁶, or R⁷ and R⁸ may bond together to form a ring with the carbon atoms to which they are attached and the intervenient atoms.

Suitable halogen atoms represented by R¹ to R⁸ include fluorine, chlorine, bromine and iodine. The C₁-C₁₀ hydrocarbyl group represented by R¹ to R⁸ may be saturated or unsaturated and straight, branched or cyclic. Examples thereof include C₁-C₁₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ to R⁸ are preferably C₁-C₄ hydrocarbyl groups.

In formulae (1) to (3), R¹¹ to R¹⁴ are each independently halogen or a C₁-C₄₀ hydrocarbyl group which may contain a heteroatom. When n2 is 2 or more, a plurality of R¹¹ may be identical or different and a plurality of R¹¹ may bond together to form a ring with the carbon atoms on the aromatic ring to which they are attached. When n4 is 2 or more, a plurality of R¹² may be identical or different and a plurality of R¹² may bond together to form a ring with the carbon atoms on the aromatic ring to which they are attached. When n6 is 2 or more, a plurality of R¹³ may be identical or different and a plurality of R¹³ may bond together to form a ring with the carbon atoms on the aromatic ring to which they are attached. When n7 is 2 or more, a plurality of R¹⁴ may be identical or different and a plurality of R¹⁴ may bond together to form a ring with the carbon atoms on the aromatic ring to which they are attached.

Suitable halogen atoms represented by R¹¹ to R¹⁴ include fluorine, chlorine, bromine and iodine. The C₁-C₄₀ hydrocarbyl group represented by R¹¹ to R¹⁴ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

In formula (3), R¹⁵ is a C₁-C₄₀ (n8)-valent hydrocarbon group or C₂-C₄₀ (n8)-valent heterocyclic group. When n8=2, R¹⁵ may also be an ether bond, carbonyl group, azo group, thioether bond, carbonate bond, carbamate bond, sulfinyl group, sulfonyl group or thioketone bond. Some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety. R¹⁴ and R¹⁵ may bond together to form a ring with the carbon atoms to which they are attached and the intervenient atoms.

The (n8)-valent hydrocarbon group represented by R¹⁵ may be saturated or unsaturated and straight, branched or cyclic. The (n8)-valent hydrocarbon group is obtained by eliminating “n8” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptene, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The (n8)-valent heterocyclic group represented by R¹⁵ is obtained by eliminating “n8” number of hydrogen atoms from a heterocyclic compound. Suitable heterocyclic compounds include furane, pyridine, pyrazole, and thiazolidine.

Also included are the (n8)-valent hydrocarbon groups or (n8)-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the (n8)-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

In formula (4), R²¹ is halogen or a C₁-C₁₀ hydrocarbyl group which may contain a heteroatom. Examples of the halogen and hydrocarbyl group represented by R²¹ are the same as exemplified above for the halogen and hydrocarbyl groups R¹ to R⁸.

In formula (4), R²² is halogen or a C₁-C₄₀ hydrocarbyl group which may contain a heteroatom. When n9 is 2 or more, a plurality of R²² may be identical or different and a plurality of R²² may bond together to form a ring with the carbon atoms on the aromatic ring to which they are attached. Examples of the halogen and hydrocarbyl group represented by R²² are the same as exemplified above for the halogen and hydrocarbyl groups R¹¹ to R¹⁴.

In formula (4), R²³ is carbonyl or a C₁-C₁₀ hydrocarbylene group which may contain a heteroatom. The C₁-C₁₀ hydrocarbylene group may be saturated or unsaturated and straight, branched or cyclic. Examples thereof include C₁-C₁₀ alkylene groups such as methanediyl, ethane-1,1-diyl, ethane-1,2-diyl, propane-1,1-diyl, propane-1,2-diyl, propane-1,3-diyl, propane-2,2-diyl, butane-2,3-diyl, butane-1,4-diyl, 2-methylpropane-1,2-diyl, pentane-1,5-diyl, hexane-1,6-diyl, heptane-1,7-diyl, octane-1,8-diyl, nonane-1,9-diyl, and decane-1,10-diyl; C₃-C₁₀ cyclic saturated hydrocarbylene groups such as cyclopentanediyl, cyclohexanediyl, norbornanediyl, adamantanediyl and tricyclo[5.2.1.0^{2,6}]decanediyl; C₂-C₁₀ alkenylene groups such as vinylene and propynylene; C₆-C₁₀ arylene groups such as phenylene, methylphenylene, ethylphenylene, n-propylphenylene, isopropylphenylene, n-butylphenylene and naphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, halogenated alkyl, halogen, carbonyl, ether bond, thioether bond, ester bond, sulfonate ester bond, carbonate bond, carbamate bond, lactone ring, sultone ring, carboxylic anhydride (—C(═O)—O—C(═O)—). R²³ is preferably carbonyl, a C₁-C₄ hydrocarbylene group or C₁-C₄ fluorinated hydrocarbylene group.

In formula (4), *1 and *2 each designate a point of attachment to a carbon atom on the aromatic ring in the formula, with the proviso that *1 and *2 are attached to adjoining carbon atoms on the aromatic ring. As the combination of *1, *2 and m2, the following seven patterns are contemplated.

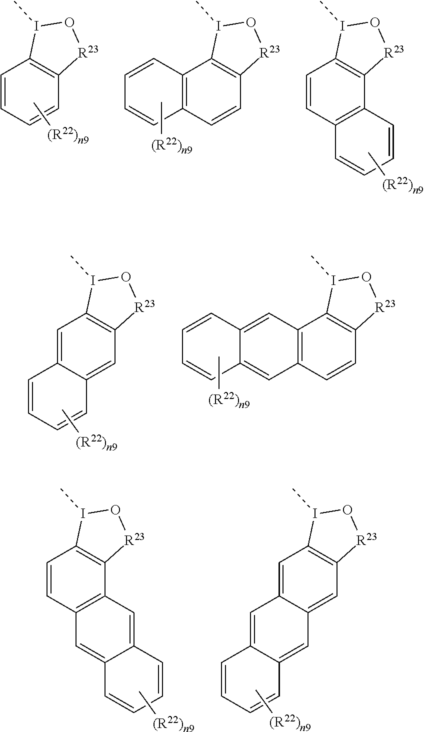

Herein n9, R²² and R²³ are as defined above, the broken line designates a point of attachment to R²¹—C(═O)—O—.

Examples of the hypervalent iodine compound having formula (1) are shown below, but not limited thereto.

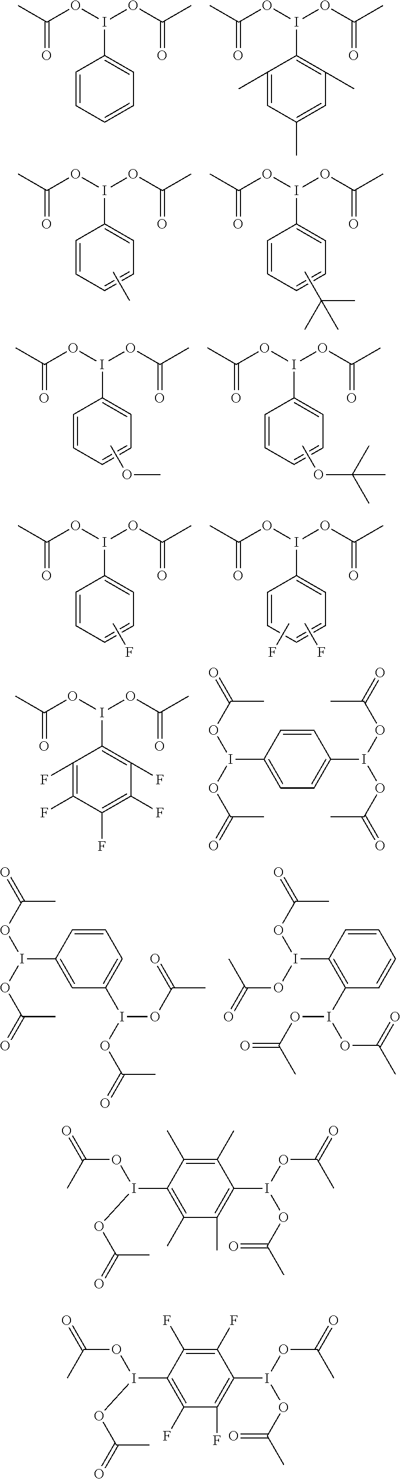

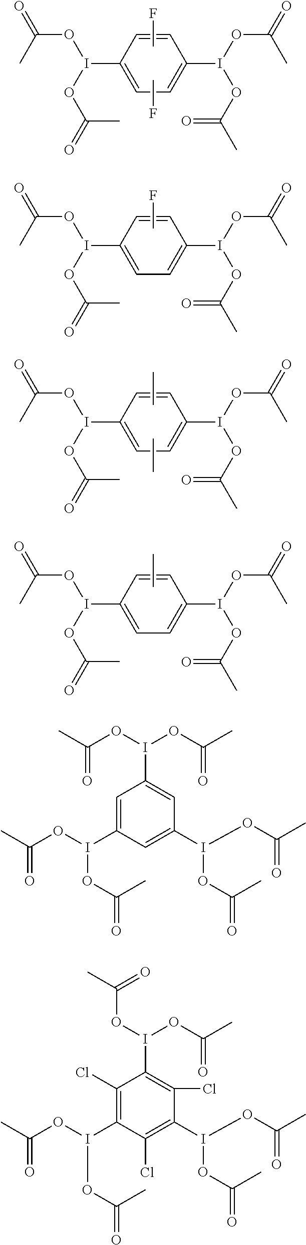

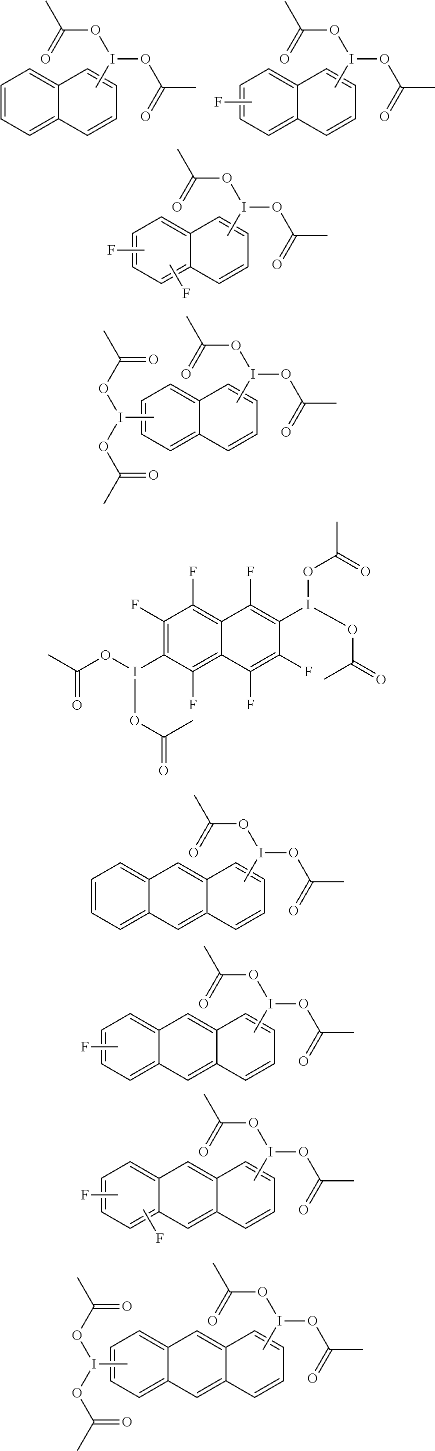

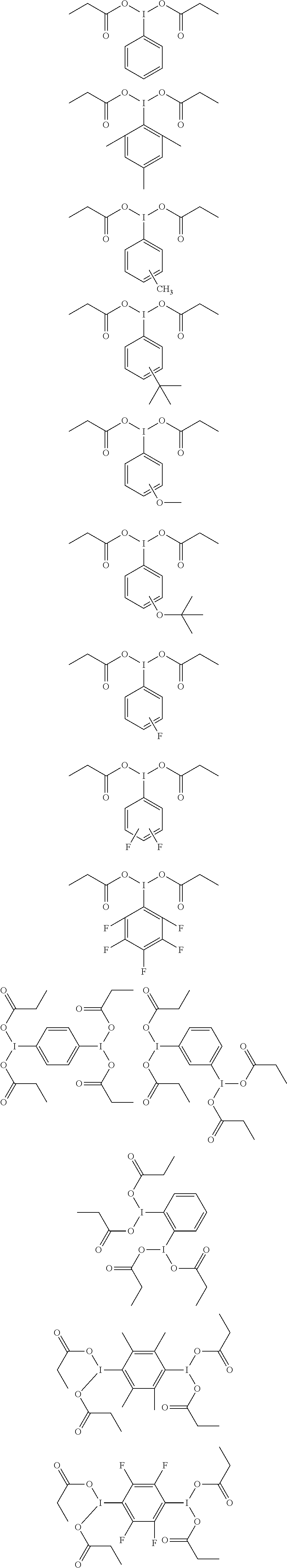

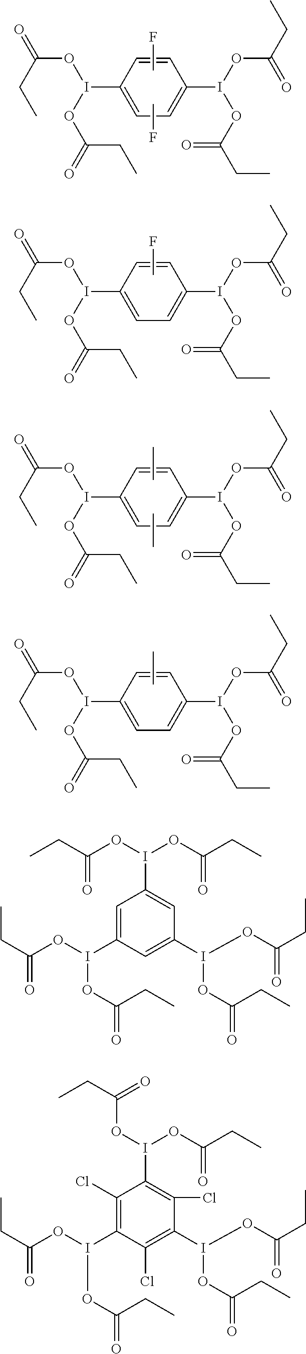

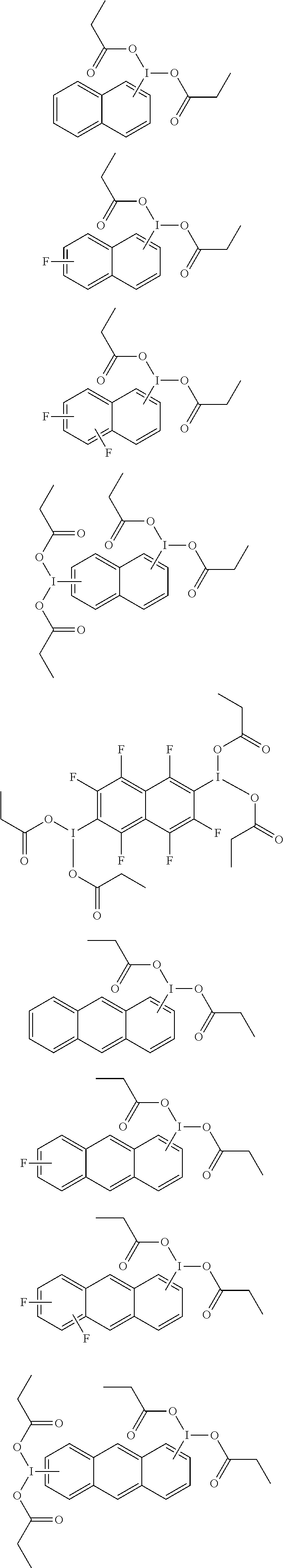

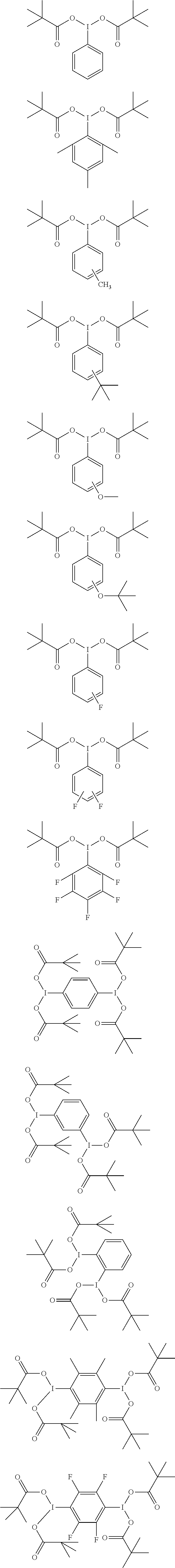

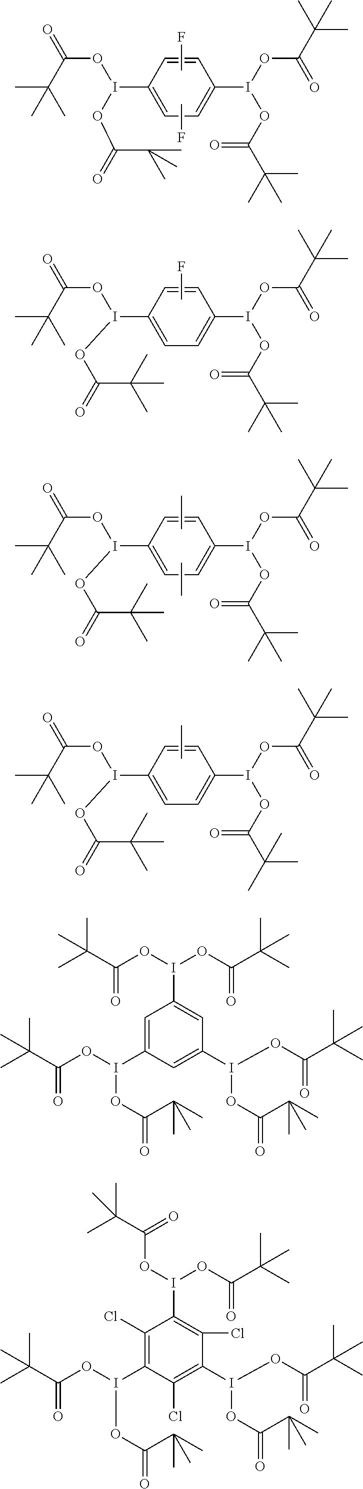

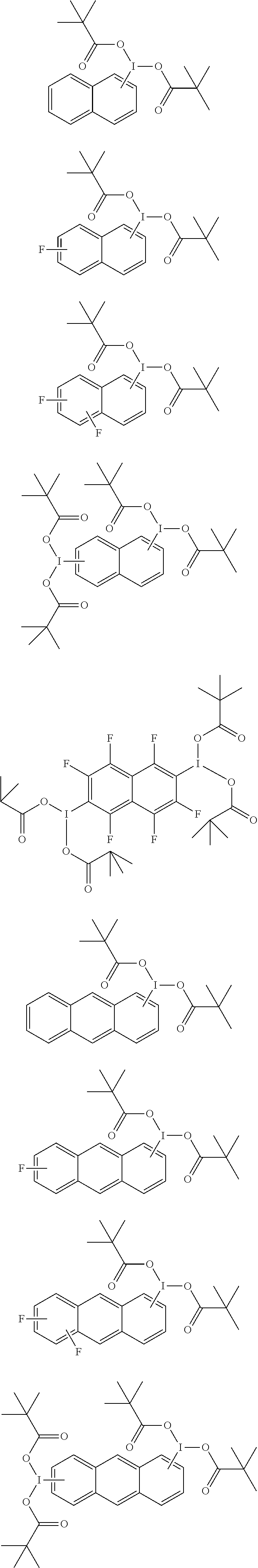

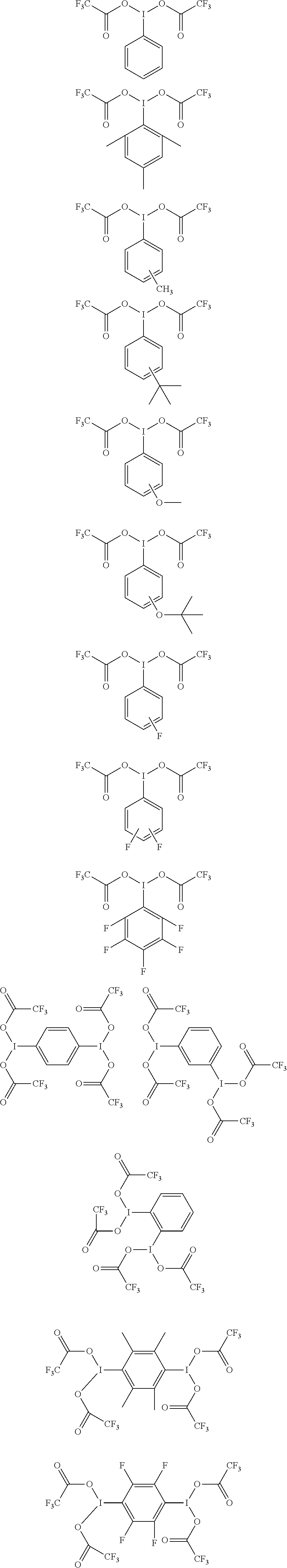

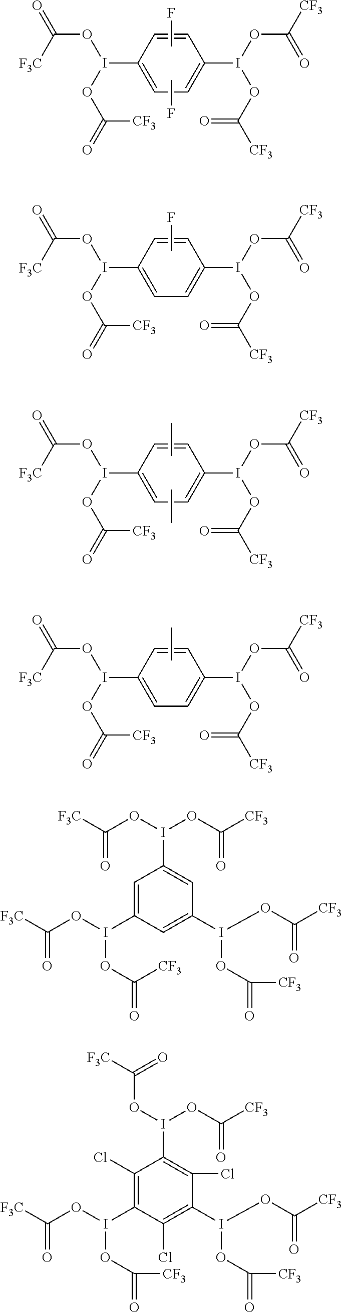

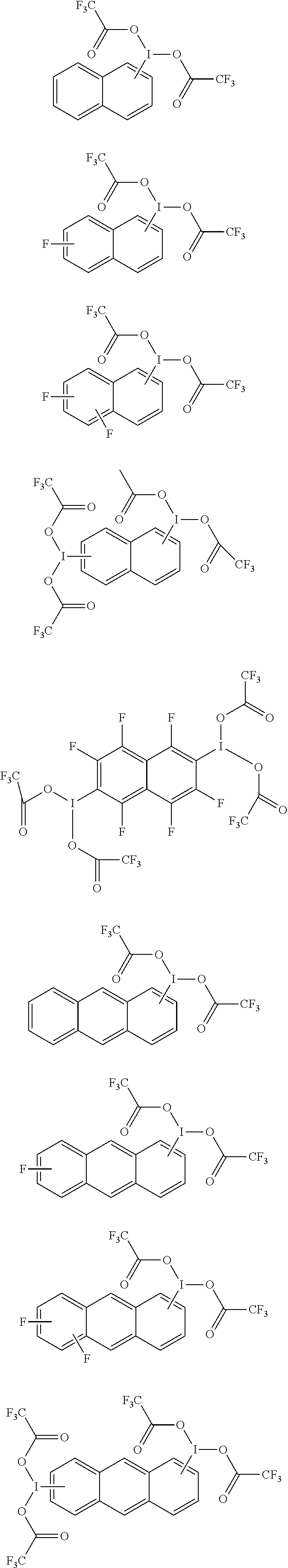

Examples of the hypervalent iodine compound having formula (2) are shown below, but not limited thereto.

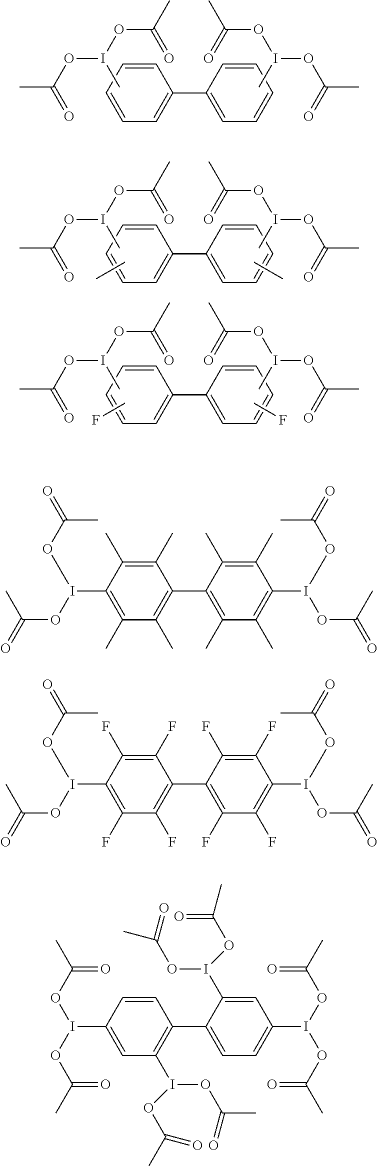

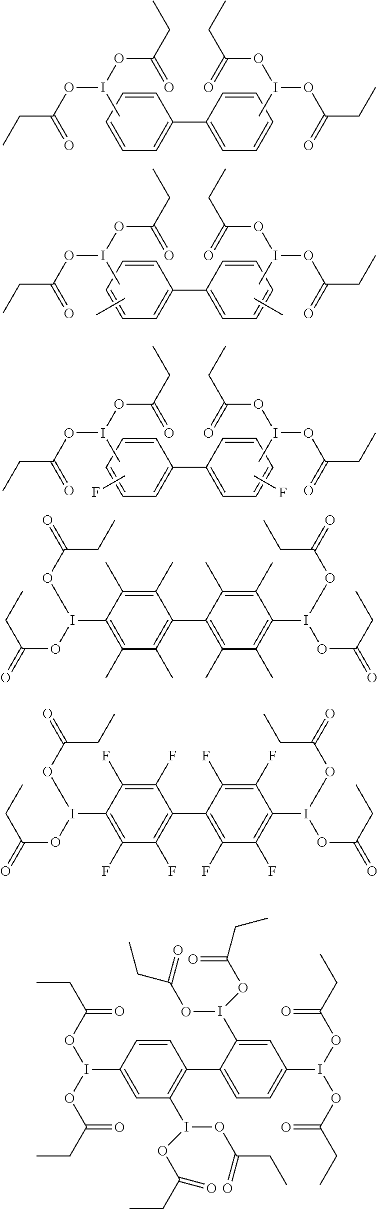

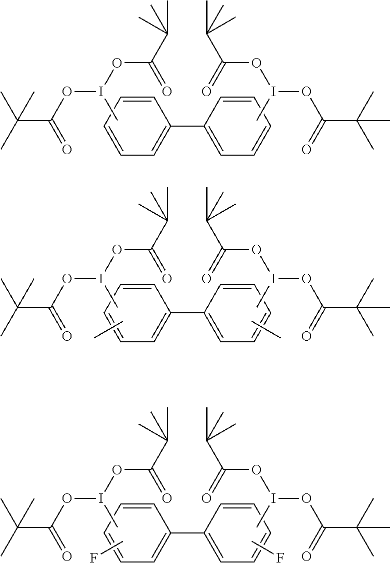

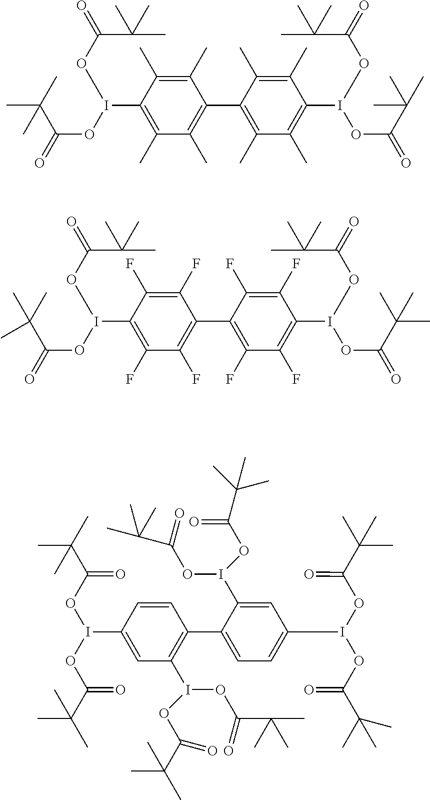

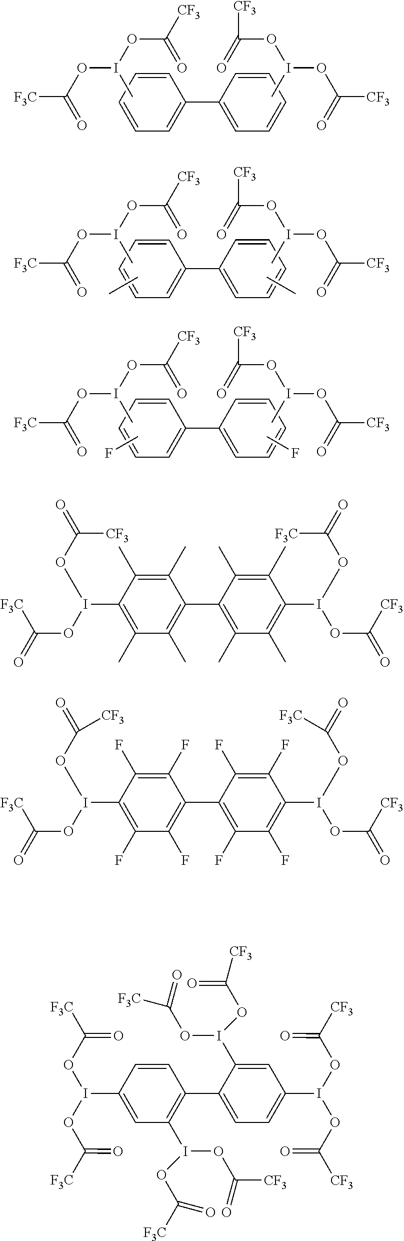

Examples of the hypervalent iodine compound having formula (3) are shown below, but not limited thereto.

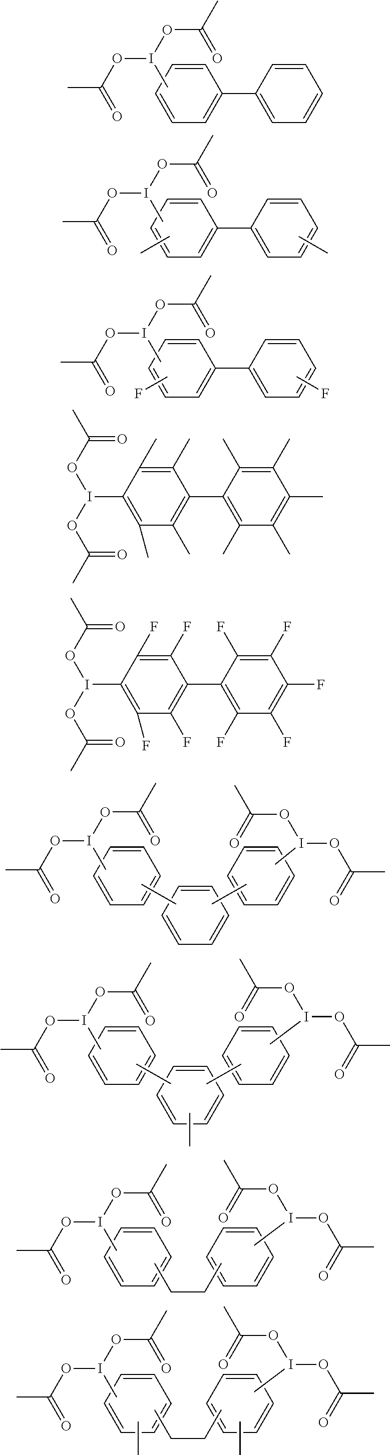

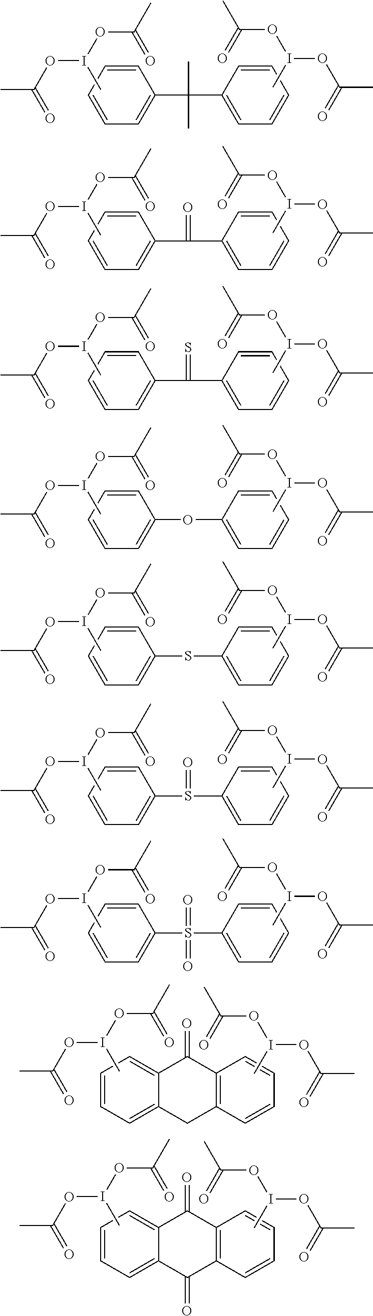

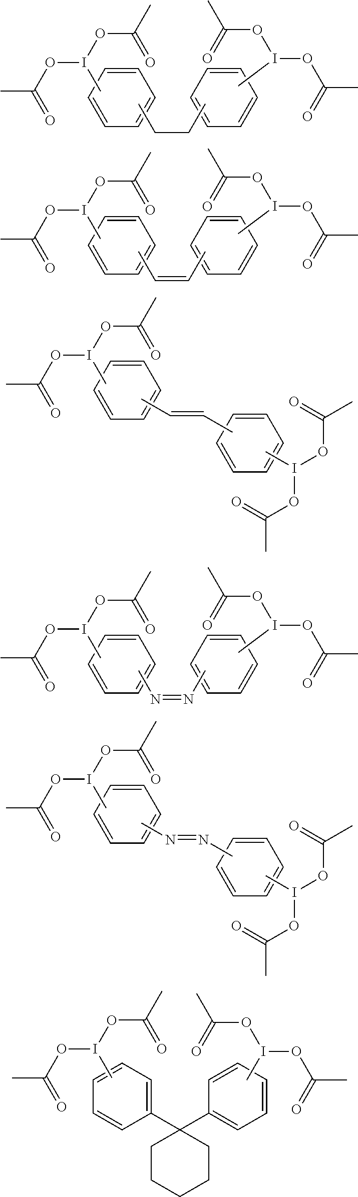

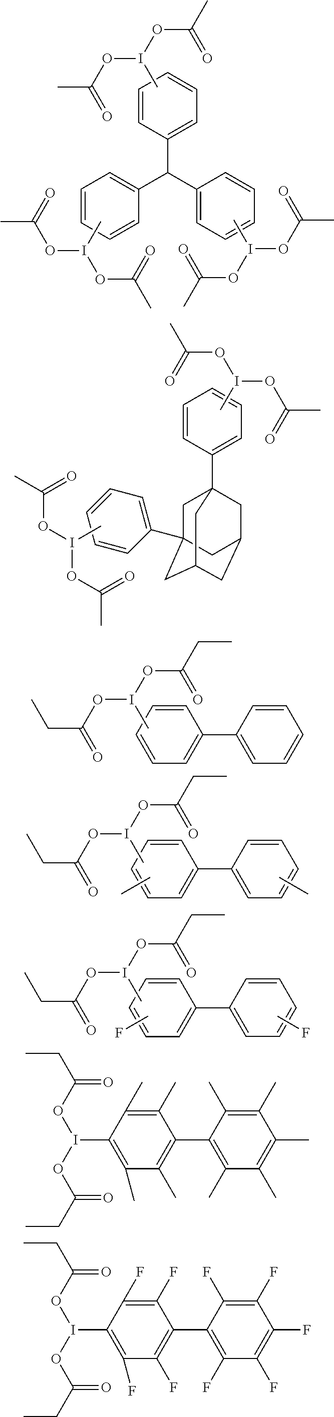

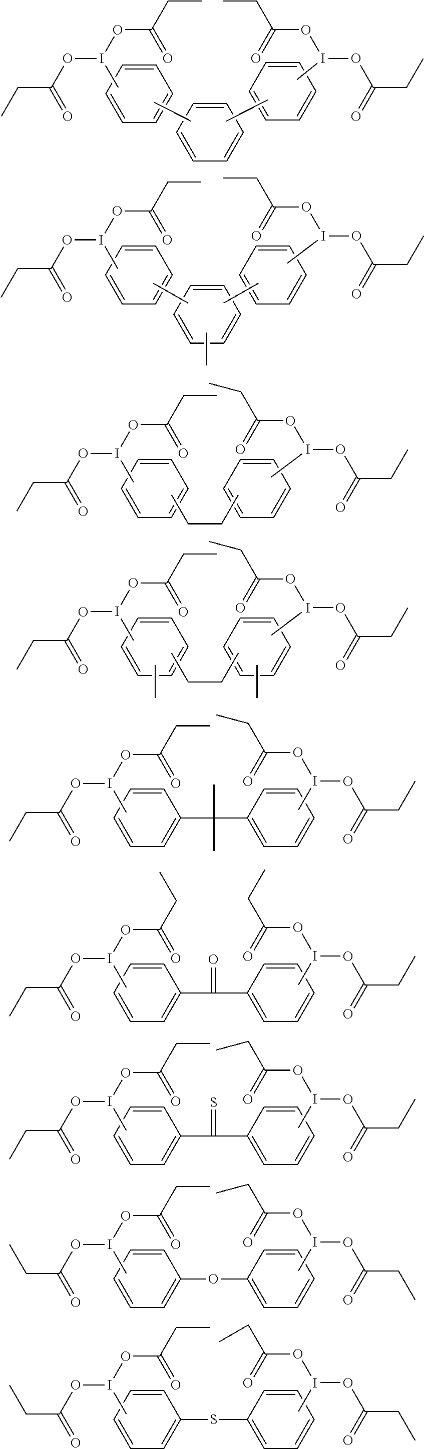

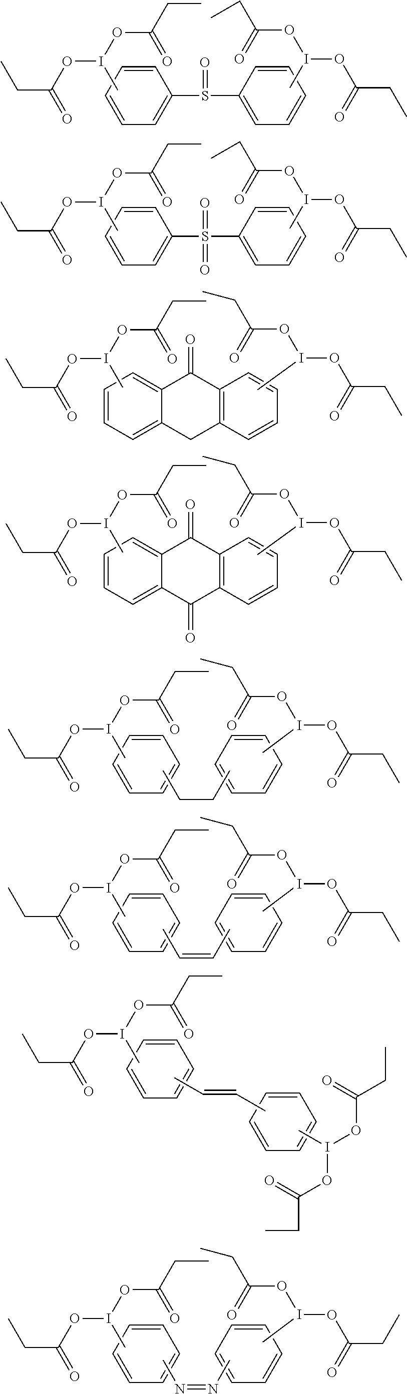

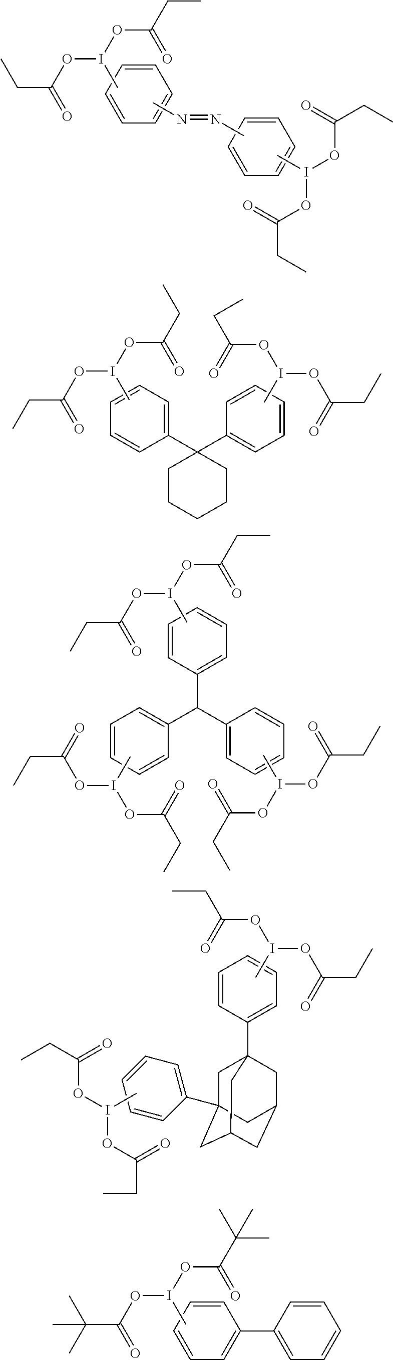

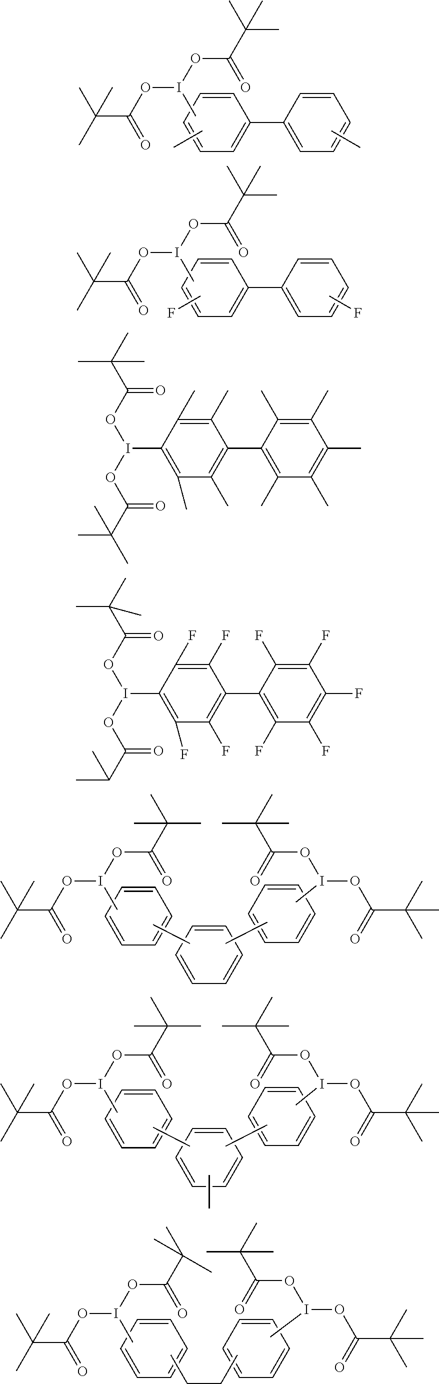

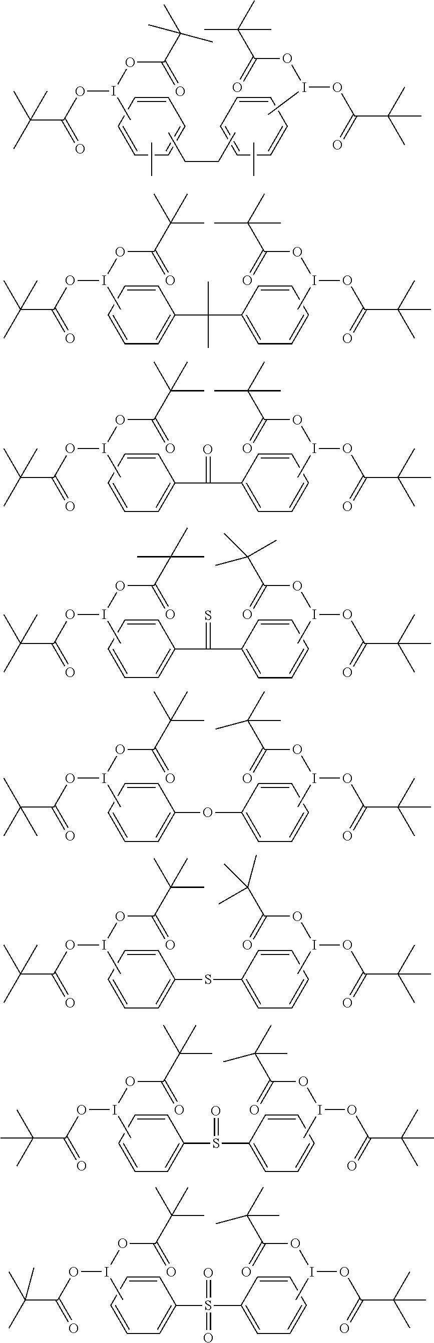

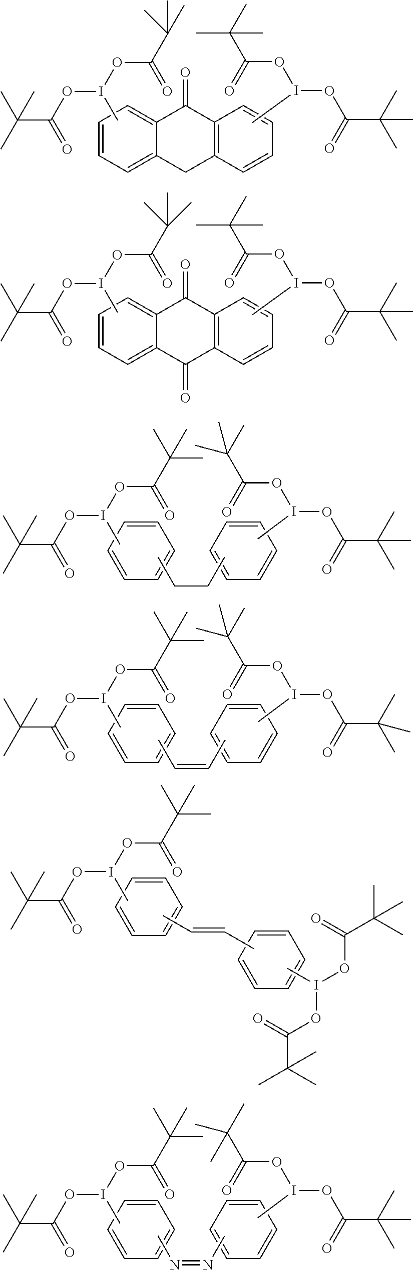

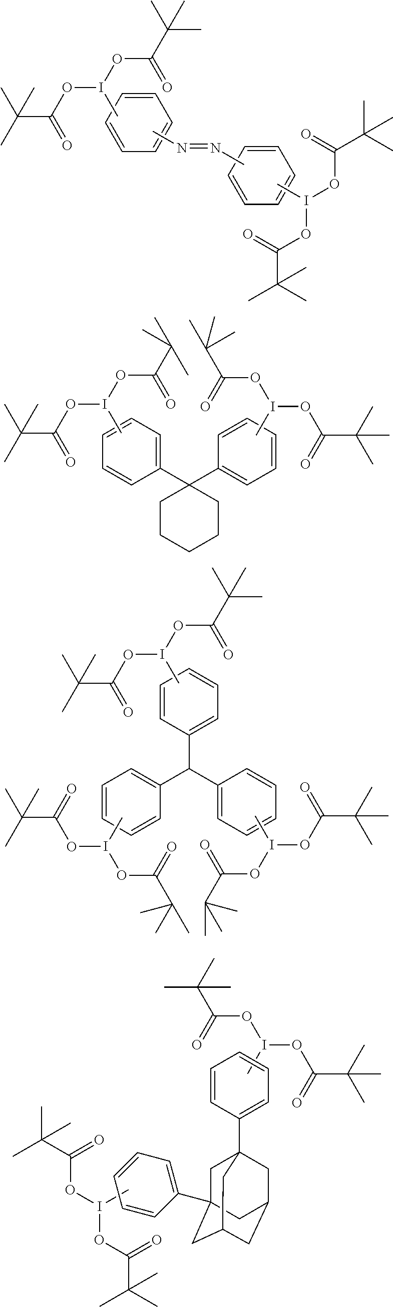

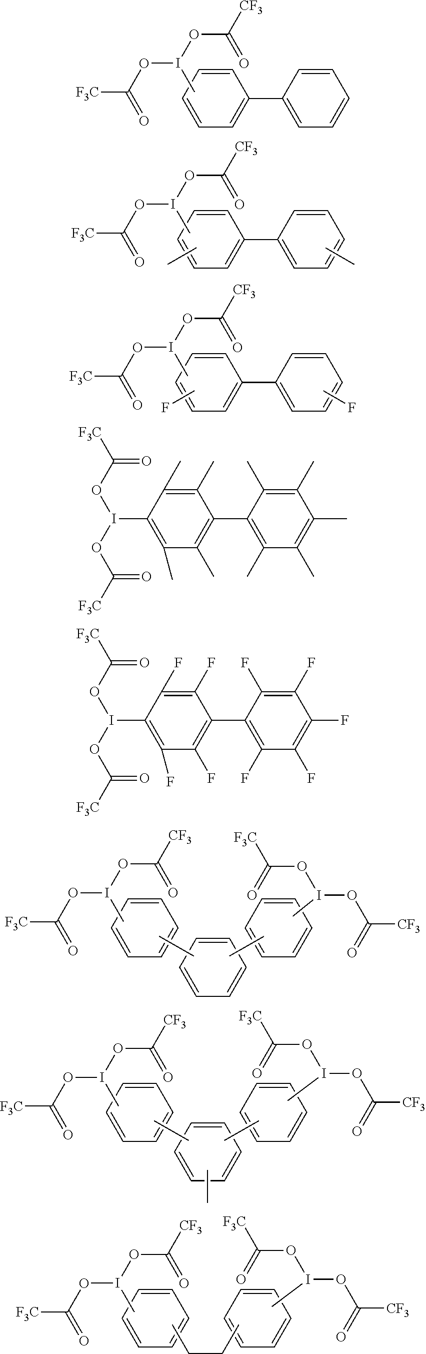

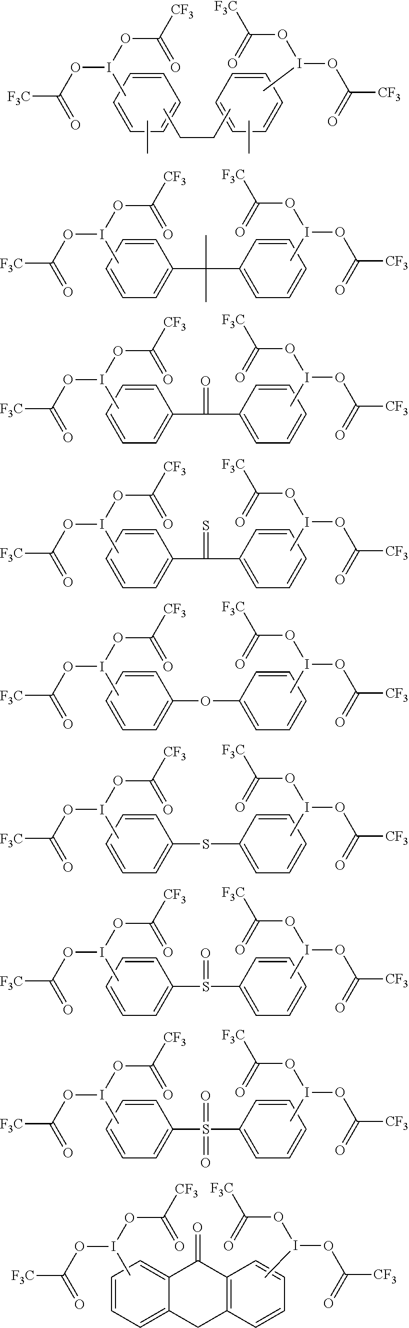

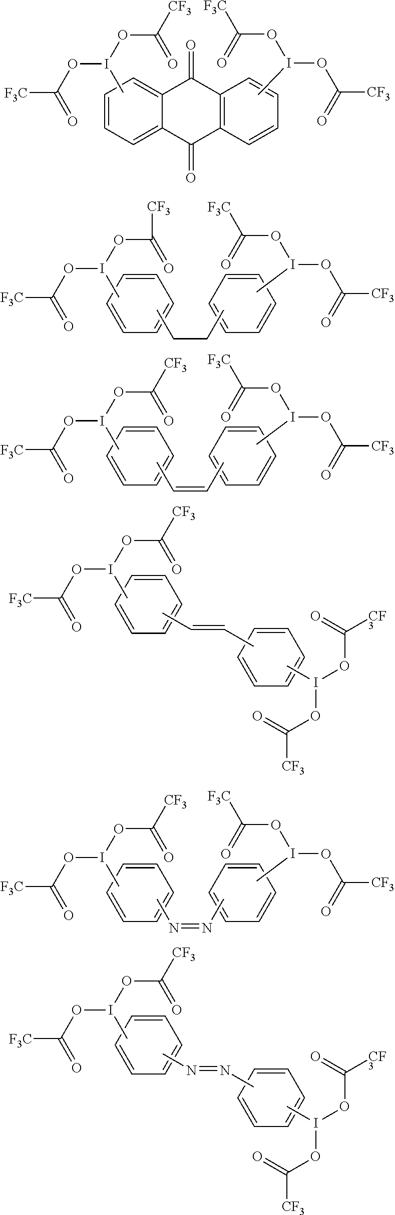

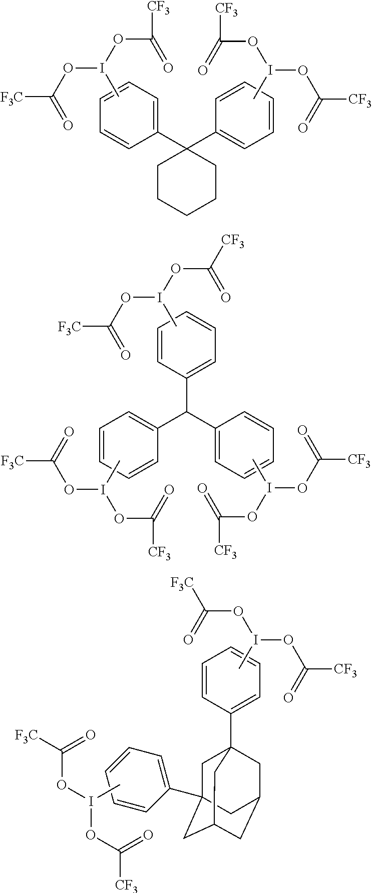

Examples of the hypervalent iodine compound having formula (4) are shown below, but not limited thereto.

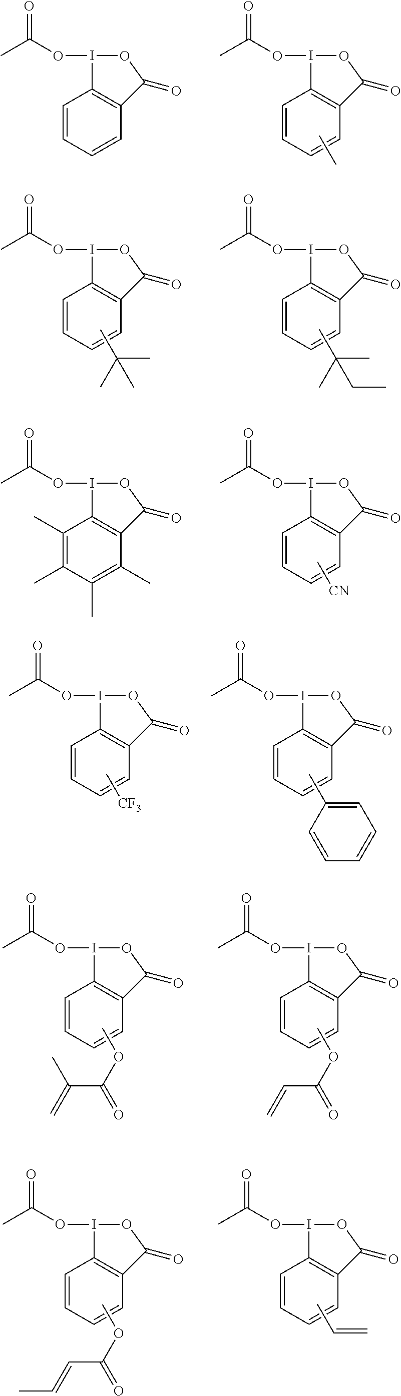

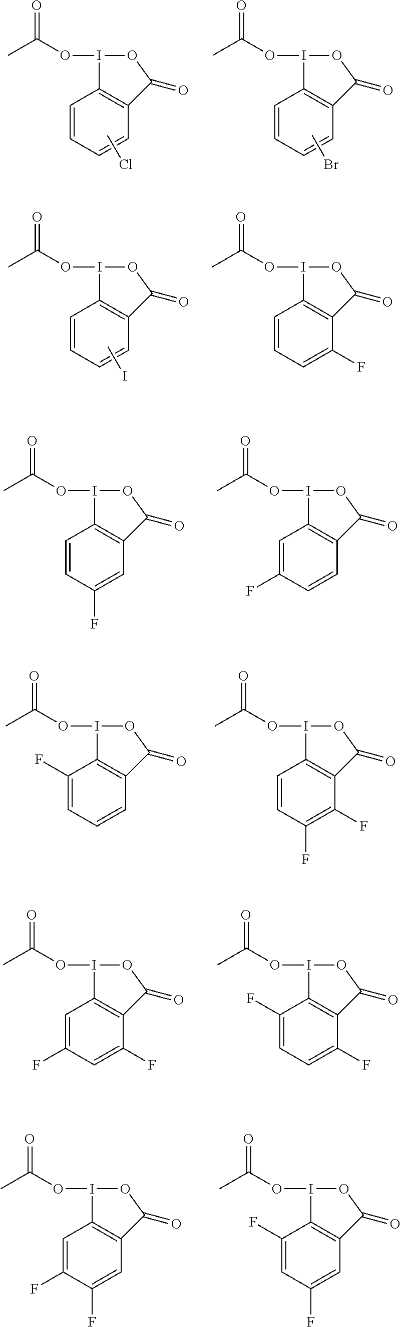

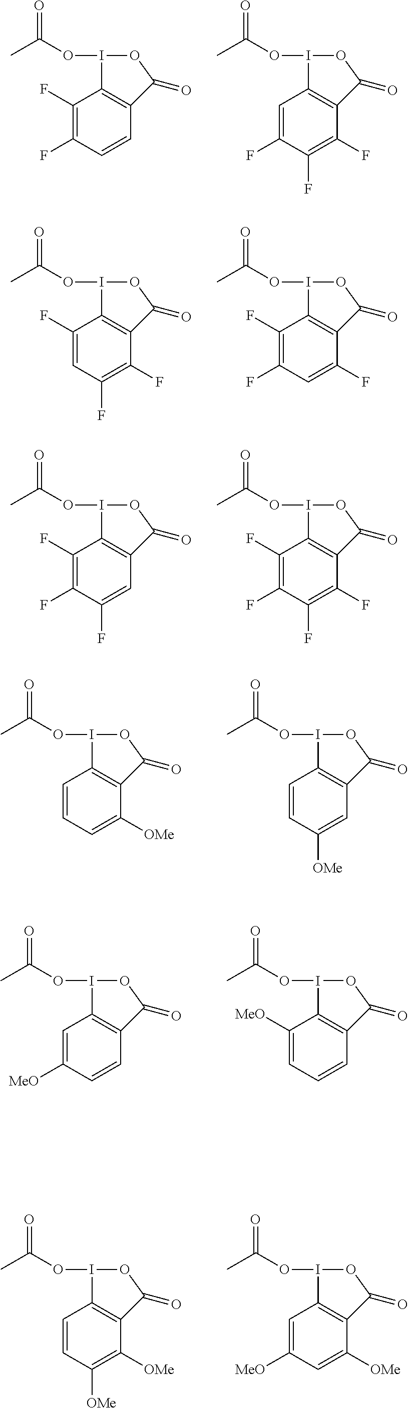

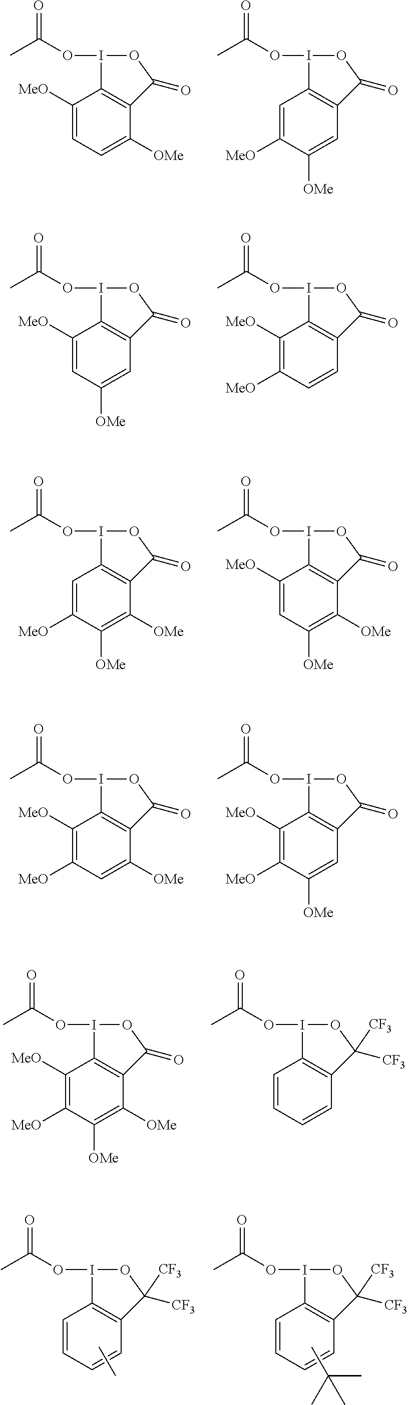

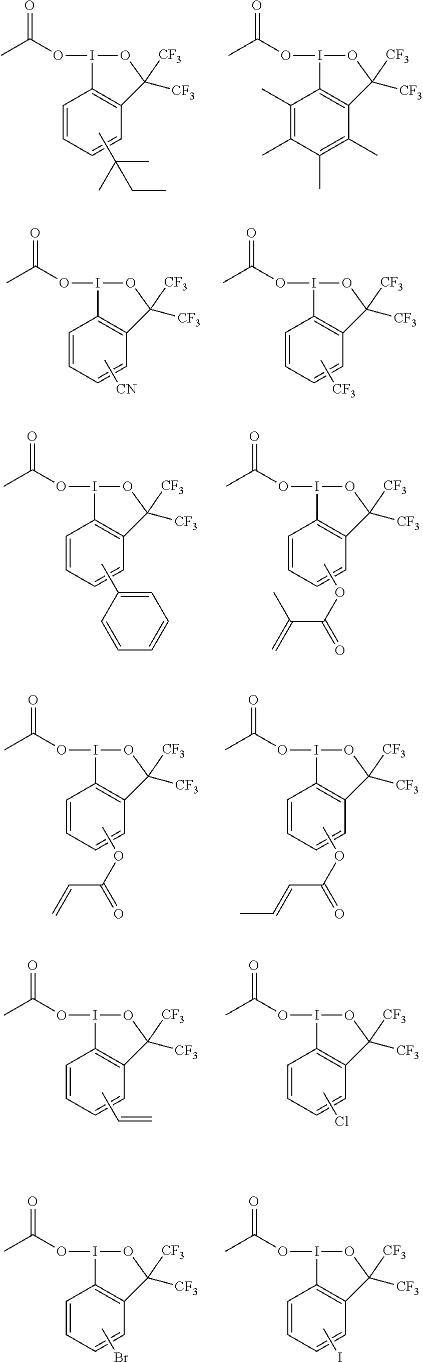

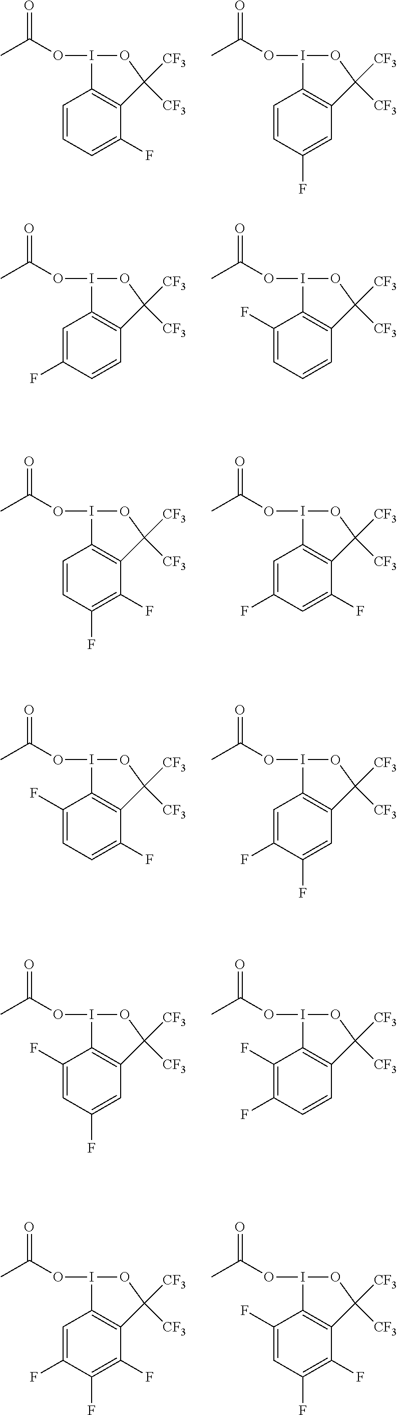

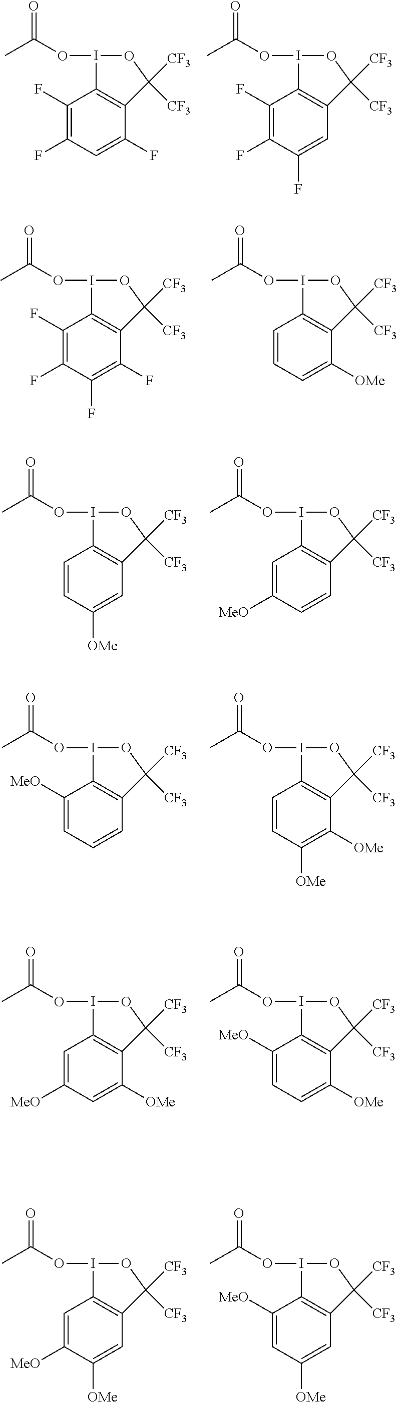

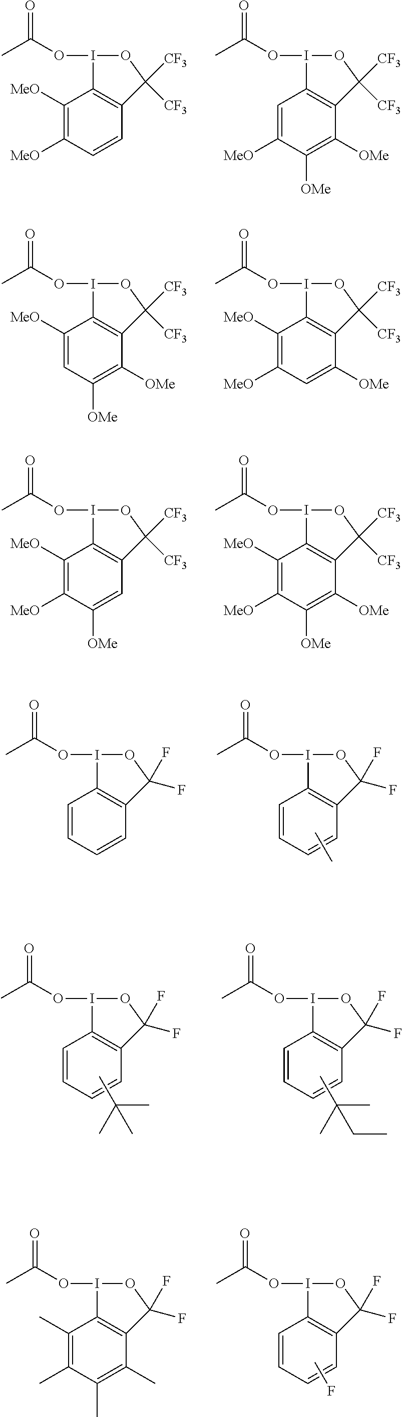

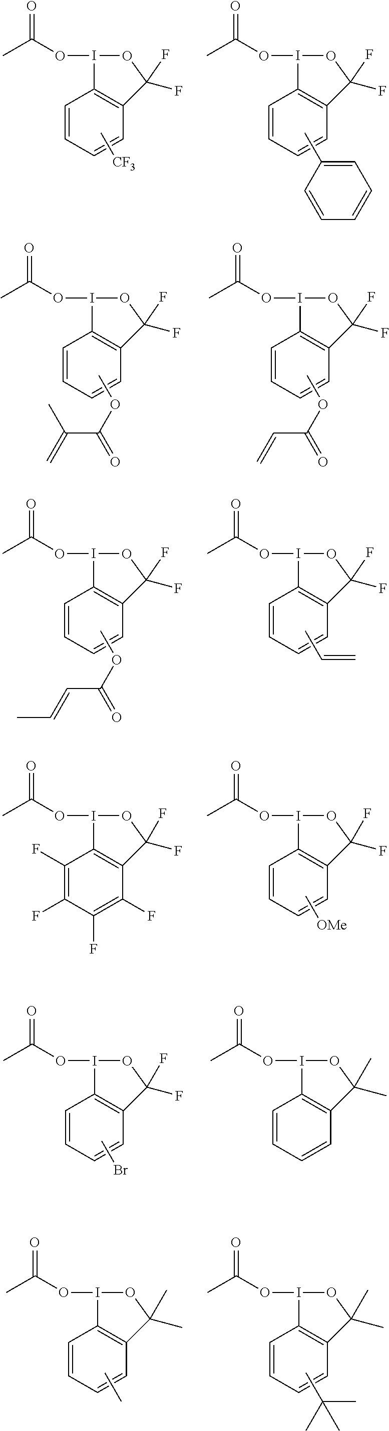

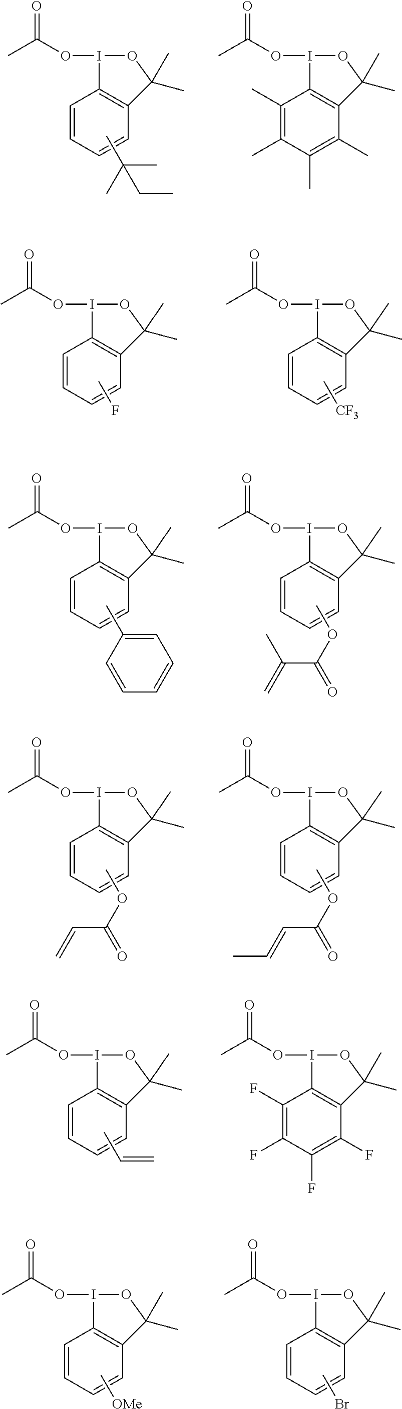

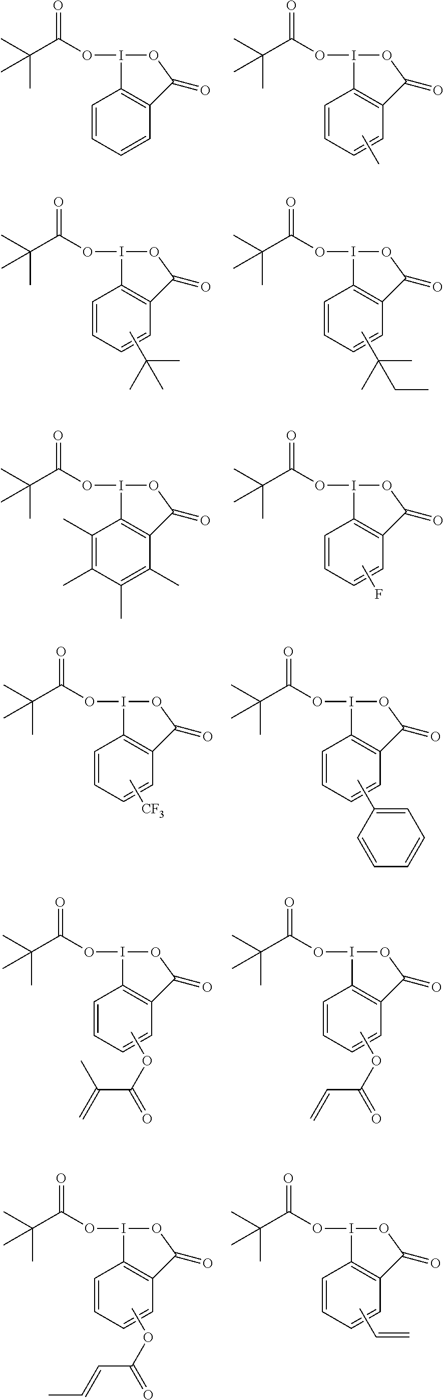

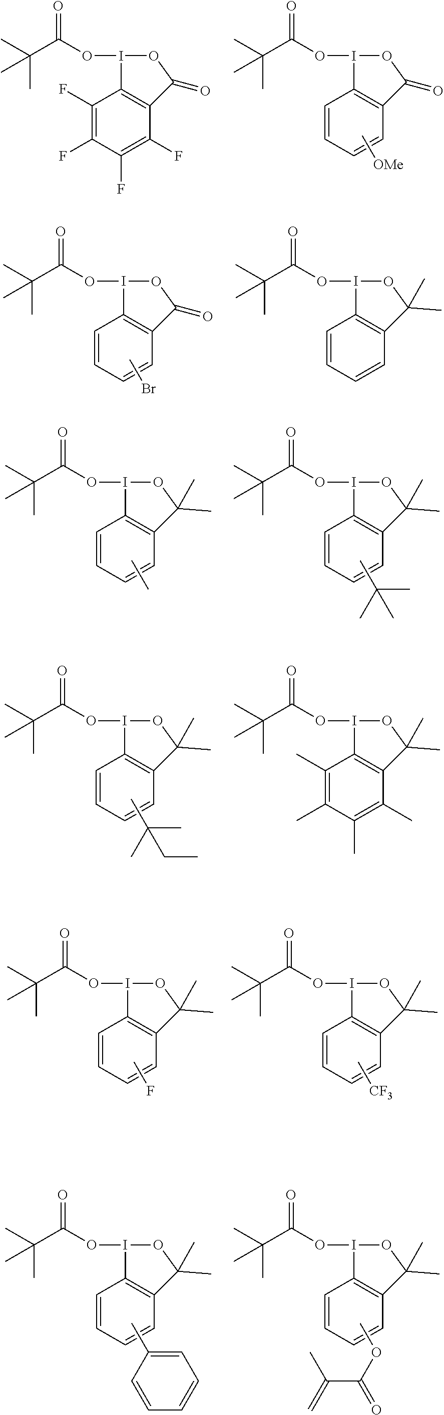

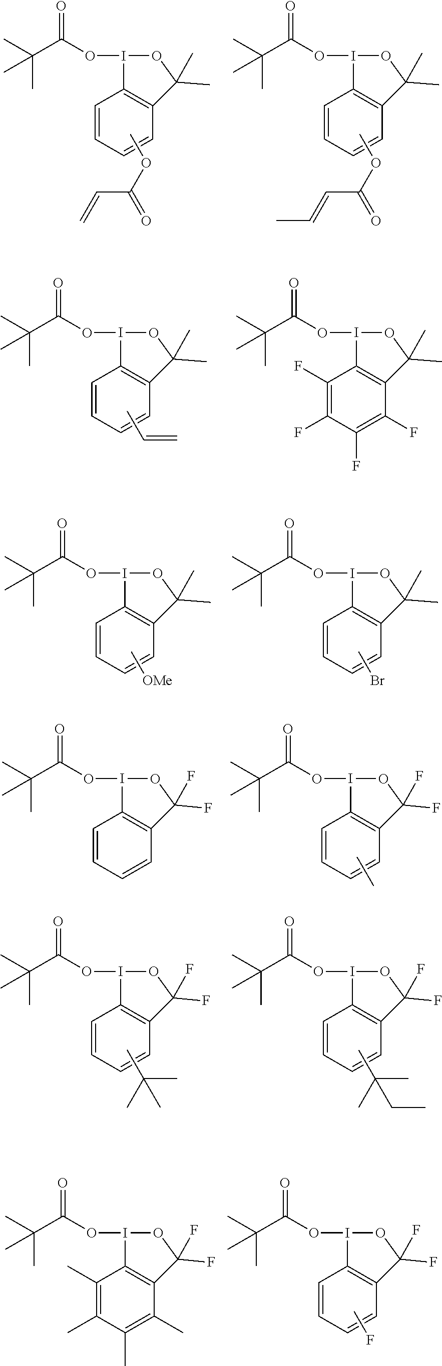

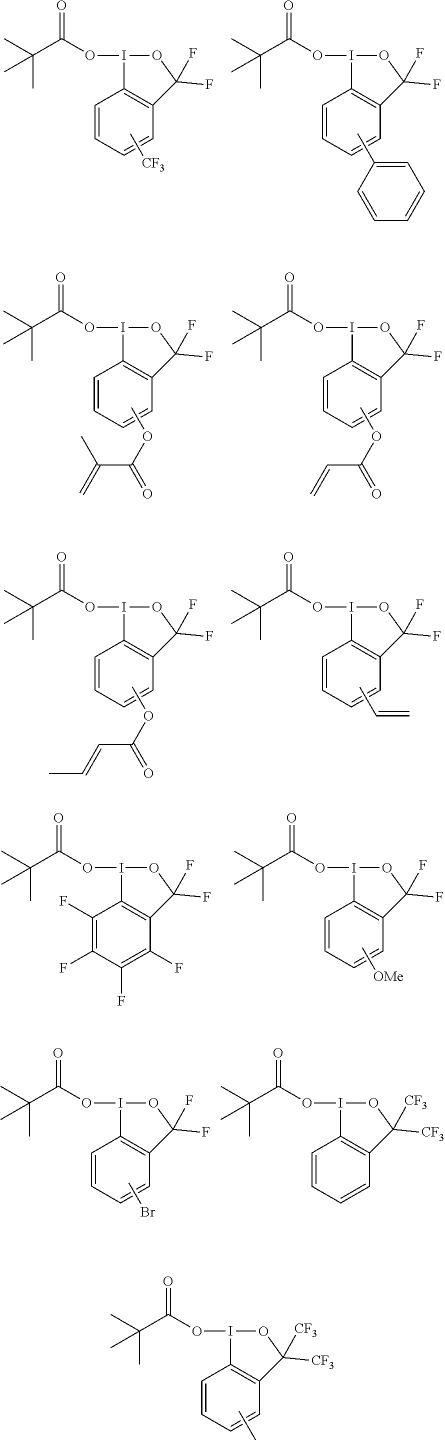

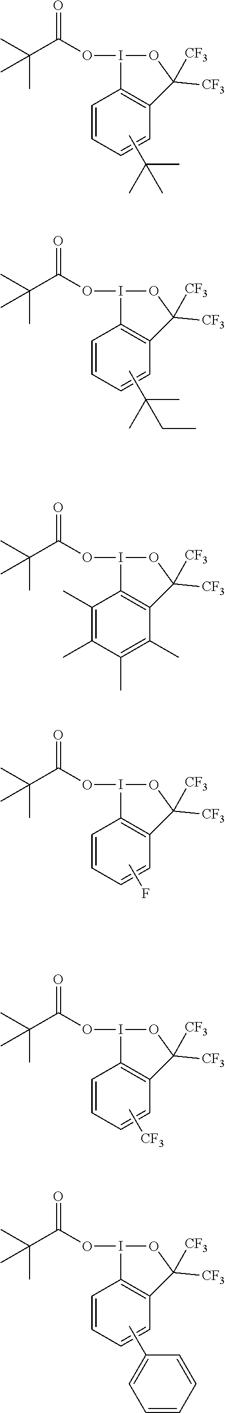

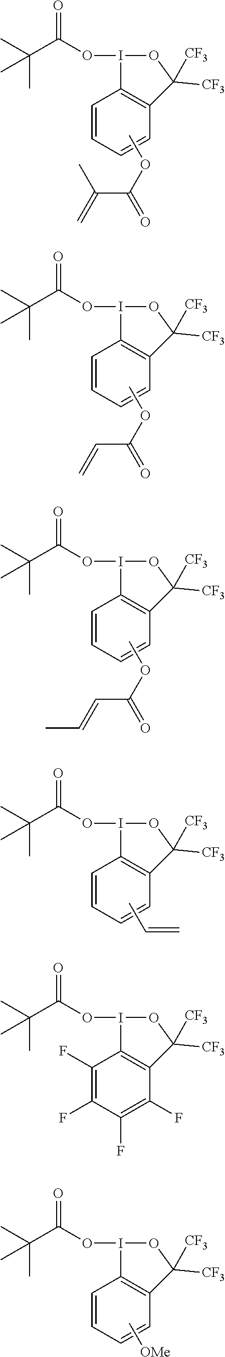

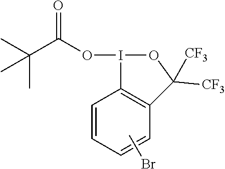

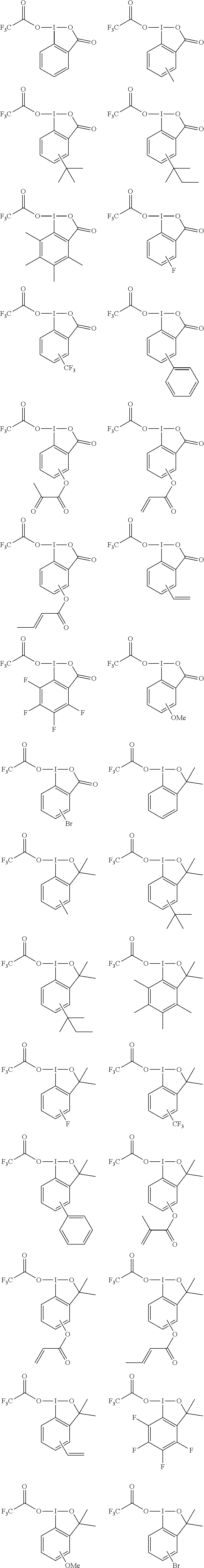

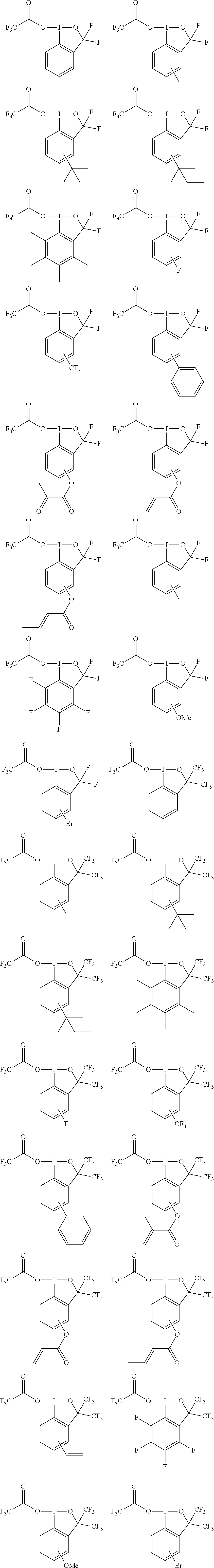

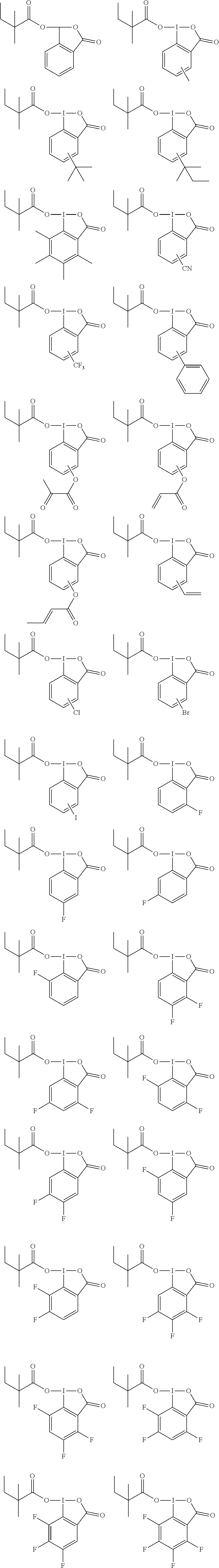

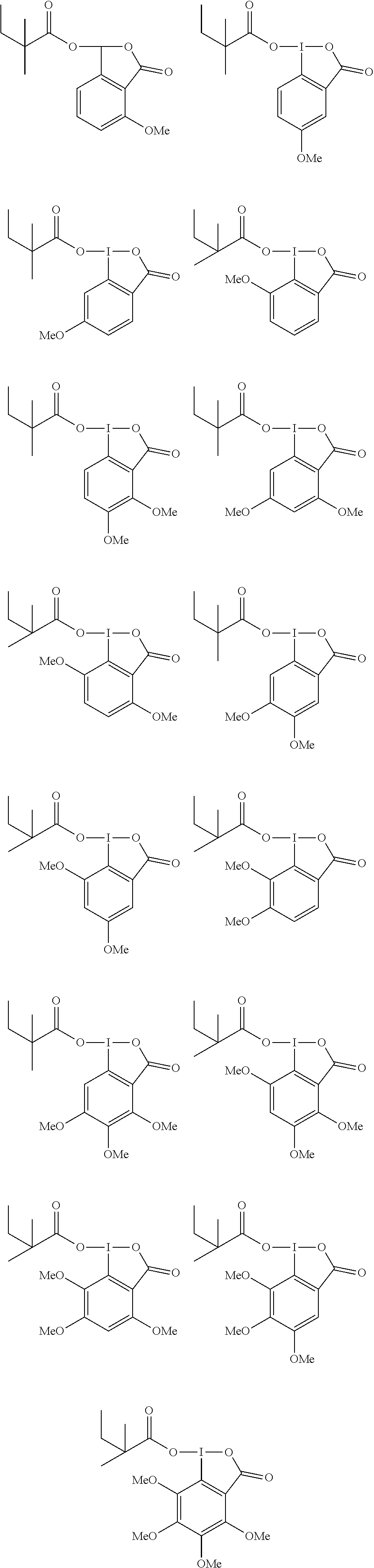

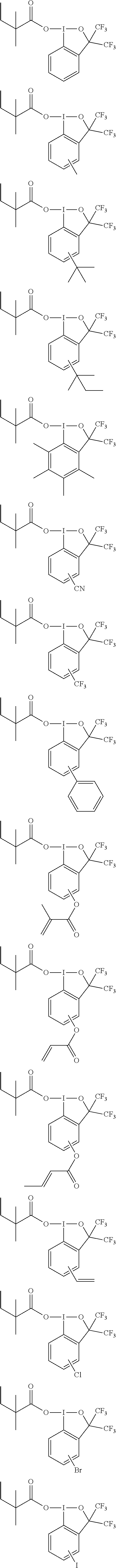

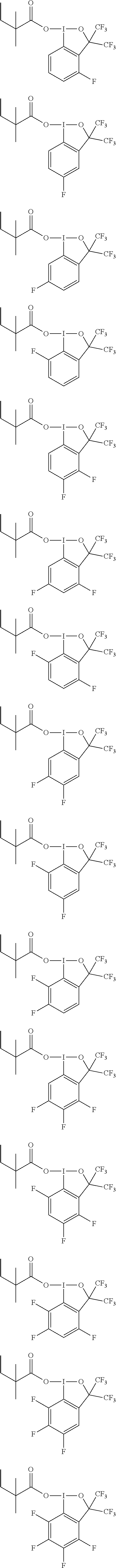

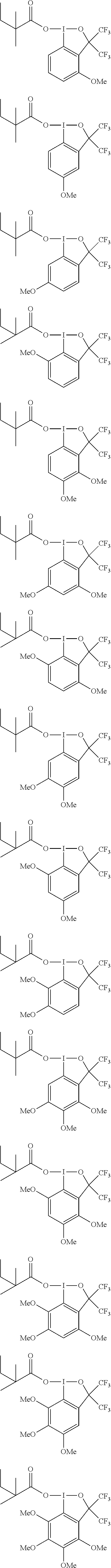

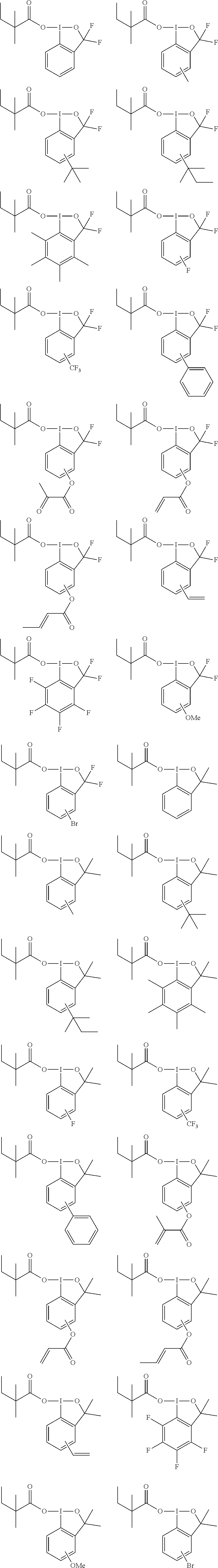

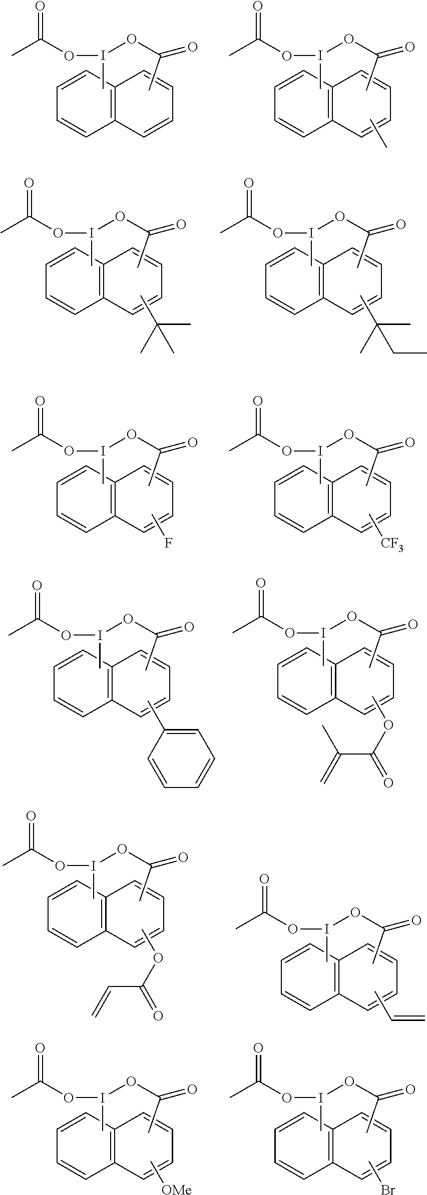

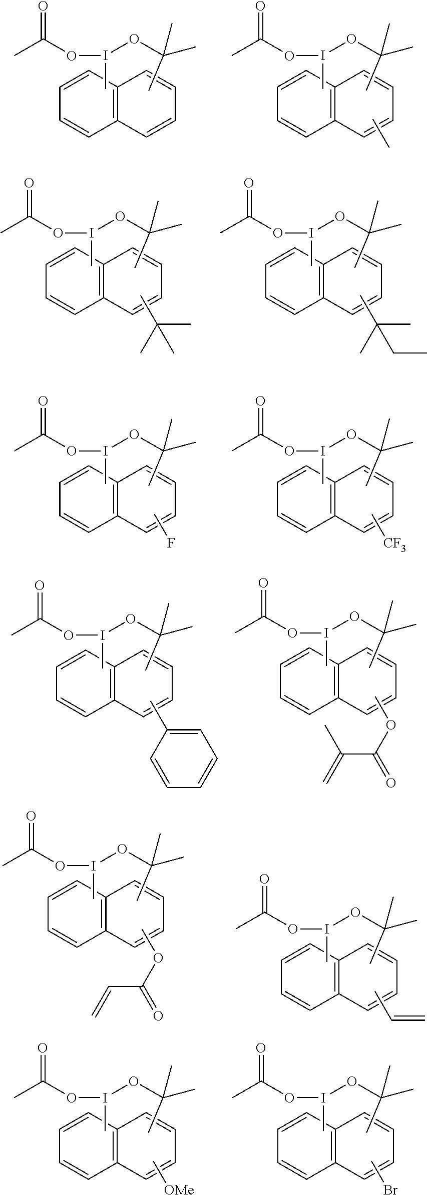

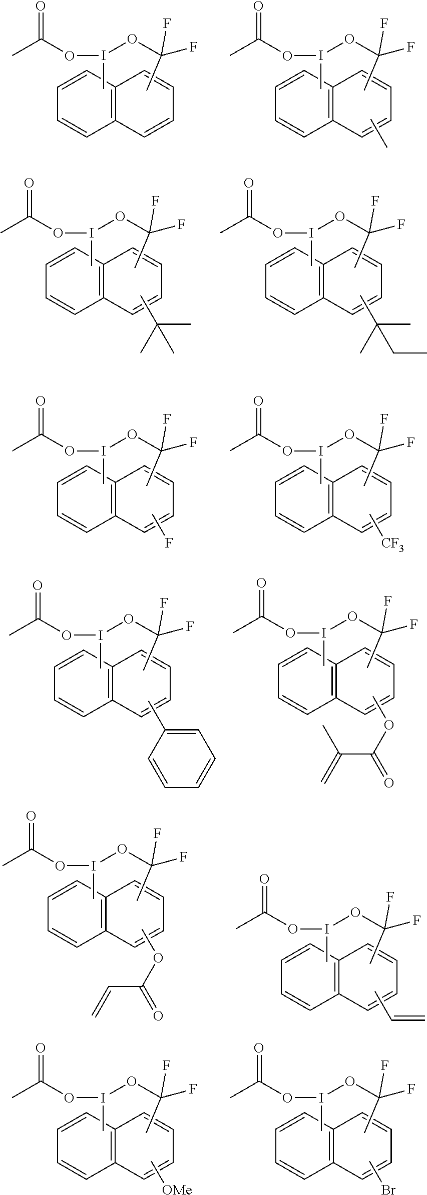

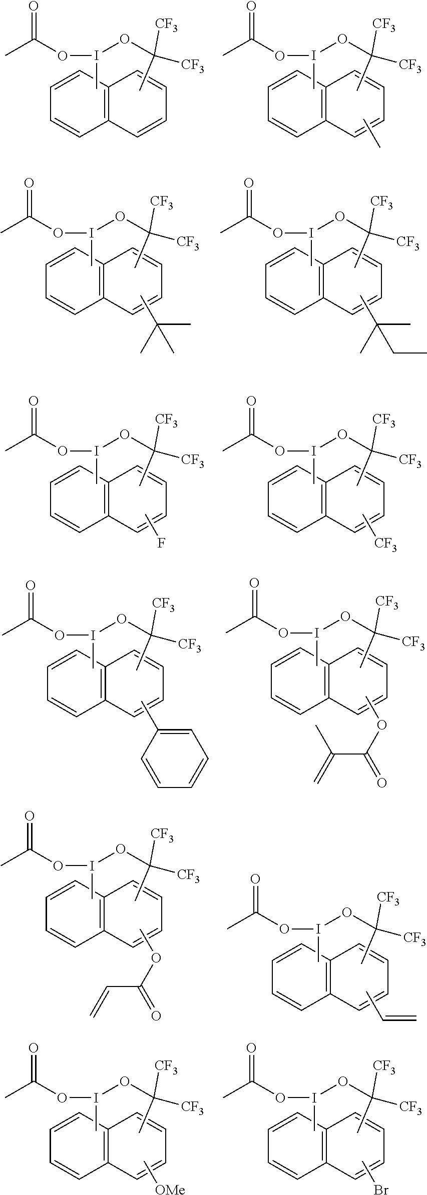

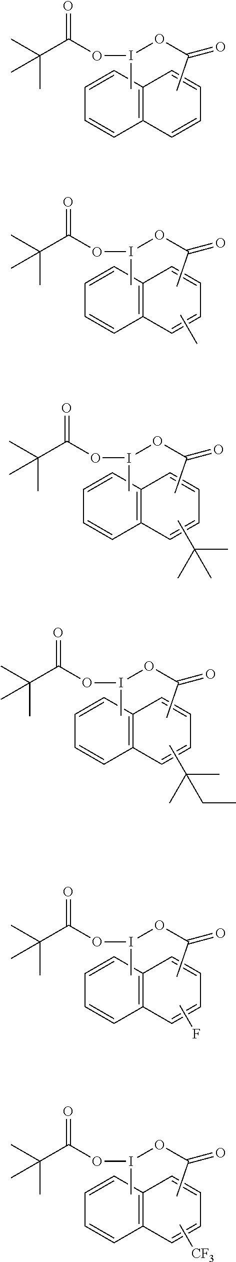

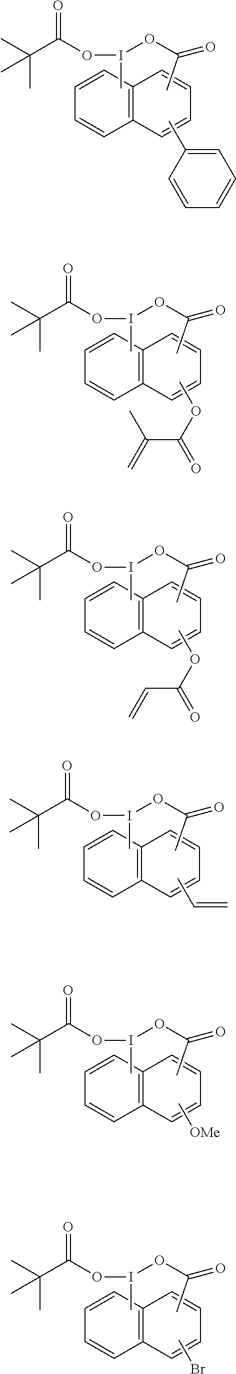

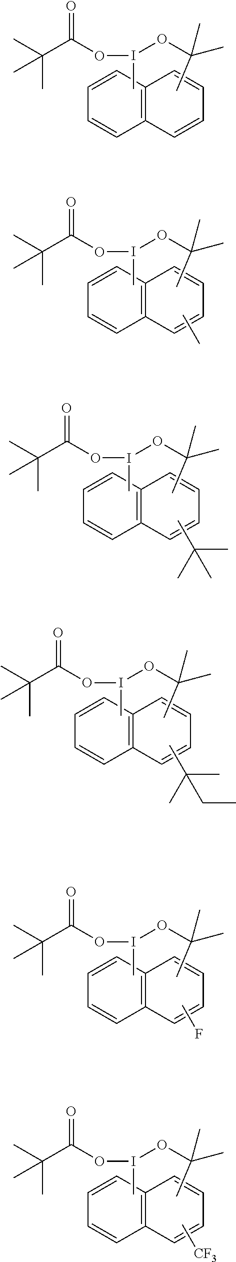

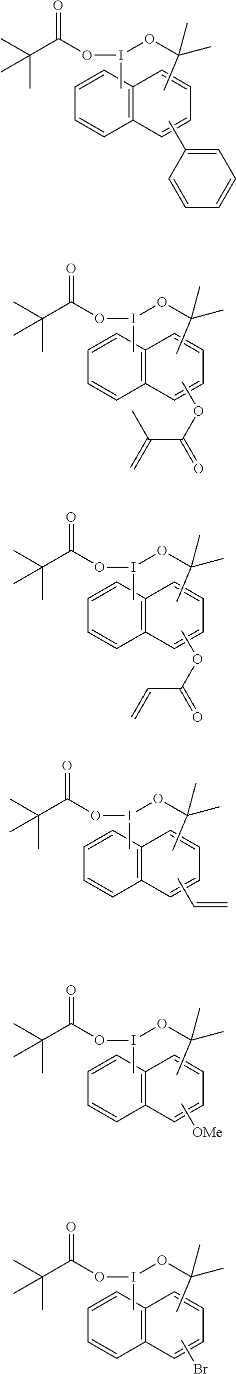

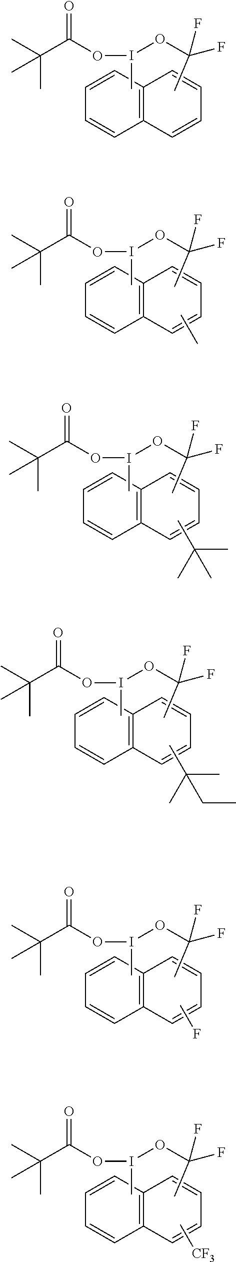

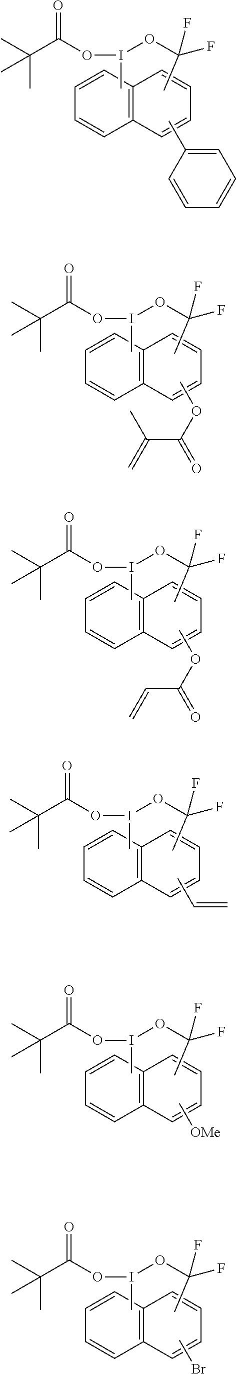

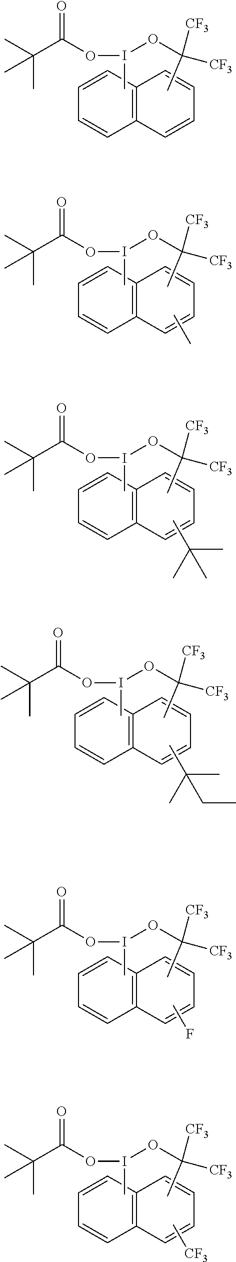

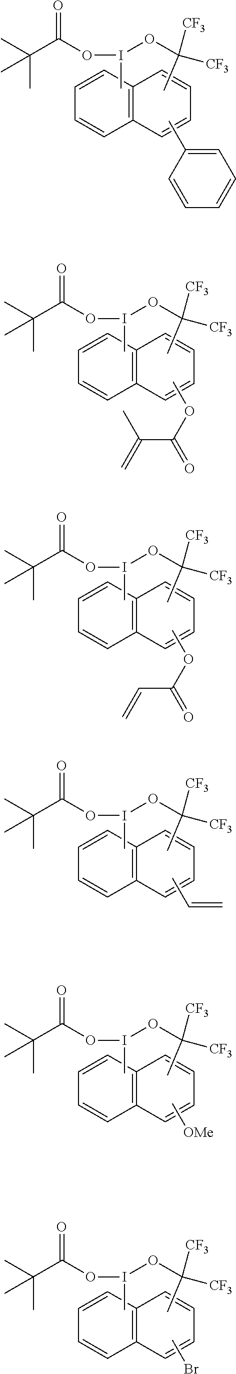

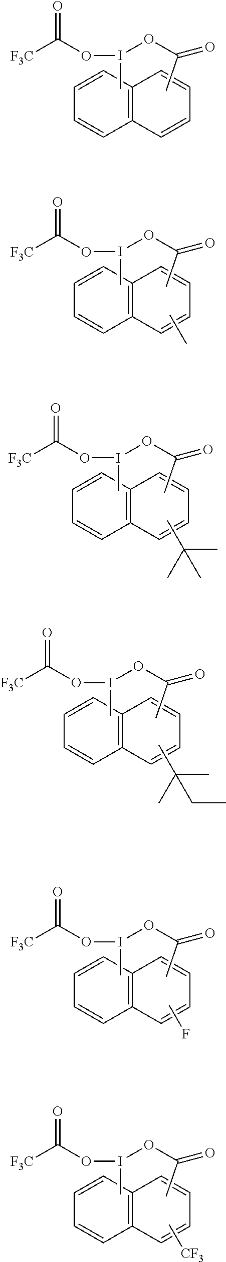

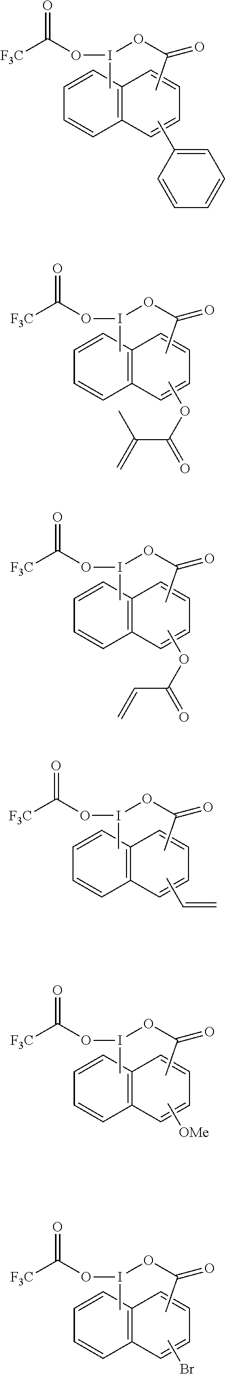

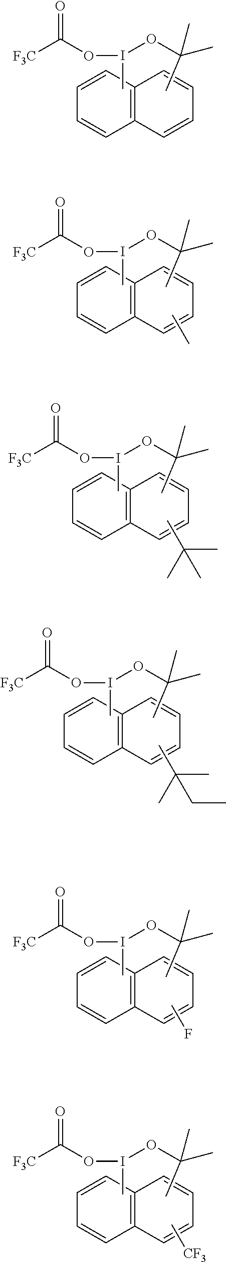

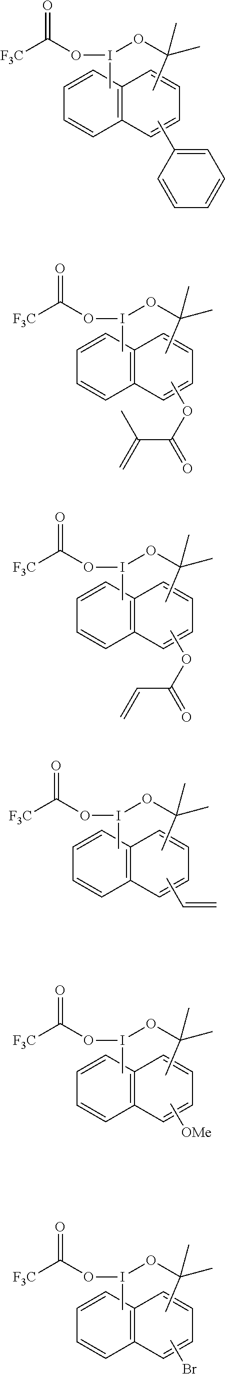

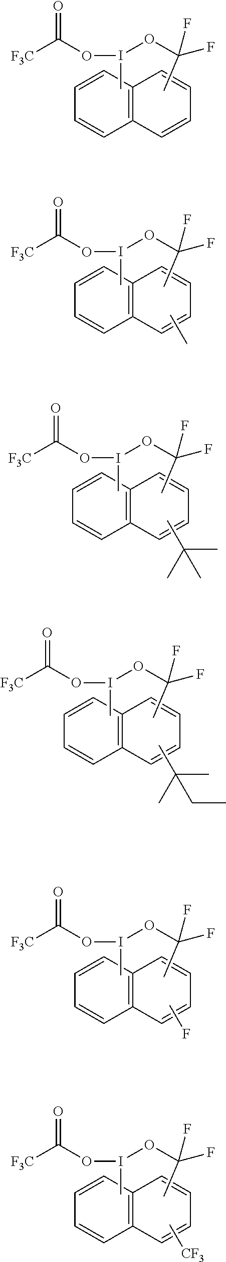

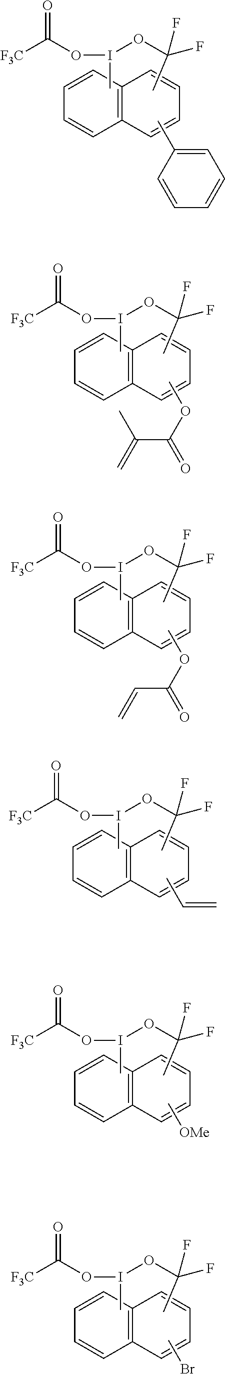

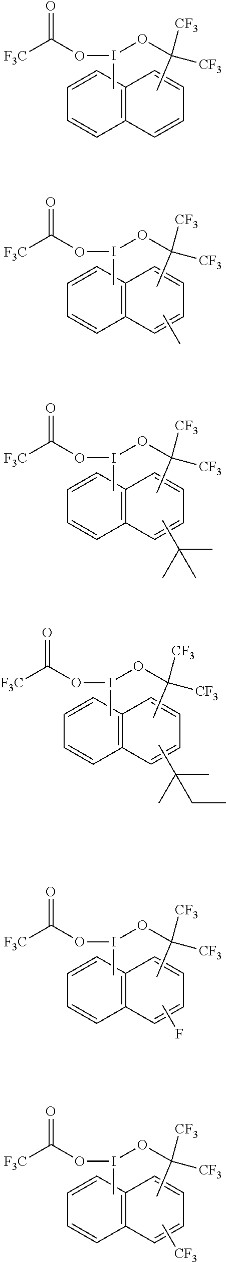

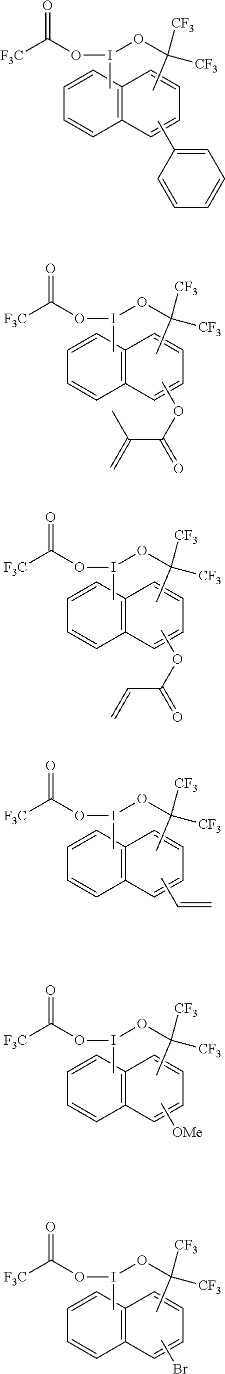

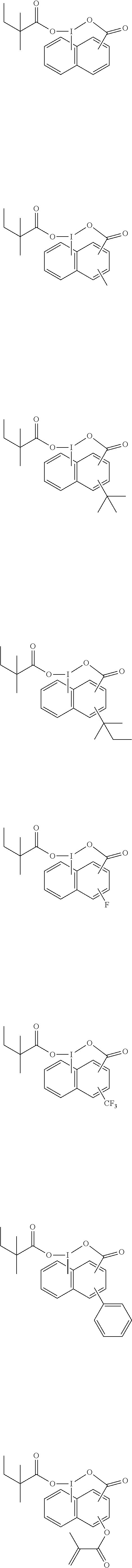

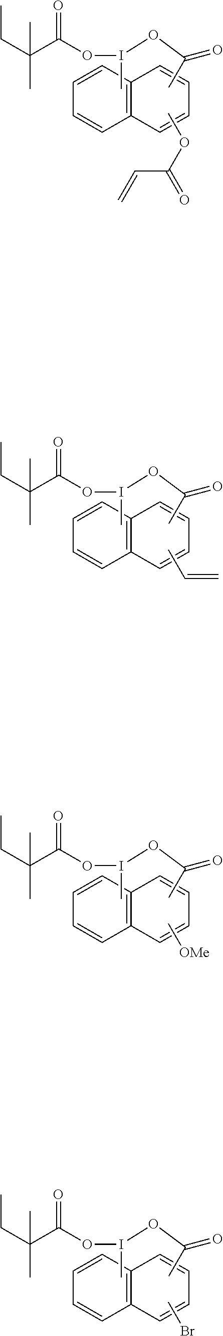

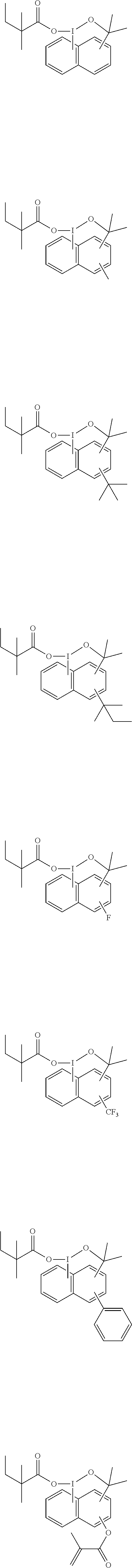

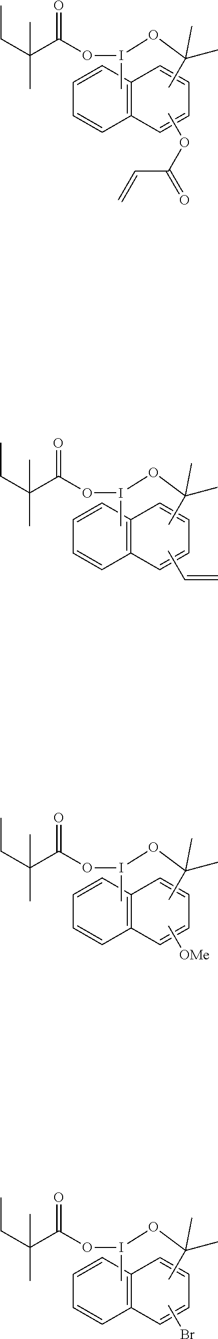

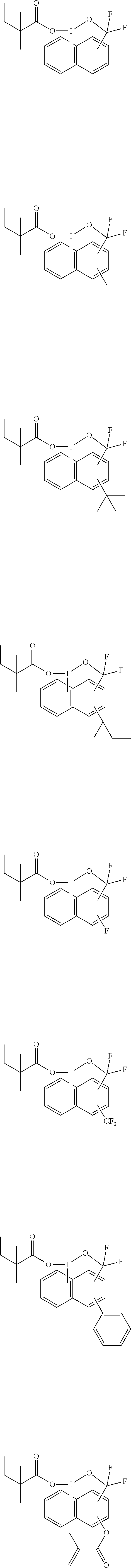

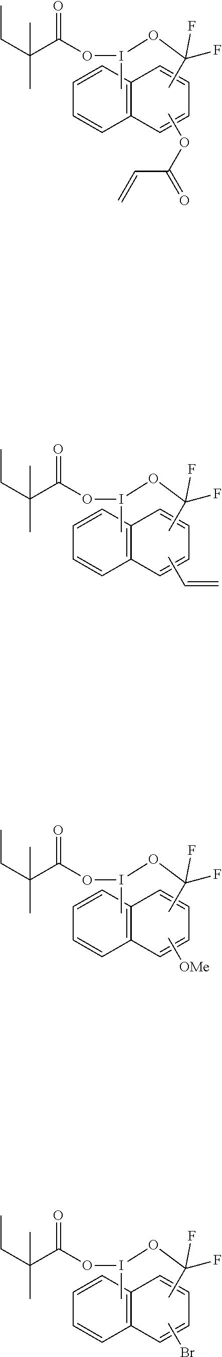

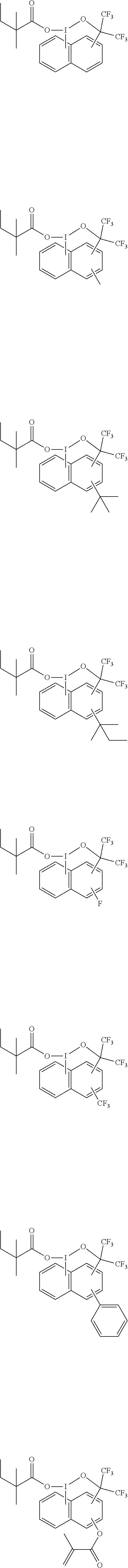

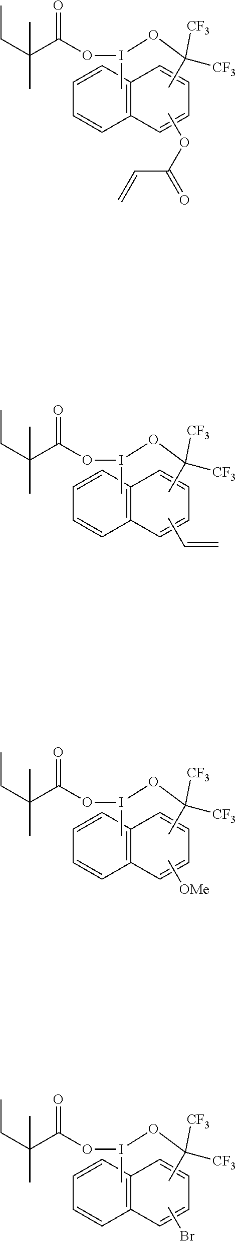

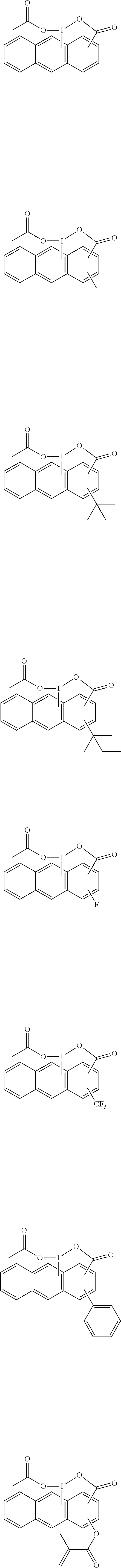

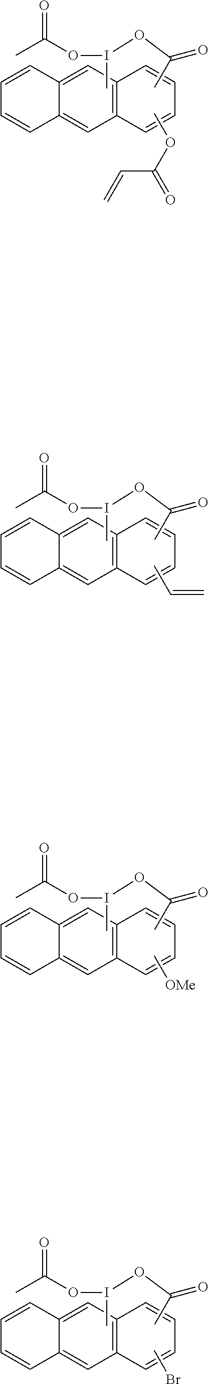

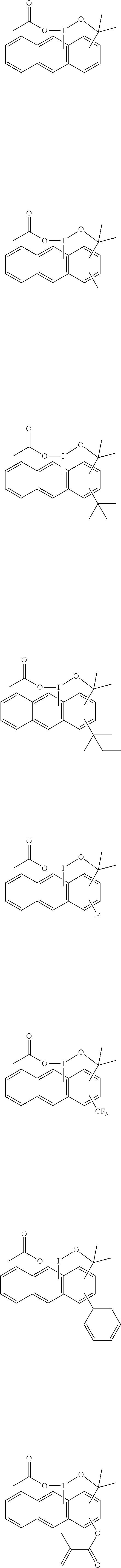

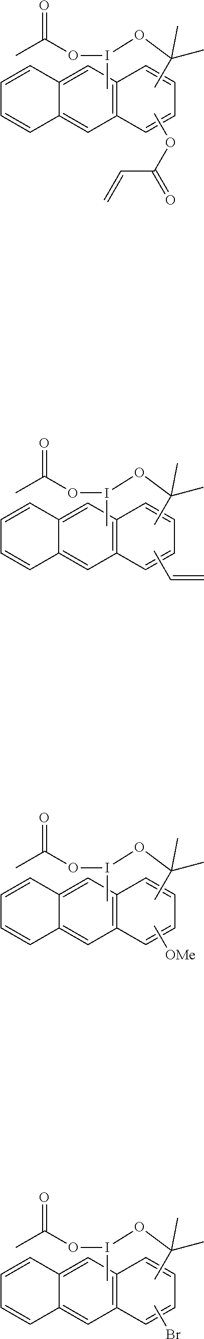

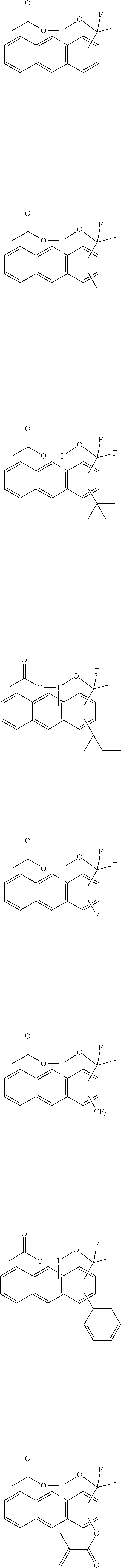

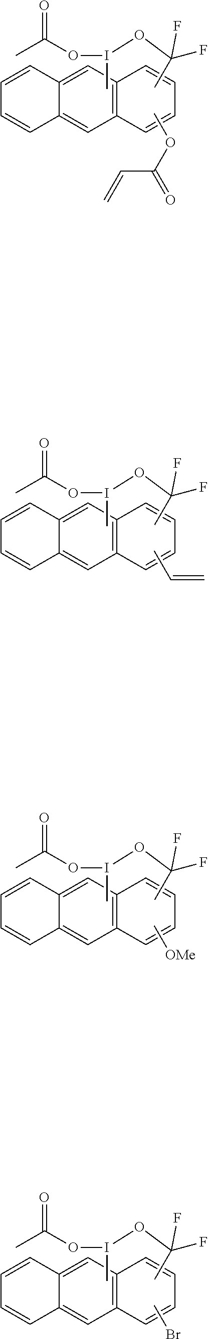

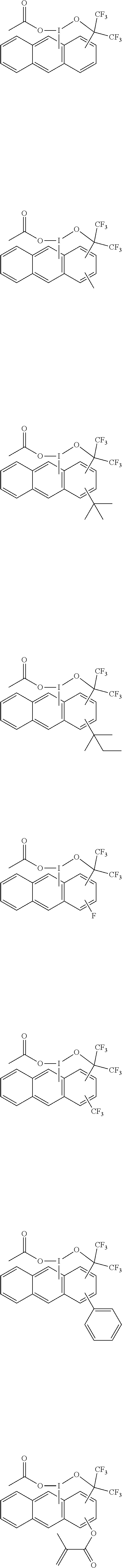

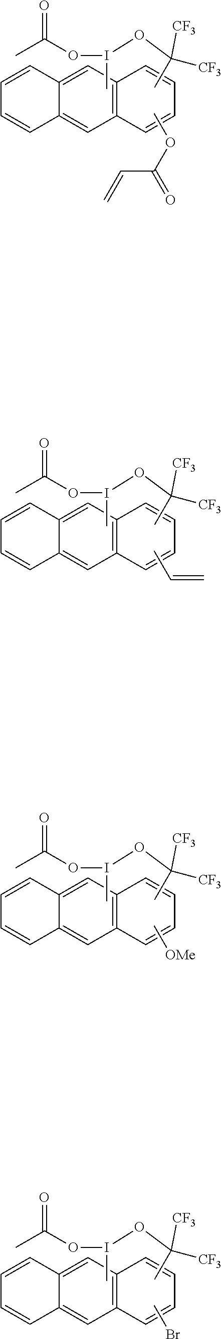

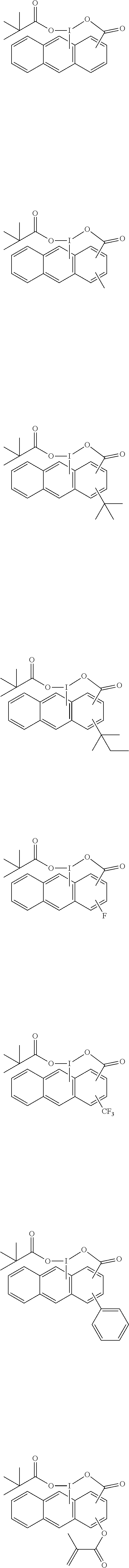

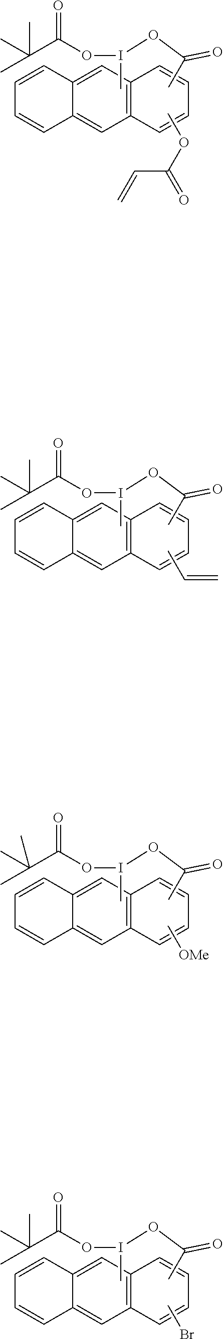

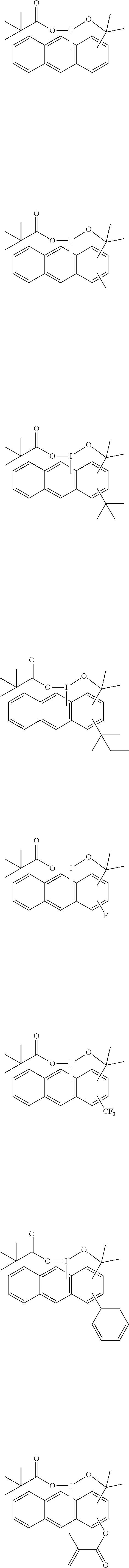

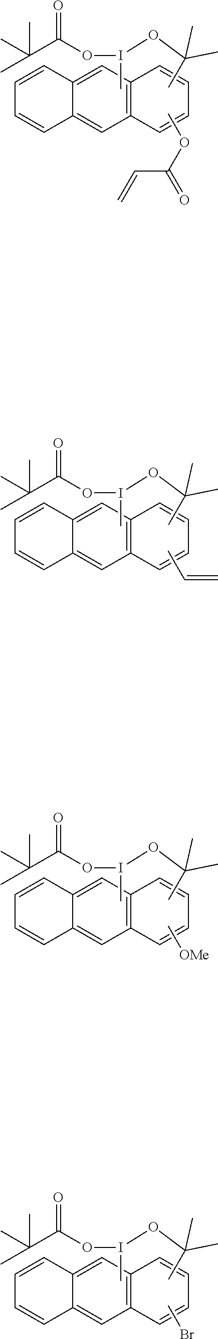

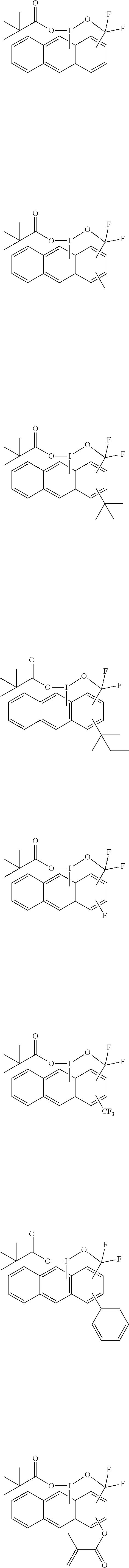

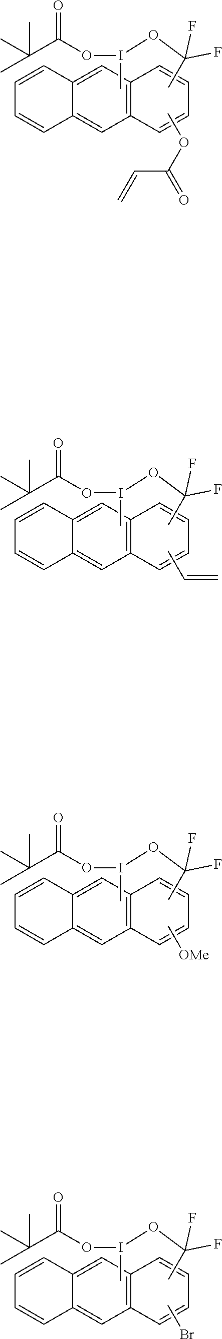

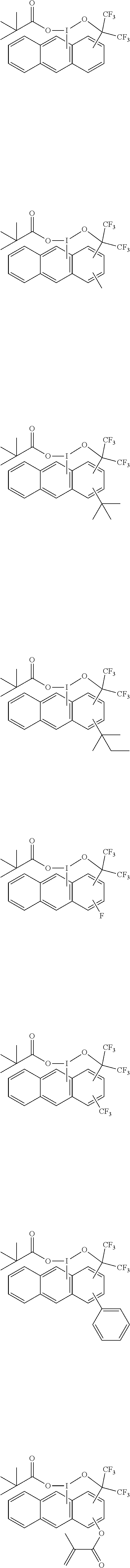

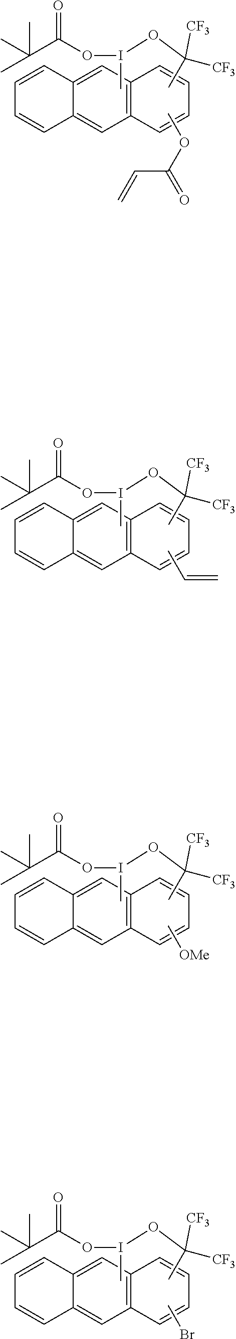

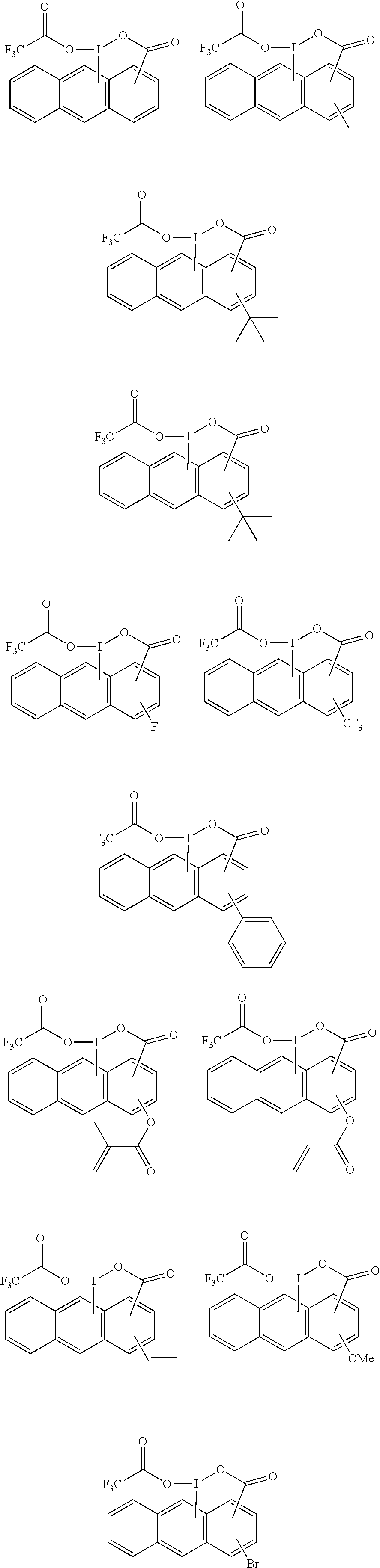

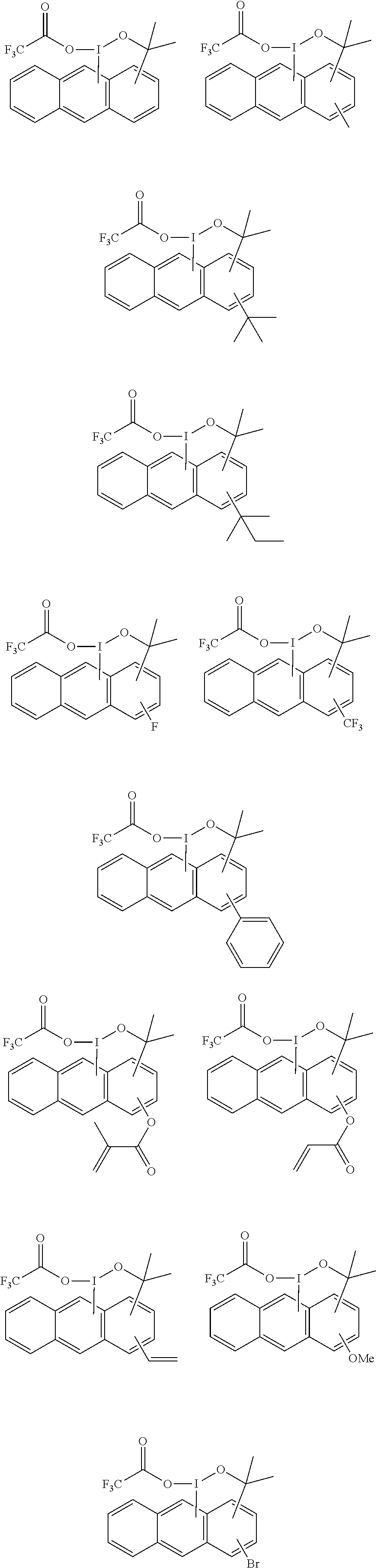

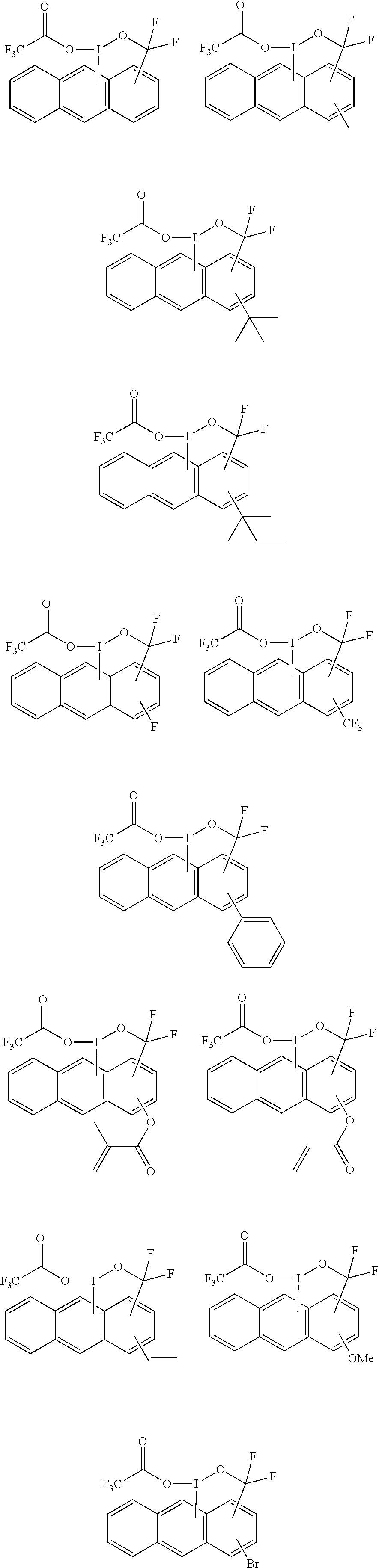

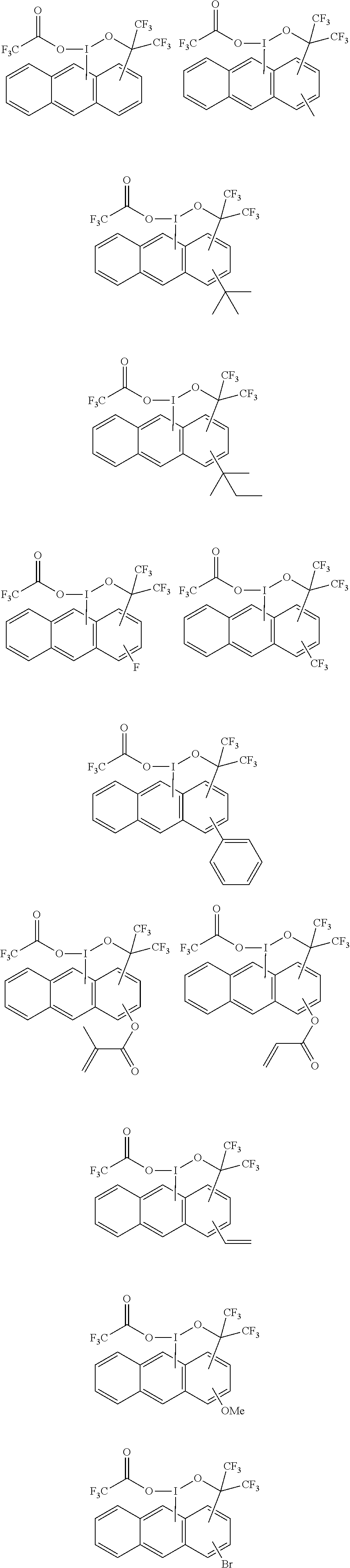

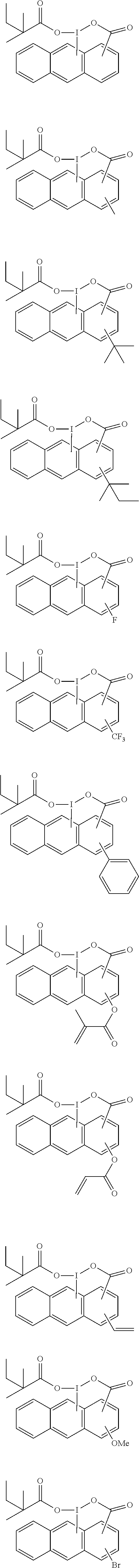

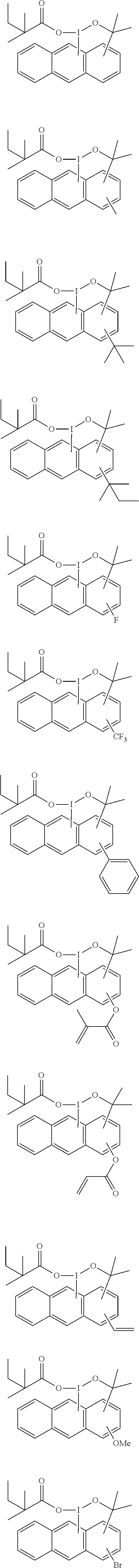

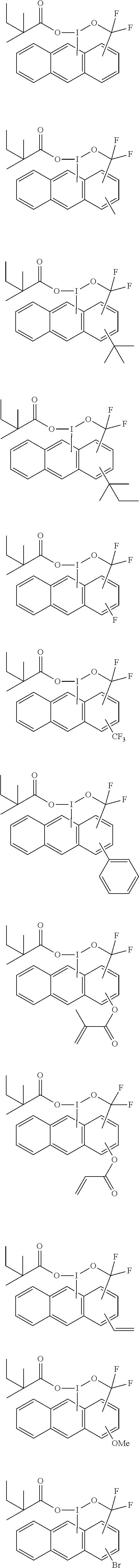

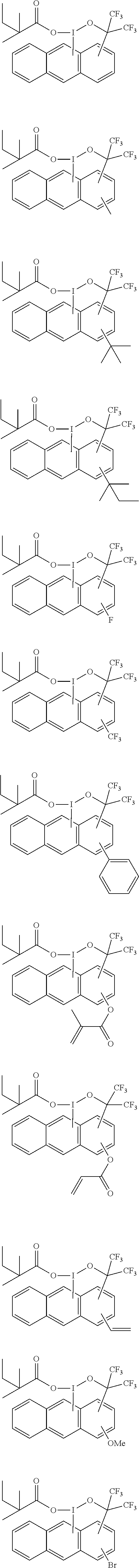

### Onium Salt

The onium salt compound contains a sulfonium cation having the formula (5-1) or iodonium cation having the formula (5-2).

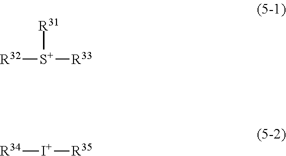

In formulae (5-1) and (5-2), R³¹ to R³⁵ are each independently halogen or a C₁-C₃₀ hydrocarbyl group which may contain a heteroatom.

Suitable halogen atoms include fluorine, chlorine, bromine, and iodine.

The hydrocarbyl group may be saturated or unsaturated and straight, branched or cyclic. Examples thereof include C₁-C₃₀ alkyl groups such as methyl, ethyl, n-propyl, isopropyl, n-butyl, isobutyl, sec-butyl, and tert-butyl; C₃-C₃₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₃₀ alkenyl groups such as vinyl, allyl, propenyl, butenyl, and hexenyl; C₃-C₃₀ cyclic unsaturated hydrocarbyl groups such as cyclohexenyl; C₆-C₃₀ aryl groups such as phenyl, naphthyl, and thienyl; C₇-C₃₀ aralkyl groups such as benzyl, 1-phenylethyl, and 2-phenylethyl, and combinations thereof. Of these, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

R³¹ and R³² may bond together to form a ring with the sulfur atom to which they are attached. Examples of the ring are shown below.

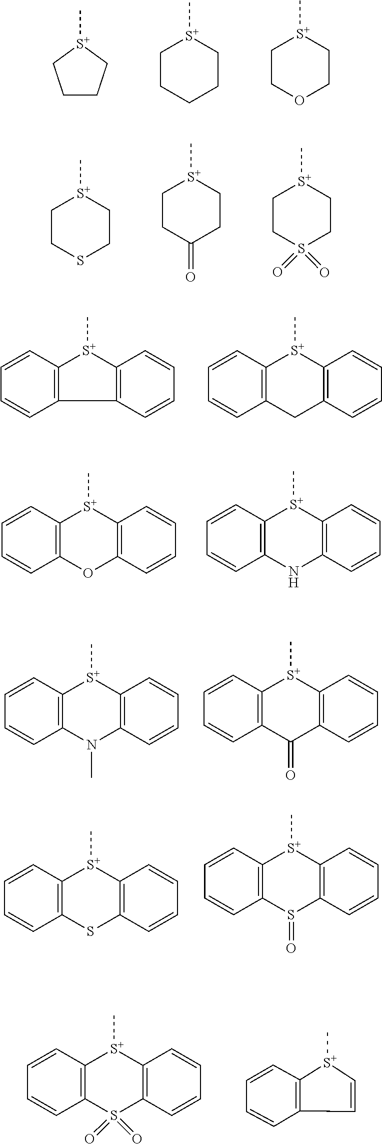

Herein the broken line designates a point of attachment to R³³.

Examples of the sulfonium cation having formula (5-1) are shown below, but not limited thereto.

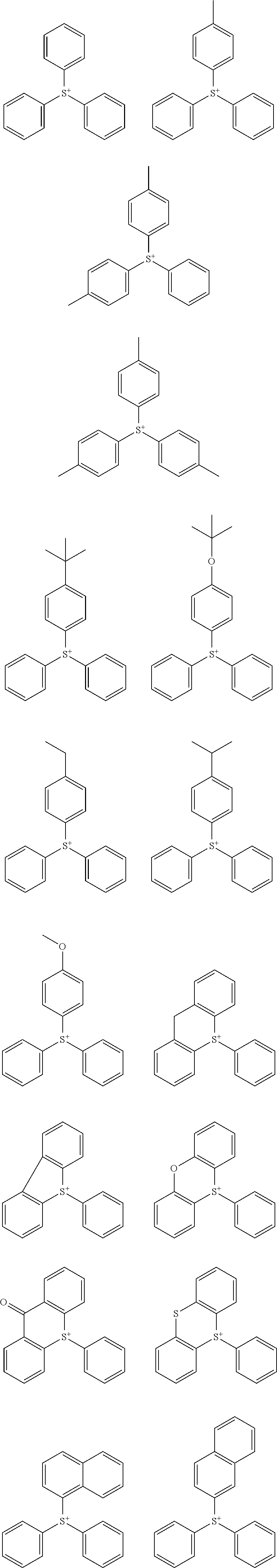

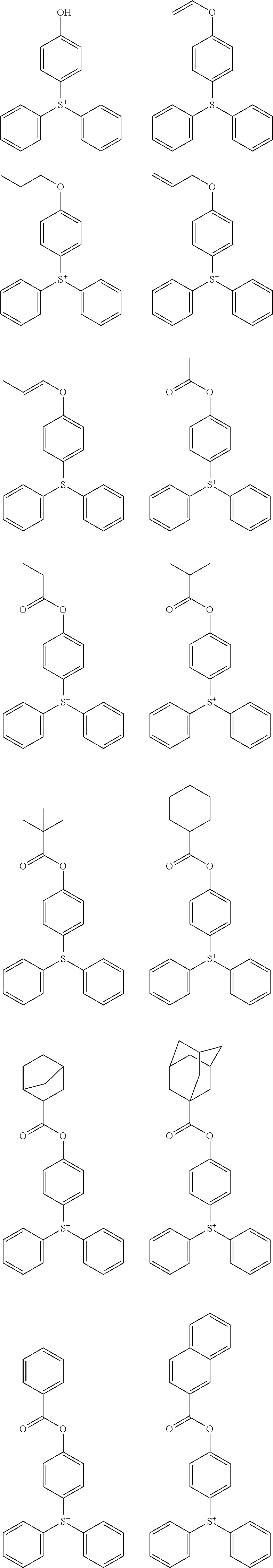

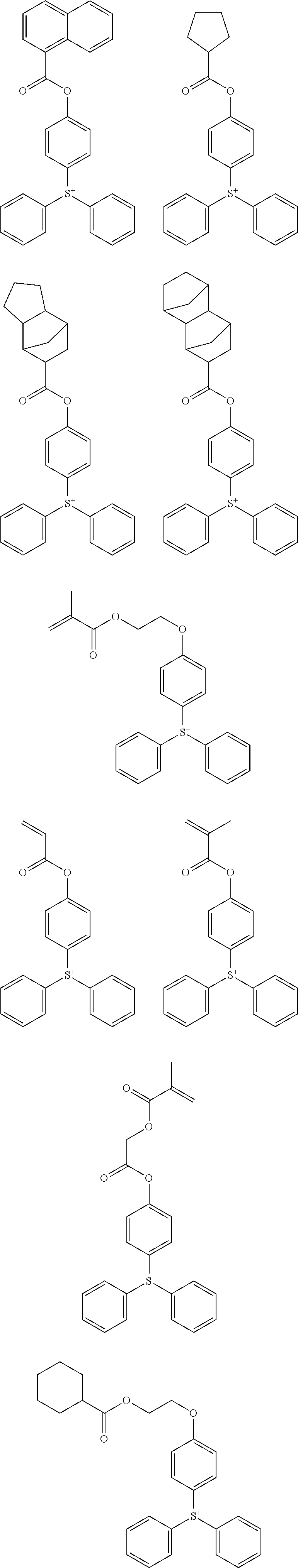

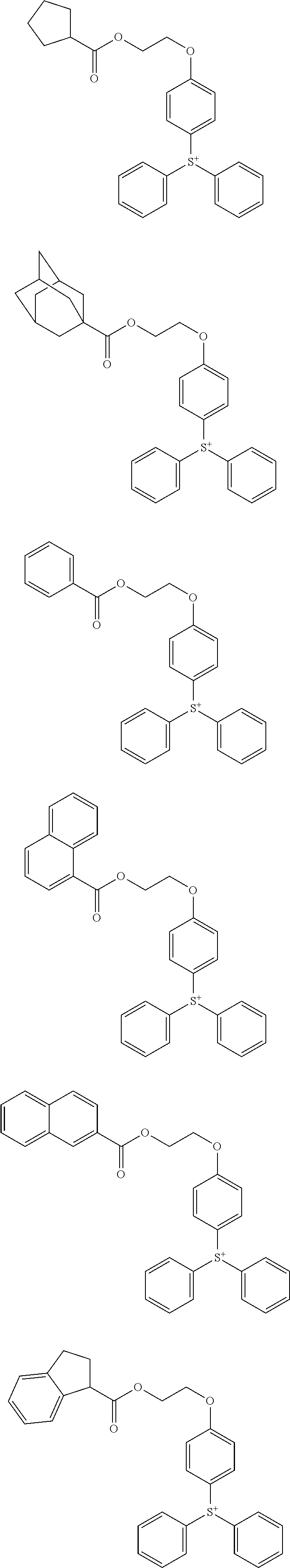 [SMILES: O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

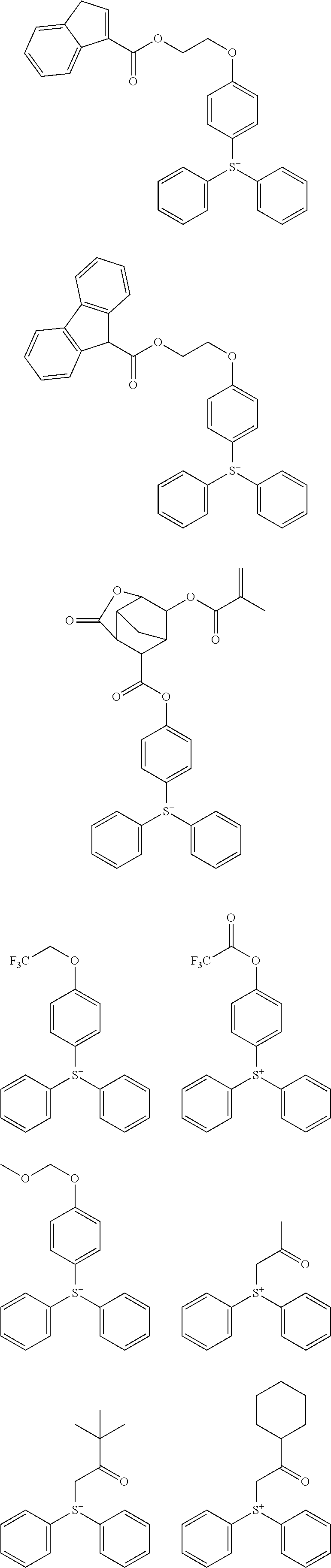

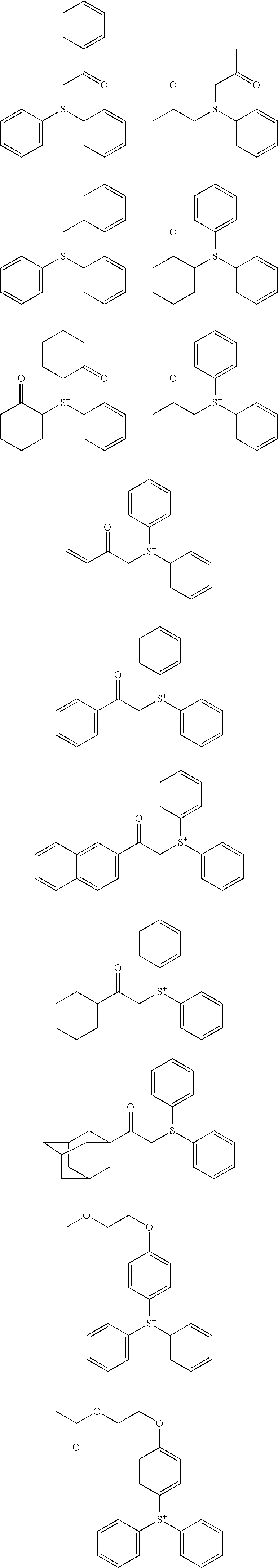

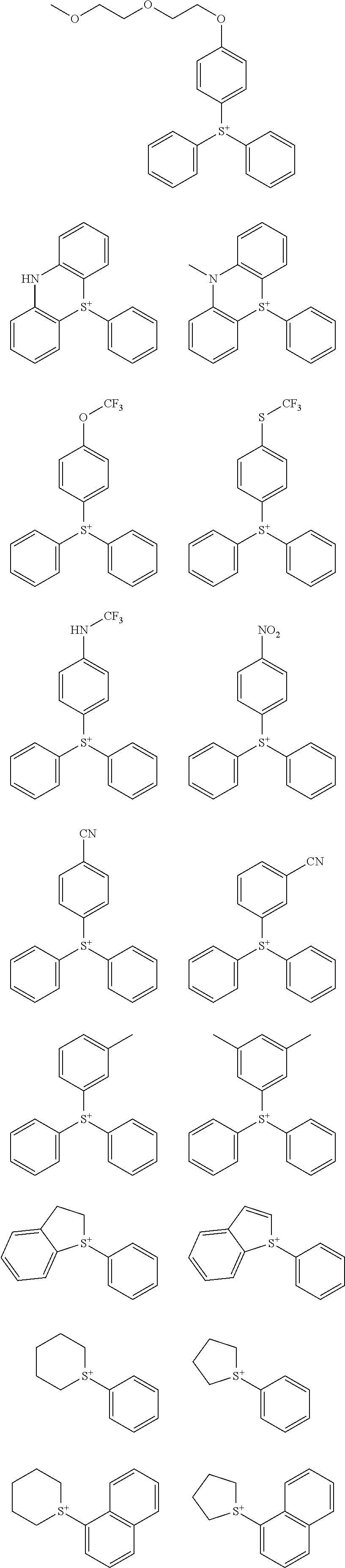

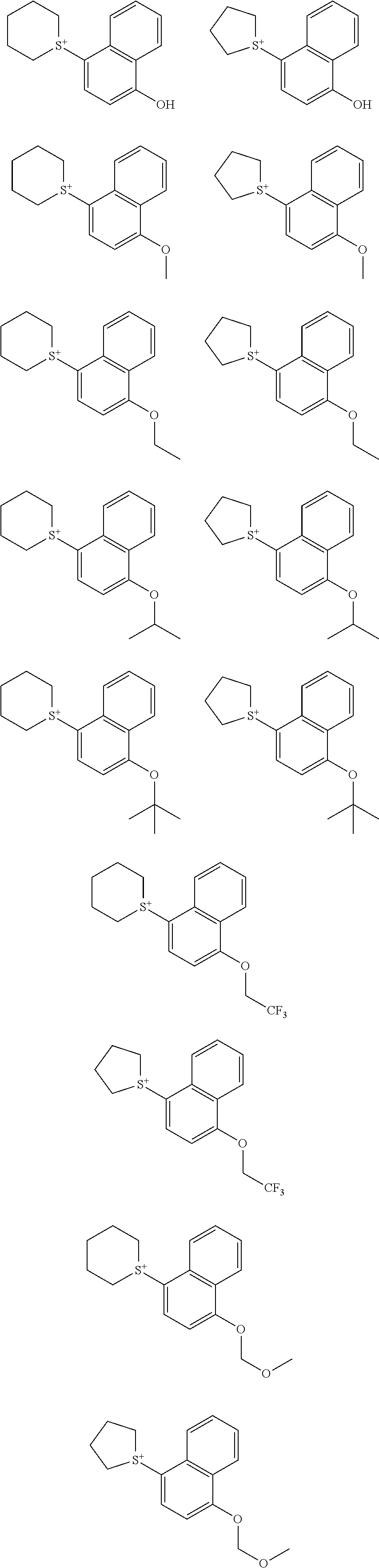

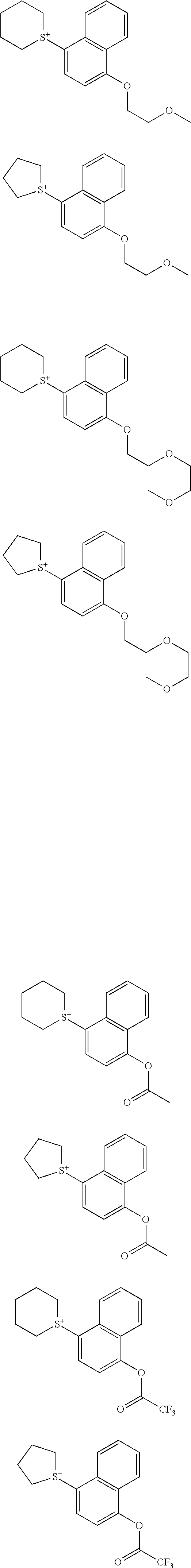

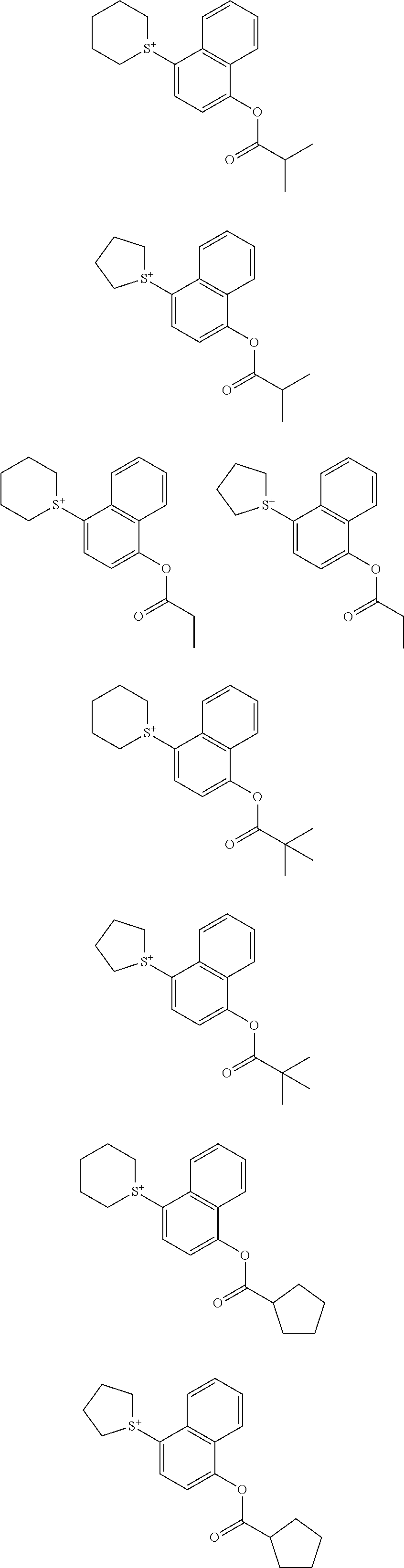

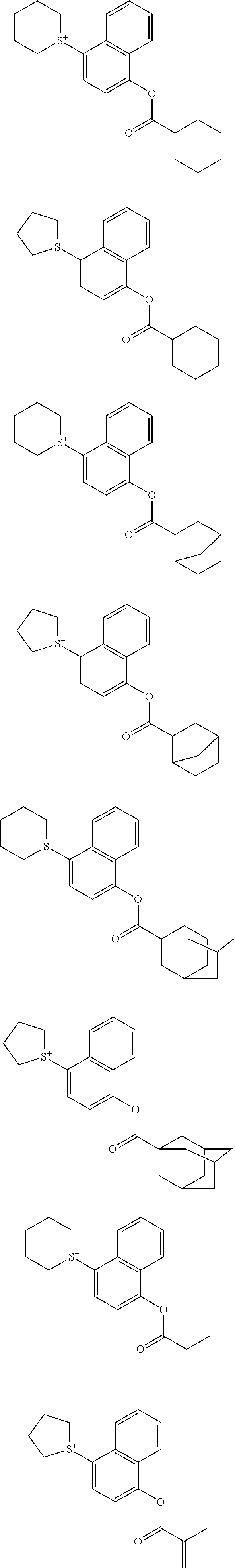

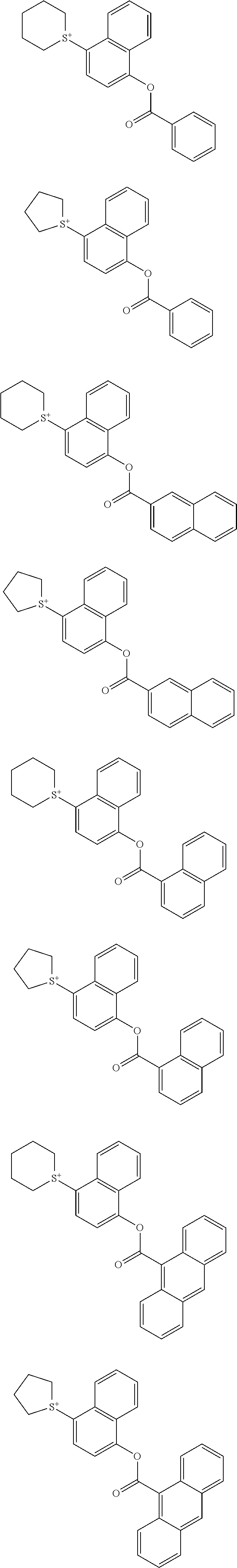

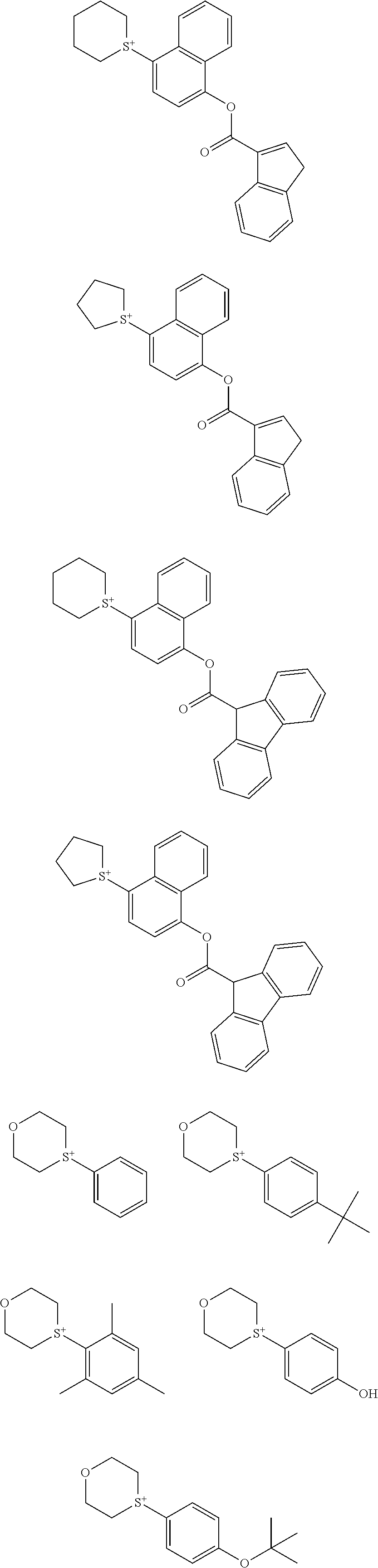

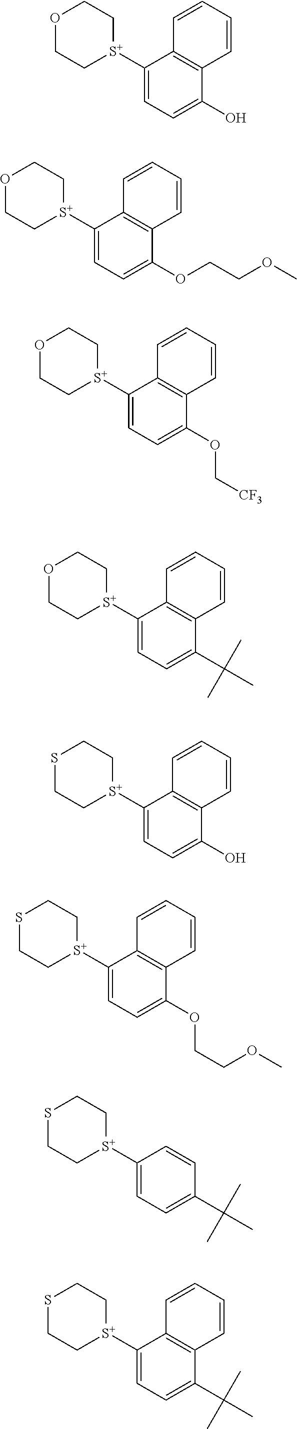

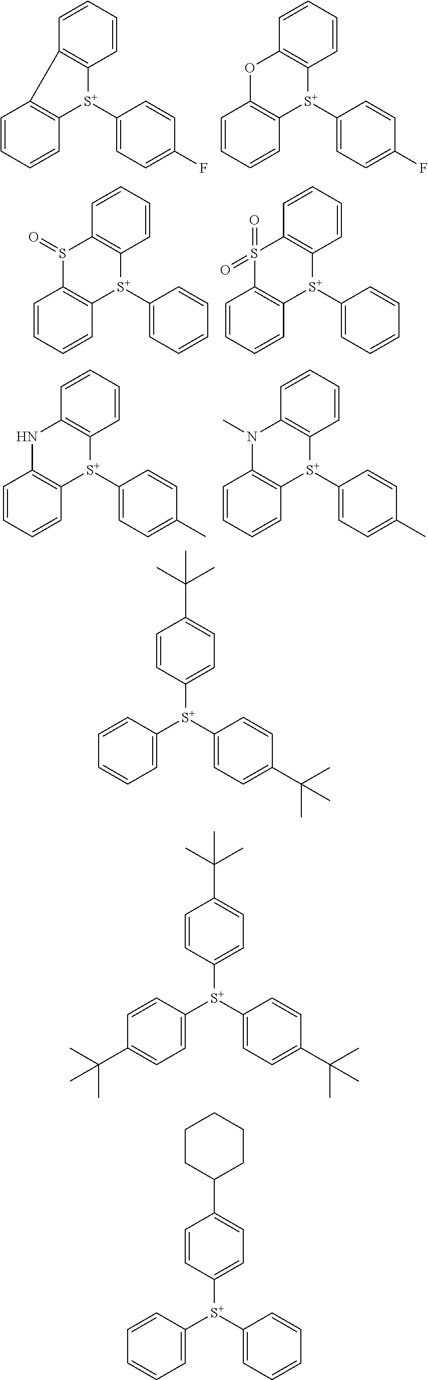

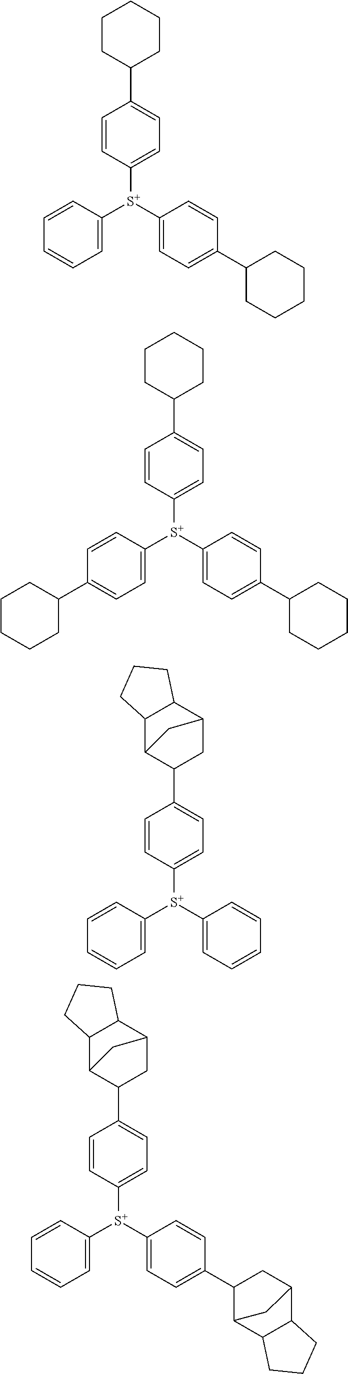 [SMILES: c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

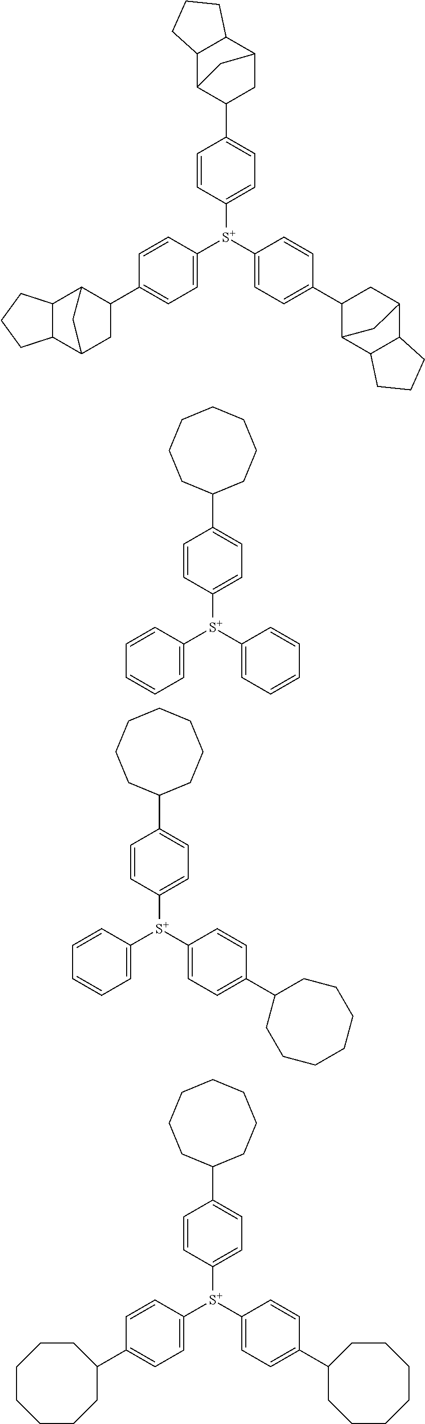 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

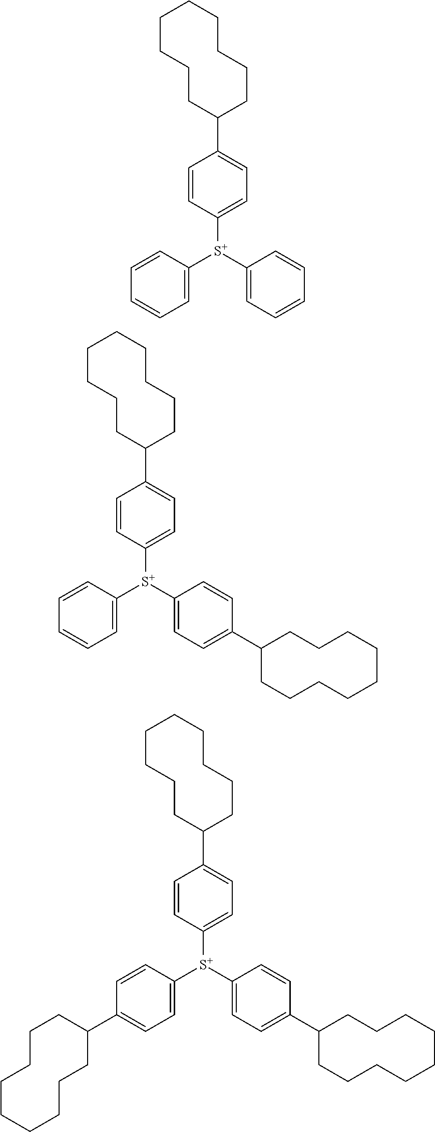 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

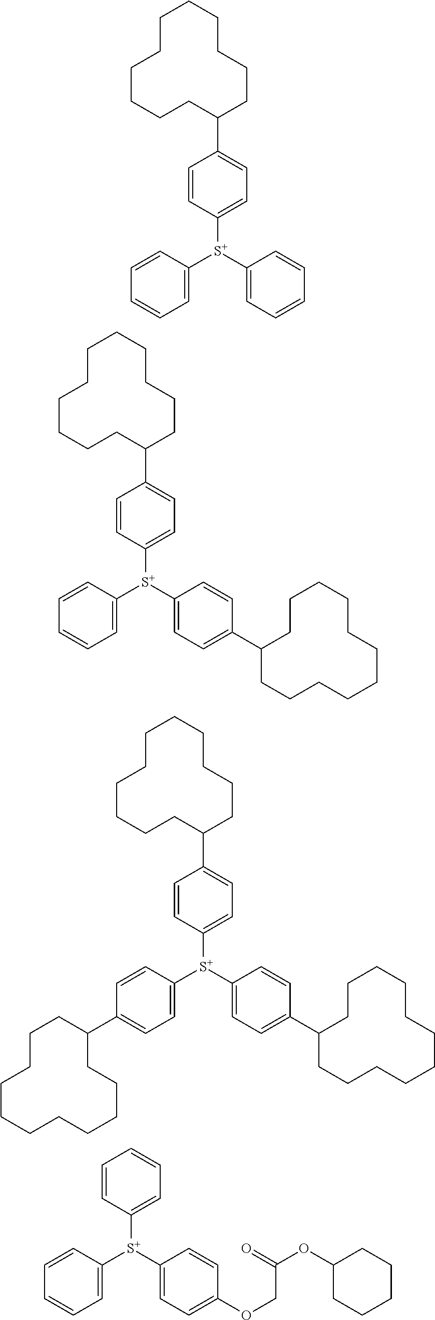 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1]

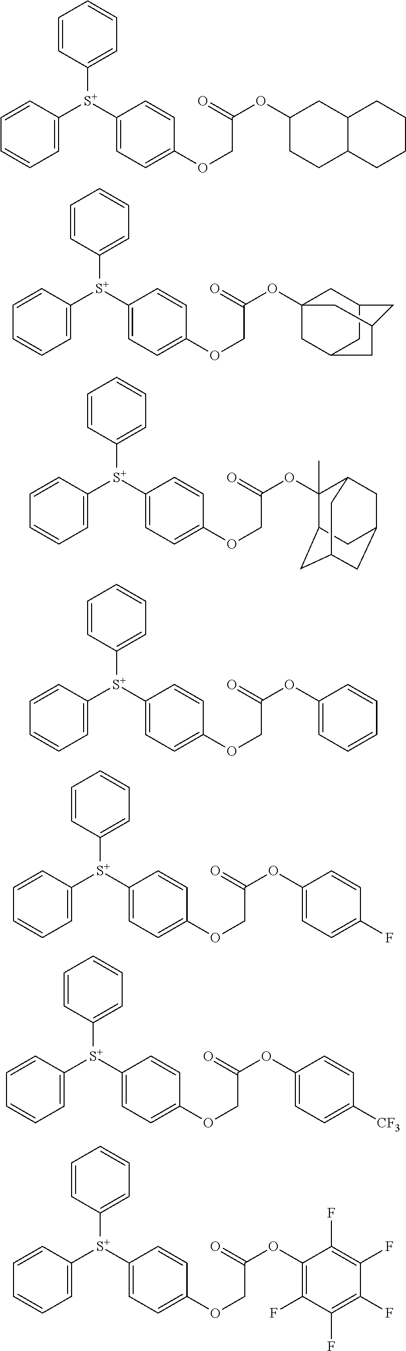

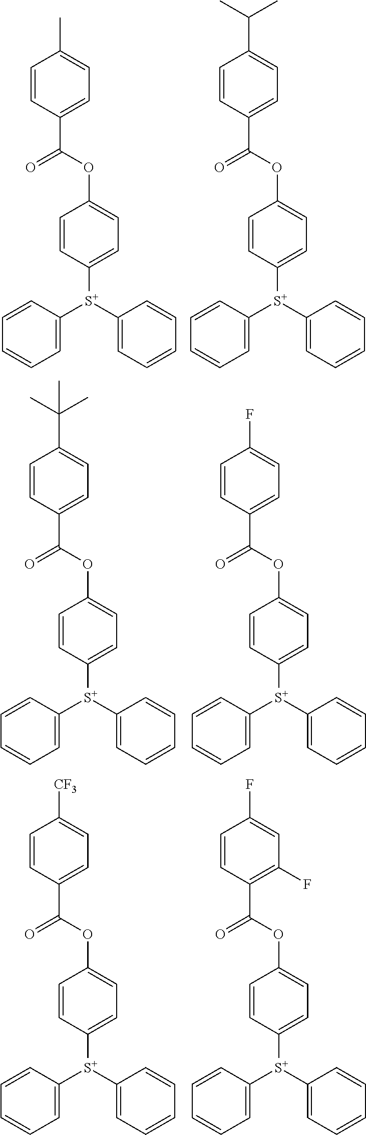 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

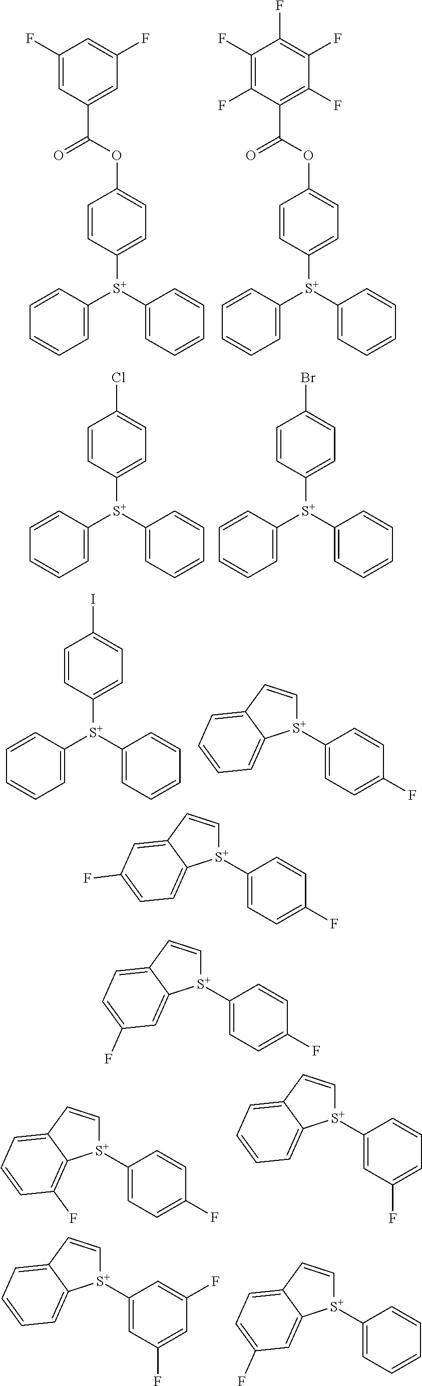

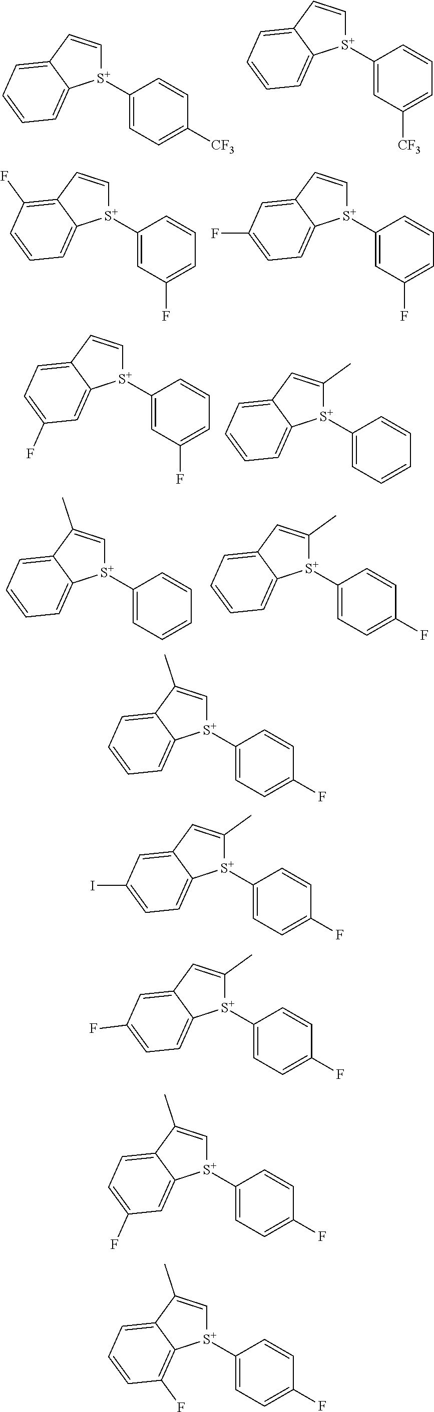

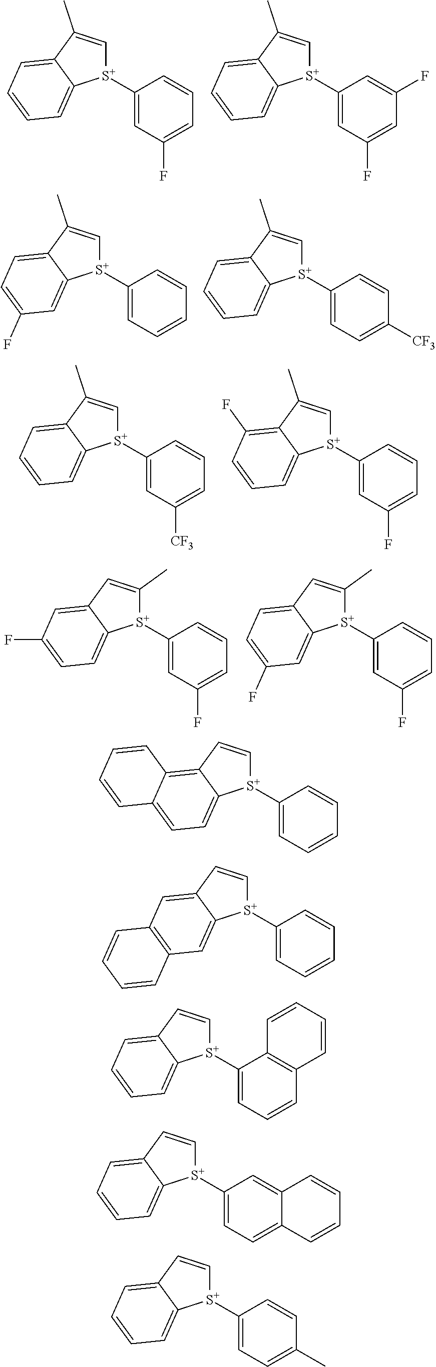

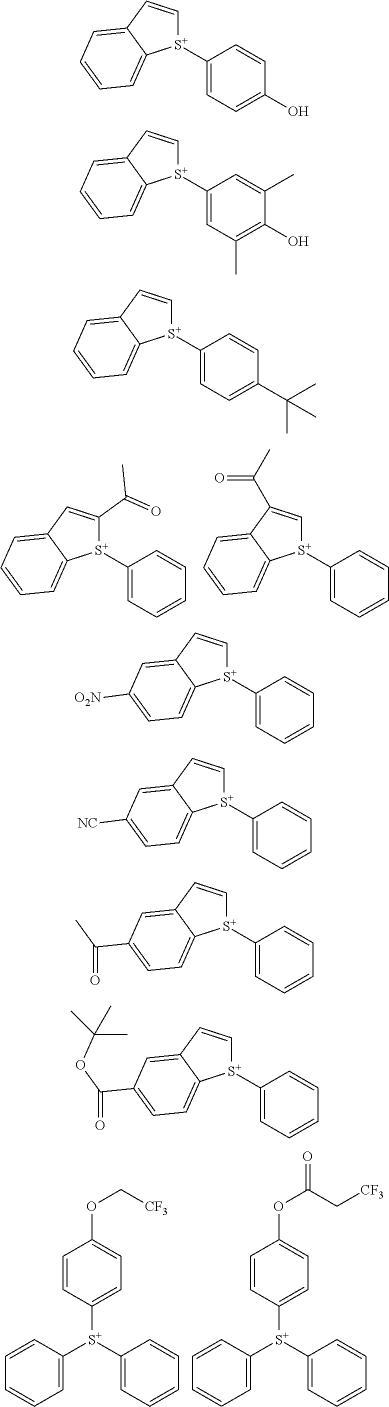

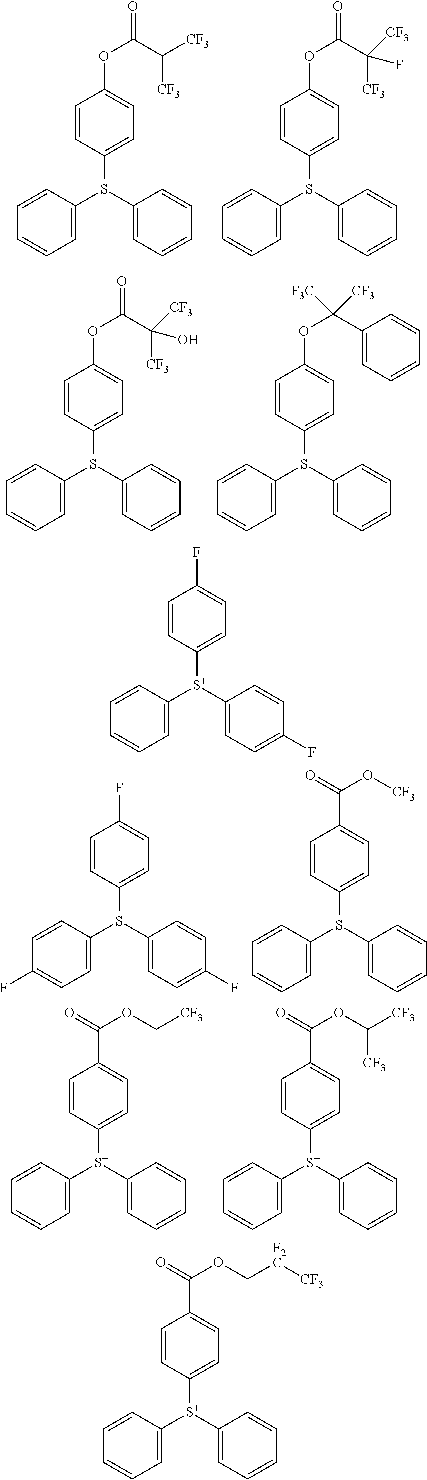

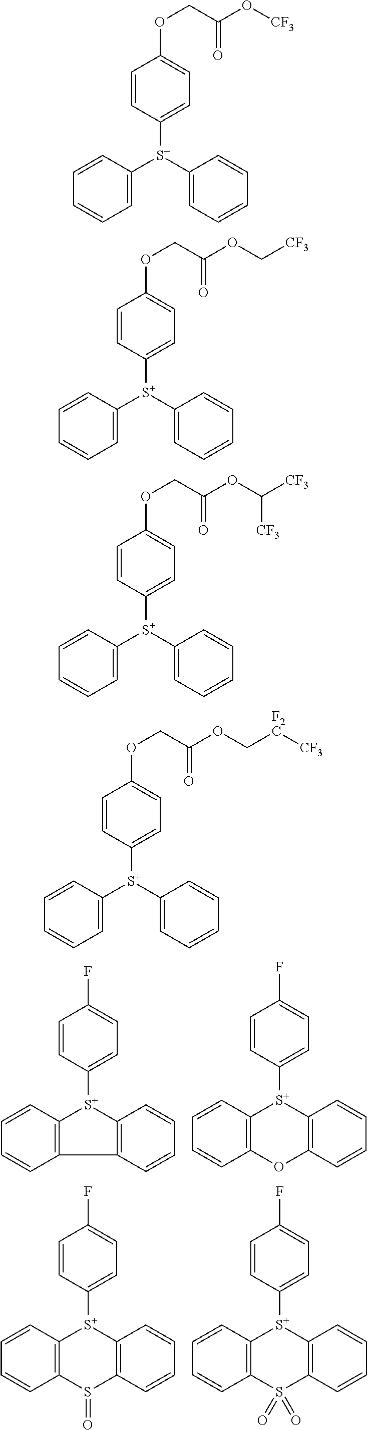

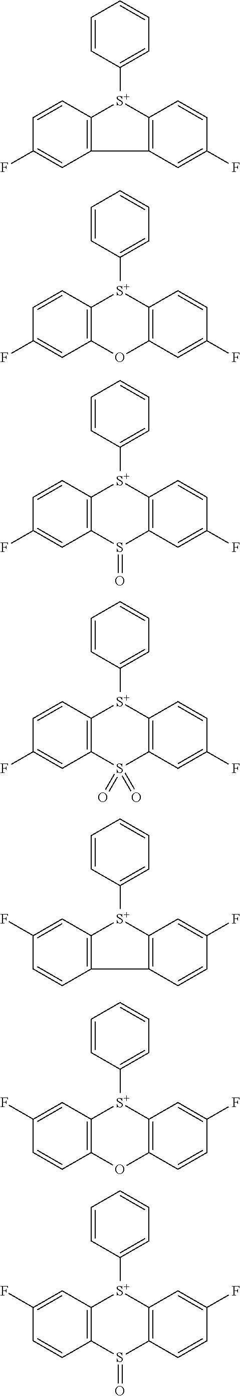

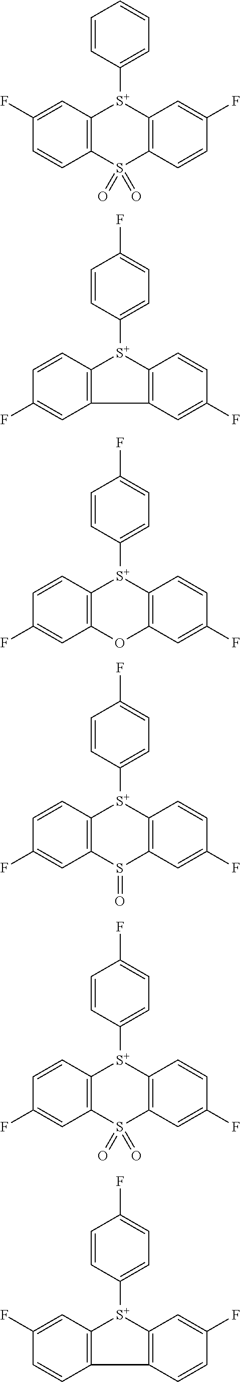 [SMILES: O=S1(=O)c2ccc(F)cc2[S+](c2ccccc2)c2cc(F)ccc21 ; Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21 ; Fc1ccc(-[s+]2c3cc(F)ccc3c3ccc(F)cc32)cc1]

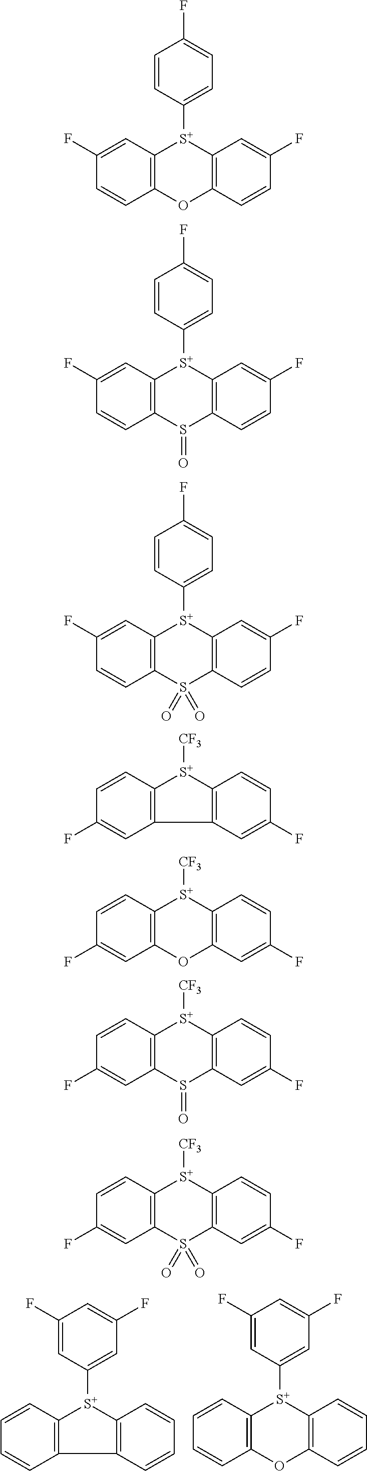

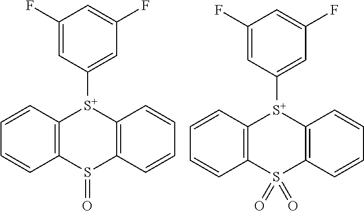 [SMILES: O=S1c2ccccc2[S+](c2cc(F)cc(F)c2)c2ccccc21 ; O=S1(=O)c2ccccc2[S+](c2cc(F)cc(F)c2)c2ccccc21]

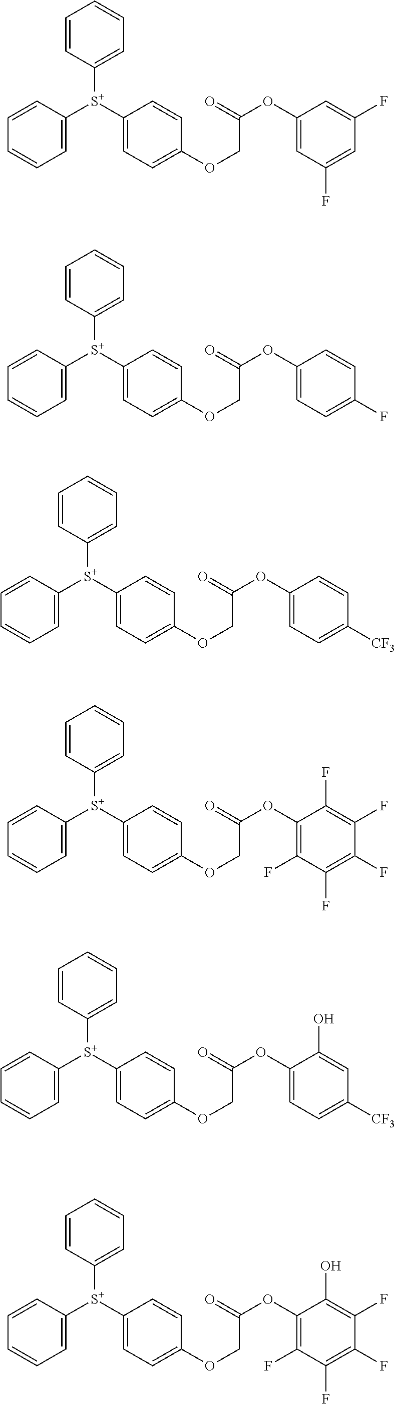 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F]

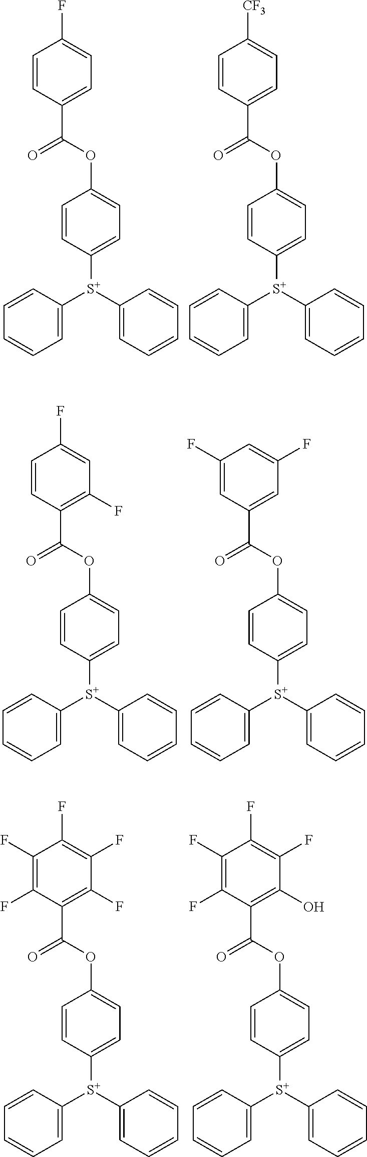 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; O=C(Oc1ccc([S+](c2ccccc2)c2ccccc2)cc1)c1c(O)c(F)c(F)c(F)c1F]

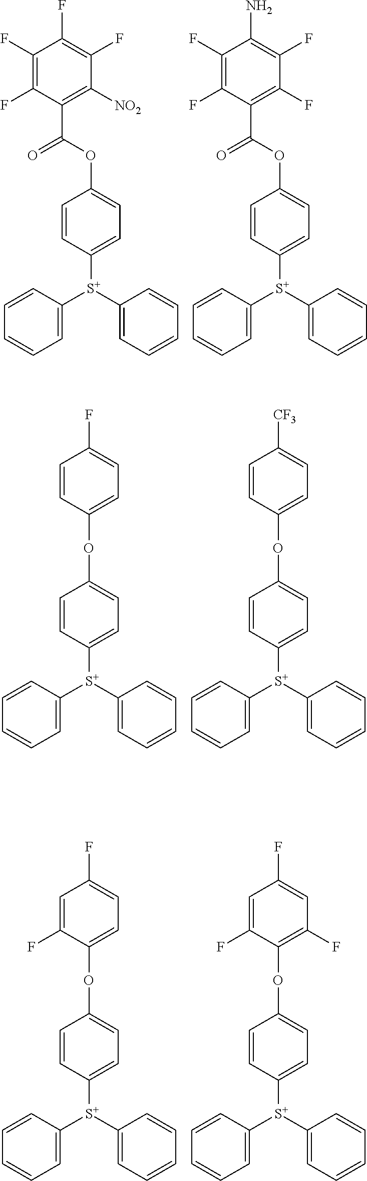 [SMILES: O=C(Oc1ccc([S+](c2ccccc2)c2ccccc2)cc1)c1c(F)c(F)c(F)c(F)c1[N+](=O)[O-] ; Nc1c(F)c(F)c(C(=O)Oc2ccc([S+](c3ccccc3)c3ccccc3)cc2)c(F)c1F ; Fc1ccc(Oc2ccc([S+](c3ccccc3)c3ccccc3)cc2)cc1 ; FC(F)(F)c1ccc(Oc2ccc([S+](c3ccccc3)c3ccccc3)cc2)cc1 ; Fc1ccc(Oc2ccc([S+](c3ccccc3)c3ccccc3)cc2)c(F)c1 ; Fc1cc(F)c(Oc2ccc([S+](c3ccccc3)c3ccccc3)cc2)c(F)c1]

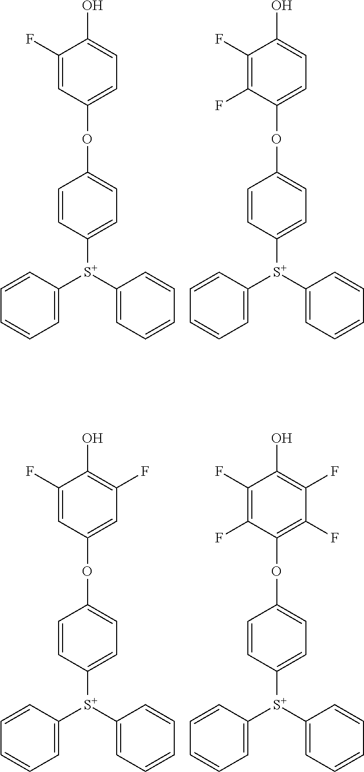 [SMILES: Oc1ccc(Oc2ccc([S+](c3ccccc3)c3ccccc3)cc2)cc1F ; Oc1ccc(Oc2ccc([S+](c3ccccc3)c3ccccc3)cc2)c(F)c1F ; Oc1c(F)cc(Oc2ccc([S+](c3ccccc3)c3ccccc3)cc2)cc1F ; Oc1c(F)c(F)c(Oc2ccc([S+](c3ccccc3)c3ccccc3)cc2)c(F)c1F]

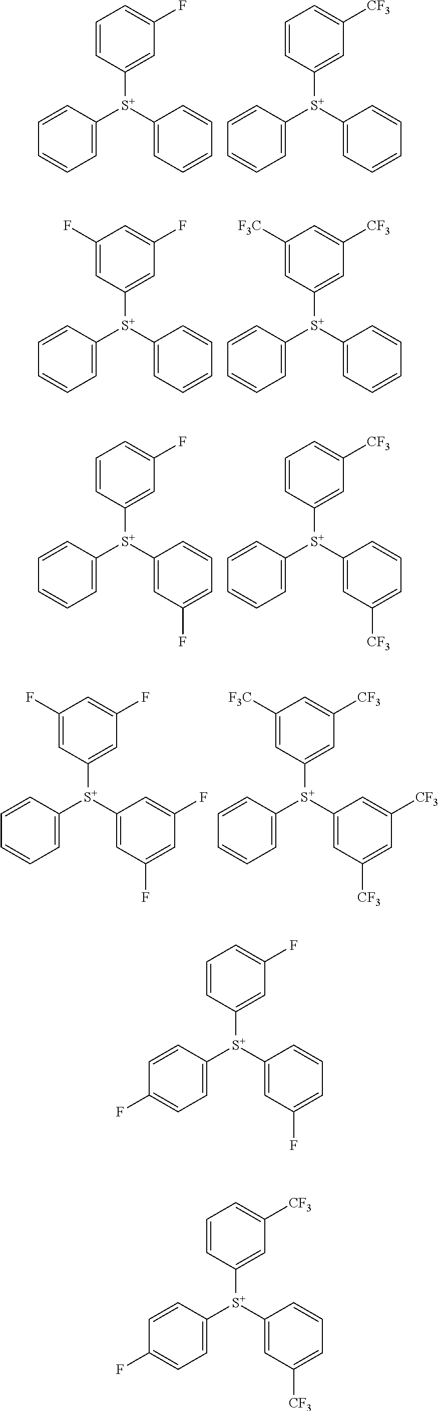

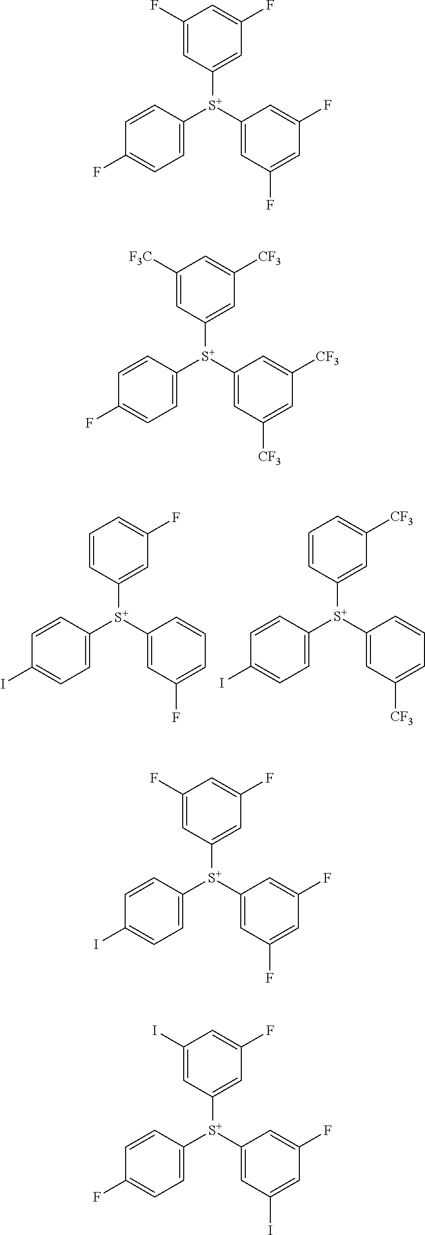 [SMILES: Fc1ccc([S+](c2cc(F)cc(F)c2)c2cc(F)cc(F)c2)cc1 ; Fc1ccc([S+](c2cc(C(F)(F)F)cc(C(F)(F)F)c2)c2cc(C(F)(F)F)cc(C(F)(F)F)c2)cc1 ; Fc1cccc([S+](c2ccc(I)cc2)c2cccc(F)c2)c1 ; FC(F)(F)c1cccc([S+](c2ccc(I)cc2)c2cccc(C(F)(F)F)c2)c1 ; Fc1cc(F)cc([S+](c2ccc(I)cc2)c2cc(F)cc(F)c2)c1 ; Fc1ccc([S+](c2cc(F)cc(I)c2)c2cc(F)cc(I)c2)cc1]

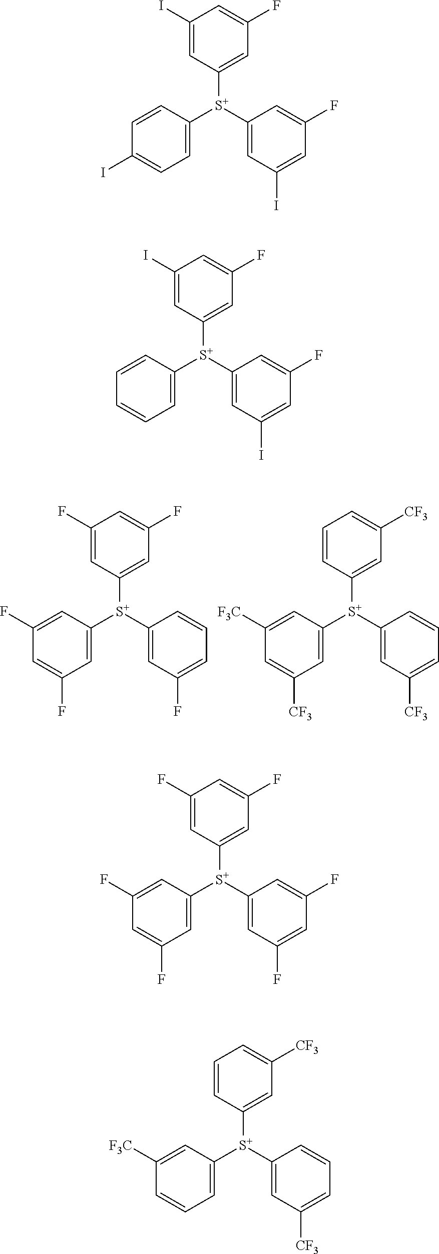 [SMILES: Fc1cc(I)cc([S+](c2ccc(I)cc2)c2cc(F)cc(I)c2)c1 ; Fc1cc(I)cc([S+](c2ccccc2)c2cc(F)cc(I)c2)c1 ; Fc1cccc([S+](c2cc(F)cc(F)c2)c2cc(F)cc(F)c2)c1 ; FC(F)(F)c1cccc([S+](c2cccc(C(F)(F)F)c2)c2cc(C(F)(F)F)cc(C(F)(F)F)c2)c1 ; Fc1cc(F)cc([S+](c2cc(F)cc(F)c2)c2cc(F)cc(F)c2)c1 ; FC(F)(F)c1cccc([S+](c2cccc(C(F)(F)F)c2)c2cccc(C(F)(F)F)c2)c1]

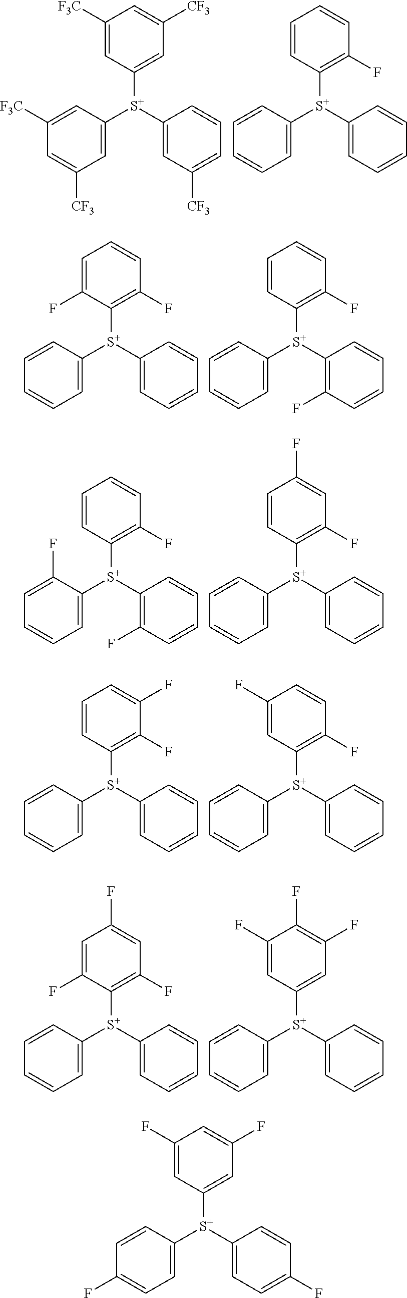

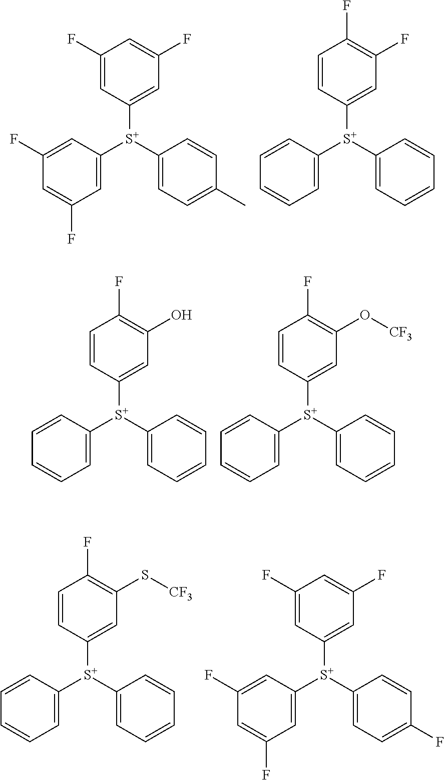 [SMILES: Cc1ccc([S+](c2cc(F)cc(F)c2)c2cc(F)cc(F)c2)cc1 ; Fc1ccc([S+](c2ccccc2)c2ccccc2)cc1F ; Oc1cc([S+](c2ccccc2)c2ccccc2)ccc1F ; Fc1ccc([S+](c2ccccc2)c2ccccc2)cc1OC(F)(F)F ; Fc1ccc([S+](c2ccccc2)c2ccccc2)cc1SC(F)(F)F ; Fc1ccc([S+](c2cc(F)cc(F)c2)c2cc(F)cc(F)c2)cc1]

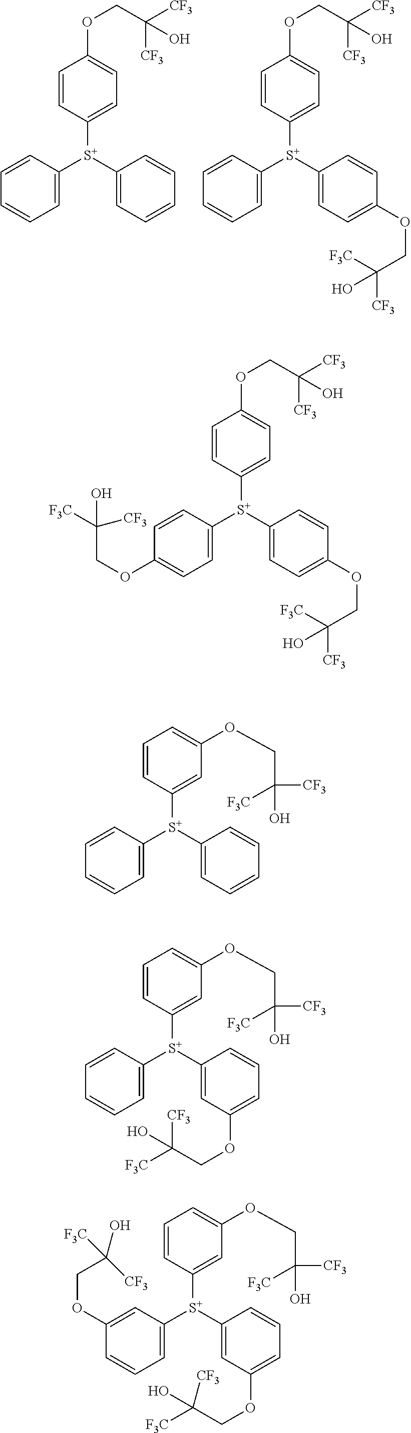

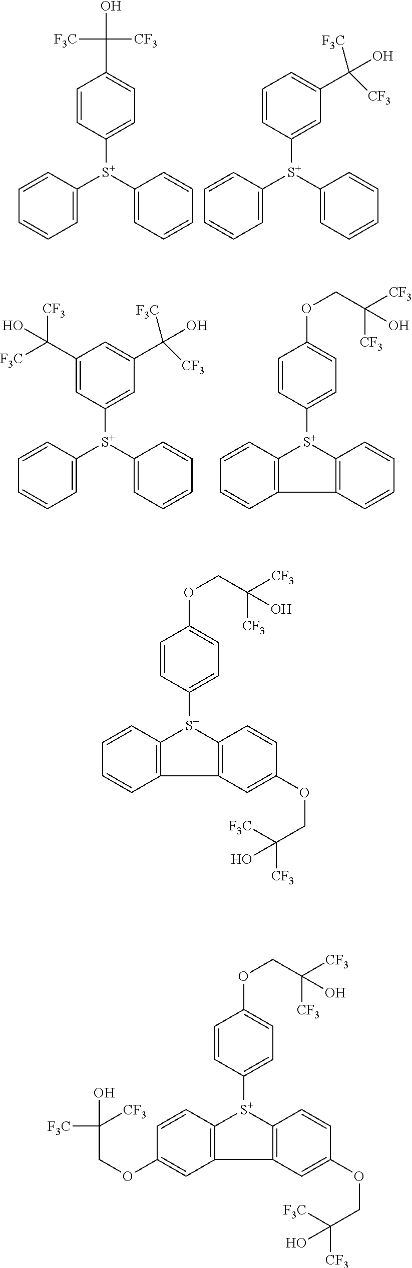 [SMILES: OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F ; OC(COc1ccc(-[s+]2c3ccccc3c3ccccc32)cc1)(C(F)(F)F)C(F)(F)F ; OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F]

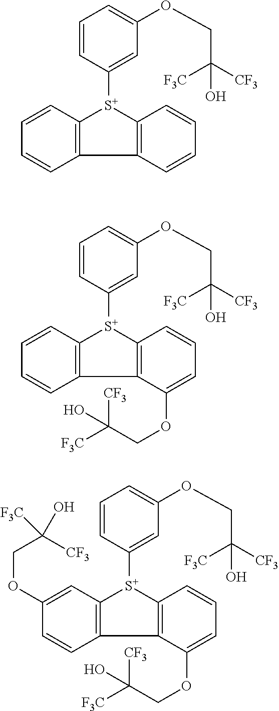 [SMILES: OC(COc1cccc(-[s+]2c3ccccc3c3ccccc32)c1)(C(F)(F)F)C(F)(F)F ; OC(COc1cccc(-[s+]2c3ccccc3c3c(OCC(O)(C(F)(F)F)C(F)(F)F)cccc32)c1)(C(F)(F)F)C(F)(F)F ; OC(COc1cccc(-[s+]2c3cc(OCC(O)(C(F)(F)F)C(F)(F)F)ccc3c3c(OCC(O)(C(F)(F)F)C(F)(F)F)cccc32)c1)(C(F)(F)F)C(F)(F)F]

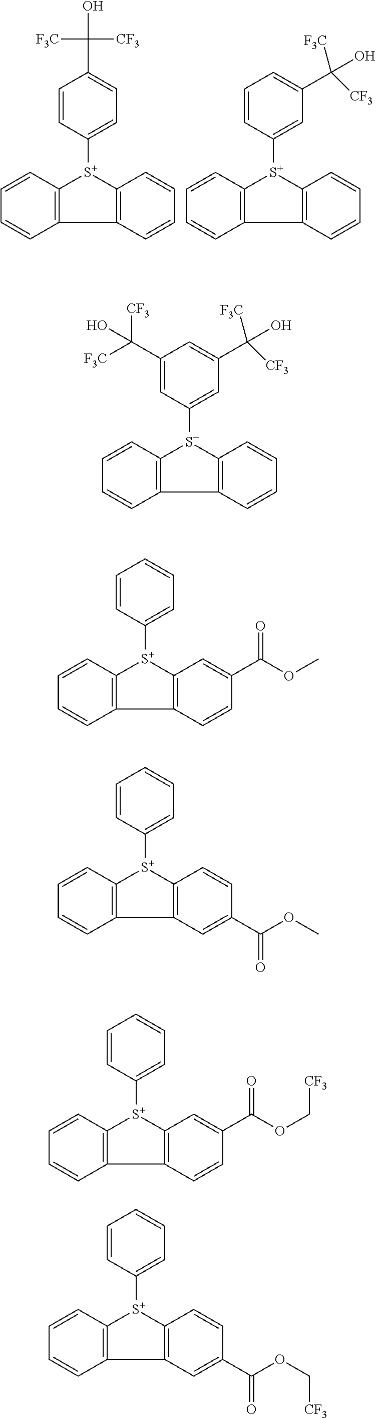

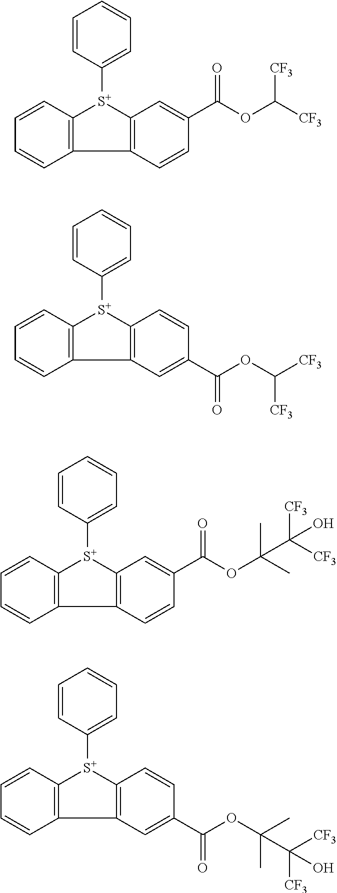 [SMILES: O=C(OC(C(F)(F)F)C(F)(F)F)c1ccc2c3ccccc3[s+](-c3ccccc3)c2c1 ; O=C(OC(C(F)(F)F)C(F)(F)F)c1ccc2c(c1)c1ccccc1[s+]2-c1ccccc1 ; CC(C)(OC(=O)c1ccc2c3ccccc3[s+](-c3ccccc3)c2c1)C(O)(C(F)(F)F)C(F)(F)F ; CC(C)(OC(=O)c1ccc2c(c1)c1ccccc1[s+]2-c1ccccc1)C(O)(C(F)(F)F)C(F)(F)F]

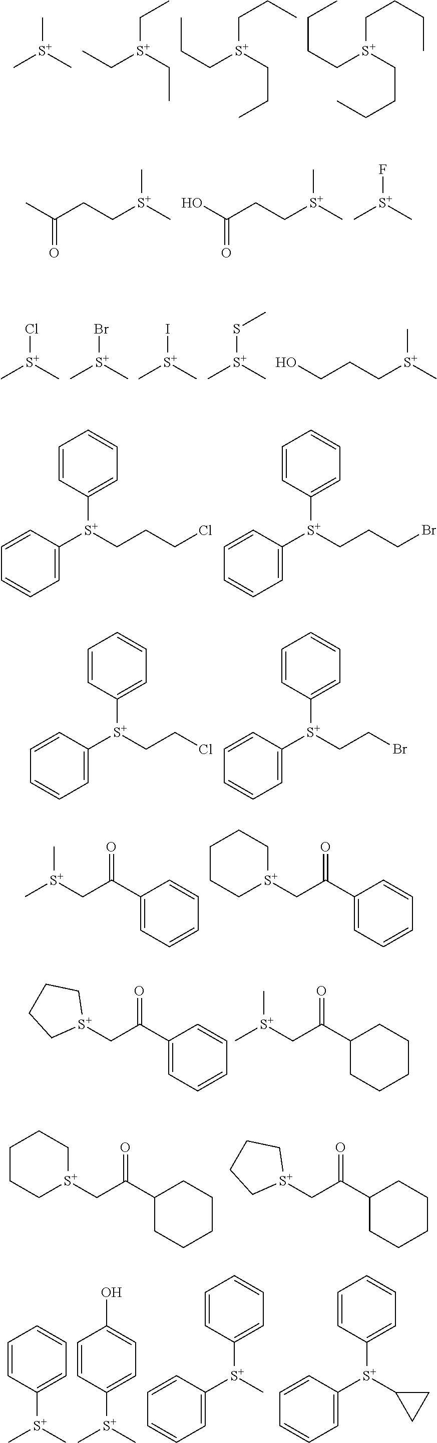

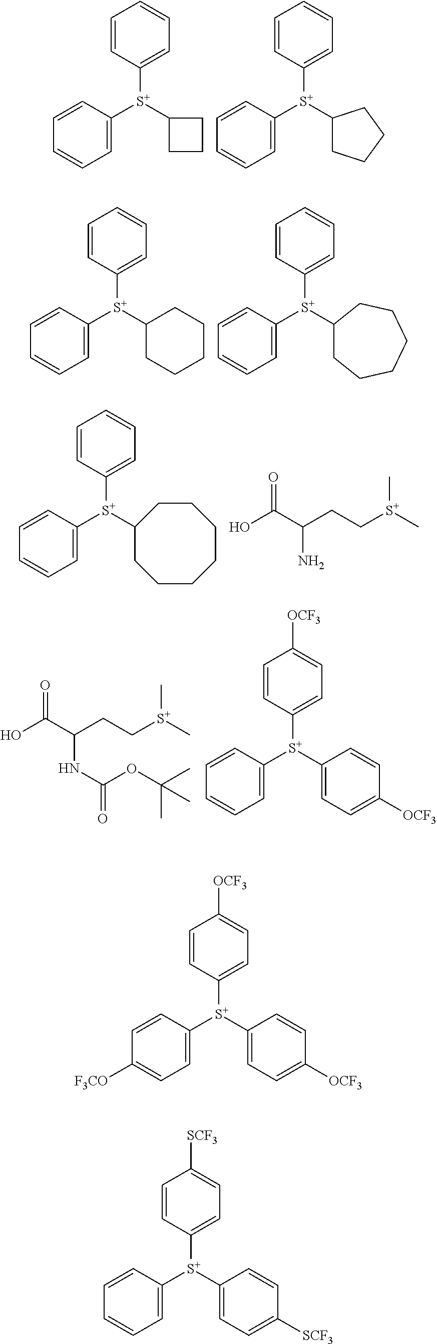

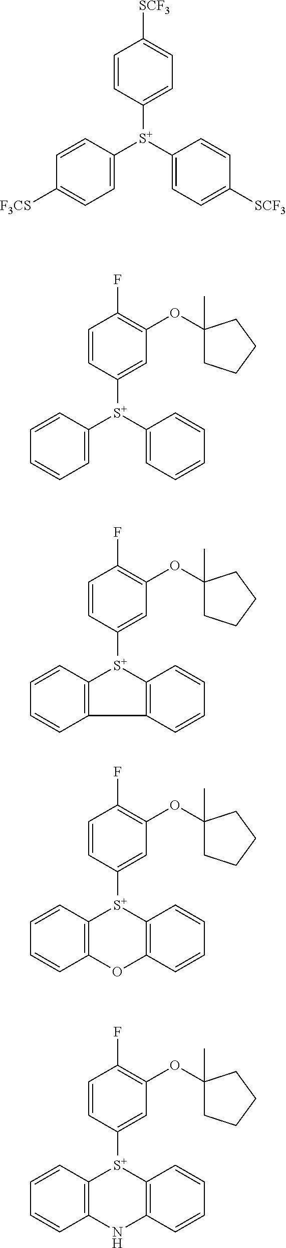

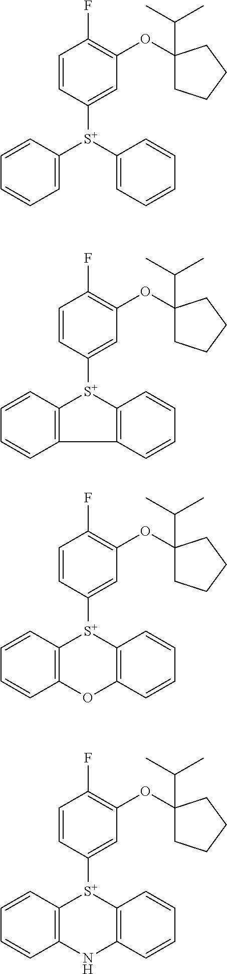 [SMILES: CC(C)C1(Oc2cc([S+](c3ccccc3)c3ccccc3)ccc2F)CCCC1 ; CC(C)C1(Oc2cc(-[s+]3c4ccccc4c4ccccc43)ccc2F)CCCC1 ; CC(C)C1(Oc2cc([S+]3c4ccccc4Oc4ccccc43)ccc2F)CCCC1 ; CC(C)C1(Oc2cc([S+]3c4ccccc4Nc4ccccc43)ccc2F)CCCC1]

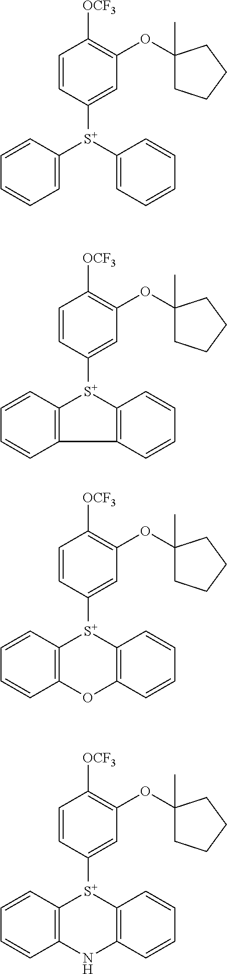 [SMILES: CC1(Oc2cc([S+](c3ccccc3)c3ccccc3)ccc2OC(F)(F)F)CCCC1 ; CC1(Oc2cc(-[s+]3c4ccccc4c4ccccc43)ccc2OC(F)(F)F)CCCC1 ; CC1(Oc2cc([S+]3c4ccccc4Oc4ccccc43)ccc2OC(F)(F)F)CCCC1 ; CC1(Oc2cc([S+]3c4ccccc4Nc4ccccc43)ccc2OC(F)(F)F)CCCC1]

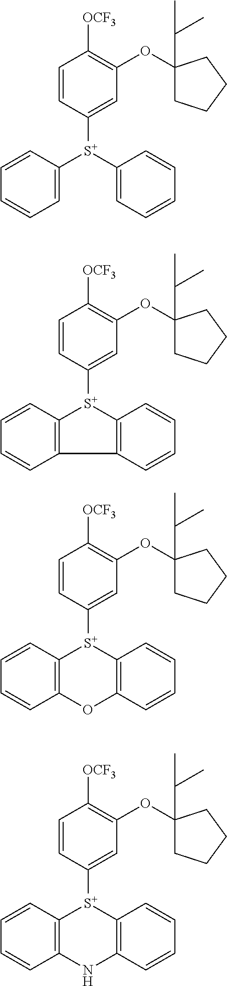 [SMILES: CC(C)C1(Oc2cc([S+](c3ccccc3)c3ccccc3)ccc2OC(F)(F)F)CCCC1 ; CC(C)C1(Oc2cc(-[s+]3c4ccccc4c4ccccc43)ccc2OC(F)(F)F)CCCC1 ; CC(C)C1(Oc2cc([S+]3c4ccccc4Oc4ccccc43)ccc2OC(F)(F)F)CCCC1 ; CC(C)C1(Oc2cc([S+]3c4ccccc4Nc4ccccc43)ccc2OC(F)(F)F)CCCC1]

Examples of the iodonium cation having formula (5-2) are shown below, but not limited thereto.

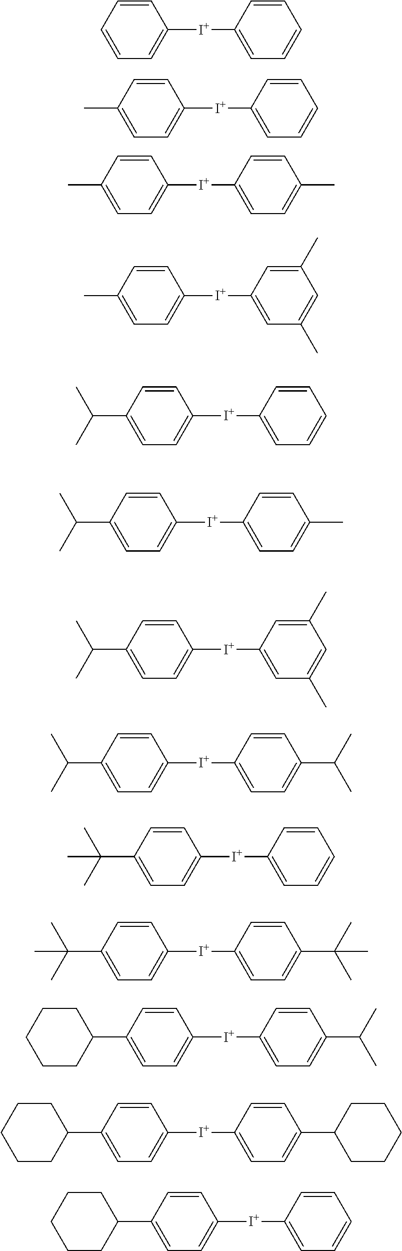

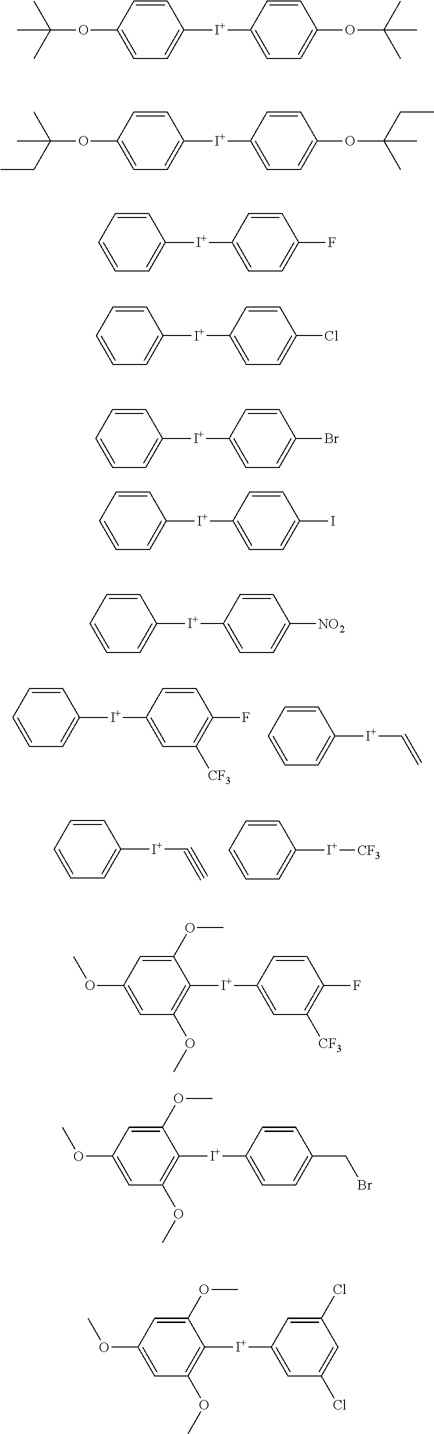

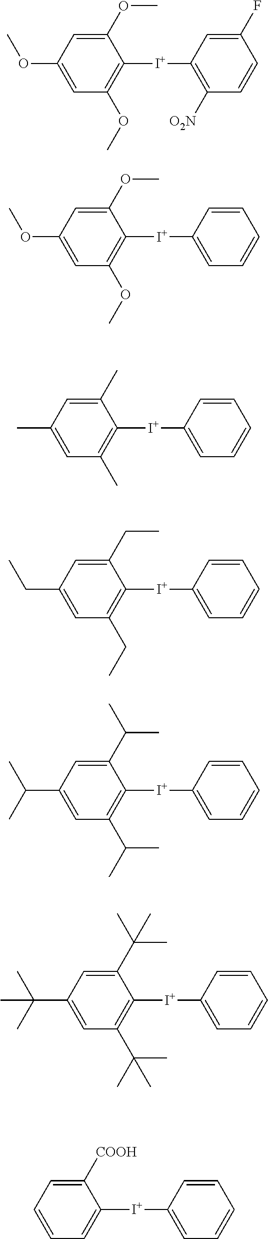

The onium salt compound also contains a halide ion, nitrate ion, hydrogensulfate ion, hydrogencarbonate ion, tetraphenylborate ion or anion having any one of the formulae (5-3) to (5-9).

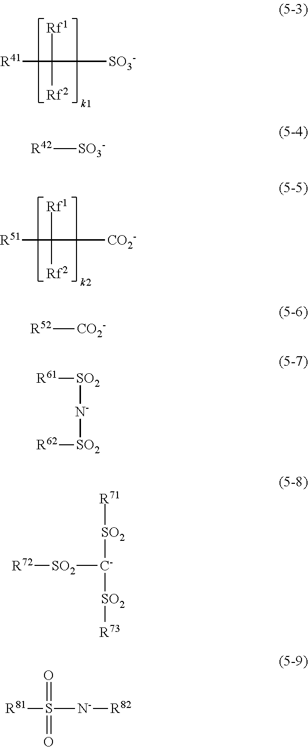

In formulae (5-3) and (5-5), k1 and k2 are each independently 1, 2, 3 or 4. Rf¹ and Rf² are each independently hydrogen, fluorine, or a C₁-C₆ fluorinated alkyl group, excluding that all Rf¹ and Rf² are hydrogen at the same time.

In formula (5-3), R⁴¹ is hydrogen, halogen, hydroxy or a C₁-C₅₀ hydrocarbyl group which may contain a heteroatom.

In formula (5-4), R⁴² is hydrogen, halogen, hydroxy or a C₁-C₅₀ hydrocarbyl group which may contain a heteroatom, exclusive of the group wherein hydrogen bonded to the carbon atom at α- or β-position relative to the sulfo group is substituted by fluorine or fluoroalkyl.

In formula (5-5), R⁵¹ is hydrogen, halogen, hydroxy or a C₁-C₅₀ hydrocarbyl group which may contain a heteroatom.

In formula (5-6), R⁵² is hydrogen, halogen, hydroxy or a C₁-C₅₀ hydrocarbyl group which may contain a heteroatom, exclusive of the group wherein hydrogen bonded to the carbon atom at α- or β-position relative to the carboxy group is substituted by fluorine or fluoroalkyl.

In formula (5-7), R⁶¹ and R⁶² are each independently a C₁-C₅₀ hydrocarbyl group which may contain a heteroatom.

In formula (5-8), R⁷¹ to R⁷³ are each independently a C₁-C₅₀ hydrocarbyl group which may contain a heteroatom.

In formula (5-9), R⁸¹ is fluorine or a C₁-C₁₀ fluorinated hydrocarbyl group which may contain hydroxy, ether bond or ester bond. R⁸² is hydrogen or a C₁-C₂₀ hydrocarbyl group which may contain hydroxy, ether bond or ester bond. R⁸¹ and R⁸² may bond together to form a ring with the atoms to which they are attached.

The anion of the onium salt compound is preferably selected from halide ions, nitrate ions and anions having formulae (5-3) to (5-9), more preferably from halide ions, nitrate ions and anions having formulae (5-4), (5-6) and (5-8).

The C₁-C₅₀ hydrocarbyl group represented by R⁴¹, R⁴², R⁵¹, R⁵², R⁶¹, R⁶², R⁷¹, R⁷² and R⁷³ may be saturated or unsaturated and straight, branched or cyclic. Examples thereof include C₁-C₅₀ alkyl groups such as methyl, ethyl, propyl, isopropyl, n-butyl, sec-butyl, tert-butyl, n-pentyl, tert-pentyl, n-hexyl, n-octyl, 2-ethylhexyl, n-nonyl, and n-decyl; C₃-C₅₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl and adamantylmethyl; C₂-C₅₀ alkenyl groups such as vinyl, 1-propenyl, 2-propenyl, butenyl, and hexenyl; C₃-C₅₀ cyclic unsaturated hydrocarbyl groups such as cyclohexenyl; C₆-C₅₀ aryl groups such as phenyl, naphthyl and anthracenyl; C₇-C₅₀ aralkyl groups such as benzyl, 1-phenylethyl, and 2-phenylethyl, and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, halogen, carbonyl moiety, ether bond, thioether bond, ester bond, sulfonate ester bond, carbonate bond, carbamate bond, lactone ring, sultone ring, carboxylic anhydride (—C(═O)—O—C(═O)—).

The C₁-C₁₀ fluorinated hydrocarbyl group R⁸¹ is a C₁-C₁₀ hydrocarbyl group in which some or all hydrogen atoms are substituted by fluorine. The C₁-C₁₀ hydrocarbyl group may be saturated or unsaturated and straight, branched or cyclic. Examples thereof are as exemplified above for the C₁-C₅₀ hydrocarbyl group represented by R⁴¹, R⁴², R⁵¹, R⁵², R⁶¹, R⁶², R⁷¹, R⁷² and R⁷³, but of 1 to 10 carbon atoms.

The C₁-C₂₀ hydrocarbyl group R⁸² may be saturated or unsaturated and straight, branched or cyclic. Examples thereof are as exemplified above for the C₁-C₅₀ hydrocarbyl group represented by R⁴¹, R⁴², R⁵¹, R⁵², R⁶¹, R⁶², R⁷¹, R⁷² and R⁷³, but of 1 to 20 carbon atoms.

The anion having any one of formulae (5-3) to (5-9) may have in its structure a C₂-C₅₀ hydrocarbyl group which contains a polymerizable functional group and may contain a heteroatom. Examples thereof are shown below, but not limited thereto.

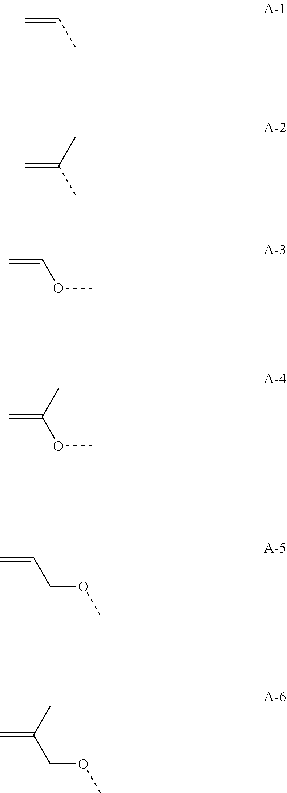

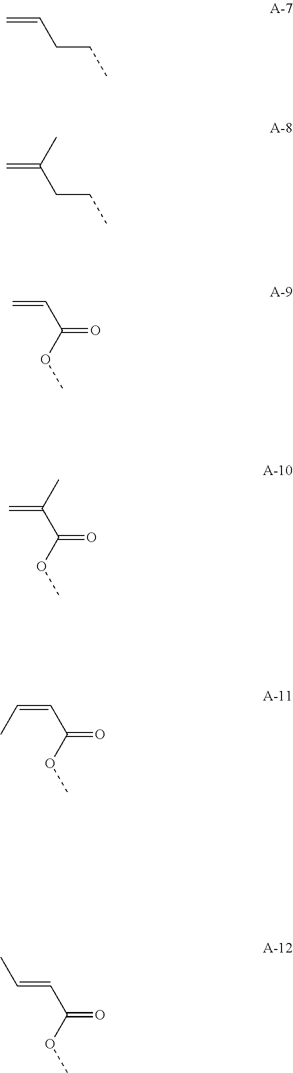

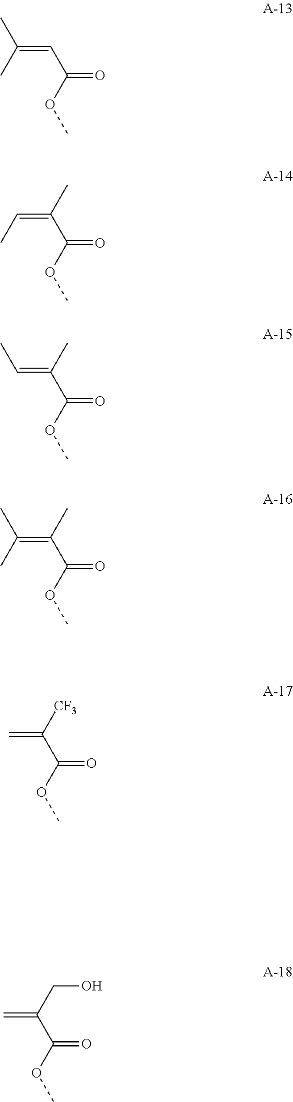

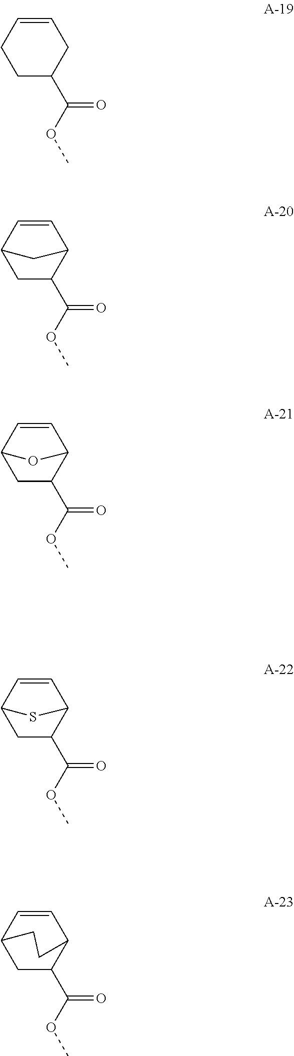

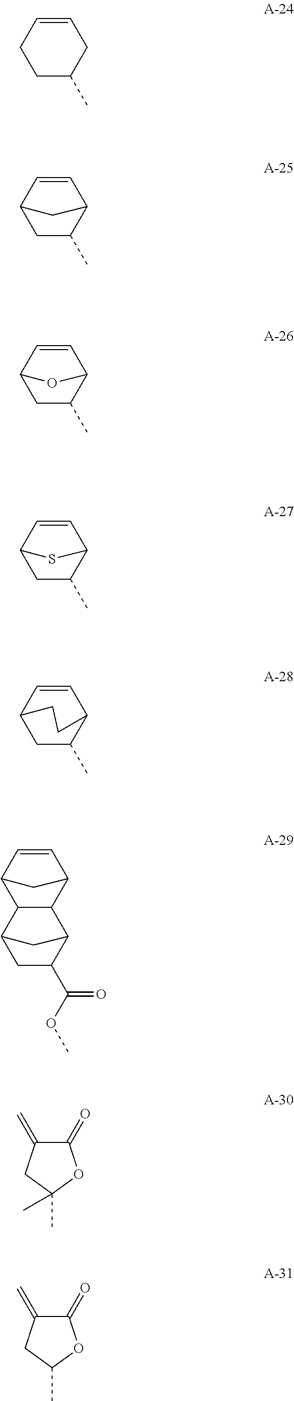

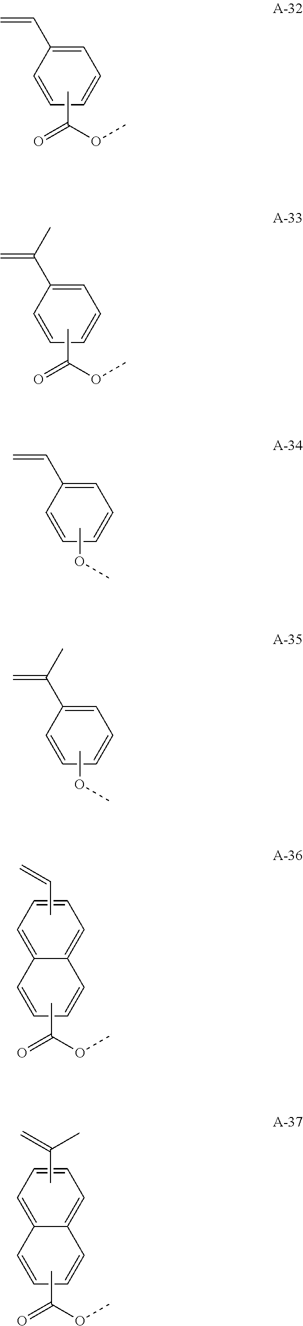

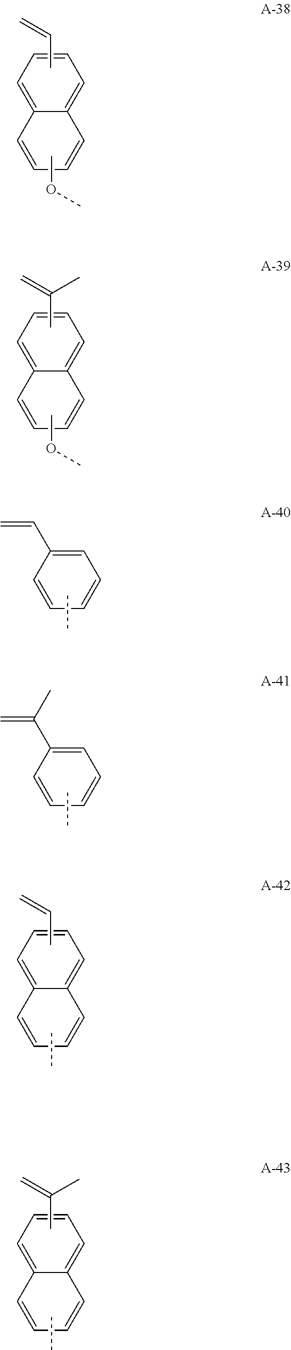

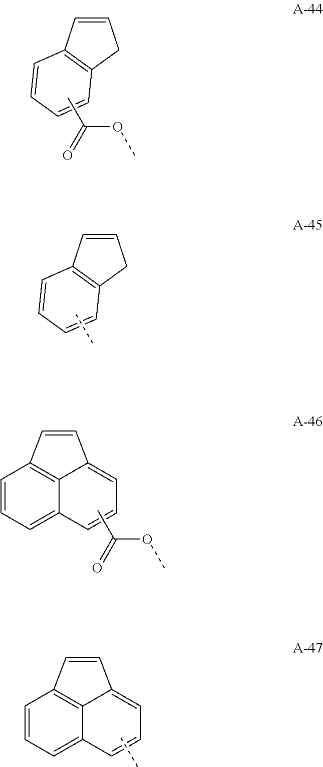

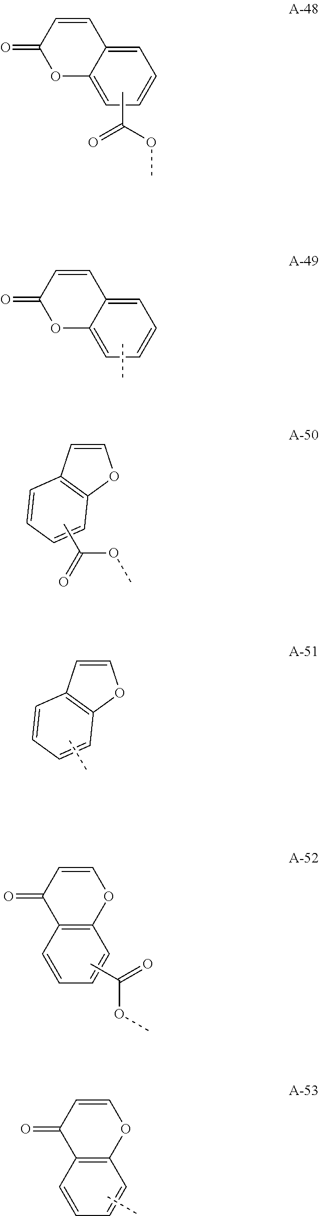

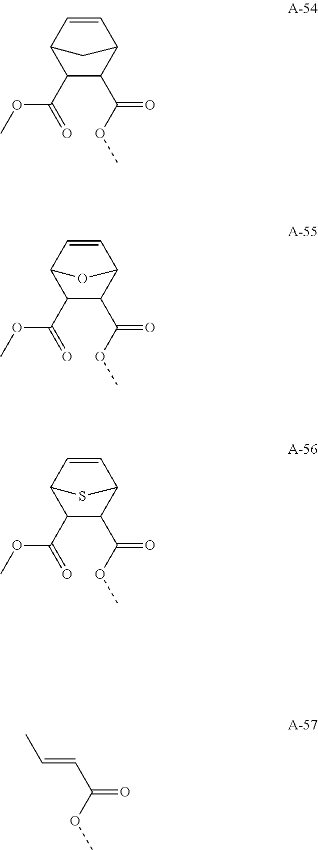

Examples of the anion having formula (5-3) are shown below, but not limited thereto. Herein Rf¹ is as defined above.

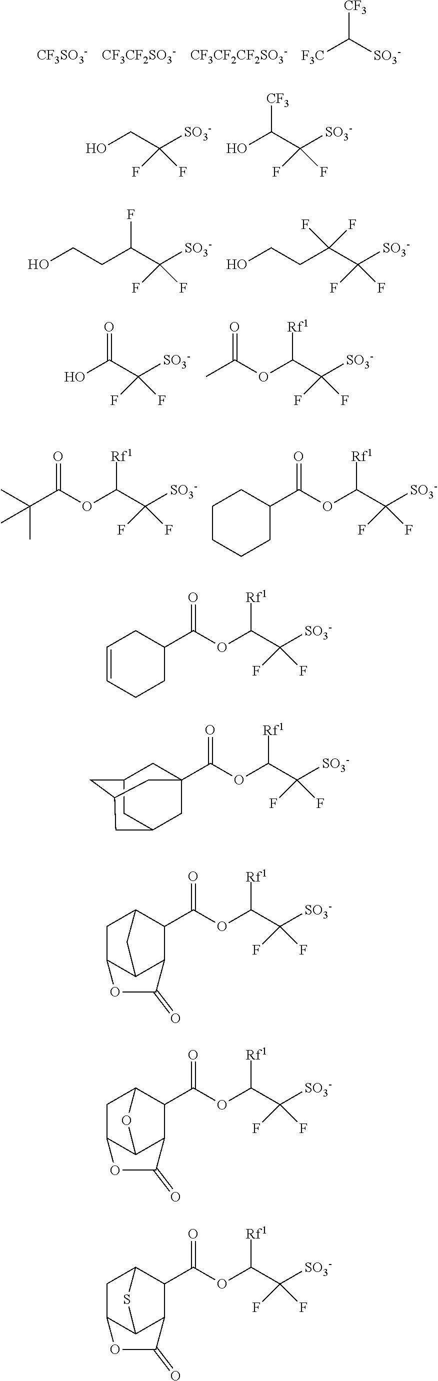

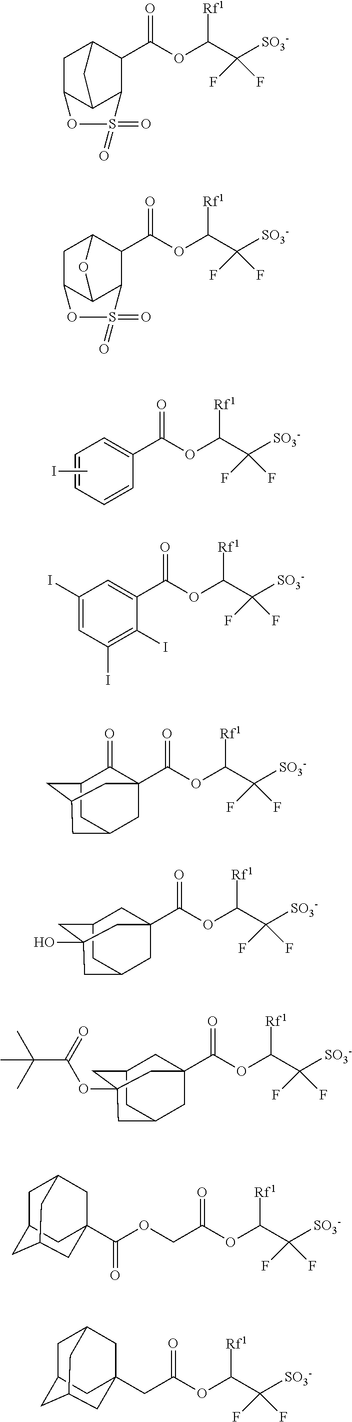

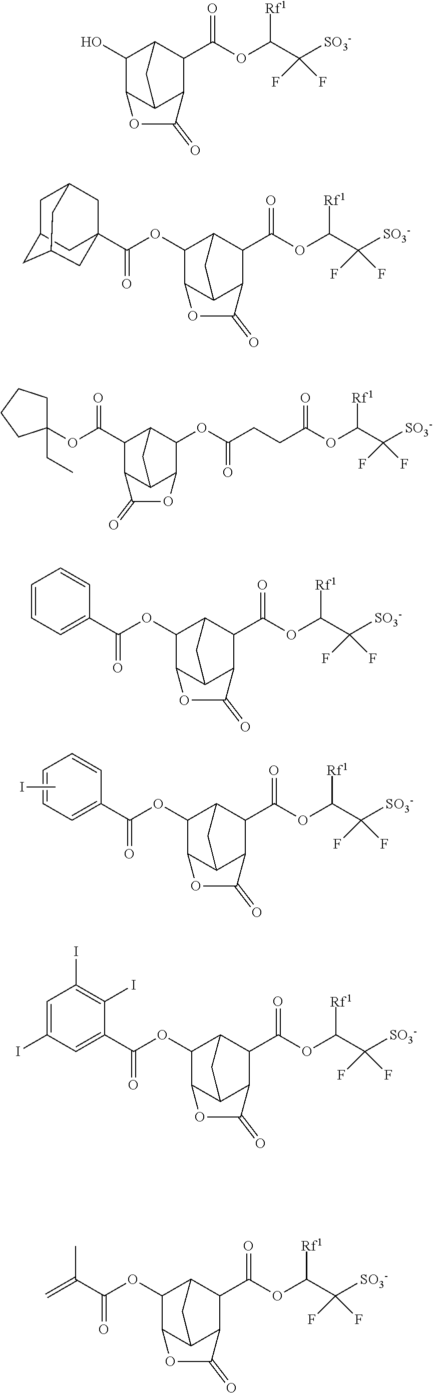

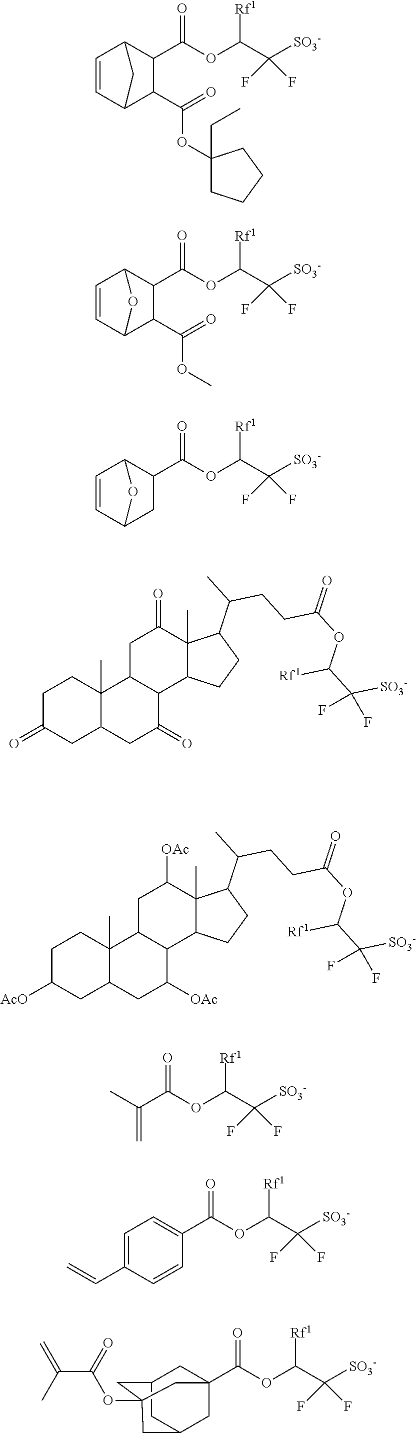

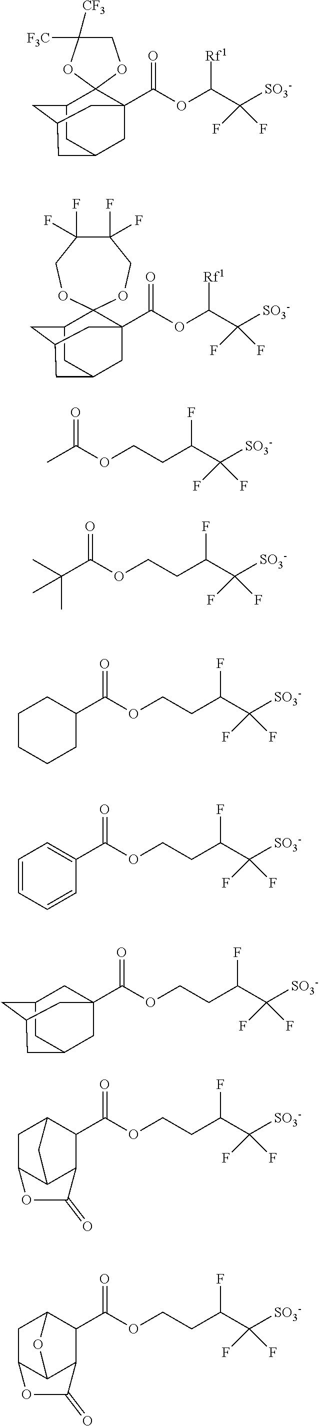

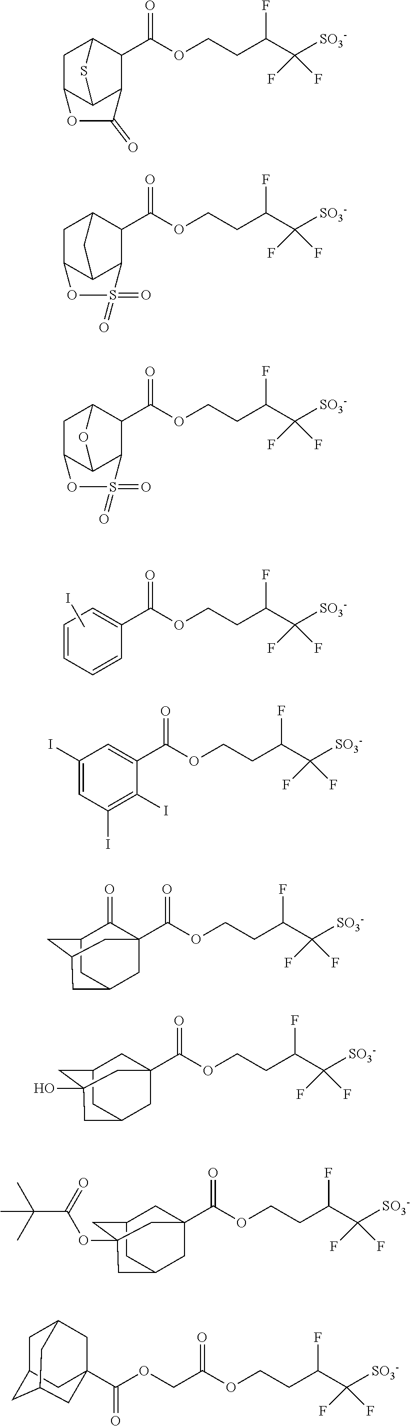

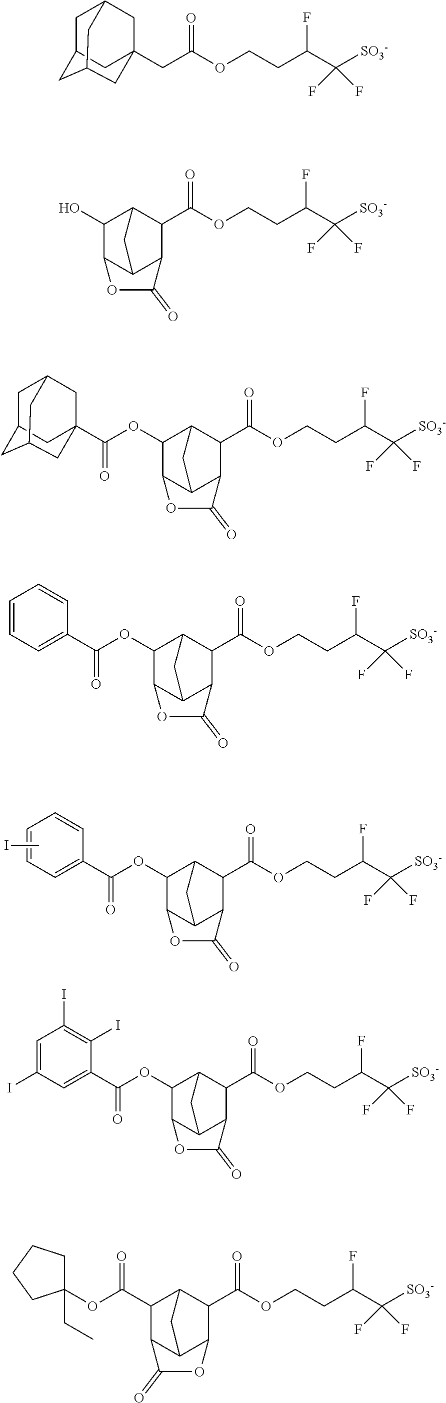

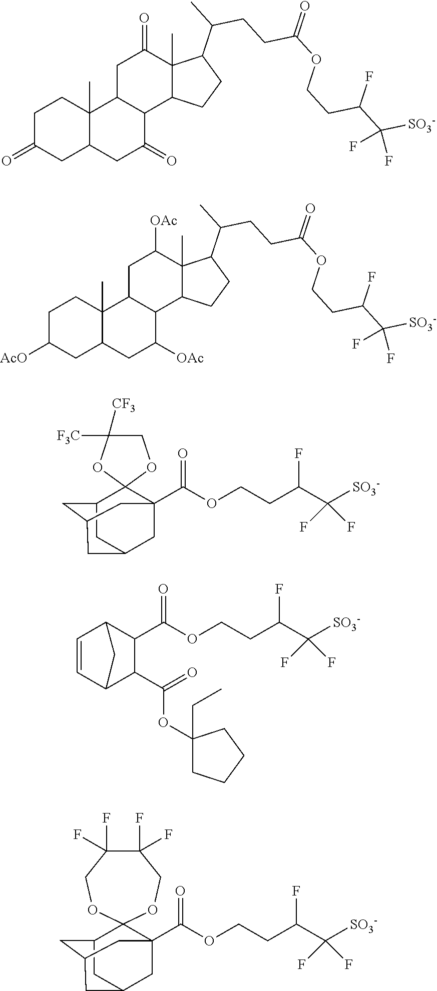

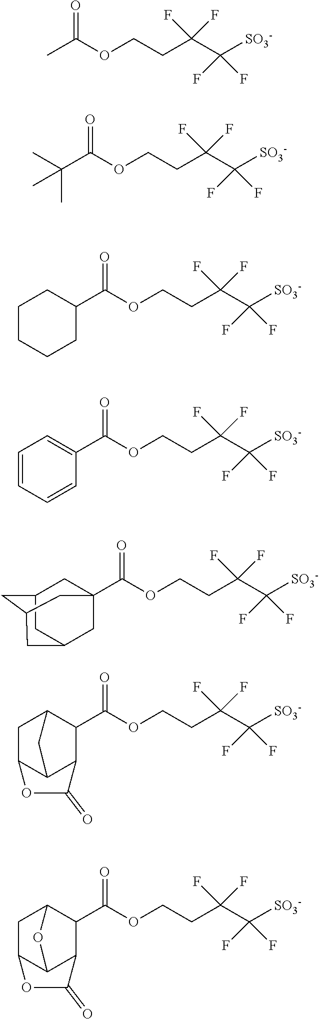

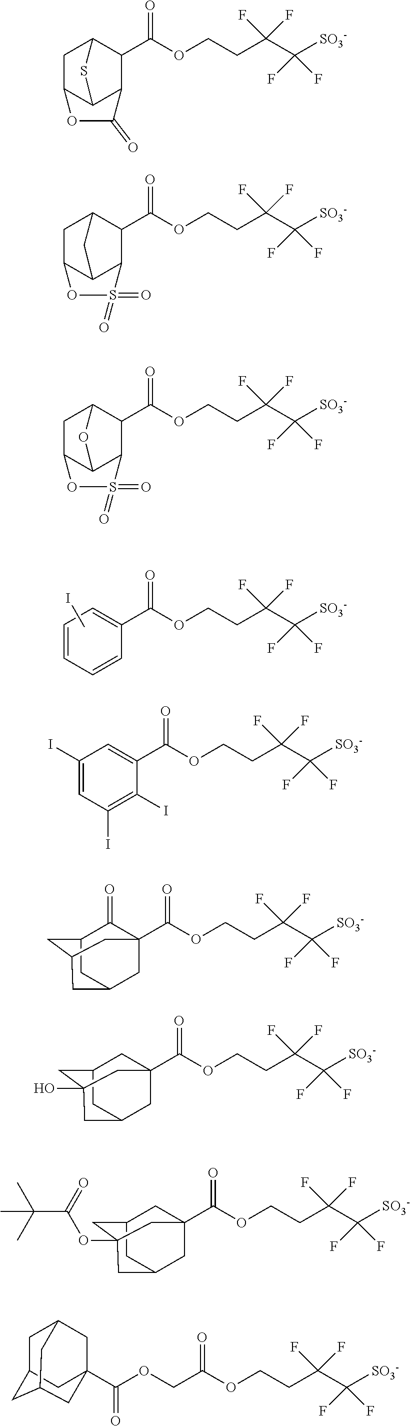

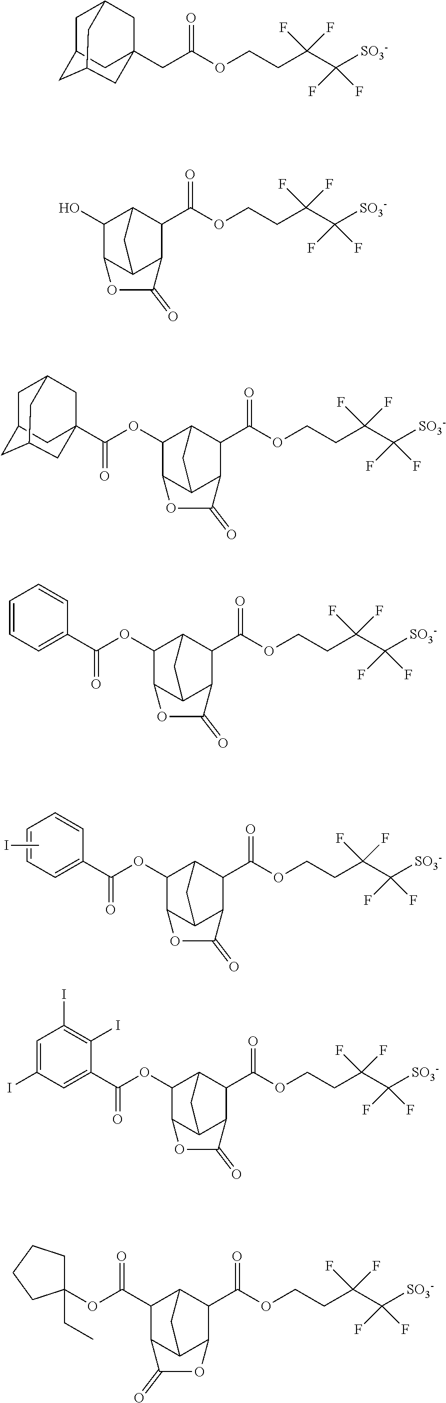

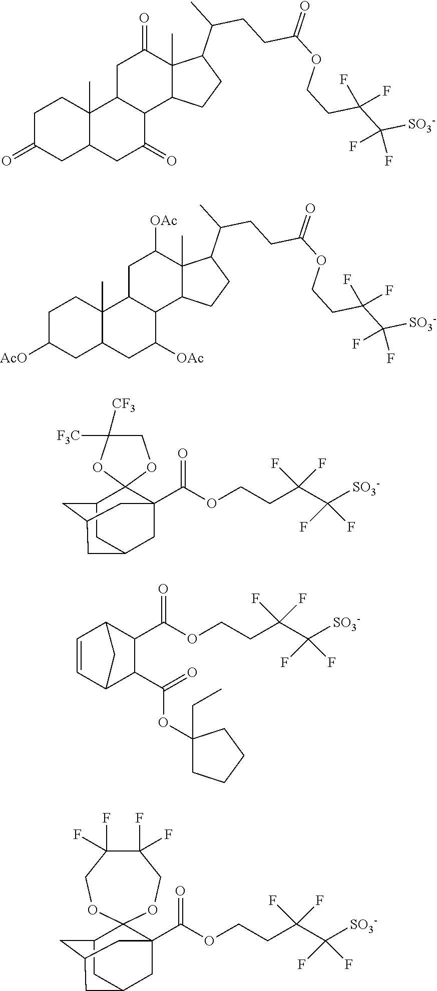

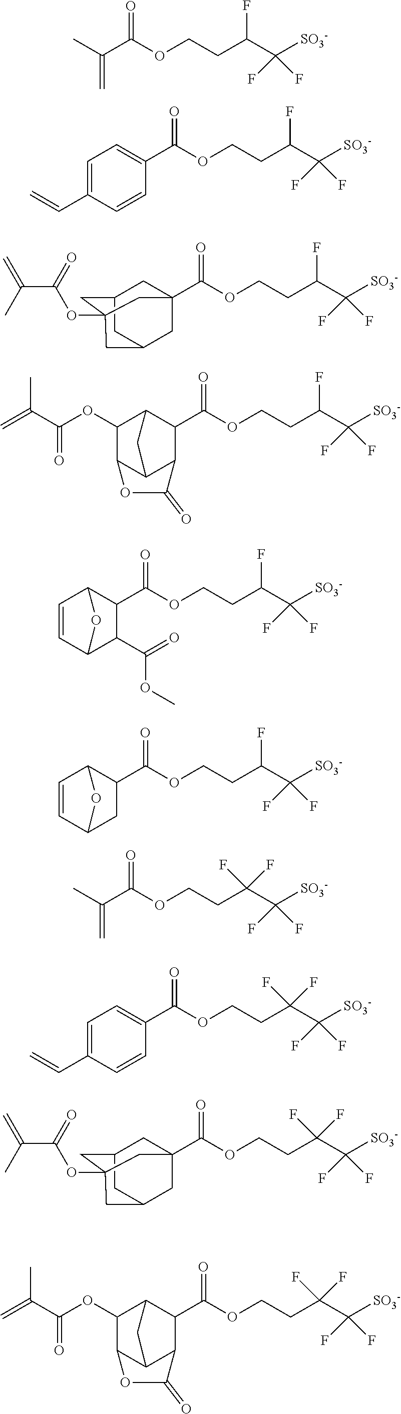

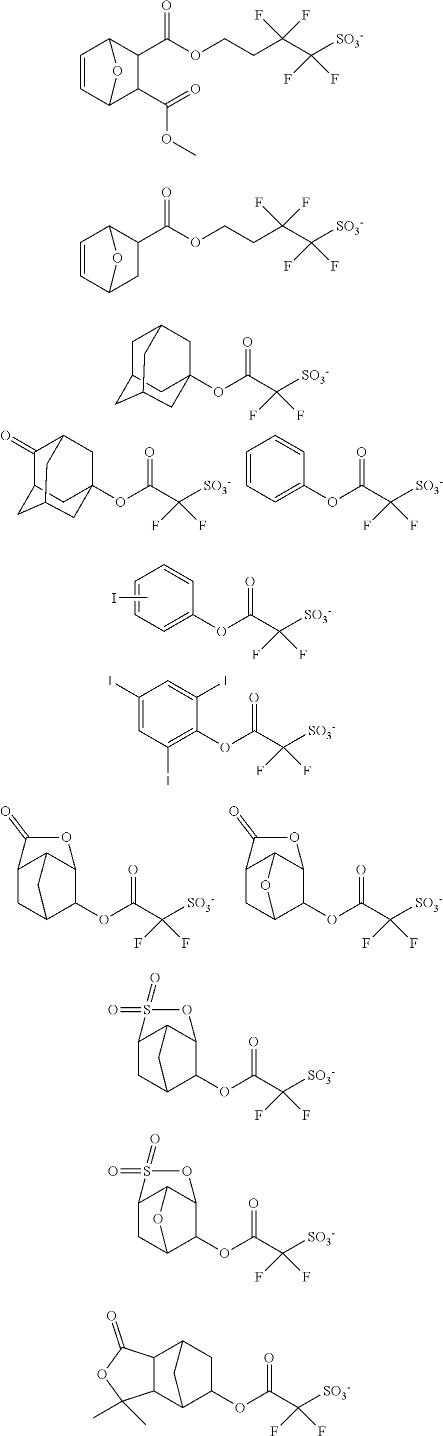

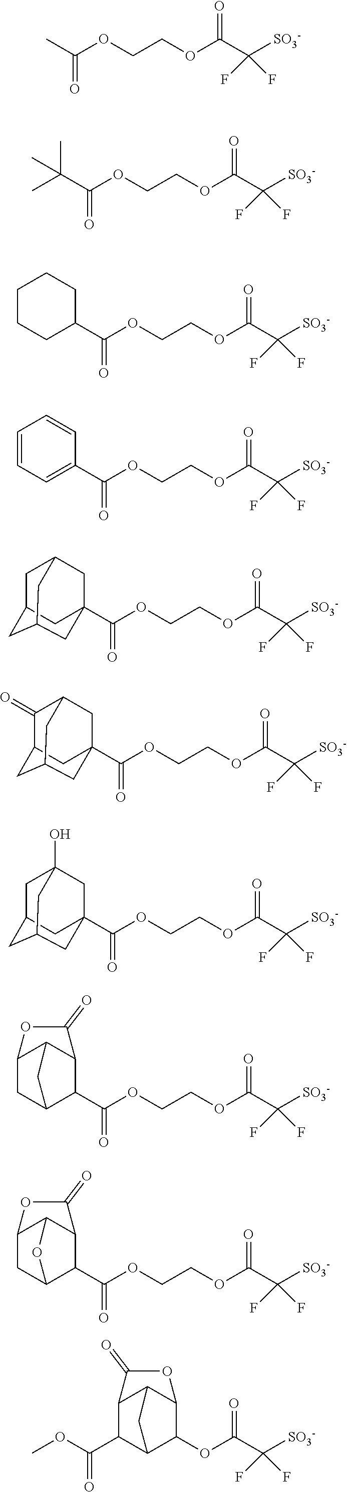

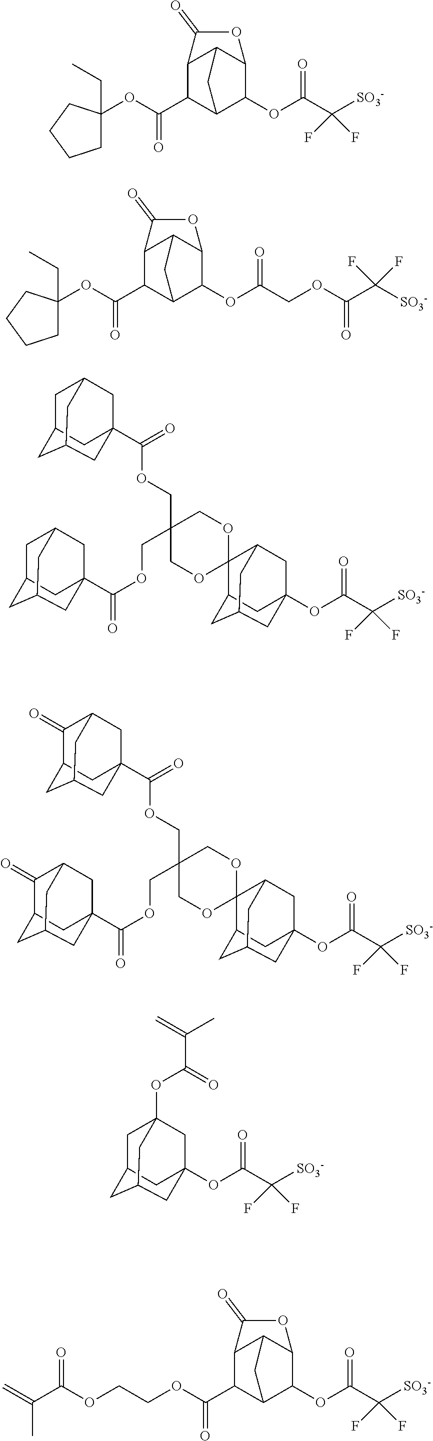

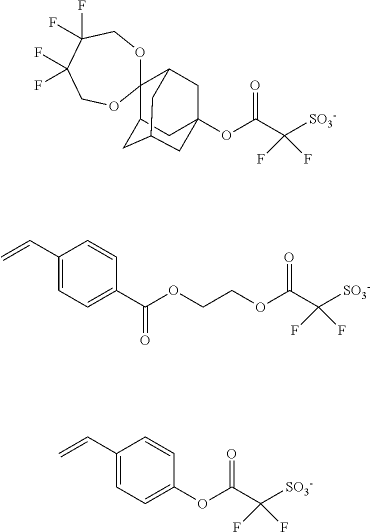

Examples of the anion having formula (5-4) are shown below, but not limited thereto.

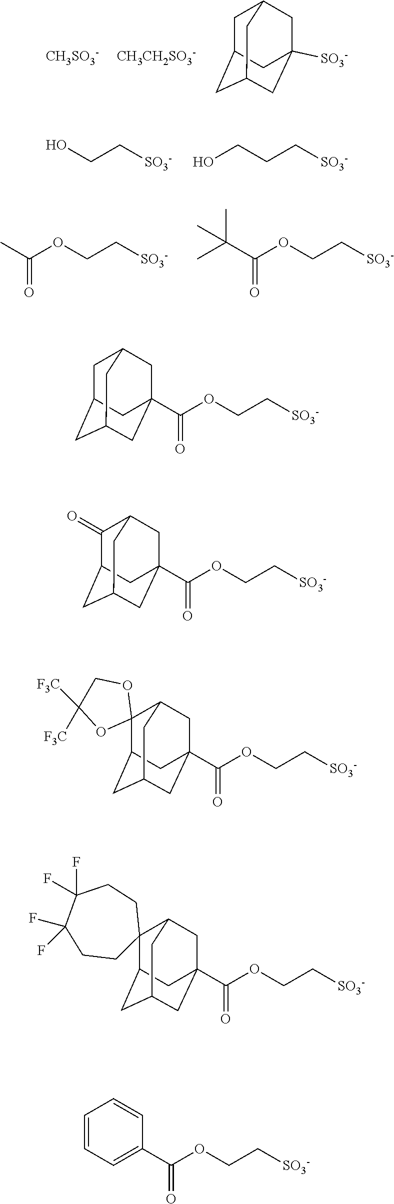

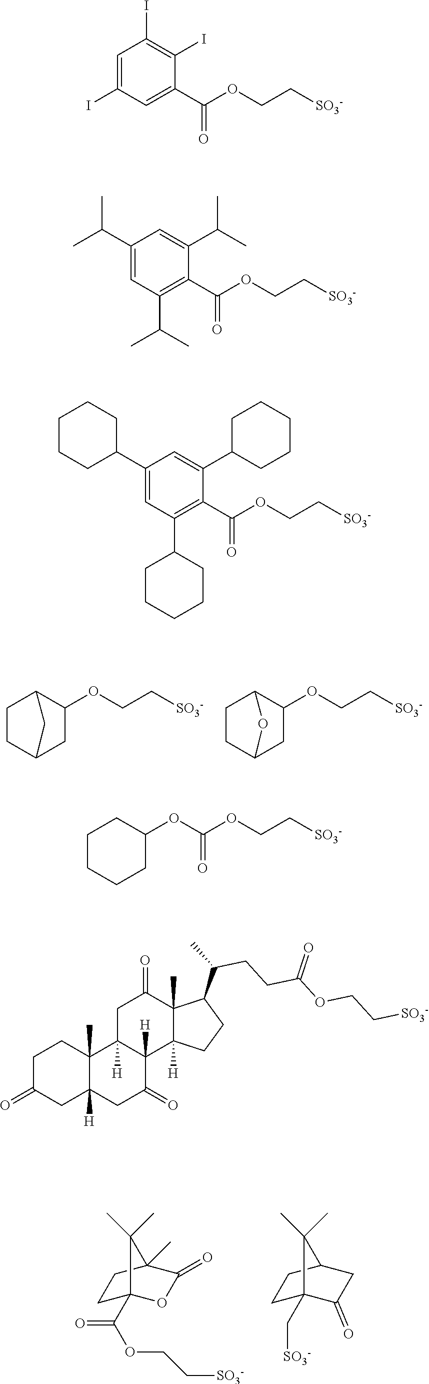

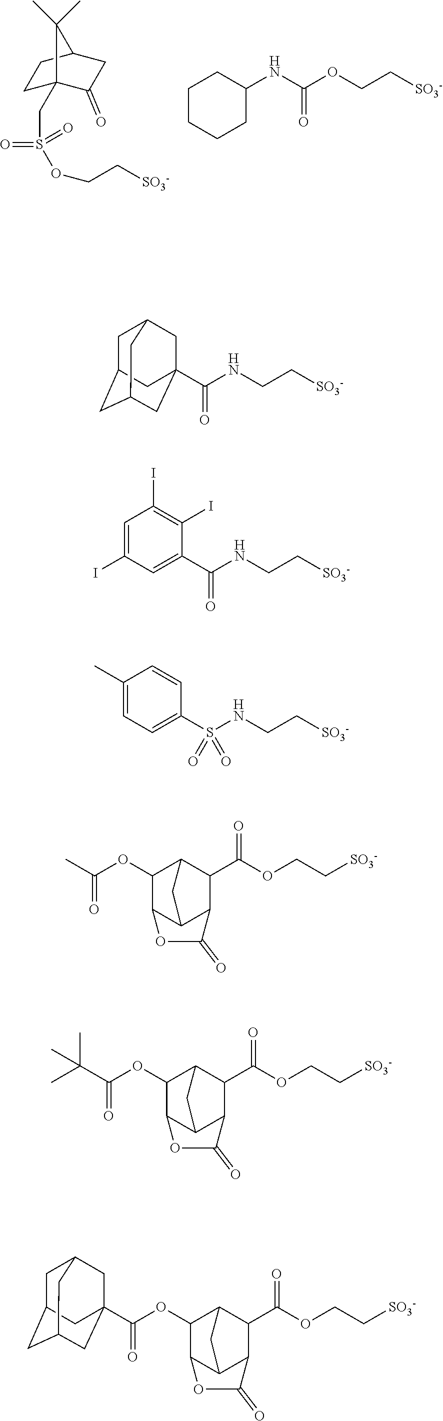

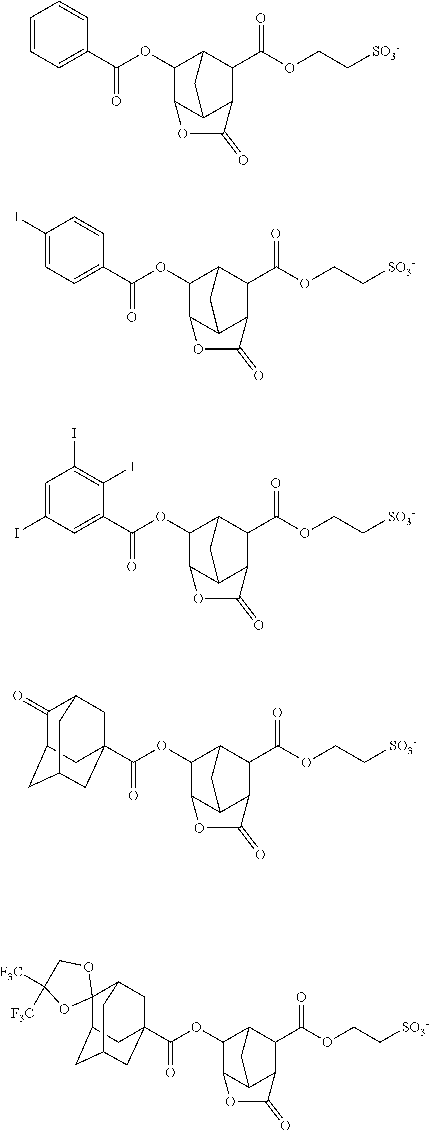

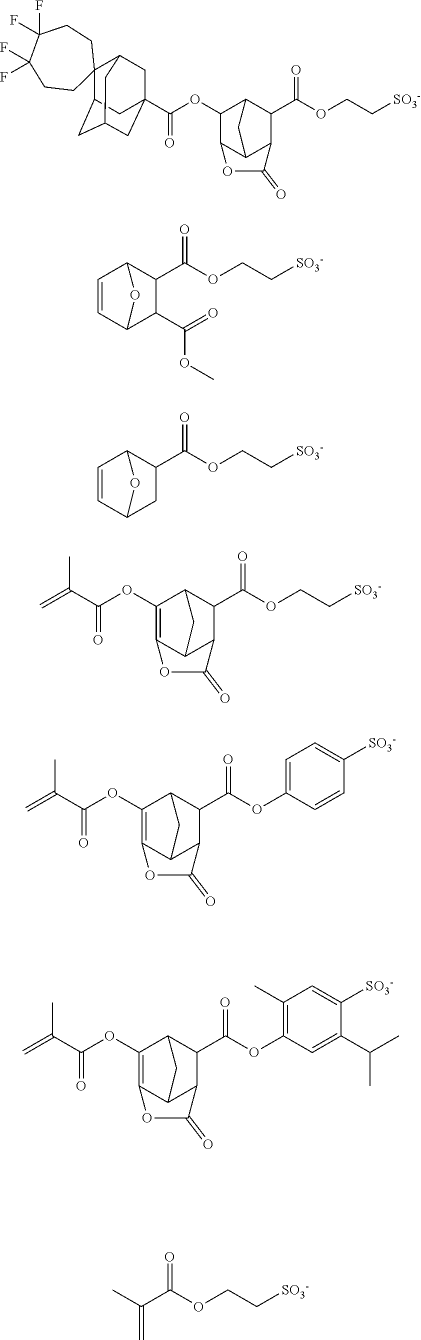

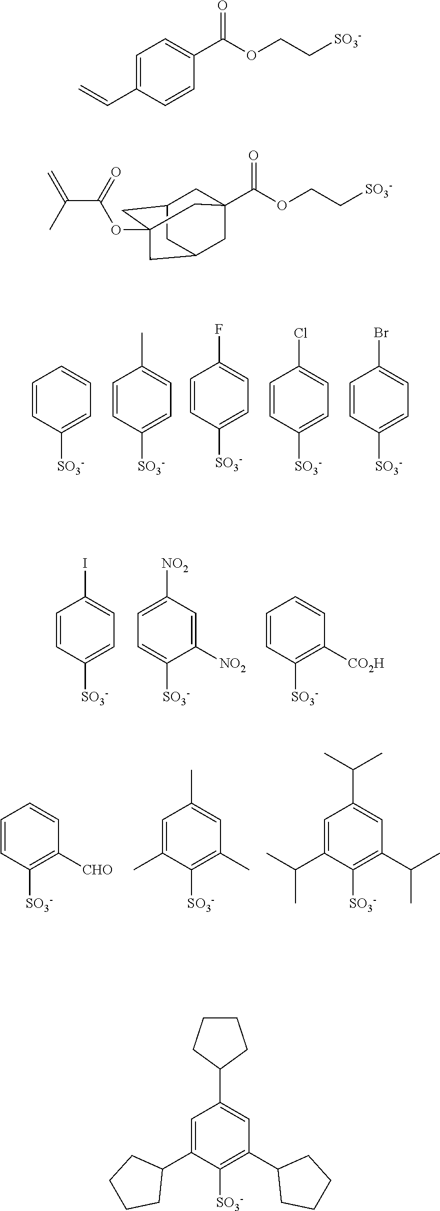

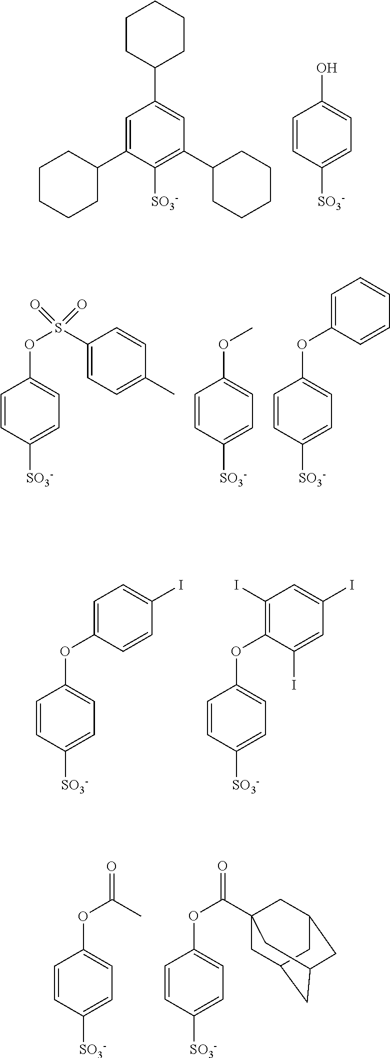

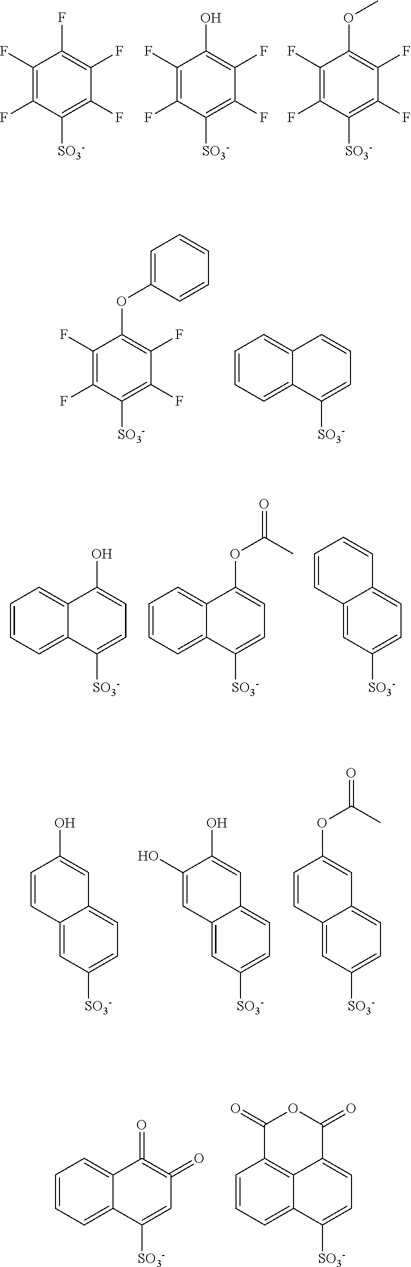

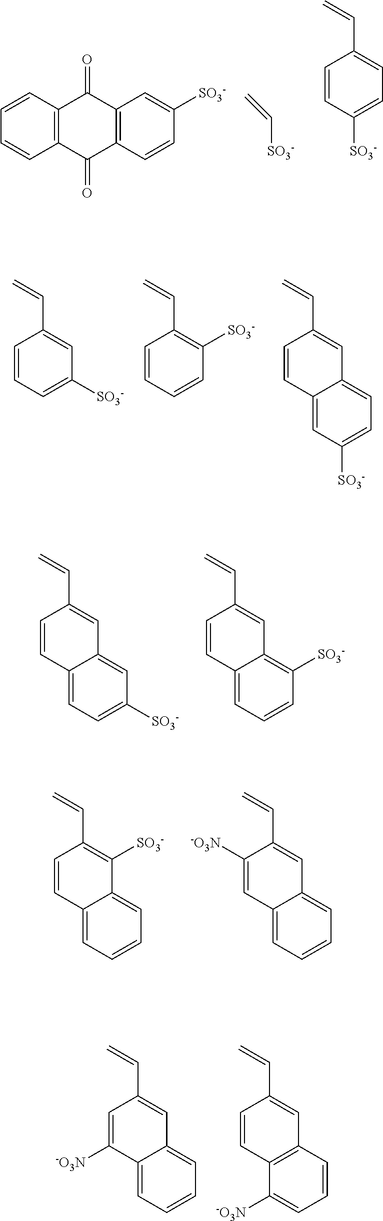

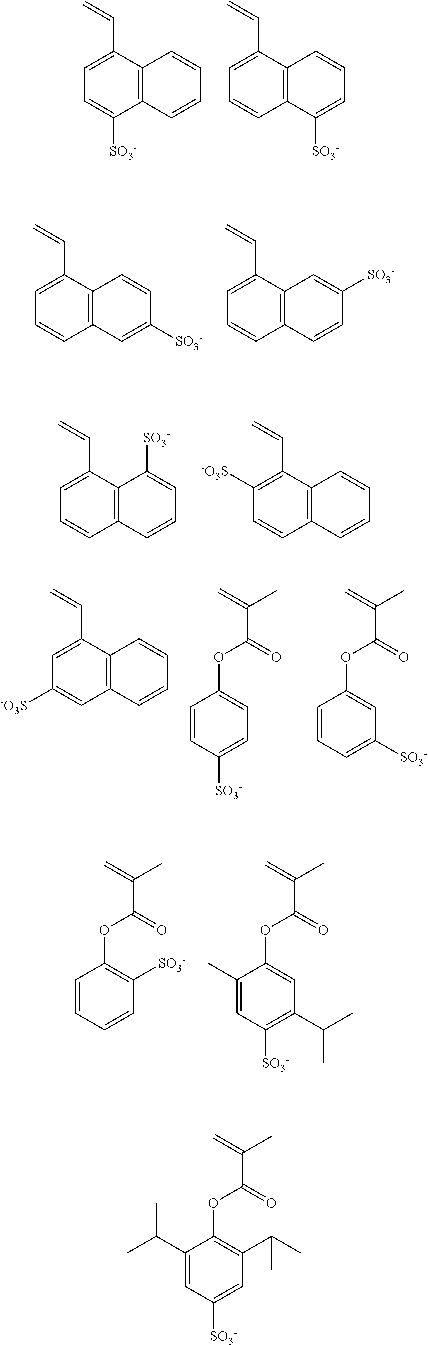

Examples of the anion having formula (5-5) are shown below, but not limited thereto.

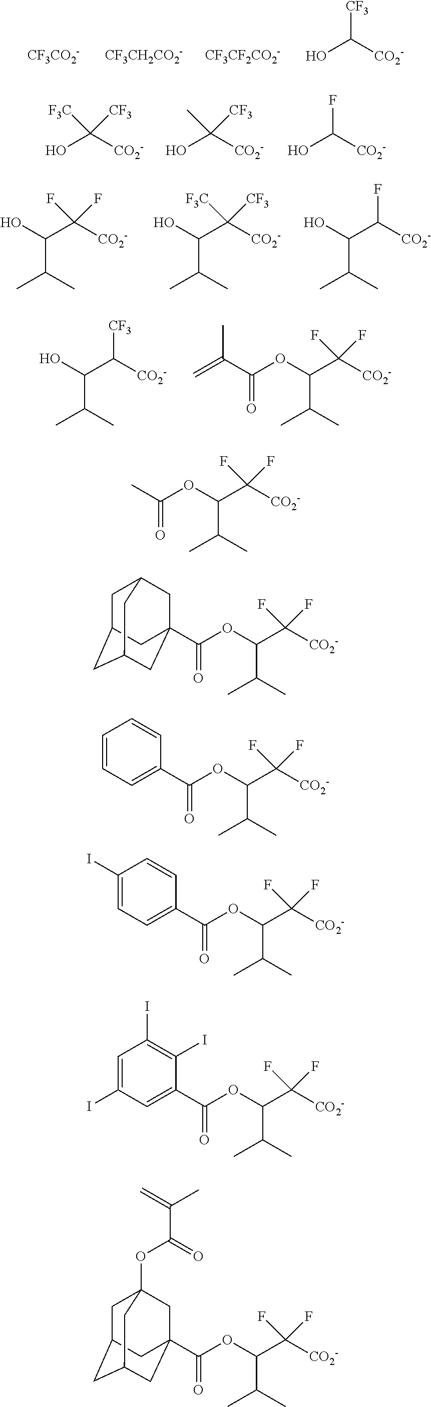

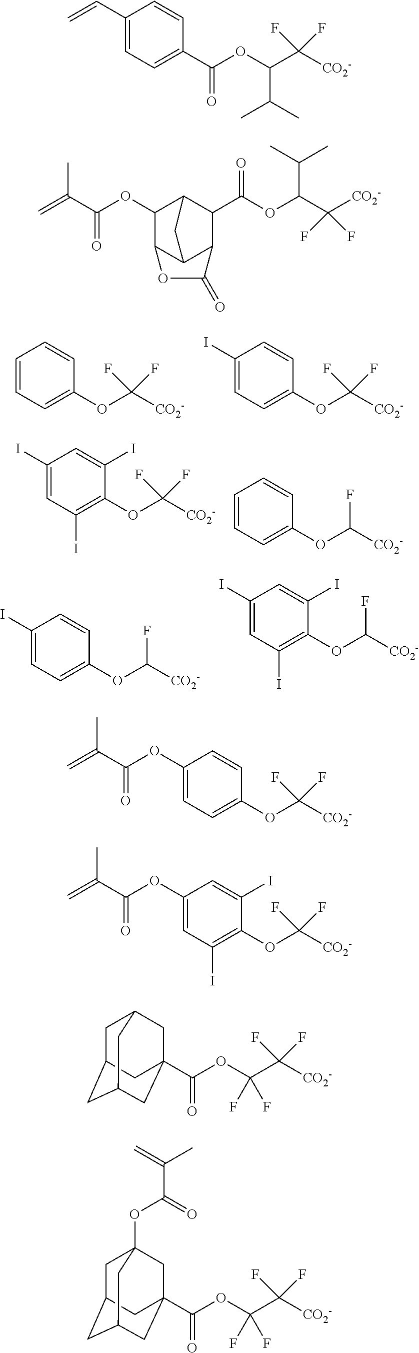

Examples of the anion having formula (5-6) are shown below, but not limited thereto.

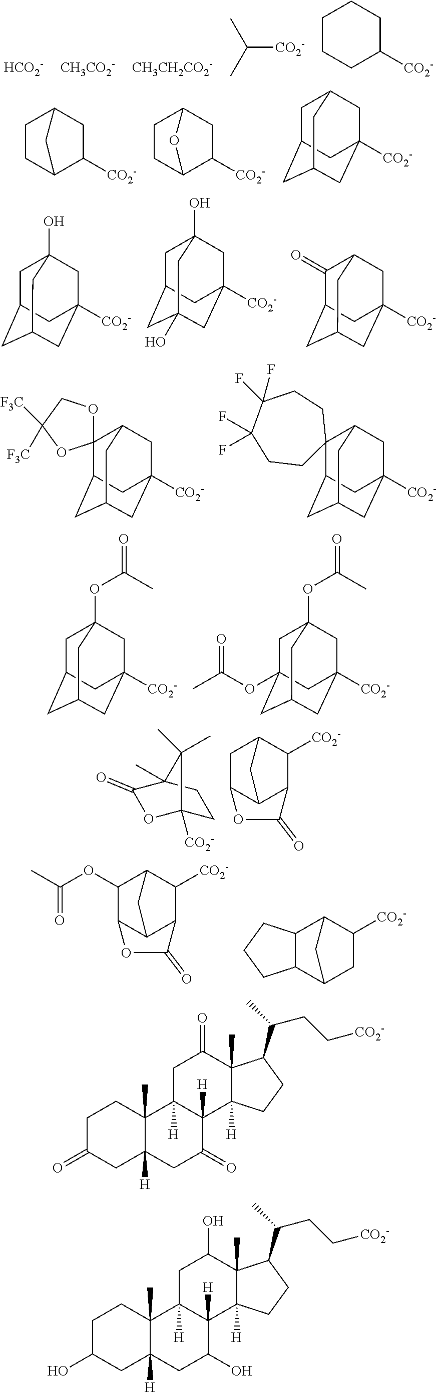

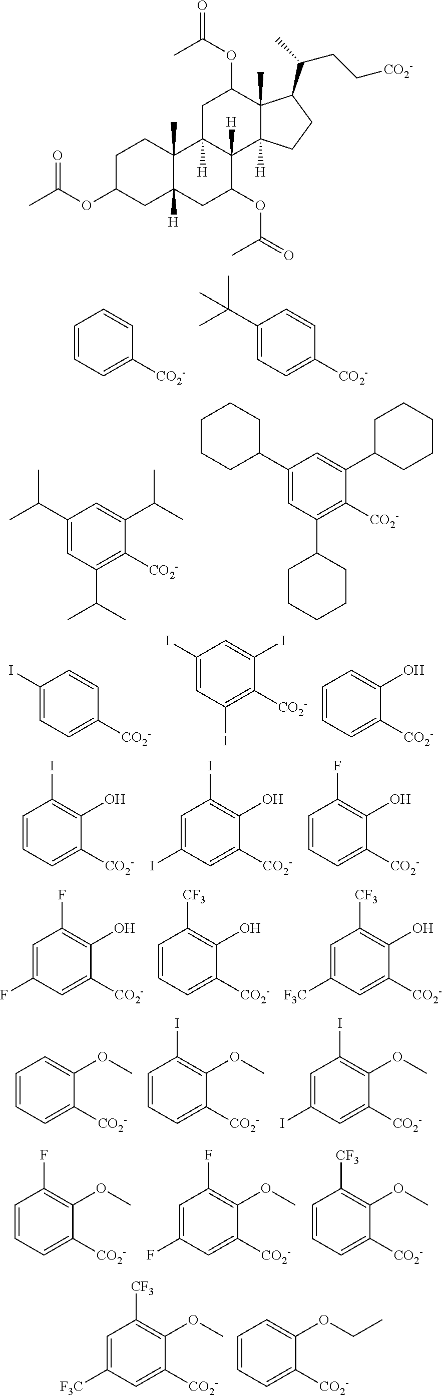

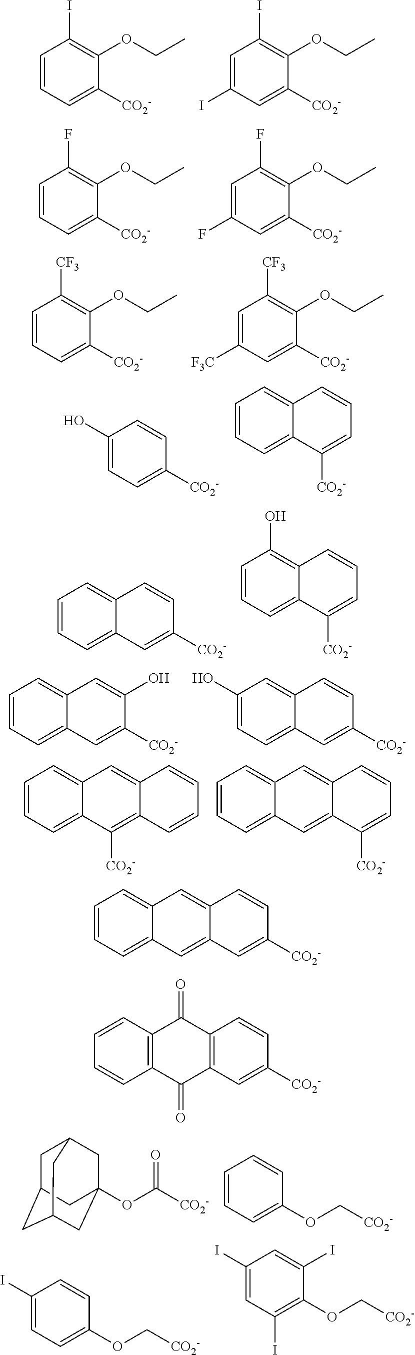

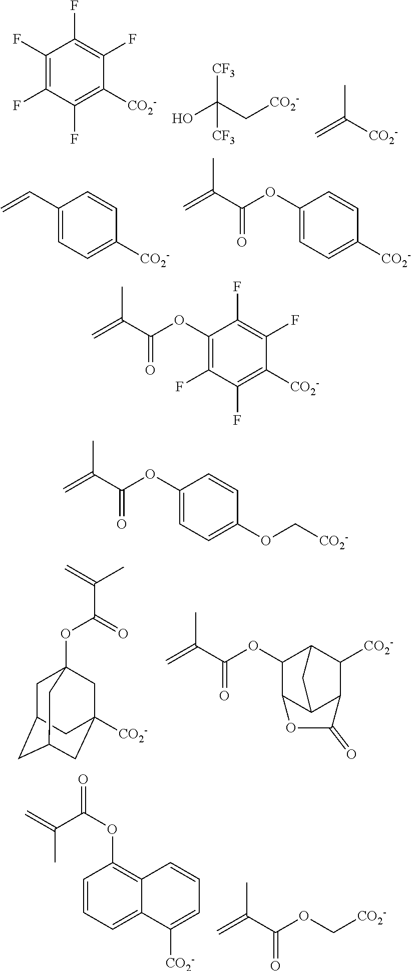

Examples of the anion having formula (5-7) are shown below, but not limited thereto.

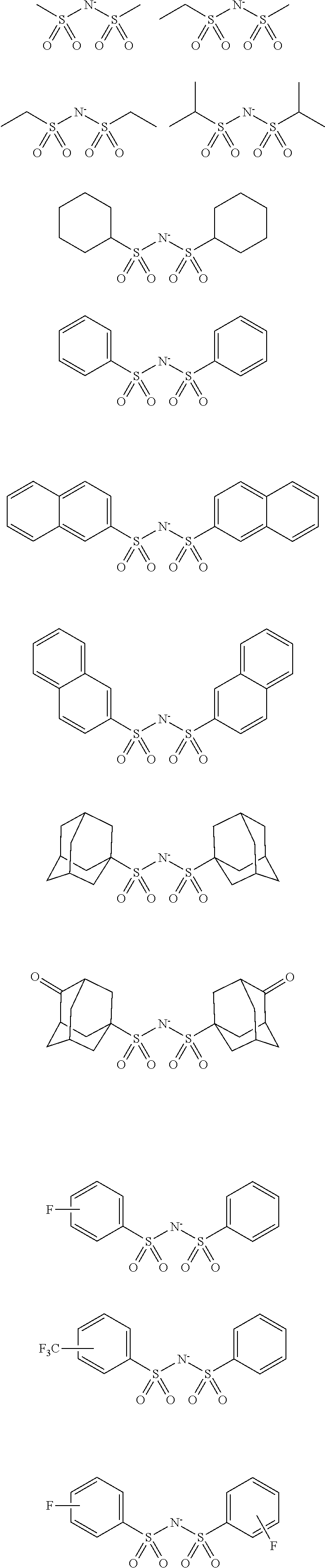

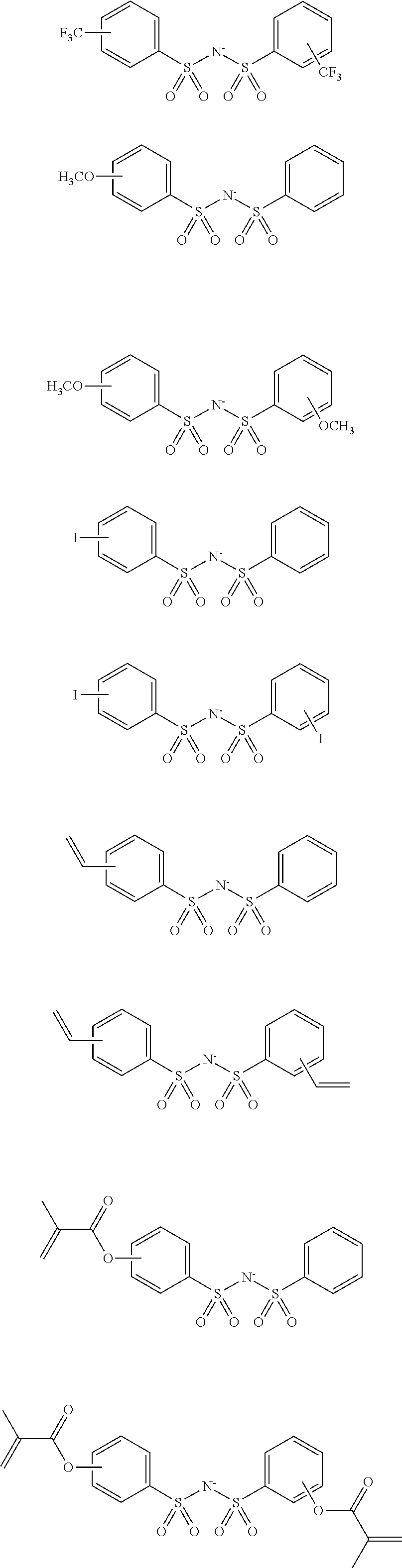

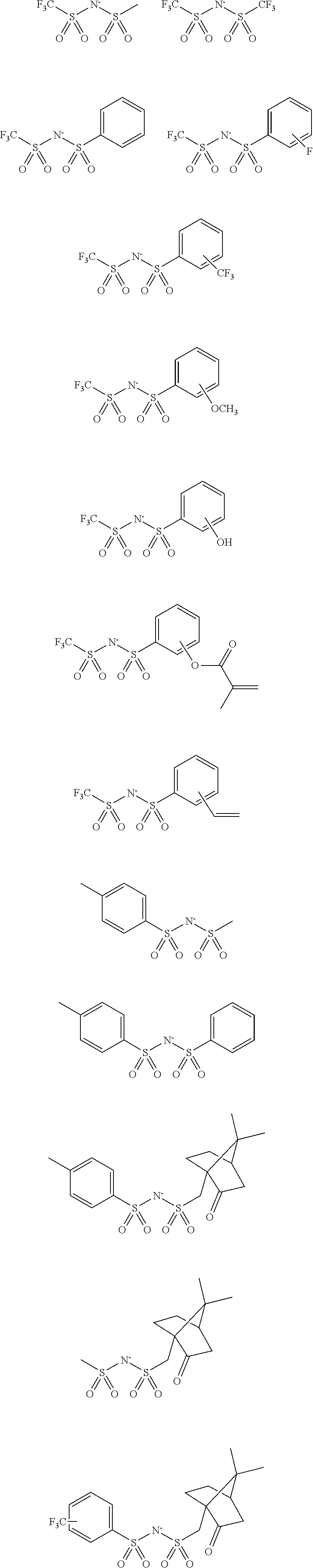

Examples of the anion having formula (5-8) are shown below, but not limited thereto.

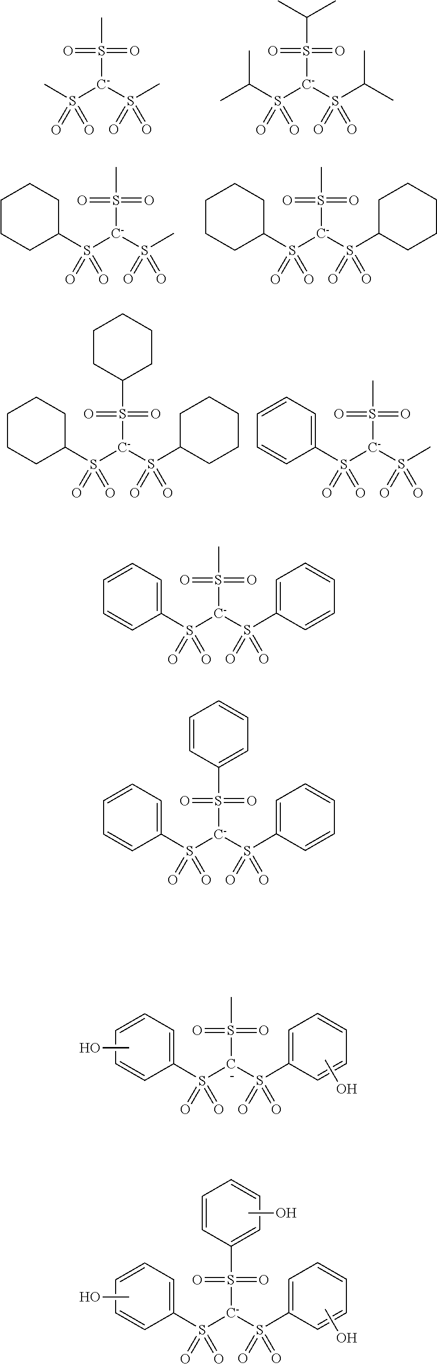

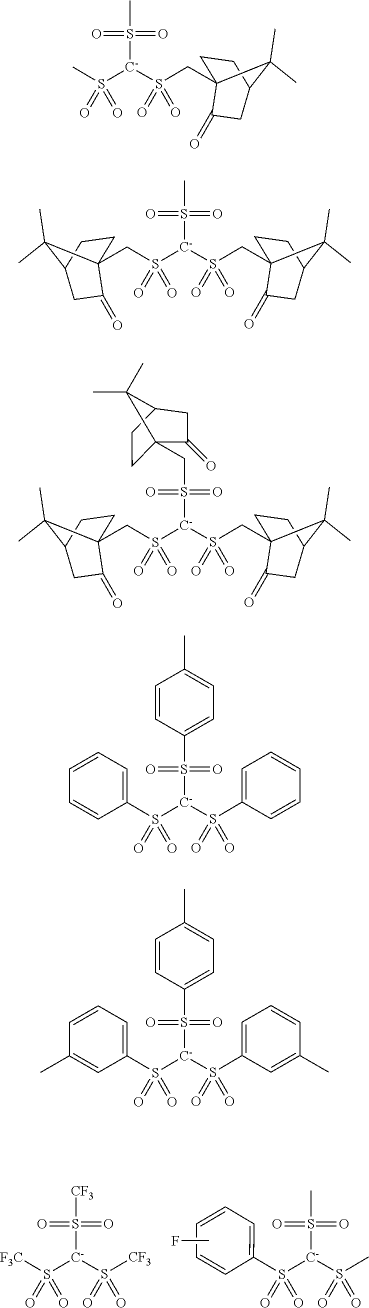

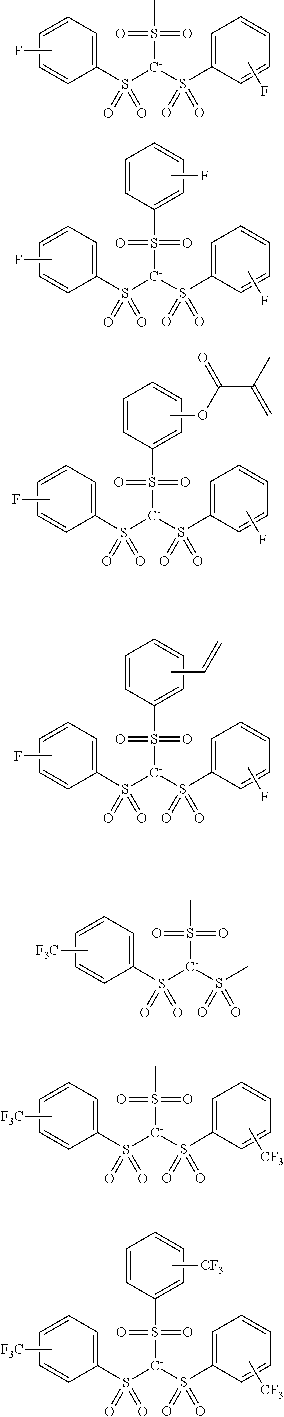

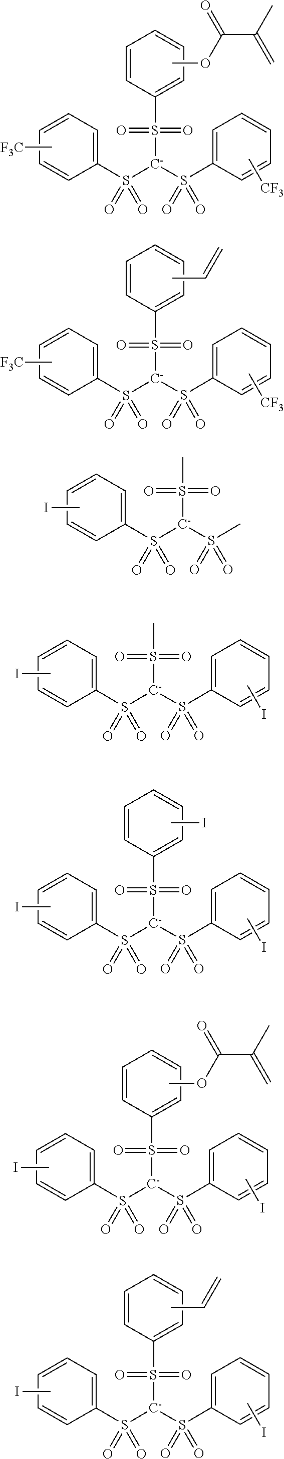

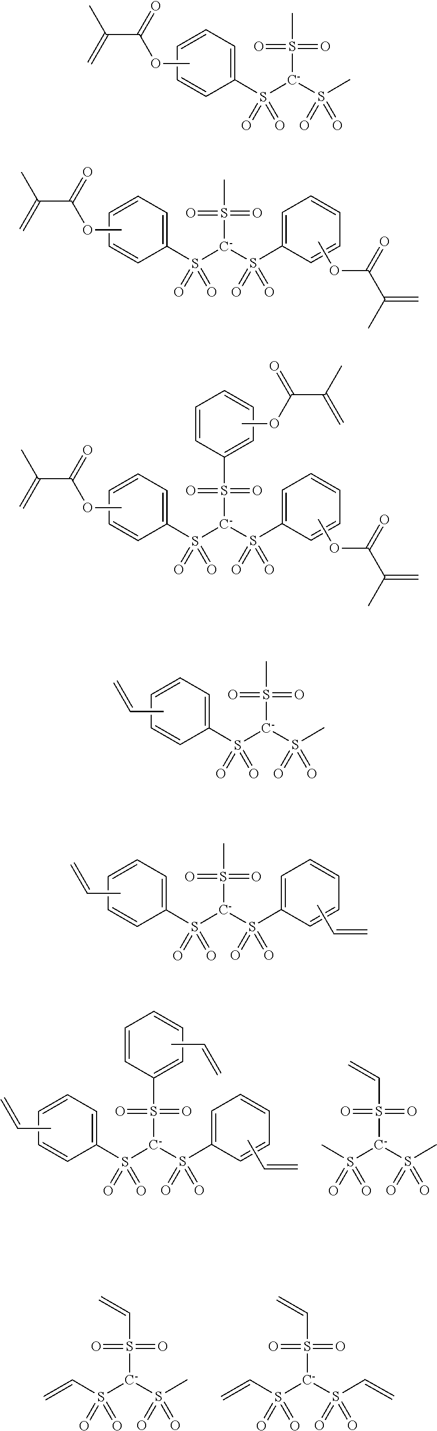

Examples of the anion having formula (5-9) are shown below, but not limited thereto.

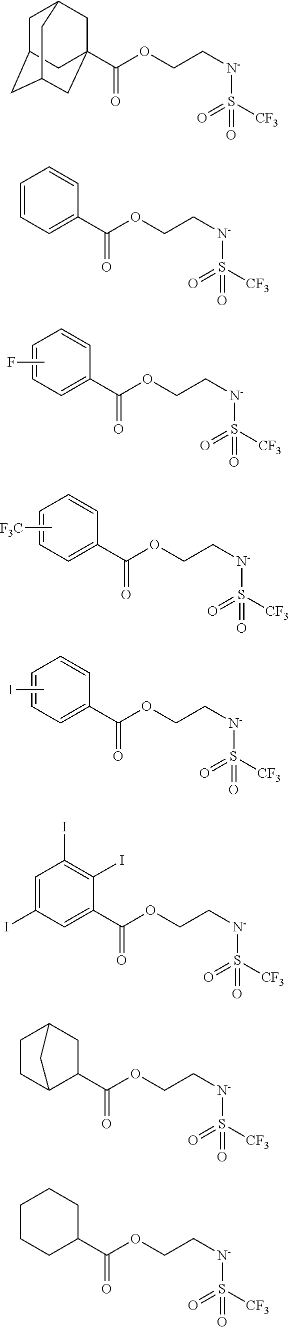

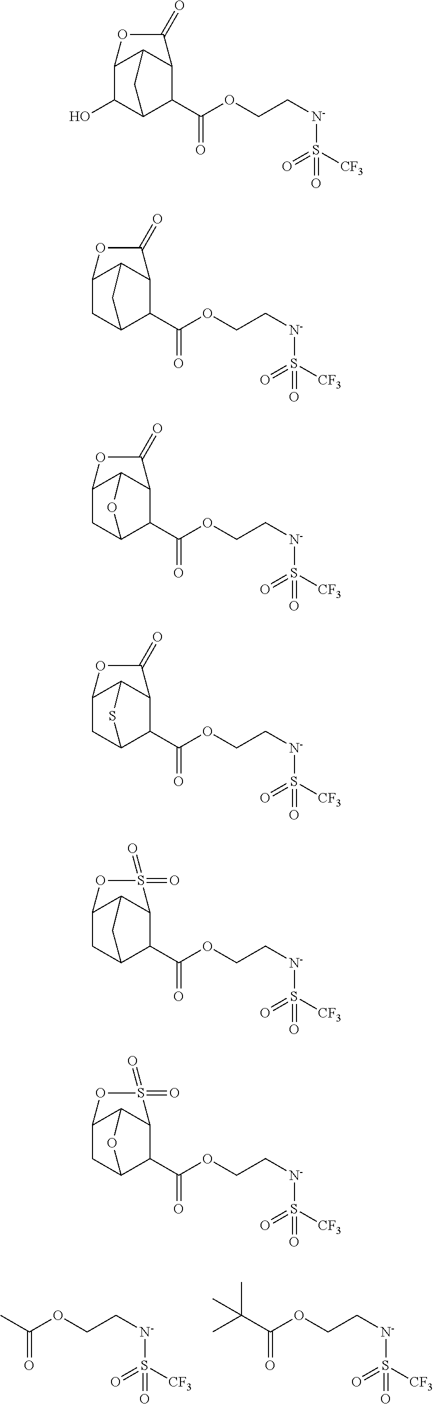

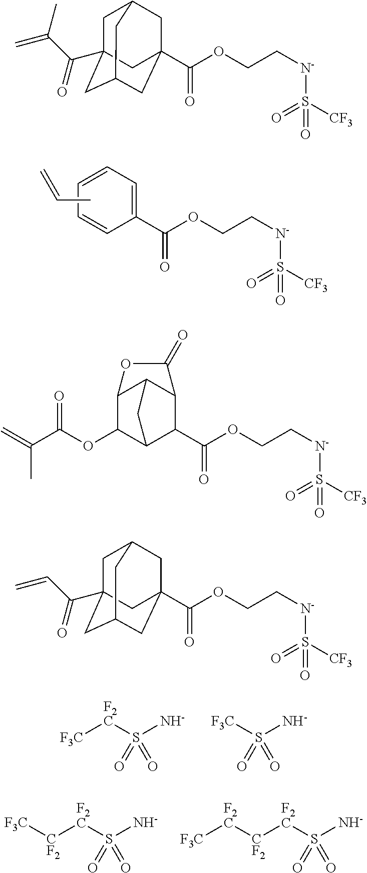

Examples of the onium salt having formula (5) include arbitrary combinations of the anion with the cation, both as exemplified above. For convenience sake, the onium salt defined above is referred to as onium salt having formula (5).

The onium salt having formula (5) is a useful photoacid generator. The onium salt having formula (5) may be used alone or in admixture of two or more. When a mixture of two or more onium salts having formula (5) is used, it is preferable to combine photoacid generators capable of generating acids having different acidity. Then the photoacid generator capable of generating an acid having lower acidity functions to quench the acid generated in the exposed region of a resist film and thus prevent the generated acid from diffusing to the unexposed region. This ensures that a pattern is formed at a high resolution.

In the resist composition, the hypervalent iodine compound and the photoacid generator are present in a molar ratio of preferably 1:1,000 to 1,000:1, more preferably 1:500 to 500:1.

When the onium salt has a bulky substituent group having a high molecular weight, it has a large excluded volume enough to fully suppress diffusion of the generated acid. This embodiment is advantageous in forming small-size patterns.

When the onium salt contains an element having a high EUV light-absorbing effect such as fluorine or iodine, a large number of secondary electrons are generated to promote decomposition of the cation. This embodiment is advantageous in forming small-size patterns at a high sensitivity.

### Carboxy-Containing Compound

The carboxy-containing compound is preferably a polymer comprising repeat units having the formula (6) or a compound having the formula (7).

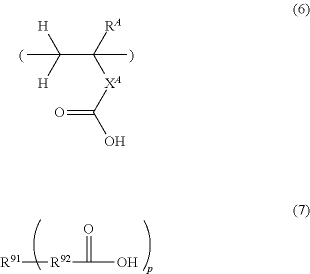

In formula (6), R^{A} is hydrogen, halogen, methyl or trifluoromethyl. X^{A} is a single bond, phenylene, naphthylene, or *—C(═O)—O—X^{A1}—. X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone.

In formula (7), p is 1, 2, 3 or 4.

In formula (7), R⁹¹ is a C₁-C₄₀ p-valent hydrocarbon group or C₂-C₄₀ p-valent heterocyclic group. When p=2, R⁹¹ may also be an ether bond, carbonyl group, azo group, thioether bond, carbonate bond, carbamate bond, sulfinyl group or sulfonyl group. Some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety.

The p-valent hydrocarbon group represented by R⁹¹ may be saturated or unsaturated and straight, branched or cyclic. The p-valent hydrocarbon group is obtained by eliminating “p” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptene, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The p-valent heterocyclic group represented by R⁹¹ is obtained by eliminating “p” number of hydrogen atoms from a heterocyclic compound. Suitable heterocyclic compounds include furane, pyridine, pyrazole, and thiazolidine.

Also included are the p-valent hydrocarbon groups or p-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the p-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

In formula (7), R⁹² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety. When p is 2, 3 or 4, a plurality of R⁹² may be identical or different.

The hydrocarbylene group represented by R⁹² may be saturated or unsaturated and straight, branched or cyclic. Examples thereof include C₁-C₁₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl; C₃-C₁₀ cyclic saturated hydrocarbylene groups such as cyclopentanediyl, cyclohexanediyl, norbornanediyl and adamantanediyl; C₂-C₁₀ unsaturated aliphatic hydrocarbylene groups such as vinylene and propene-1,3-diyl; C₆-C₁₀ arylene groups such as phenylene and naphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, thioether bond, ester bond, sulfonate ester bond, carbonate bond, carbamate bond, lactone ring, sultone ring, carboxylic anhydride (—C(═O)—O—C(═O)—).

Of the carboxylic acids having formula (7), those wherein p is 2, 3 or 4 are preferred. When these carboxylic acids are mixed with the hypervalent iodine compound, there is a likelihood of forming a robust resist film having a high molecular weight, which is preferred in view of etch resistance and developer resistance.

Examples of the carboxy-containing repeat unit having formula (6) are shown below, but not limited thereto. Herein R^{A} is as defined above.

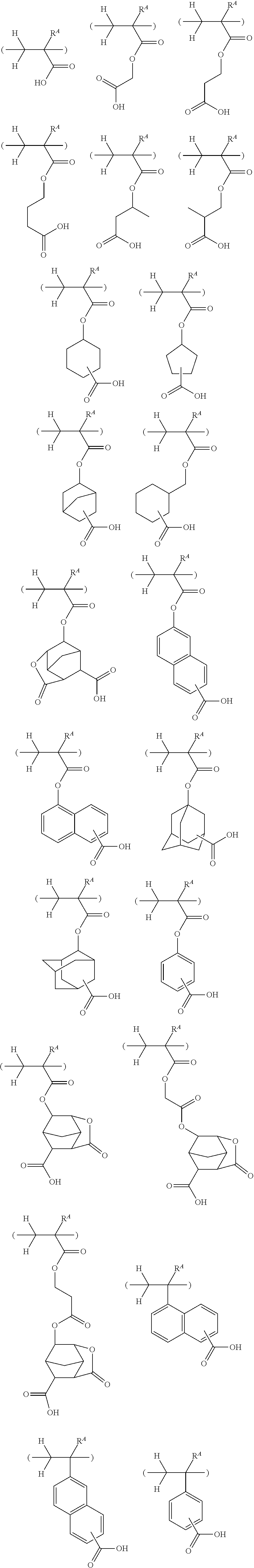

Examples of the carboxylic acid having formula (7) are shown below, but not limited thereto.

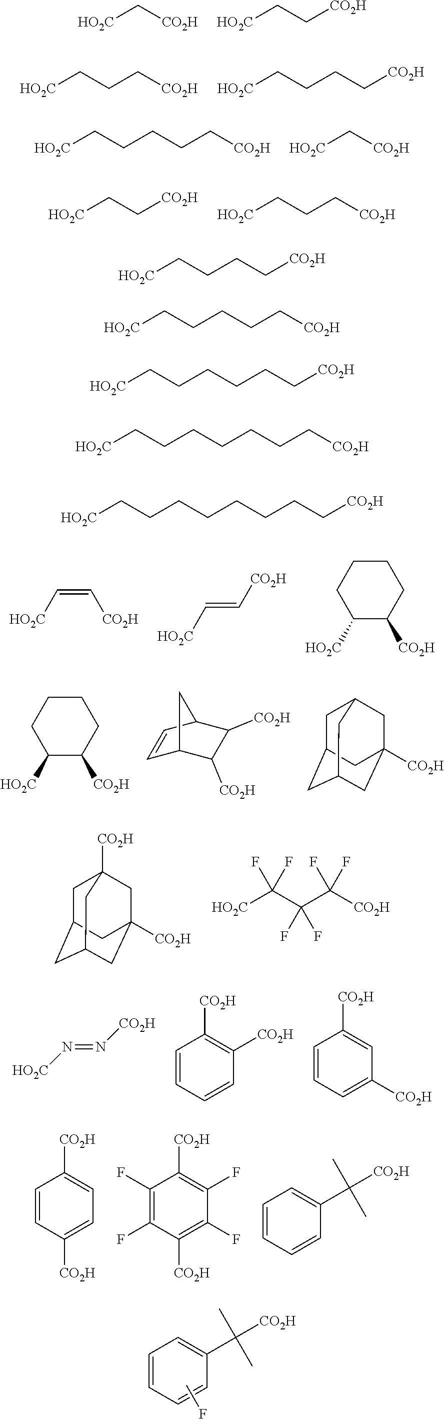

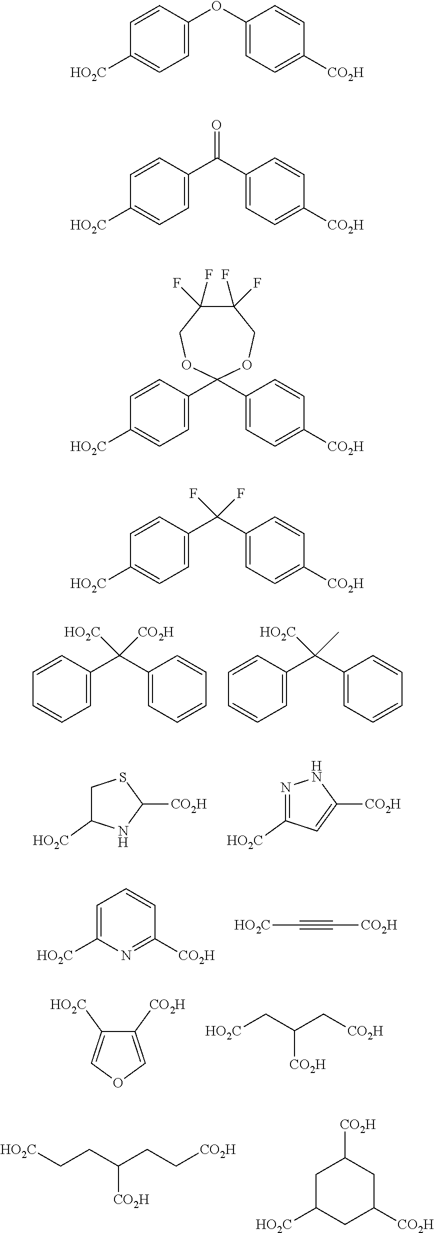

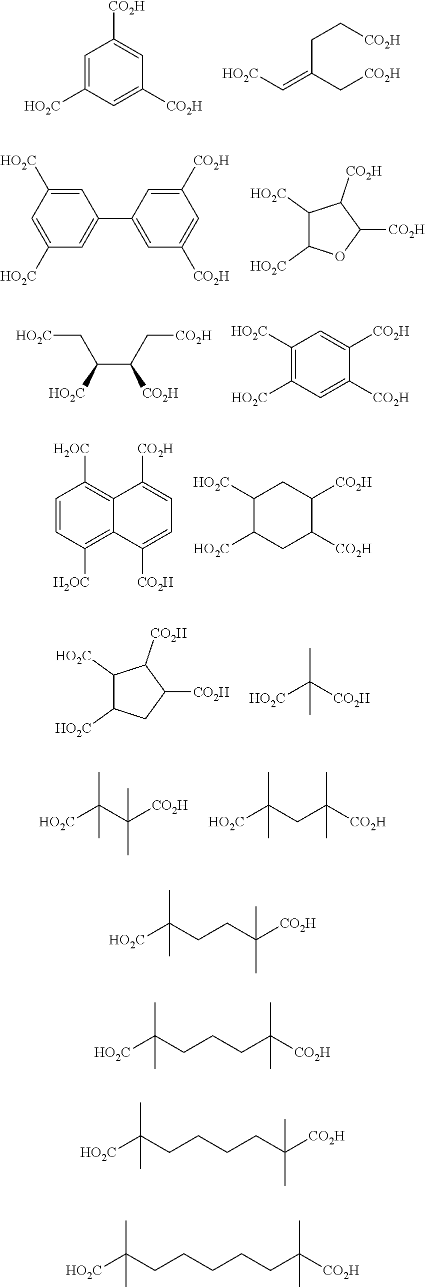

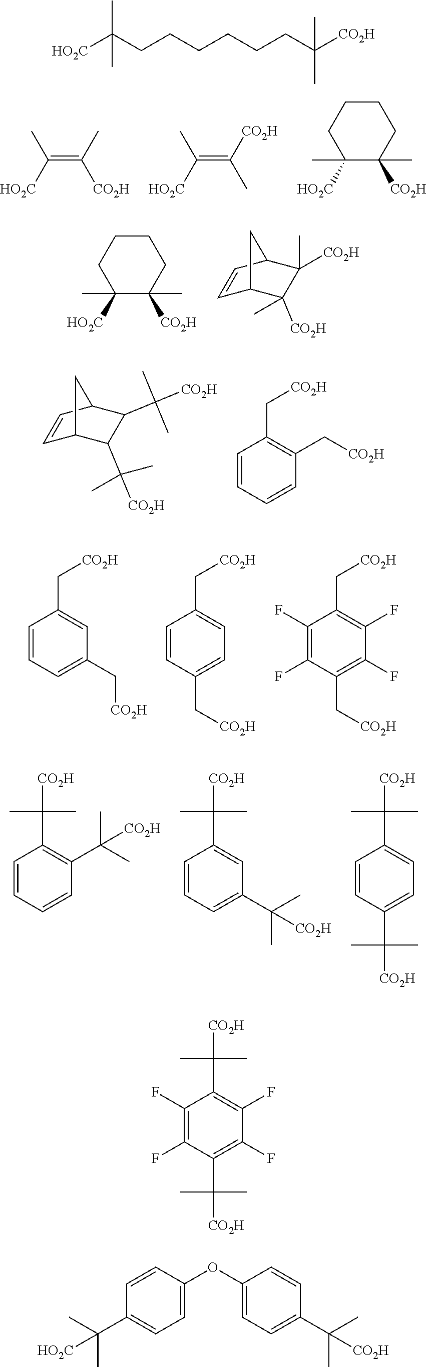

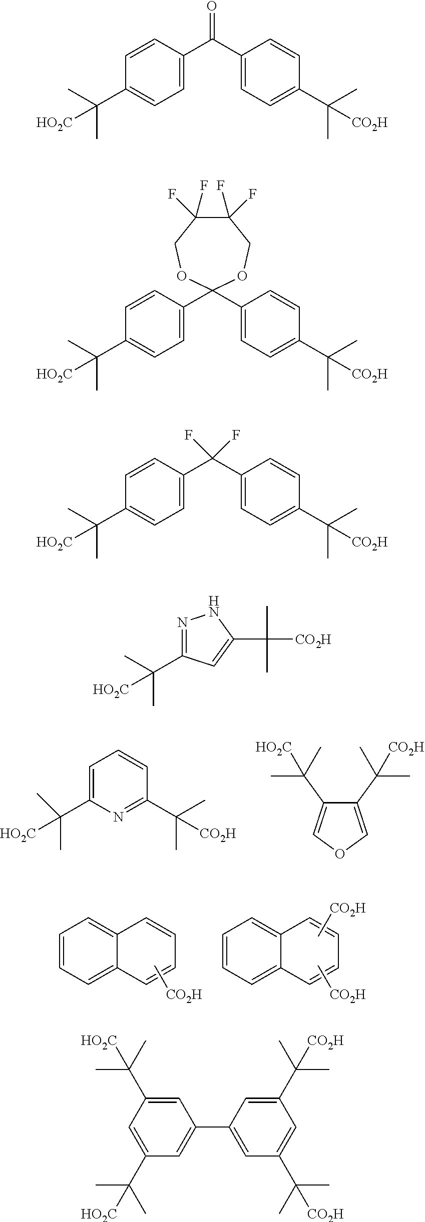

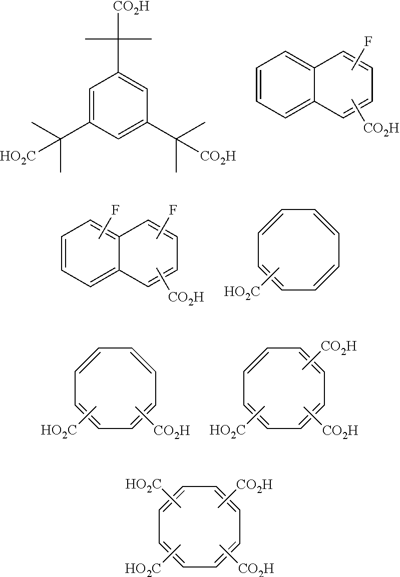

The carboxy-containing polymer comprising repeat units having formula (6) may further comprise repeat units other than the carboxy-containing repeat units having formula (6). Although the other repeat units are not particularly limited, preference is given to repeat units capable of increasing the solvent solubility of a polymer which is substantially insoluble when the polymer consists of carboxy-containing repeat units. The preferred other repeat units include repeat units having a robust skeleton, typically repeat units having a cyclic structure from which high etch resistance is expectable and repeat units having a styrene skeleton.

Examples of the other repeat unit are shown below, but not limited thereto. Herein R^{A} is as defined above, and X^{B} is each independently —CH₂— or —O—.

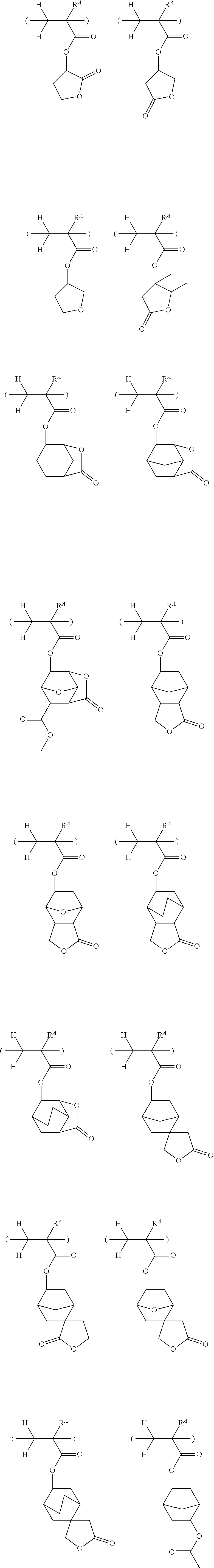

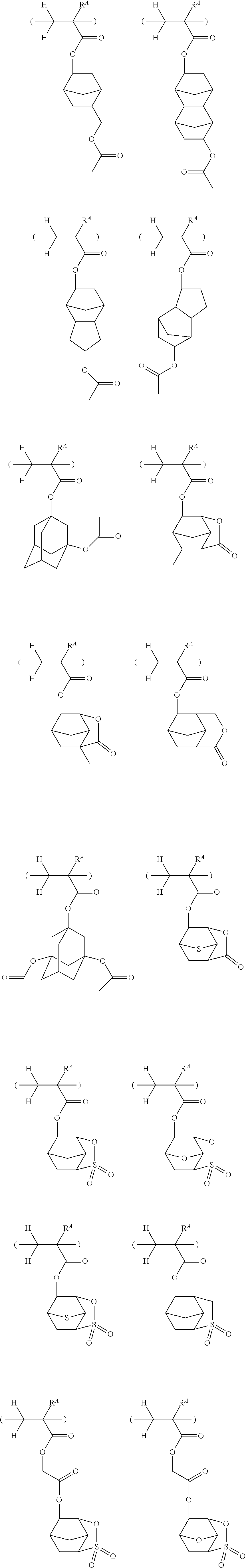

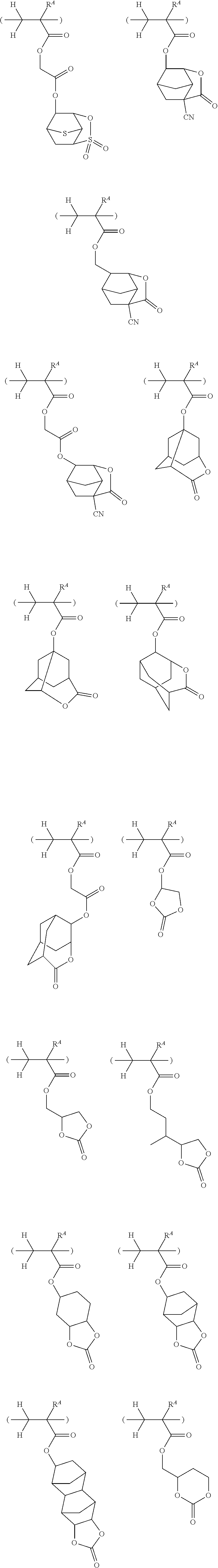

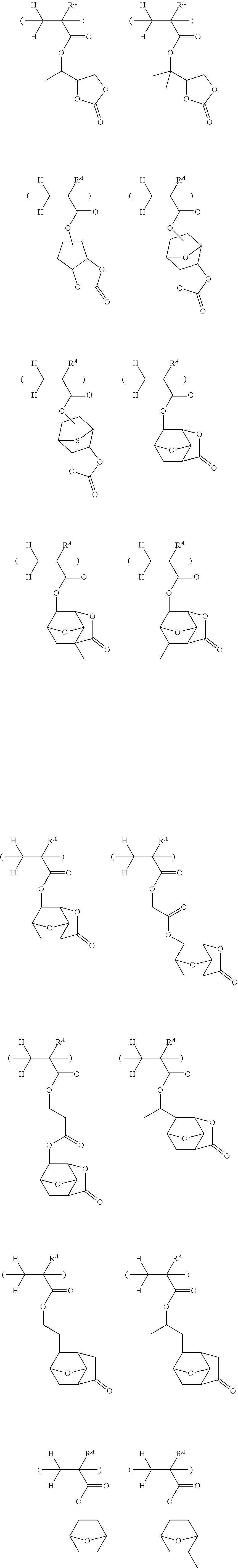

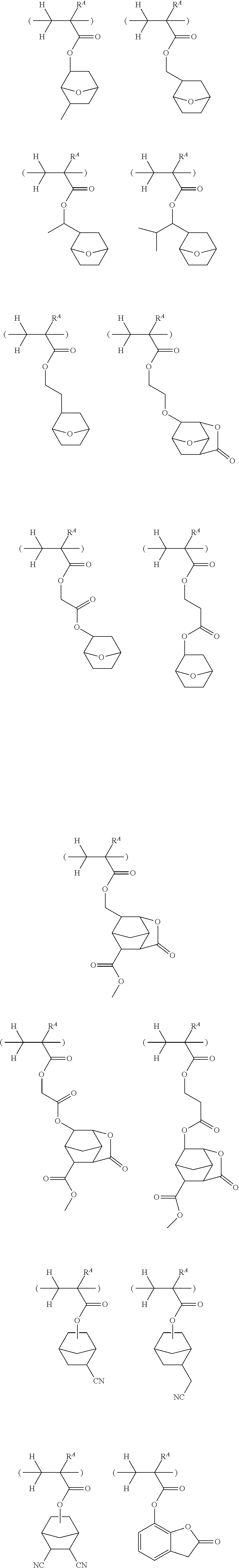

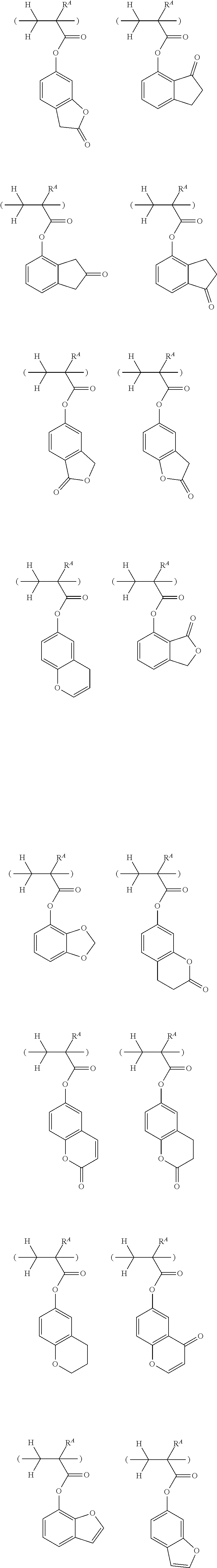

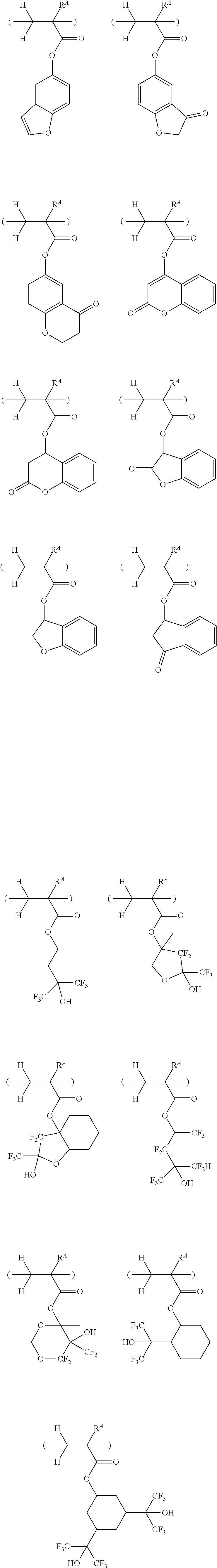

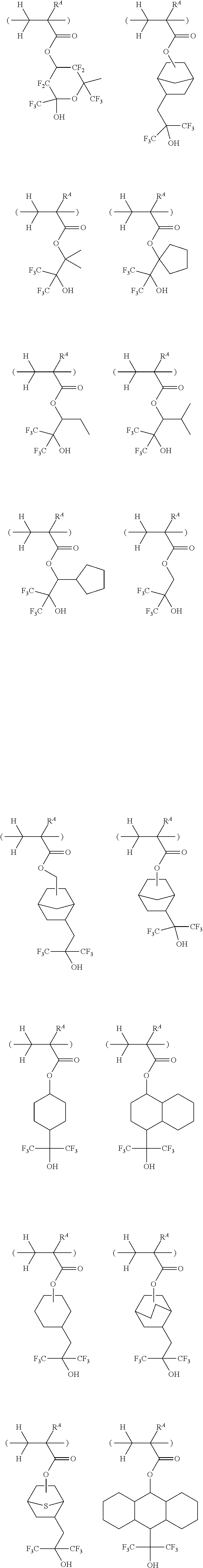

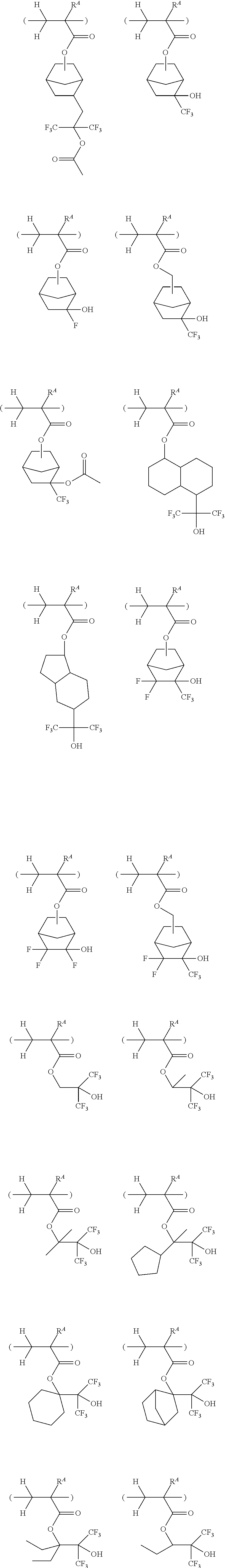

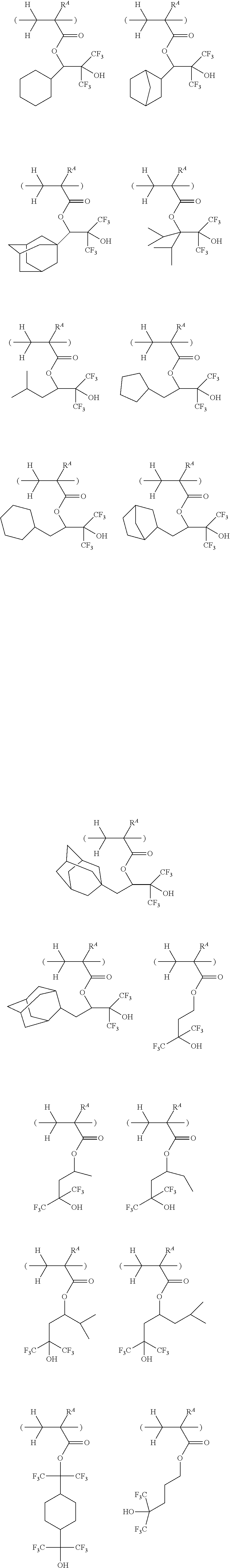

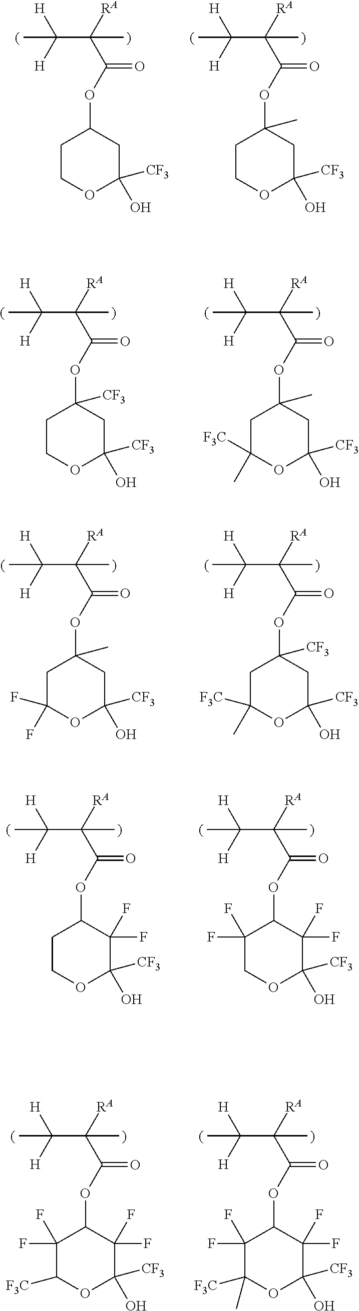

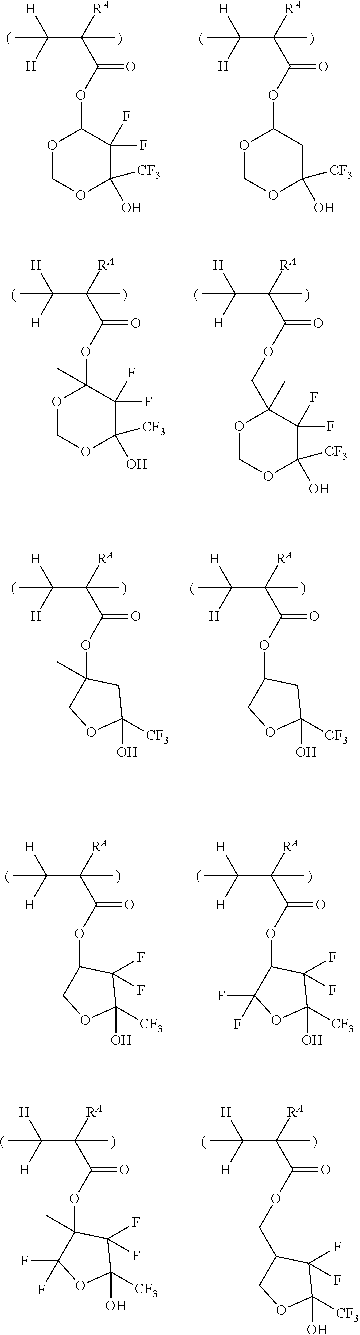

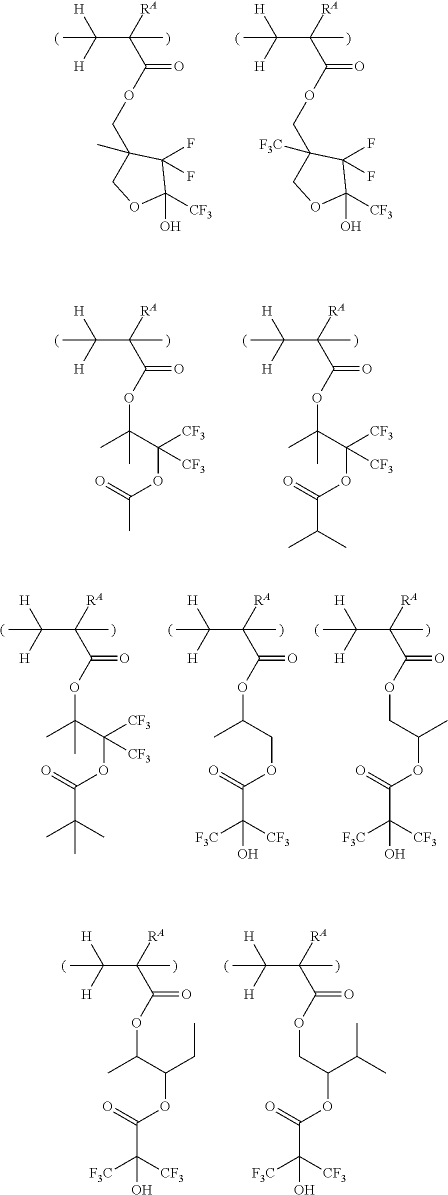

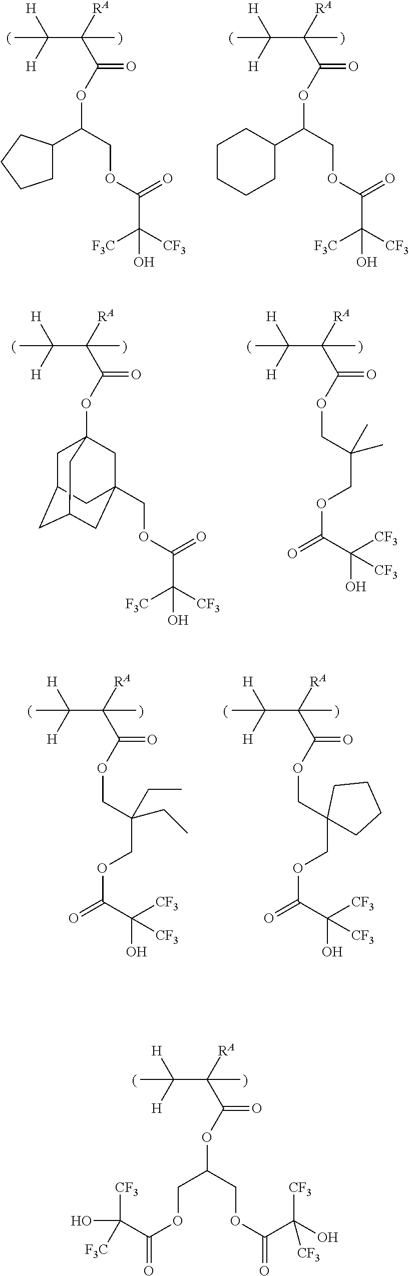

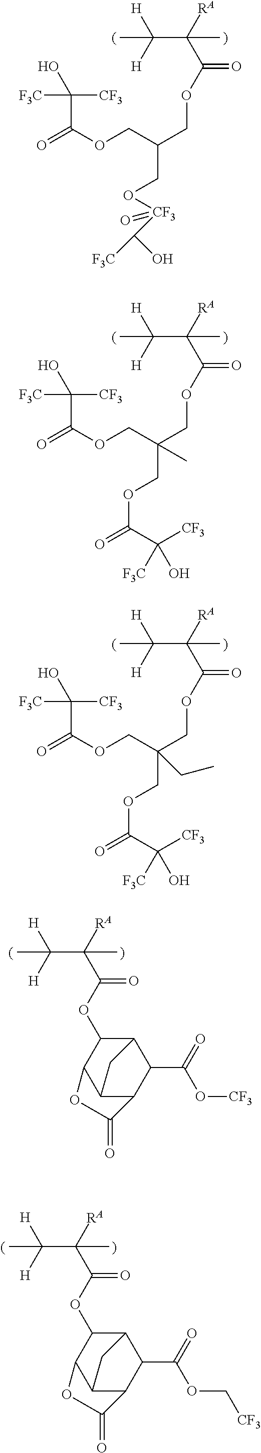

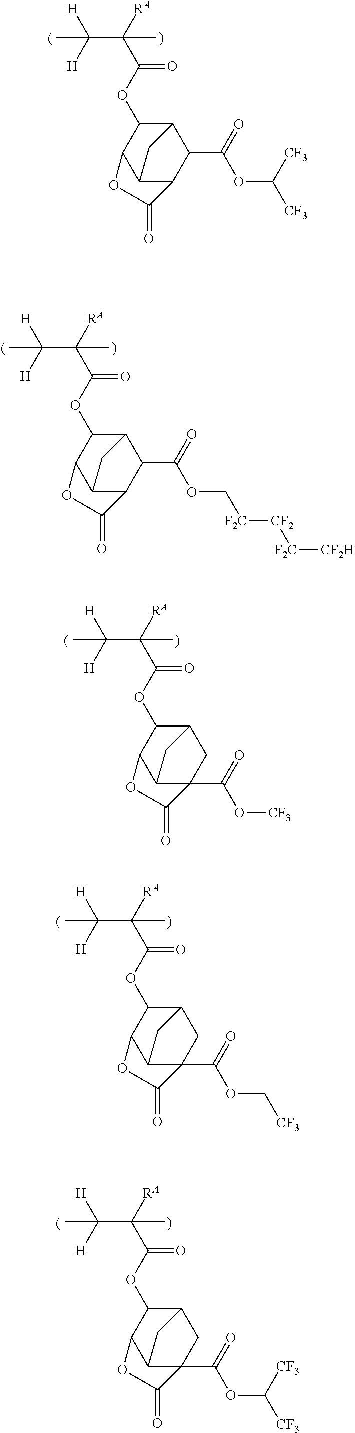

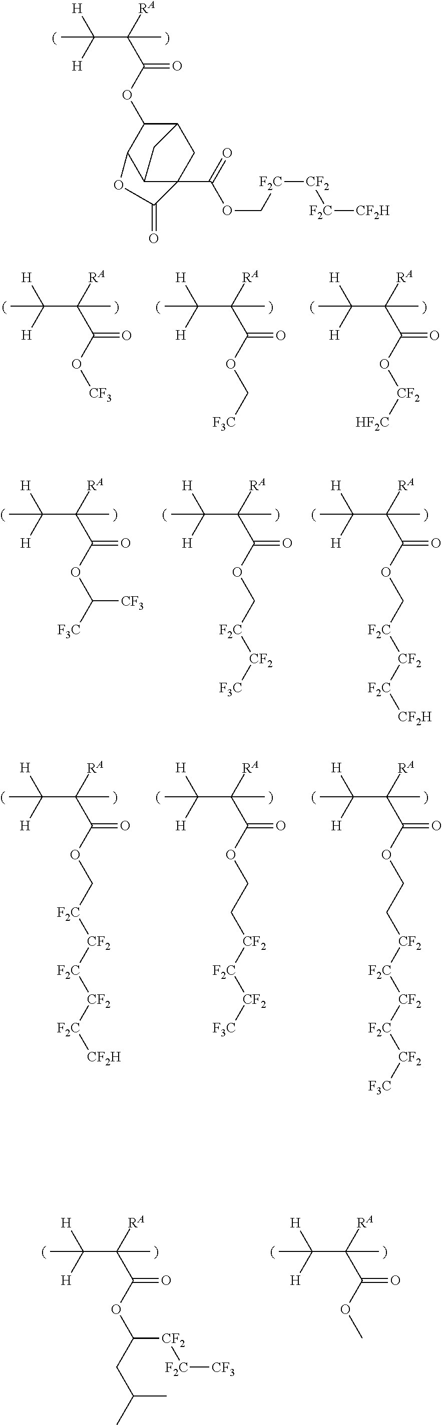

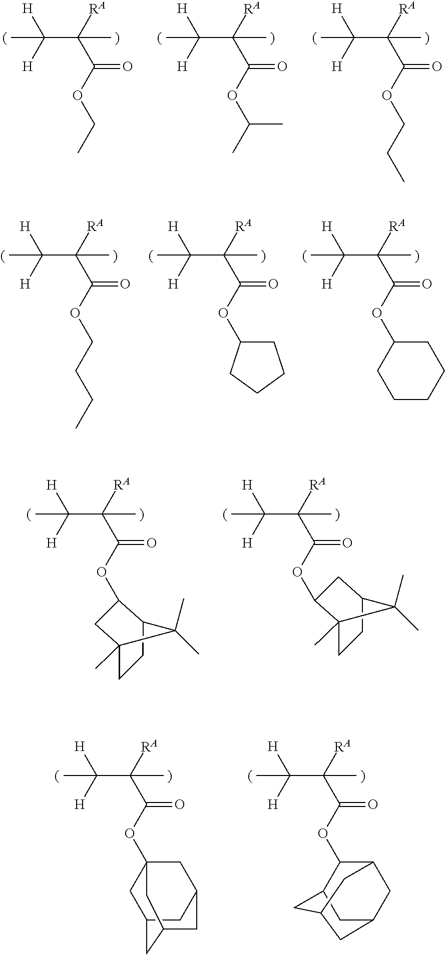

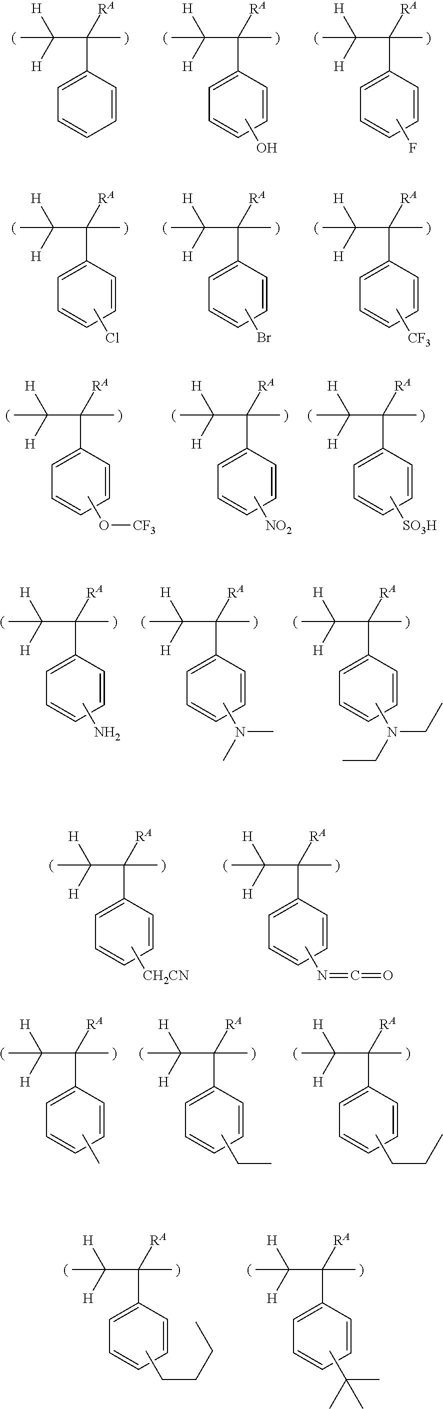

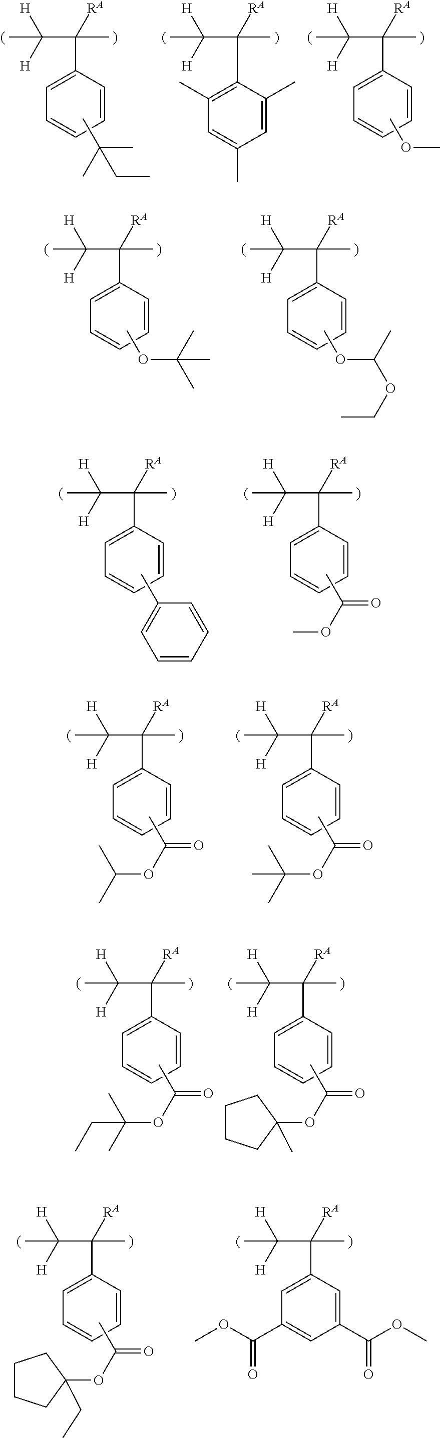

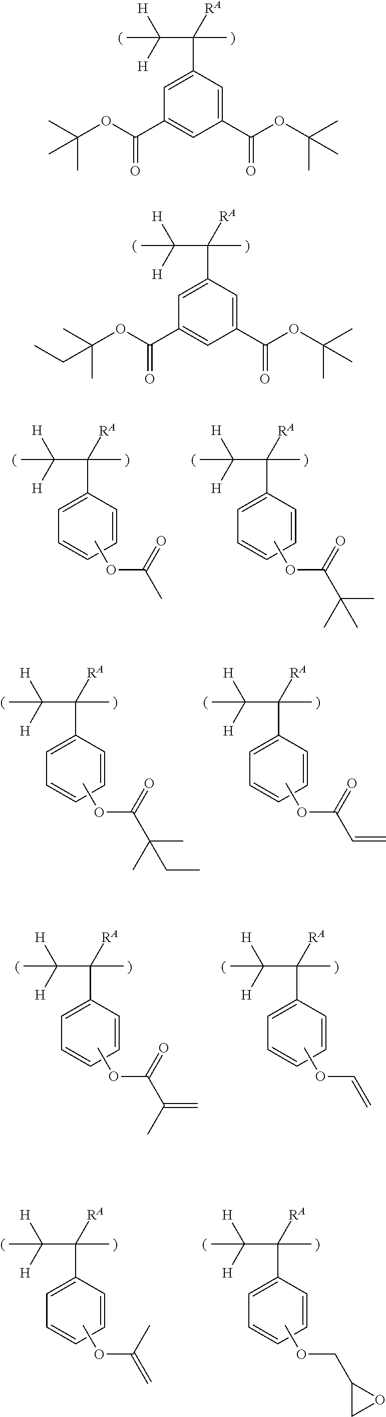

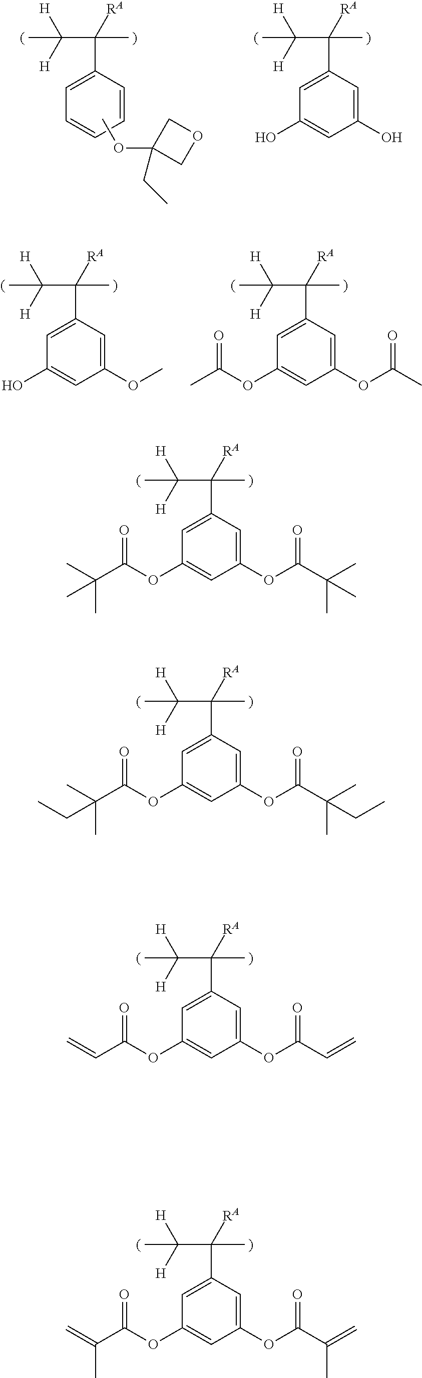

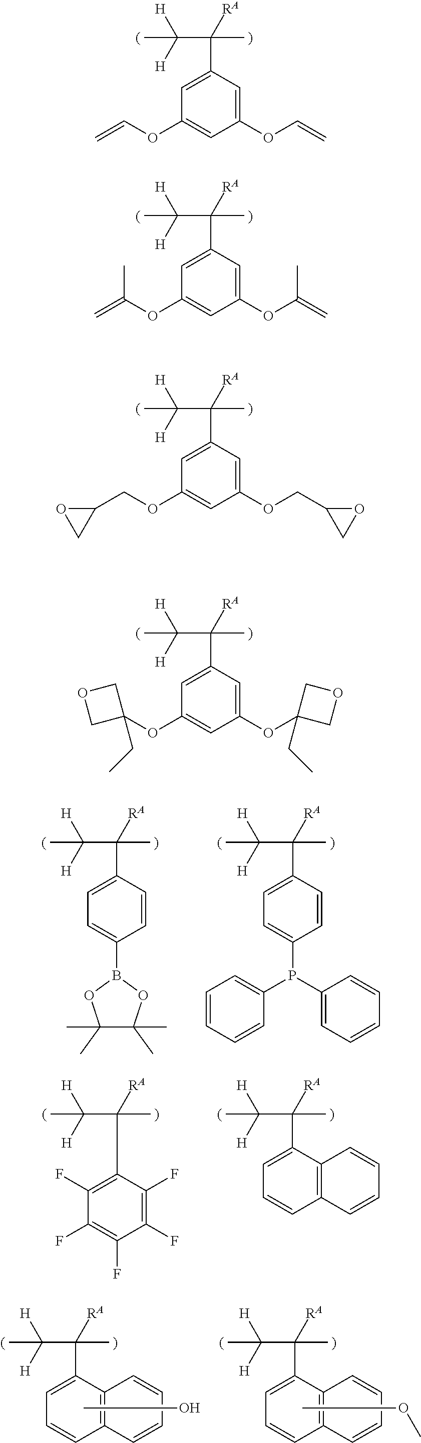

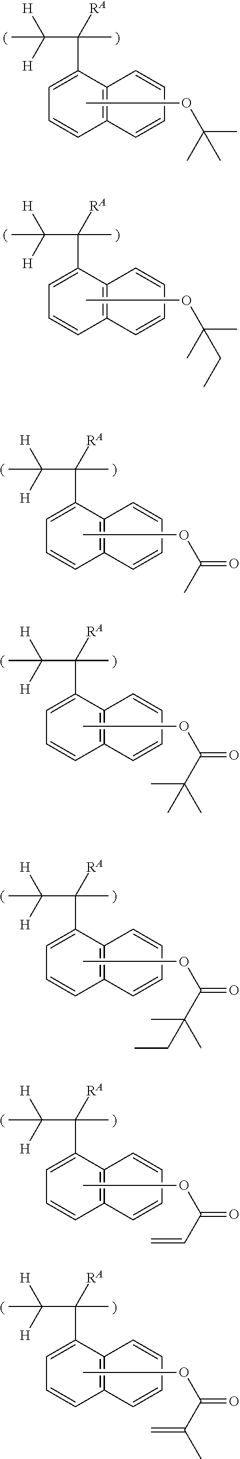

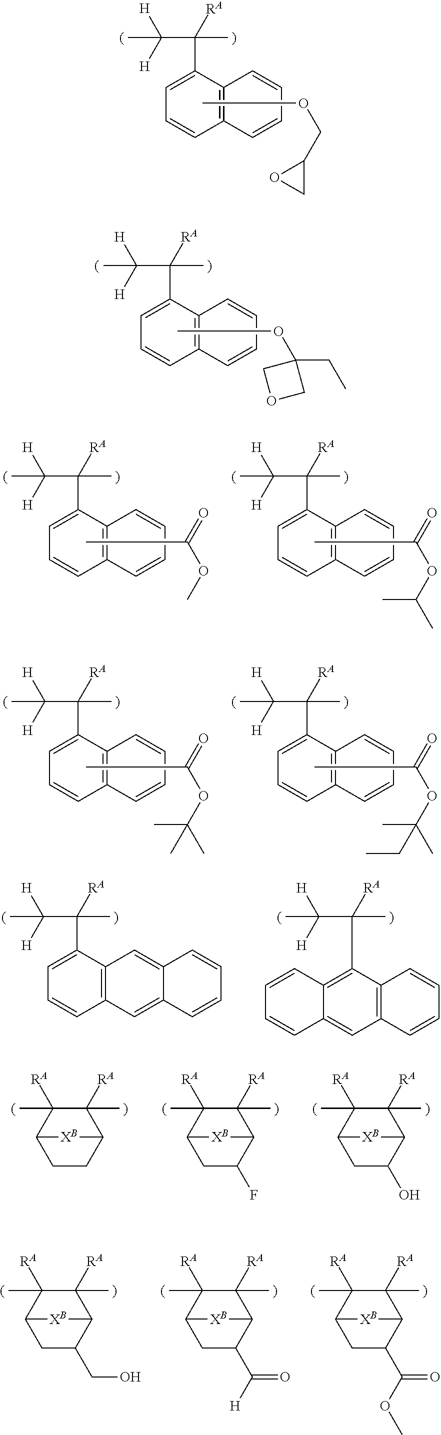

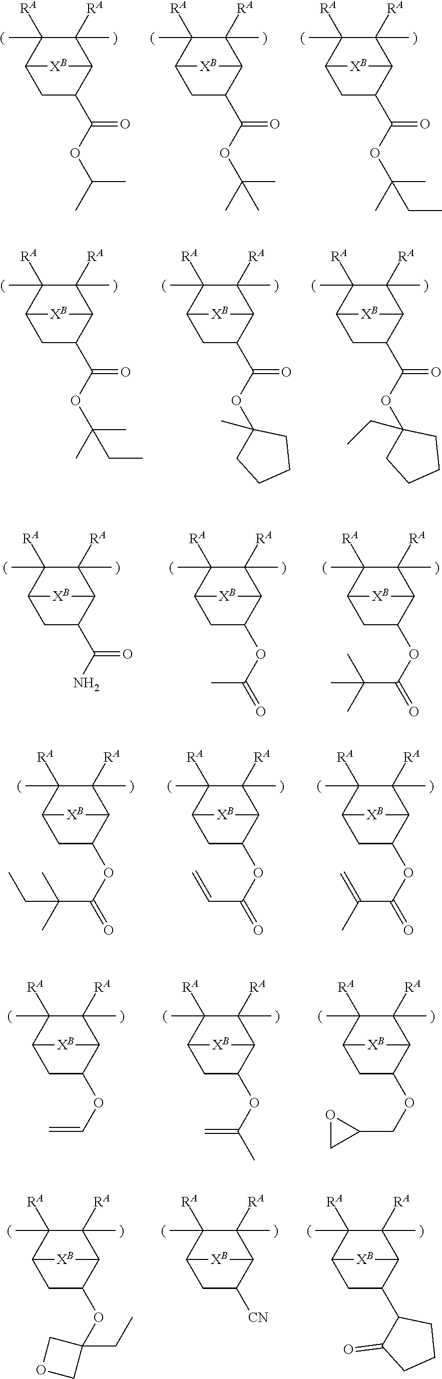

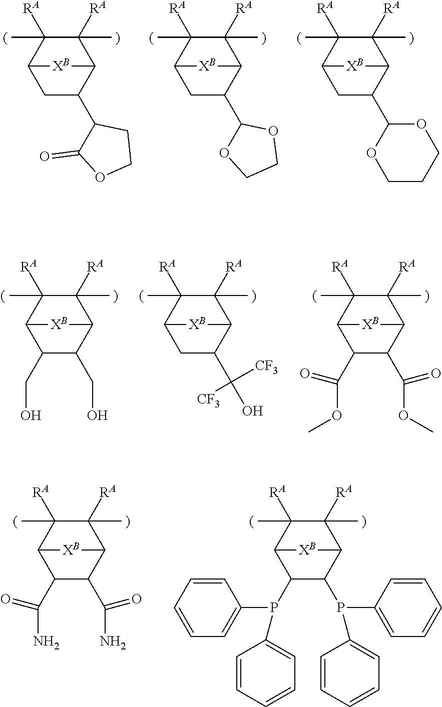

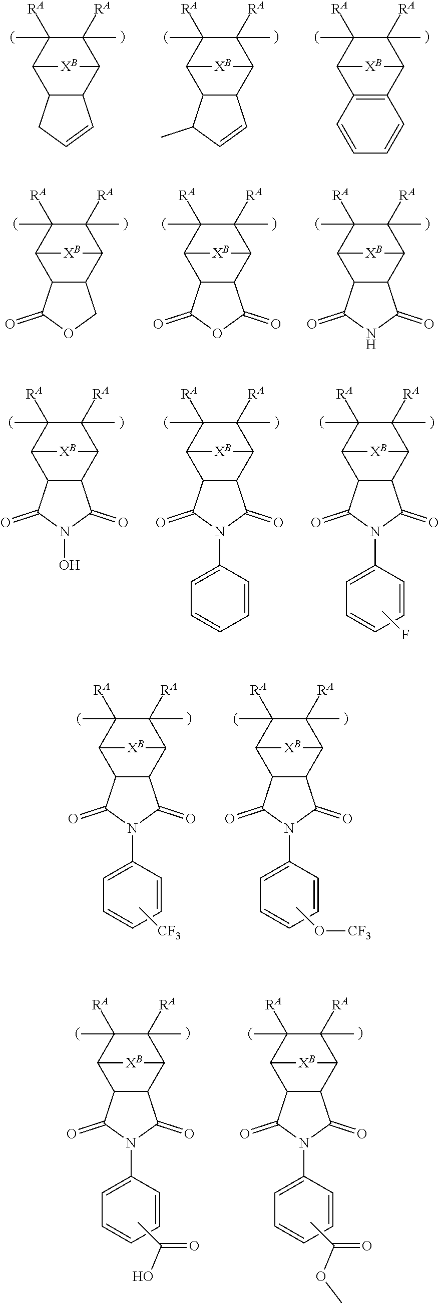

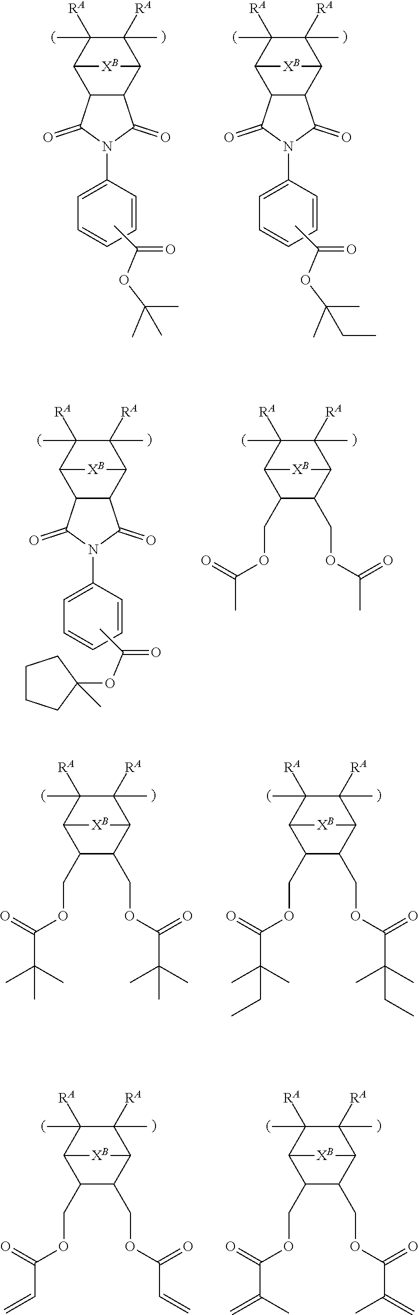

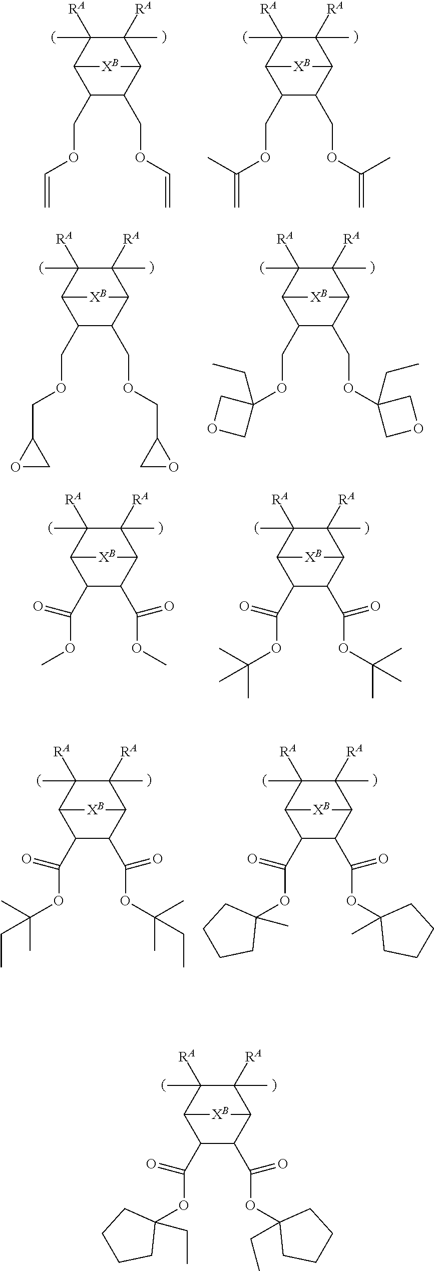

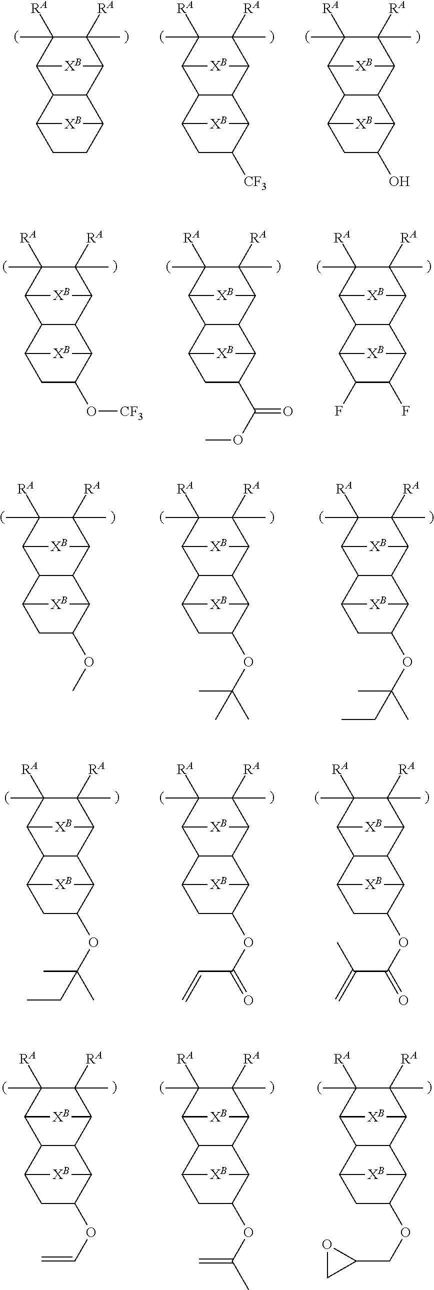

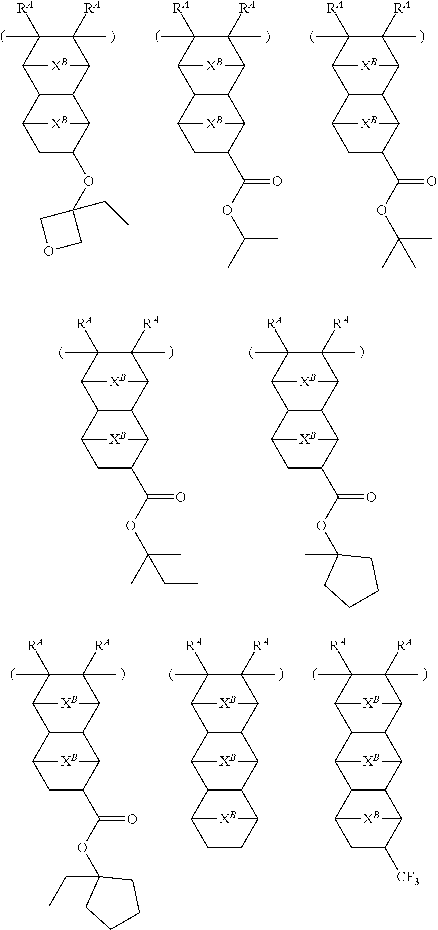

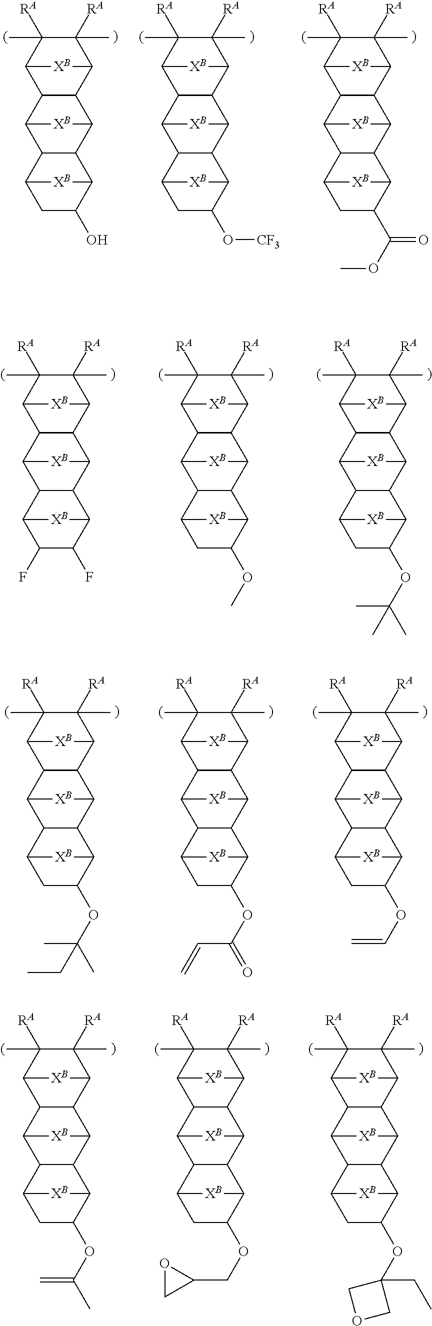

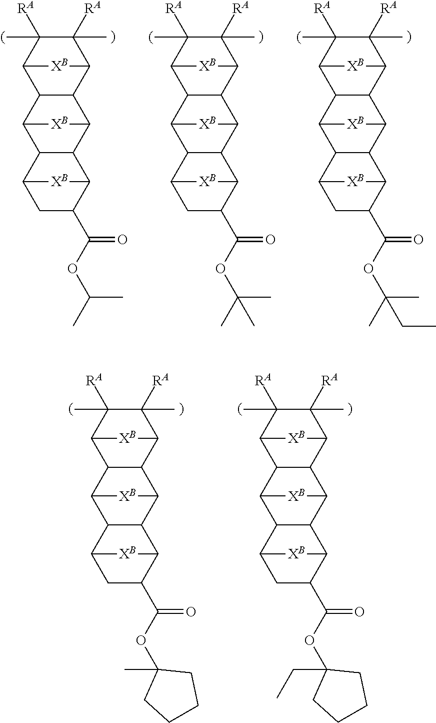

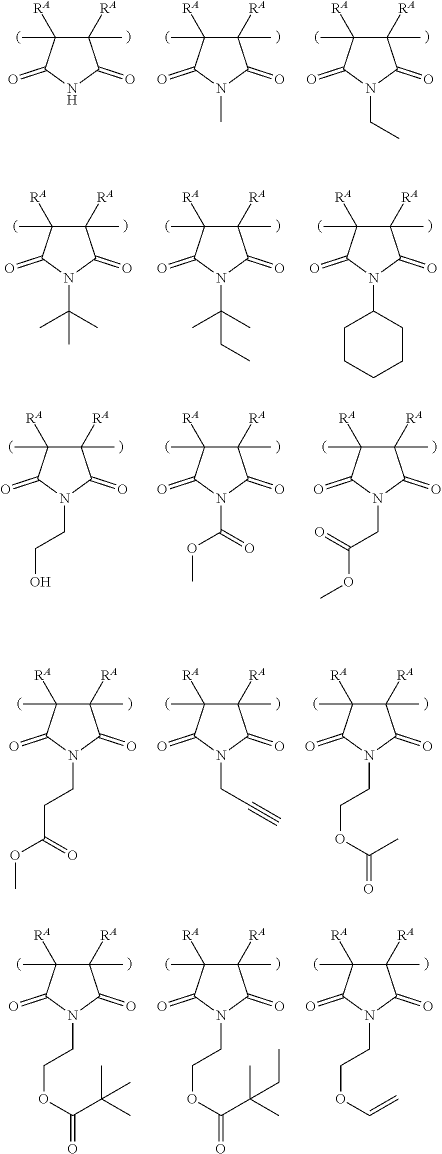

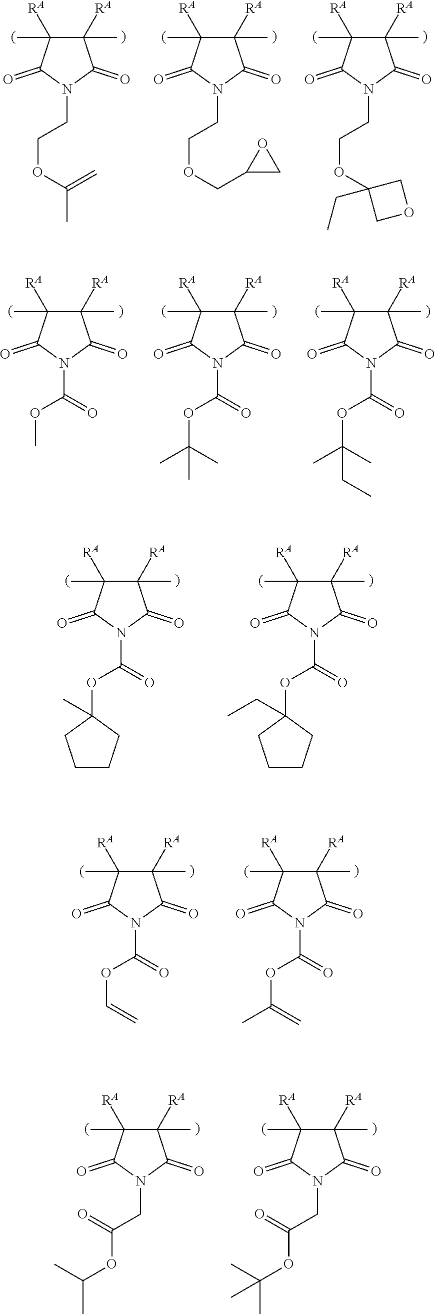

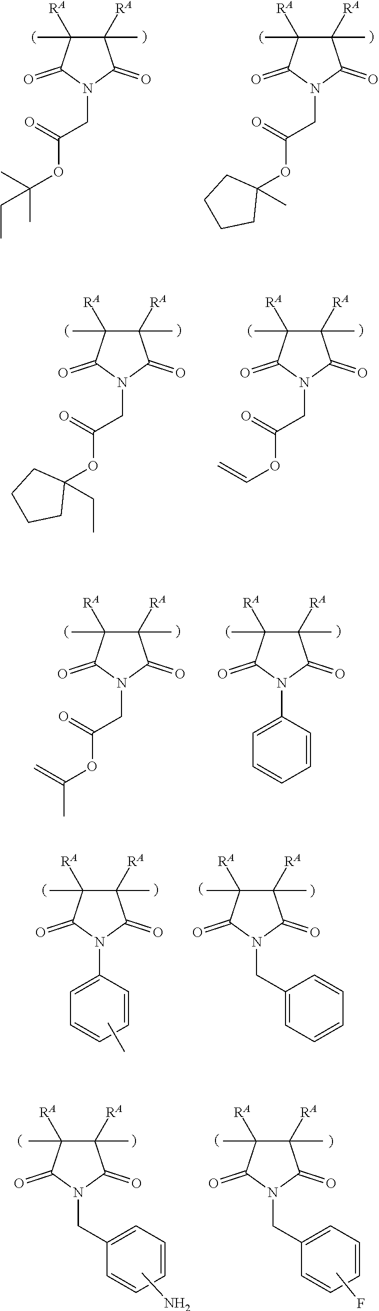

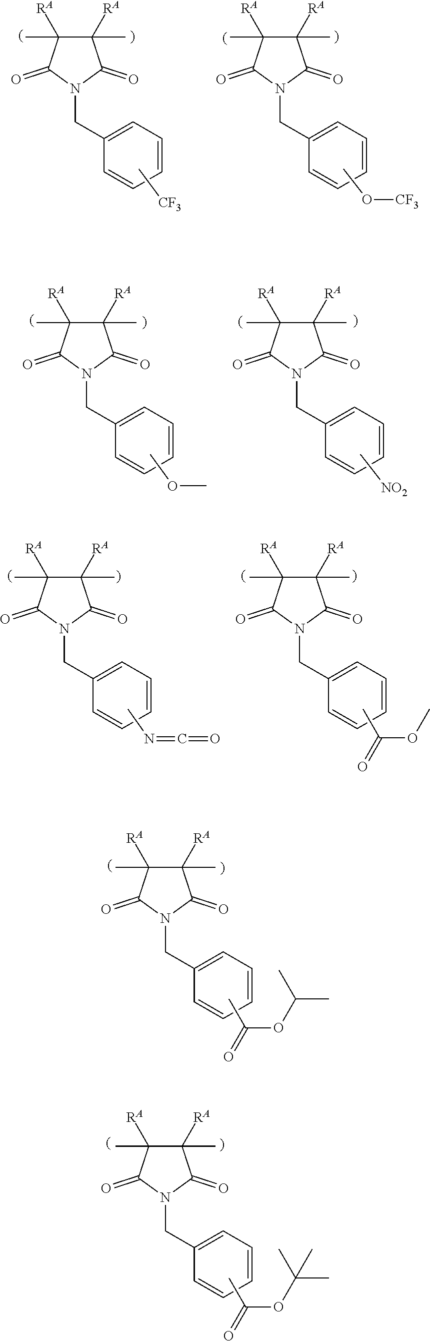

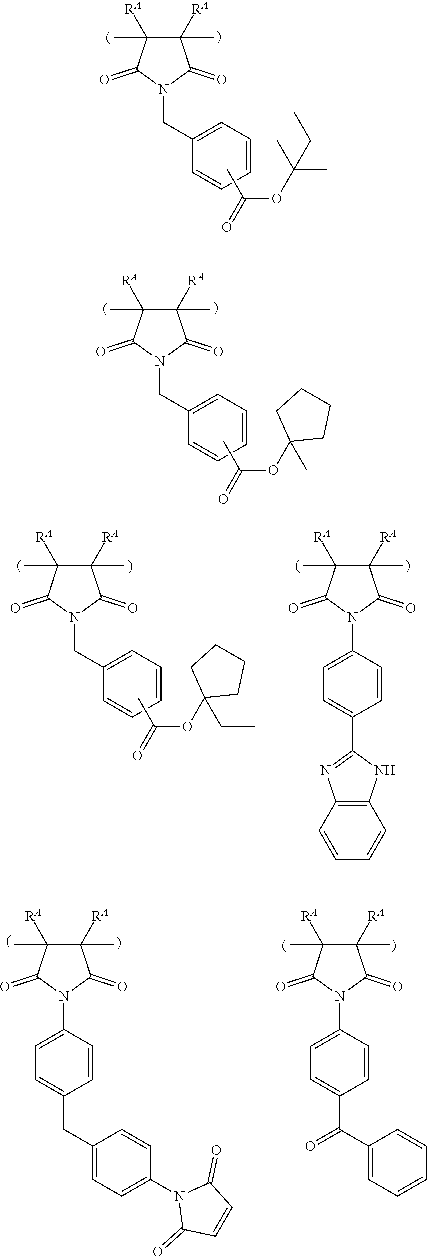

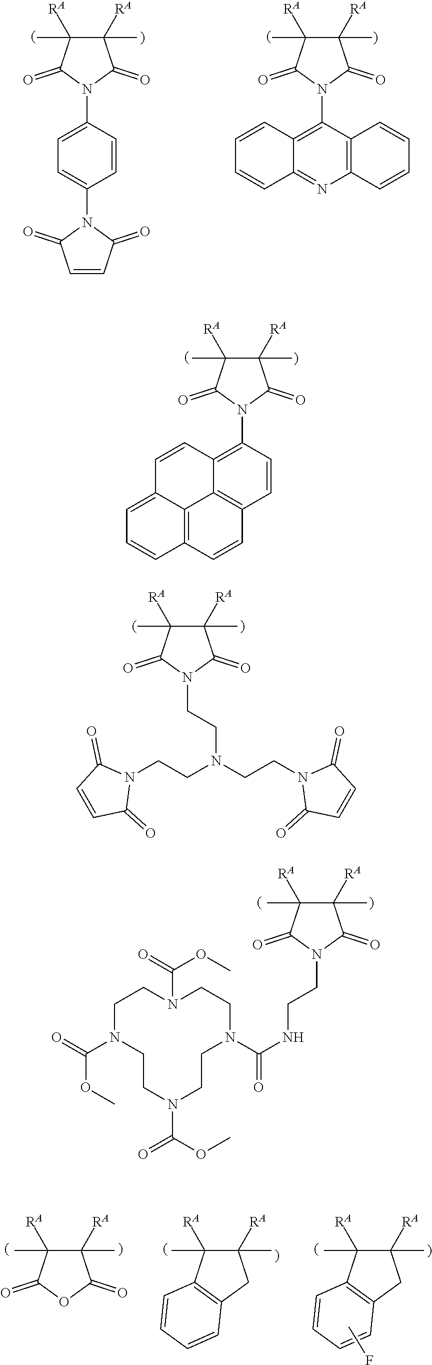

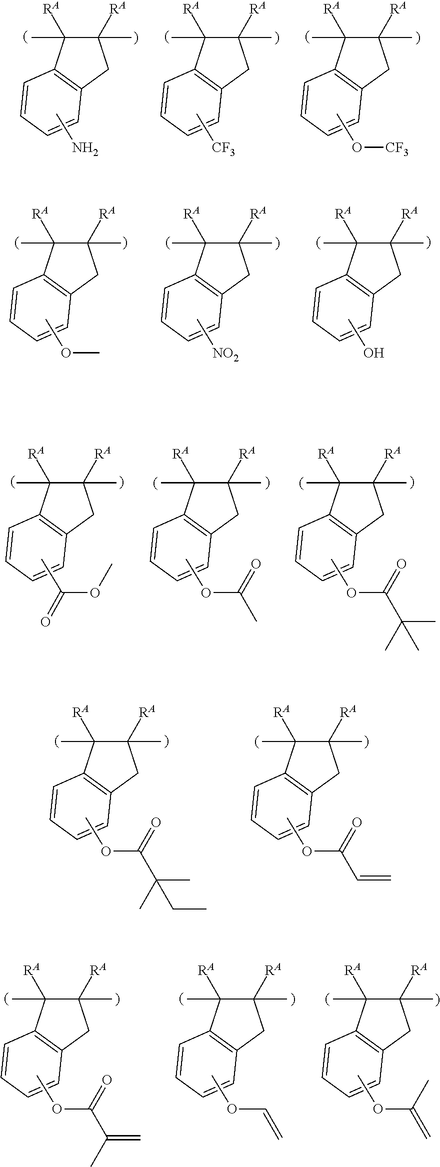

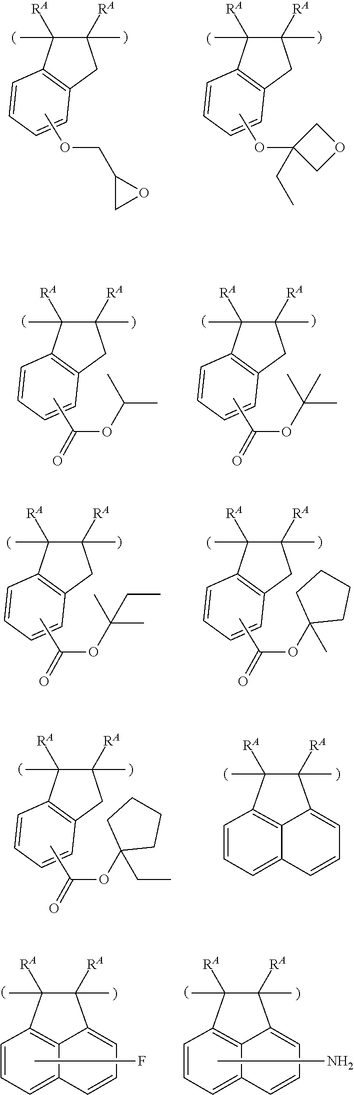

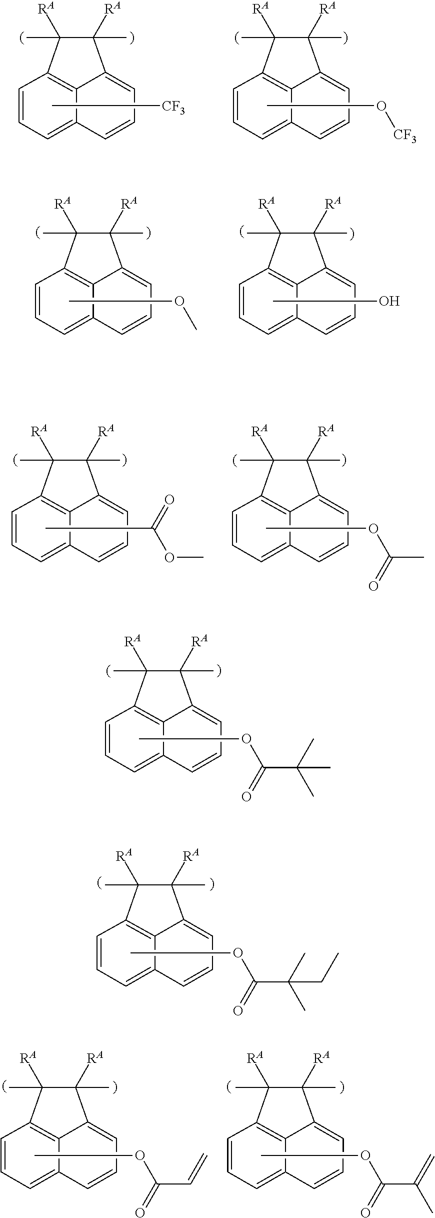

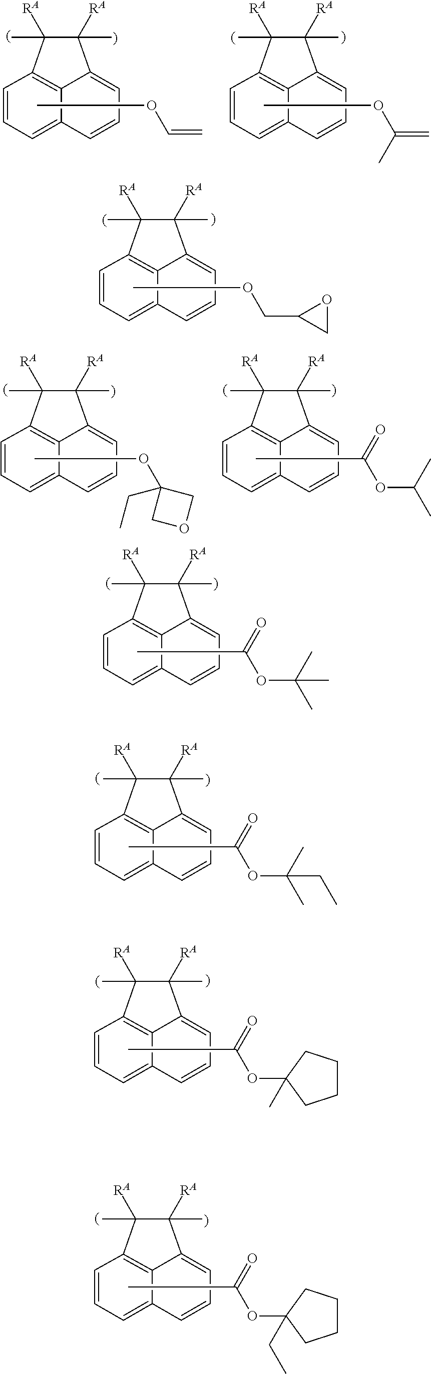

In the carboxy-containing polymer, the molar ratio of carboxy-containing repeat units to other repeat units ranges preferably from 10:90 to 90:10, more preferably from 15:85 to 85:15, even more preferably from 20:80 to 80:20.

The carboxy-containing polymer should preferably have a weight average molecular weight (Mw) in the range of 1,000 to 500,000, and more preferably 3,000 to 100,000, as measured by GPC versus polystyrene standards using tetrahydrofuran (THF) solvent.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the carboxy-containing polymer should preferably have a narrow dispersity (Mw/Mn) of 1.0 to 2.0 in order to provide a resist composition suitable for micropatterning to a small feature size.

In the resist composition, the hypervalent iodine compound and the carboxy-containing compound (or when the carboxy-containing compound is a carboxylic acid-containing polymer, the carboxy-containing repeat units in the polymer) are preferably present such that the molar ratio of the hypervalent iodine compound to the carboxy-containing compound (or carboxy-containing repeat unit) may range from 10:90 to 90:10, more preferably from 20:80 to 80:20, even more preferably from 30:70 to 70:30. The hypervalent iodine compound may be used alone or in admixture. The carboxy-containing polymer may be used alone or as a mixture of two or more polymers having different compositional ratio, Mw and/or Mw/Mn.

The carboxy-containing polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the initiator added is preferably 0.01 to 25 mol % of the total of monomers to be polymerized. The reaction temperature is preferably 50 to 150° C., more preferably 60 to 100° C. The reaction time is preferably 2 to 24 hours, more preferably 2 to 12 hours in view of production efficiency.

The polymerization initiator may be added to the monomer solution, which is fed to the reactor. Alternatively, a solution of the polymerization initiator is prepared separately from the monomer solution, and the monomer and initiator solutions are independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

The amount of each monomer in the monomer solution is set such that the content of the corresponding repeat unit may fall in the preferred range.

### Solvent

The resist composition further contains a solvent. The solvent is not particularly limited as long as the hypervalent iodine compound, the carboxy-containing compound and other components are dissolvable therein and a film can be formed from the resulting solution. Organic solvents are preferred. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, and 4-methyl-2-pentanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, methyl 2-hydroxyisobutyrate and propylene glycol mono-tert-butyl ether acetate; carboxylic acids such as formic acid, acetic acid, and propionic acid; lactones such as γ-butyrolactone, and mixtures thereof.

The solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent.

### Other Components

The resist composition may further contain a surfactant. The surfactant is preferably selected from fluorochemical and silicone surfactants. Exemplary surfactants are described, for example, in US 2008/0248425, paragraph [0276]. Also useful are surfactants other than the fluorochemical and silicone surfactants, as described, for example, in US 2008/0248425, paragraph [0280].

When used, the surfactant is preferably present in an amount of 0.0001 to 2% by weight based on the overall solids. The surfactant may be used alone or in admixture.

The resist composition may further contain a radical scavenger (or radical trapping agent). The radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When used, the radical scavenger is preferably present in an amount of 0.01 to 10% by weight based on the overall solids. The radical scavenger may be used alone or in admixture.

The resist composition may further contain a crosslinker. Since the crosslinker functions to promote crosslinking reaction during photolithography, a pattern having a higher glass transition temperature and a better resolution in fine line formation is obtained.

Suitable crosslinkers include compounds having a carbon-carbon unsaturated bond such as vinyl, (meth)acryloyl, allyl, alkynyl and aromatic ring as a functional group. Specifically, suitable vinyl-containing compounds include optionally substituted straight-chain alkenes, branched alkenes, and cyclic alkenes. Suitable (meth)acryloyl-containing compounds include optionally substituted acrylic acid, methacrylic acid, acrylates, and methacrylates. Suitable allyl-containing compounds include optionally substituted allyl alcohols, allyl ethers, allyl esters, allyl amides, allyl amines, allyl-containing isocyanurates. Suitable alkynyl-containing compounds include optionally substituted straight-chain alkynes, branched alkynes, cyclic alkynes, alkynyl alcohols, alkynyl ethers, alkynyl esters, alkynyl amides, alkynyl amines, and alkynyl-containing isocyanurates. Suitable aromatic ring-containing compounds include optionally substituted arenes, heteroarenes, styrene, stilbene, phenylacetylene, acenaphthylene, and chalcone. The crosslinker may contain only one of the foregoing functional groups or two or more functional groups. The number of functional groups in the crosslinker is preferably from 1 to 10, more preferably from 2 to 8.

When the resist composition contains the crosslinker, the amount of the crosslinker is preferably 0.01 to 50% by weight of the overall solids. The crosslinker may be used alone or in admixture.

When the resist composition contains the crosslinker, it may further contain a photopolymerization initiator. Upon receipt of high-energy radiation, the photopolymerization initiator generates radicals to promote crosslinking reaction of the crosslinker.

Examples of the photopolymerization initiator include benzophenone derivatives such as benzophenone, methyl O-benzoylbenzoate, 4-benzyol-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)benzyl]phenyl}-2-methylpropan-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethylacetal; benzoin derivatives such as benzoin, benzoin methyl ether, and 2-hydroxy-2-methyl-1-phenylpropan-1-one; oxime compounds such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropanetrione-2-(O-benzoyl)oxime 1,2-octanedione, 1-{4-(phenylthio)-2-(O-benzoyl)oxime ethanone, and 1-[9-ethyl-6-(2-methylbenzoyl)-9H-carbazol-3-yl]-1-(O-acetyloxime); a-hydroxyketone compounds such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)benzyl]phenyl}-2-methylpropane; α-aminoalkylphenone compounds such as 2-benzyl-2-dimethylamino-1-(4-morpholinophenyl)butanone-1 and 2-dimethylamino-2-(4-methylbenzyl)-1-(4-morpholin-4-ylphenyl)butan-1-one; phosphine oxide compounds such as bis(2,4,6-trimethylbenzoyl)phenylphosphine oxide, bis(2,6-dimethoxybenzoyl)-2,4,4-trimethylpentylphosphine oxide, and 2,4,6-trimethylbenzoyl diphenylphosphine oxide; and titanocene compounds such as bis(q5-2,4-cyclopentadien-1-yl)-bis(2,6-difluoro-3-(1H-pyrrol-1-yl)phenyl)titanium.

When the resist composition contains the photopolymerization initiator, the amount of the initiator is preferably 0.1 to 10% by weight, more preferably 0.1 to 5% by weight, even more preferably 0.1 to 1% by weight of the overall solids. A sufficient effect is available as long as the amount is 0.1% by weight or more.

The resist composition contains the hypervalent iodine compound, the carboxy-containing compound and the onium salt or photoacid generator as main components, but not a polymer containing an acid labile group as used in conventional chemically amplified resist compositions. Nevertheless, this resist composition works such that the region thereof exposed to EB or EUV may become soluble in the developer to form a positive tone pattern. Although its mechanism is not well understood, the following mechanism is presumed.

The hypervalent iodine compound having formula (1), (2), (3) or (4) is a three-coordinate compound having aryl and carboxylate ligands. When such a three-coordinate iodine compound is mixed with a carboxy-containing compound, replacement of carboxylate ligands takes place as equilibration reaction. If the original carboxylate ligands are removed by any suitable means, a hypervalent iodine compound having new ligands is created. For example, if 1-iodonaphthylene diacetate as a hypervalent iodine compound is mixed with a carboxy-containing compound, and the resulting low-boiling acetic acid is removed, then ligand exchange is completed. There is obtained a polymer in which the carboxy-containing compound is crosslinked with the hypervalent iodine compound.

The polymer crosslinked with the hypervalent iodine compound is formed during film preparation. The reason is that even when such a crosslinked polymer is previously synthesized, the polymer is not soluble in most organic solvents so that a solution may not be prepared. If the hypervalent iodine compound having a low solvent solubility because of inherently strong polarization has taken therein a carboxy-containing compound as a ligand, then the compound suffers from a further loss of solubility. It is thus desirable that a resist film be formed while ligand exchange reaction be completed by removing the original low-molecular-weight carboxylic acid component during film formation and subsequent bake steps.

After a resist film is formed from the resist composition, the hypervalent iodine compound as the main component is photo-decomposed in the exposure step to bring about a polarity switch, and a pattern is formed in the subsequent development step. Although its mechanism is not well understood, the following mechanism is presumed.

The resist film obtained from the resist composition contains the polymer to which the hypervalent iodine compound is bonded during film formation. Upon receipt of light, the hypervalent iodine compound is decomposed into a monovalent iodine compound. At the same time, the crosslink between the hypervalent iodine compound and the carboxy-containing compound is canceled and the molecular weight is reduced. As a result, the resist film in the exposed region is dissolved away in the organic solvent, yielding a pattern of positive tone.

Since the resist composition contains the PAG in addition to the hypervalent iodine compound and the carboxy-containing compound, a positive tone pattern can be formed at a higher sensitivity than similar resist compositions free of the PAG. Although its mechanism is not well understood, the following mechanism is presumed.

In the resist composition containing the PAG, the acid generated from the PAG in the resist exposure step undergoes an exchange with the hypervalent iodine compound to convert to new ligands, canceling the crosslink between the hypervalent iodine compound and the carboxy-containing compound. In addition to the photo-induced cleavage of I—O bonds, there arises a polarity switch due to the new ligand exchange by the acid generated from the PAG, or a lowering of molecular weight (when the carboxy-containing compound is a polymer). Then a positive tone pattern can be formed at a high sensitivity by organic solvent development.

From the foregoing presumption, the inventive resist composition containing a PAG is regarded as falling in the concept of non-chemically-amplified resist composition. There is no need for an acid labile group-containing polymer as used in conventional chemically amplified resist compositions. The acid generated from the PAG reacts with ligands of the hypervalent iodine compound in the exposed region and becomes new ligands of the hypervalent iodine compound. Since the inventive resist composition does not possess the amplification mechanism of a chemically amplified resist composition that the acid reacts with an acid labile group to re-generate an acid, a small-size pattern can be resolved without any adverse effect (e.g., image blur) due to acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small-size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, the inventive resist composition which does not resort to metal elements is advantageous in defectiveness over the metal resist and eliminates the problem of solvent solubility. The inventive resist composition is applicable to positive tone. In the step of forming contact holes, for example, although a metal resist composition subject to negative tone development requires the reversal processing step after pillar pattern formation, the positive resist composition does not require the reversal step. From the aspect of process simplicity, the inventive resist composition is regarded more useful than the metal resist composition.

JP-A 2015-180928 and JP-A 2018-095853 describe a resist composition comprising a hypervalent iodine compound as an additive and a resist composition comprising a base polymer having a hypervalent iodine compound incorporated in its framework. The resist compositions described therein comprise a polymer which must contain an acid labile group in repeat units and are successful in improving only line edge roughness. The patent documents refer nowhere to a possibility of photo-decomposition of the hypervalent iodine compound and an ability to function as a non-chemically-amplified resist. In these resist compositions, the hypervalent iodine compound is not a main component as understood from the addition amount and examples described therein. It is then believed that a material capable of reducing shot noise during the EUV lithography and forming a small-size pattern as the non-chemically-amplified resist is not conceivable from these patent documents. That is, the present invention provides a definitely novel resist composition and pattern forming process.

### Pattern Forming Process

When the resist composition is used in the fabrication of various integrated circuits, any well-known lithography techniques are applicable. For example, the invention provides a pattern forming process comprising the steps of applying the resist composition onto a substrate or a substrate having an underlying film thereon to form a resist film on the substrate or underlying film, exposing the resist film to high-energy radiation, and optionally developing the exposed resist film in a developer.

First, the resist composition is applied onto a substrate for integrated circuit fabrication (e.g., Si, SiO₂, SiN, SiON, TiN, WSi, BPSG, SOG, or organic antireflective coating) or a substrate having an underlying film thereon, or a substrate for mask circuit fabrication (e.g., Cr, CrO, CrON, MoSi₂, or SiO₂) or a substrate having an underlying film thereon by any suitable technique such as spin coating, roll coating, flow coating, dip coating, spray coating or doctor coating. The coating is prebaked (PAB) on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm. Notably, the underlying film refers to a film formed between a substrate and a resist film in the multilayer resist process. The underlying film is not particularly limited and any of well-known films may be used.

Next the resist film is exposed to high-energy radiation. The radiation is selected from among UV, deep UV, EB, EUV, X-ray, soft X-ray, excimer laser radiation, y-ray, and synchrotron radiation. On use of UV, deep UV, EUV, X-ray, soft X-ray, excimer laser radiation, y-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 8,000 μC/cm², more preferably about 0.5 to 5,000 μC/cm². The resist composition is best suited in micropatterning using EB or EUV as the high-energy radiation.

If necessary, the resist film is post-exposure baked (PEB). Preferably PEB is performed on a hot plate or in an oven at 30 to 200° C. for 10 seconds to 30 minutes, more preferably at 60 to 120° C. for 30 seconds to 20 minutes.

After the exposure or PEB, the resist film is developed in a developer to form a pattern, if necessary. Typical of the developer are alkaline aqueous solutions such as aqueous solutions of tetramethylammonium hydroxide and tetrabutylammonium hydroxide; and organic solvents such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, n-butanol, tert-butyl alcohol, isoamyl alcohol, tert-pentyl alcohol, n-pentanol, cyclohexanol, formic acid, acetic acid, propionic acid, propyl acetate, butyl acetate, isobutyl acetate, pentyl acetate, isopentyl acetate, butenyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole and ε-caprolactone. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight.

### [1] Synthesis of Polymers

Polymers P-1 to P-5 were synthesized using the monomers shown below.

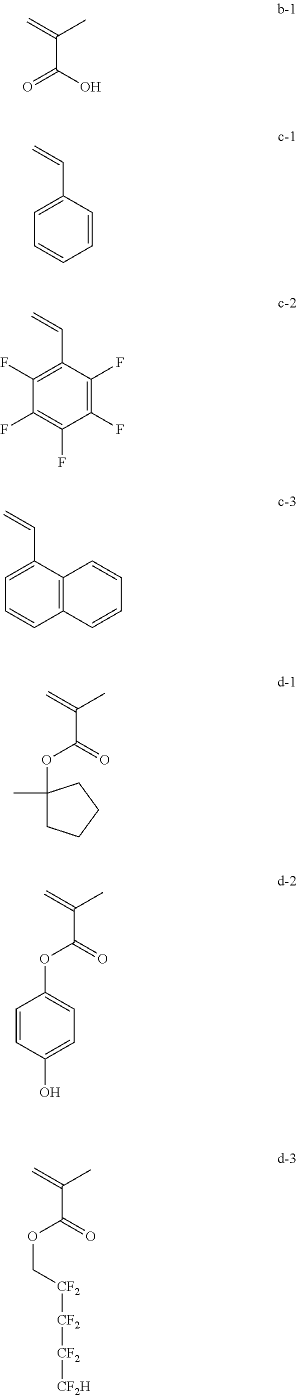

### Synthesis Example 1

### Synthesis of Polymer P-1

In nitrogen atmosphere, a flask was charged with 56 g of Monomer b-1, 36 g of Monomer c-1, 5.4 g of dimethyl 2,2′-azobis(isobutyrate) (V-601, FUJIFILM Wako Pure Chemical Corp.), and 180 g of methyl ethyl ketone (MEK) to form a monomer/initiator solution. Another flask in nitrogen atmosphere was charged with 55 g of MEK and heated at 80° C. with stirring, after which the monomer/initiator solution was added dropwise over 4 hours. After the completion of dropwise addition, the polymerization solution was continuously stirred for 2 hours while keeping the temperature of 80° C. It was then cooled to room temperature. With vigorous stirring, the polymerization solution was added dropwise to 4,000 g of hexane whereupon a polymer precipitated. The polymer was collected by filtration, washed twice with 1,200 g of hexane, and vacuum dried at 50° C. for 20 hours, obtaining Polymer P-1 in white powder form. Amount 90 g and yield 98%. Polymer P-1 had a Mw of 8,000 and a Mw/Mn of 1.42 as measured by GPC versus polystyrene standards using THF solvent.

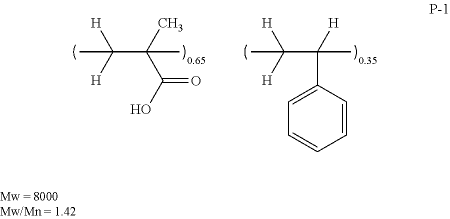

### Synthesis Examples 2 to 5

### Synthesis of Polymers P-2 to P-5

Polymers P-2 to P-5 shown in Table 1 were prepared by the same procedure as in Synthesis Example 1 except that the type and amount of monomers used were changed.

TABLE 1

| | Unit | Incorporation | Unit | Incorporation | | Mw/ |
|---|---|---|---|---|---|---|
| Polymer | 1 | ratio (mol %) | 2 | ratio (mol %) | Mw | Mn |
| P-1 | b-1 | 65 | c-1 | 35 | 8,000 | 1.42 |
| P-2 | b-1 | 50 | c-2 | 50 | 8,400 | 1.51 |
| P-3 | b-1 | 60 | c-3 | 40 | 8,100 | 1.42 |
| P-4 | b-1 | 60 | d-3 | 40 | 8,100 | 1.42 |
| P-5 | d-1 | 65 | d-2 | 35 | 8,000 | 1.44 |

### [2] Preparation of Resist Composition

Examples 1-1 to 1-18 and Comparative Examples 1-1 to 1-3 Resist compositions (R-01 to R-18 and CR-01) were prepared by dissolving a hypervalent iodine compound, a carboxy-containing compound and a photoacid generator in a solvent containing 0.01 wt % of a surfactant (PF-636, Omnova Solutions, Inc.) in accordance with the recipe shown in Table 2, and filtering the solution through a Teflon® filter having a pore size of 0.2 μm. Also, resist compositions (CR-02 and CR-03) were prepared by dissolving a polymer, a photoacid generator, and a sensitivity modifier in a solvent containing 0.01 wt % of a surfactant (PF-636) in accordance with the recipe shown in Table 3, and filtering the solution through a Teflon® filter having a pore size of 0.2 μm.

TABLE 2

| | | | Hypervalent | Hypervalent | Carboxy- | | | | |
|---|---|---|---|---|---|---|---|---|---|
| | | | iodine | iodine | containing | Photoacid | Photoacid | | |
| | | Resist | compound 1 | compound 2 | compound | generator 1 | generator 2 | Solvent 1 | Solvent 2 |
| | | composition | (pbw) | (pbw) | (pbw) | (pbw) | (pbw) | (pbw) | (pbw) |
| Example | 1-1 | R-01 | I-1 | — | P-1 | PAG-1 | — | PGMEA | AcOH |
| | | | (12) | | (9) | (0.5) | | (800) | (200) |
| | 1-2 | R-02 | I-1 | — | P-1 | PAG-1 | — | PGMEA | AcOH |
| | | | (12) | | (9) | (1) | | (800) | (200) |
| | 1-3 | R-03 | I-1 | — | P-1 | PAG-1 | — | PGMEA | AcOH |
| | | | (12) | | (9) | (5) | | (800) | (200) |
| | 1-4 | R-04 | I-1 | — | P-1 | PAG-3 | PAG-2 | PGMEA | AcOH |
| | | | (12) | | (9) | (0.3) | (0.1) | (800) | (200) |
| | 1-5 | R-05 | I-1 | — | P-1 | PAG-2 | — | PGMEA | AcOH |
| | | | (12) | | (9) | (0.5) | | (800) | (200) |
| | 1-6 | R-06 | I-1 | — | P-1 | PAG-3 | — | PGMEA | AcOH |
| | | | (12) | | (9) | (0.7) | | (800) | (200) |
| | 1-7 | R-07 | I-1 | — | P-1 | PAG-4 | — | PGMEA | AcOH |
| | | | (12) | | (9) | (0.7) | | (800) | (200) |
| | 1-8 | R-08 | I-1 | — | P-1 | PAG-5 | — | PGMEA | AcOH |
| | | | (12) | | (9) | (0.9) | | (800) | (200) |
| | 1-9 | R-09 | I-1 | — | P-1 | PAG-6 | — | PGMEA | AcOH |
| | | | (12) | | (9) | (0.8) | | (800) | (200) |
| | 1-10 | R-10 | I-2 | — | P-1 | PAG-1 | — | PGMEA | AcOH |
| | | | (10) | | (9) | (0.5) | | (800) | (200) |
| | 1-11 | R-11 | I-3 | — | P-1 | PAG-1 | — | PGMEA | AcOH |
| | | | (10) | | (9) | (0.5) | | (800) | (200) |
| | 1-12 | R-12 | I-1 | I-2 | P-1 | PAG-1 | — | PGMEA | AcOH |
| | | | (6) | (5) | (9) | (0.5) | | (800) | (200) |
| | 1-13 | R-13 | I-1 | — | P-2 | PAG-1 | — | PGMEA | AcOH |
| | | | (12) | | (17) | (0.5) | | (800) | (200) |
| | 1-14 | R-14 | I-1 | — | P-3 | PAG-1 | — | PGMEA | AcOH |
| | | | (12) | | (11) | (0.5) | | (800) | (200) |
| | 1-15 | R-15 | I-1 | — | P-4 | PAG-1 | — | PGMEA | AcOH |
| | | | (12) | | (17) | (0.5) | | (800) | (200) |
| | 1-16 | R-16 | I-1 | — | m-1 | PAG-1 | — | PGMEA | AcOH |
| | | | (12) | | (7) | (0.5) | | (800) | (200) |
| | 1-17 | R-17 | I-1 | — | m-2 | PAG-1 | — | PGMEA | AcOH |
| | | | (12) | | (4) | (0.5) | | (800) | (200) |
| | 1-18 | R-18 | I-1 | — | m-3 | PAG-1 | — | PGMEA | AcOH |
| | | | (12) | | (7) | (0.5) | | (800) | (200) |
| Comparative | 1-1 | CR-01 | I-1 | — | P-1 | — | — | PGMEA | AcOH |
| Example | | | (12) | | (9) | | | (800) | (200) |

TABLE 3

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-2 | CR-02 | P-5 (80) | PAG-7 (19) | Q-1 (6) | PGMEA (1890) | GBL (210) |
| Example | 1-3 | CR-03 | P-5 (80) | PAG-7 (19) | I-1 (5) | PGMEA (1890) | GBL (210) |

In Tables 2 and 3, the hypervalent iodine compound (I-1 to I-3), carboxy-containing compound (m-1 to m-3), photoacid generator (PAG-1 to PAG-7), sensitivity modifier (Q-1), and solvent are identified below.

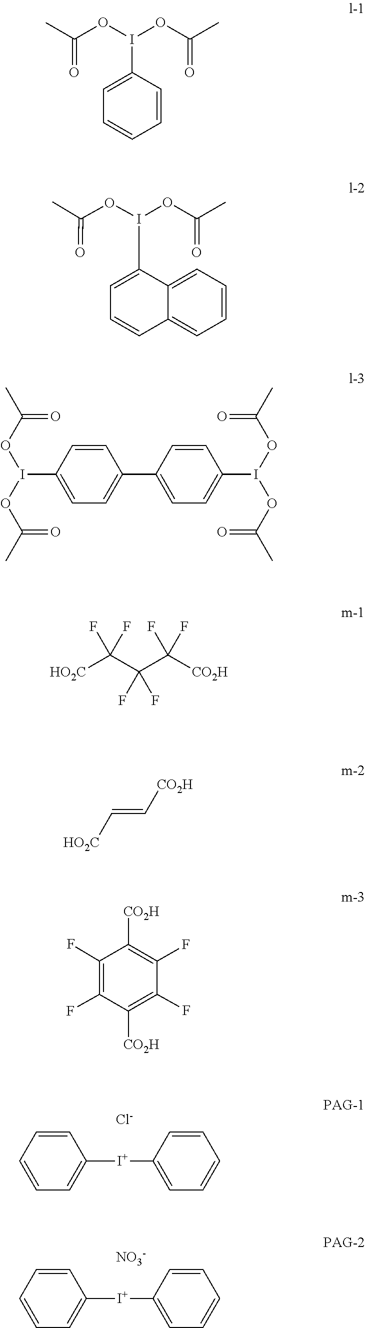

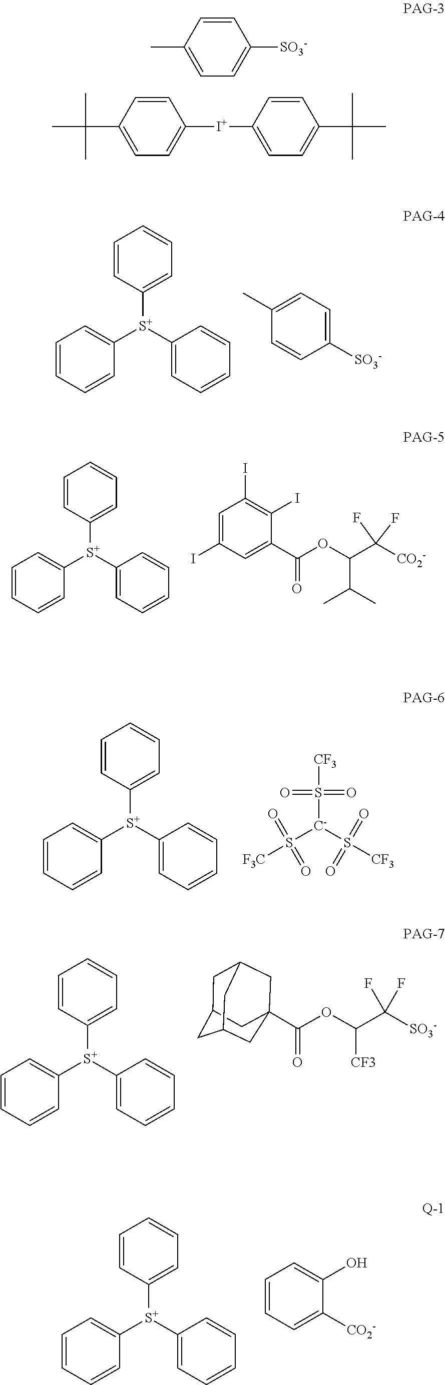

### Solvent:

AcOH (acetic acid)
GBL (γ-butyrolactone)

### [3] EUV Lithography Test (Line-and-Space Pattern)

### Examples 2-1 to 2-18 and Comparative Examples 2-1 to 2-3

Each of the resist compositions (R-01 to R-18, CR-01 to CR-03) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 4 for 60 seconds to form a resist film of 40 nm thick. Using an EUV scanner NXE3400 (ASML, NA 0.33, σ0.9, 900 dipole illumination), the resist film was exposed to EUV through a mask bearing a 36-nm 1:1 line-and-space (LS) pattern. The resist film was baked (PEB) on a hotplate at the temperature shown in Table 4 for 60 seconds and developed in the developer shown in Table 4 for 30 seconds to form a LS pattern having a space width of 18 nm and a pitch of 36 nm.

The LS pattern was observed under CD-SEM (CG-6300, Hitachi High-Technologies Corp.) and evaluated for sensitivity, LWR and maximum resolution by the following methods. The results are shown in Table 4.

### [Evaluation of Sensitivity]

The optimum dose Eop (mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 4

| | | Resist | PAB/PEB | | Eop | LWR | Maximum |
|---|---|---|---|---|---|---|---|
| | | composition | temp. (° C.) | Developer | (mJ/cm²) | (nm) | resolution (nm) |
| Example | 2-1 | R-01 | 110/90 | nBA | 38 | 3.5 | 15 |
| | 2-2 | R-02 | 110/90 | nBA | 32 | 3.2 | 14 |
| | 2-3 | R-03 | 110/90 | nBA | 25 | 4.0 | 15 |
| | 2-4 | R-04 | 110/90 | nBA | 32 | 3.5 | 13 |
| | 2-5 | R-05 | 110/90 | nBA | 39 | 3.0 | 14 |
| | 2-6 | R-06 | 110/90 | nBA | 30 | 3.6 | 14 |
| | 2-7 | R-07 | 110/90 | nBA | 32 | 3.4 | 14 |
| | 2-8 | R-08 | 110/90 | nBA | 35 | 3.3 | 14 |
| | 2-9 | R-09 | 110/90 | nBA | 28 | 4.0 | 13 |
| | 2-10 | R-10 | 110/90 | nBA | 38 | 3.3 | 13 |
| | 2-11 | R-11 | 110/90 | nBA | 40 | 3.7 | 15 |
| | 2-12 | R-12 | 110/90 | nBA | 39 | 3.3 | 14 |
| | 2-13 | R-13 | 110/90 | nBA | 38 | 3.4 | 14 |
| | 2-14 | R-14 | 110/90 | nBA | 40 | 3.2 | 14 |
| | 2-15 | R-15 | 110/90 | nBA | 38 | 3.4 | 15 |
| | 2-16 | R-16 | 110/90 | nBA | 42 | 3.6 | 15 |
| | 2-17 | R-17 | 110/90 | nBA | 44 | 3.4 | 15 |
| | 2-18 | R-18 | 110/90 | nBA | 40 | 3.4 | 17 |
| Comparative | 2-1 | CR-01 | 105/90 | nBA | 40 | 3.4 | 17 |
| Example | 2-2 | CR-02 | 105/90 | TMAH | 85 | 3.6 | 18 |
| | 2-3 | CR-03 | 105/90 | TMAH | 85 | 4.4 | 18 |

Developer:
nBA (n-butyl acetate)
TMAH (2.38 wt % tetramethylammonium hydroxide aqueous solution)

As is evident from Table 4, a comparison of Example 2-1 with Comparative Example 2-1 reveals that the addition of PAG ensures to form a pattern at a high sensitivity. Examples 2-1 to 2-3 show that a larger amount of PAG added is helpful in forming a pattern at a higher sensitivity. In Example 2-4 wherein two PAGs capable of generating acids having different acidity are added, the PAG capable of generating weaker acid quenches the strong acid which will otherwise diffuse to the unexposed region, so that a pattern can be formed at a high resolution. In Examples 2-9 and 2-10 wherein PAGs having a high molecular weight are used, a pattern can be formed at a high resolution because the generated acid has a short diffusion length. A comparison of resist compositions within the scope of the invention with chemically amplified resist compositions of Comparative Examples 2-2 and 2-3 using acid catalyst reaction reveals better sensitivity, resolution and LWR. The resist compositions within the scope of the invention form LS patterns at a high sensitivity when processed by the EUV lithography.

### [4] EUV Lithography Test (Contact Hole Pattern)

### Examples 3-1 to 3-18 and Comparative Examples 3-1 to 3-3

Each of the resist compositions (R-01 to R-18, CR-01 to CR-03) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 5 for 60 seconds to form a resist film of 50 nm thick. Using an EUV scanner NXE3400 (ASML, NA 0.33, σ0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 5 for 30 seconds to form a hole pattern having a size of 32 nm.

The hole pattern was observed under CD-SEM (CG-6300, Hitachi High-Technologies Corp.) and evaluated for sensitivity, CDU and maximum resolution by the following methods. The results are shown in Table 5.

### [Evaluation of Sensitivity]

The optimum dose Eop (mJ/cm²) which provided a contact hole pattern with a size of 32 nm was determined and reported as sensitivity.

### [Evaluation of CDU]

The size of 50 holes which were printed at Eop was measured, from which a 3-fold value (3σ) of the standard deviation (σ) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 5

| | | Resist | PAB/PEB | | Eop | CDU | Maximum |
|---|---|---|---|---|---|---|---|
| | | composition | temp. (° C.) | Developer | (mJ/cm²) | (nm) | resolution (nm) |
| Example | 3-1 | R-01 | 110/90 | nBA | 28 | 2.7 | 26 |
| | 3-2 | R-02 | 110/90 | nBA | 22 | 2.3 | 25 |
| | 3-3 | R-03 | 110/90 | nBA | 15 | 3.4 | 25 |
| | 3-4 | R-04 | 110/90 | nBA | 22 | 2.5 | 24 |
| | 3-5 | R-05 | 110/90 | nBA | 29 | 2.9 | 25 |
| | 3-6 | R-06 | 110/90 | nBA | 20 | 3.2 | 25 |
| | 3-7 | R-07 | 110/90 | nBA | 22 | 3.0 | 25 |
| | 3-8 | R-08 | 110/90 | nBA | 25 | 2.4 | 26 |
| | 3-9 | R-09 | 110/90 | nBA | 18 | 3.2 | 24 |
| | 3-10 | R-10 | 110/90 | nBA | 28 | 3.5 | 24 |
| | 3-11 | R-11 | 110/90 | nBA | 30 | 2.9 | 26 |
| | 3-12 | R-12 | 110/90 | nBA | 27 | 2.4 | 25 |
| | 3-13 | R-13 | 110/90 | nBA | 26 | 2.4 | 26 |
| | 3-14 | R-14 | 110/90 | nBA | 30 | 2.2 | 25 |
| | 3-15 | R-15 | 110/90 | nBA | 30 | 2.4 | 27 |
| | 3-16 | R-16 | 110/90 | nBA | 32 | 2.9 | 27 |
| | 3-17 | R-17 | 110/90 | nBA | 32 | 2.5 | 26 |
| | 3-18 | R-18 | 110/90 | nBA | 30 | 2.5 | 25 |
| Example | 3-1 | CR-01 | 105/90 | nBA | 30 | 2.1 | 26 |
| | 3-2 | CR-02 | 105/90 | TMAH | 42 | 3.8 | 32 |
| | 3-3 | CR-03 | 105/90 | TMAH | 40 | 4.0 | 32 |

Developer:
nBA (n-butyl acetate)
TMAH (2.38 wt % tetramethylammonium hydroxide aqueous solution)

As is evident from Table 5, a comparison of Example 3-1 with Comparative Example 3-1 reveals that the addition of PAG ensures to form a pattern at a high sensitivity. Examples 3-1 to 3-3 show that a larger amount of PAG added is helpful in forming a pattern at a higher sensitivity. In Example 3-4 wherein two PAGs capable of generating acids having different acidity are added, the PAG capable of generating weaker acid quenches the strong acid which will otherwise diffuse to the unexposed region, so that a pattern can be formed at a high resolution. In Examples 3-9 and 3-10 using PAGs having a high molecular weight, a pattern can be formed at a high resolution because the generated acid has a short diffusion length. A comparison of resist compositions within the scope of the invention with chemically amplified resist compositions of Comparative Examples 3-2 and 3-3 using acid catalyst reaction reveals better sensitivity, resolution and CDU. The resist compositions within the scope of the invention form contact hole patterns at a high sensitivity when processed by the EUV lithography.

Japanese Patent Application No. 2024-117420 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a hypervalent iodine compound, an onium salt compound, a carboxy-containing compound, and a solvent, wherein
the hypervalent iodine compound is at least one compound selected from hypervalent iodine compounds having the formulae (1) to (4): 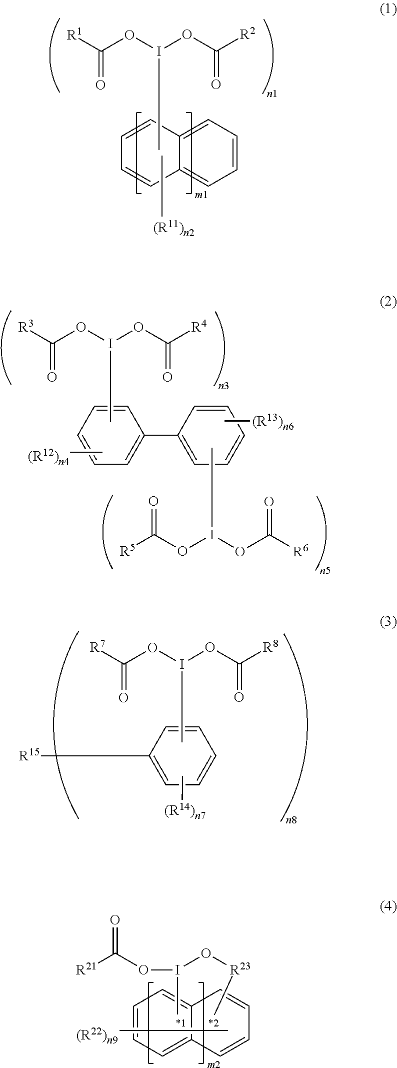
wherein m1 is 0, 1 or 2; when m1=0, n1 is 1, 2 or 3, n2 is 0, 1, 2, 3, 4 or 5 and 1≤n1+n2≤6; when m1=1, n1 is 1, 2 or 3, n2 is 0, 1, 2, 3, 4, 5, 6 or 7 and 1≤n1+n2≤8; when m1=2, n1 is 1, 2 or 3, n2 is 0, 1, 2, 3, 4, 5, 6, 7, 8 or 9 and 1≤n1+n2≤10;
n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
m2 is 0, 1 or 2; when m2=0, n9 is 0, 1, 2, 3 or 4; when m2=1, n9 is 0, 1, 2, 3, 4, 5 or 6; when m2=2, n9 is 0, 1, 2, 3, 4, 5, 6, 7 or 8;
R¹ to R⁸ are each independently halogen or a C₁-C₁₀ hydrocarbyl group which may contain a heteroatom, R¹ and R², R³ and R⁴, R⁵ and R⁶, or R⁷ and R⁸ may bond together to form a ring with the carbon atoms to which they are attached and the intervenient atoms,
R¹¹ to R¹⁴ are each independently halogen or a C₁-C₄₀ hydrocarbyl group which may contain a heteroatom; when n2 is 2 or more, a plurality of R¹¹ may be identical or different and a plurality of R¹¹ may bond together to form a ring with the carbon atoms on the aromatic ring to which they are attached; when n4 is 2 or more, a plurality of R¹² may be identical or different and a plurality of R¹² may bond together to form a ring with the carbon atoms on the aromatic ring to which they are attached; when n6 is 2 or more, a plurality of R¹³ may be identical or different and a plurality of R¹³ may bond together to form a ring with the carbon atoms on the aromatic ring to which they are attached; when n7 is 2 or more, a plurality of R¹⁴ may be identical or different and a plurality of R¹⁴ may bond together to form a ring with the carbon atoms on the aromatic ring to which they are attached;
R¹⁵ is a C₁-C₄₀ (n8)-valent hydrocarbon group or C₂-C₄₀ (n8)-valent heterocyclic group; when n8=2, R¹⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R¹⁴ and R¹⁵ may bond together to form a ring with the carbon atoms to which they are attached and the intervenient atoms,
R²¹ is halogen or a C₁-C₁₀ hydrocarbyl group which may contain a heteroatom,
R²² is halogen or a C₁-C₄₀ hydrocarbyl group which may contain a heteroatom, when n9 is 2 or more, a plurality of R²² may be identical or different and a plurality of R²² may bond together to form a ring with the carbon atoms on the aromatic ring to which they are attached;
R²³ is carbonyl or a C₁-C₁₀ hydrocarbylene group which may contain a heteroatom,
1 and *2 each designate a point of attachment to a carbon atom on the aromatic ring in the formula, *1 and *2 being attached to adjoining carbon atoms on the aromatic ring,
the onium salt compound consists of a sulfonium cation having the formula (5-1) or iodonium cation having the formula (5-2) and a halide ion, nitrate ion, hydrogensulfate ion, hydrogencarbonate ion, tetraphenylborate ion or anion having any one of the formulae (5-3) to (5-9): 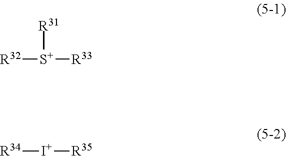
wherein R³¹ to R³⁵ are each independently halogen or a C₁-C₃₀ hydrocarbyl group which may contain a heteroatom, R³¹ and R³² may bond together to form a ring with the sulfur atom to which they are attached, 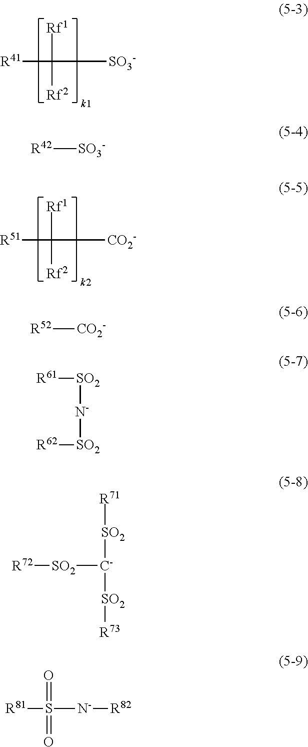
wherein k1 and k2 are each independently 1, 2, 3 or 4,
Rf¹ and Rf² are each independently hydrogen, fluorine, or a C₁-C₆ fluorinated alkyl group, excluding that all Rf¹ and Rf² are hydrogen at the same time,
R⁴¹ is hydrogen, halogen, hydroxy or a C₁-C₅₀ hydrocarbyl group which may contain a heteroatom,
R⁴² is hydrogen, halogen, hydroxy or a C₁-C₅₀ hydrocarbyl group which may contain a heteroatom, exclusive of the group wherein hydrogen bonded to the carbon atom at α- or β-position relative to the sulfo group is substituted by fluorine or fluoroalkyl,
R⁵¹ is hydrogen, halogen, hydroxy or a C₁-C₅₀ hydrocarbyl group which may contain a heteroatom,
R⁵² is hydrogen, halogen, hydroxy or a C₁-C₅₀ hydrocarbyl group which may contain a heteroatom, exclusive of the group wherein hydrogen bonded to the carbon atom at α- or β-position relative to the carboxy group is substituted by fluorine or fluoroalkyl,
R⁶¹ and R⁶² are each independently a C₁-C₅₀ hydrocarbyl group which may contain a heteroatom,
R⁷¹ to R⁷³ are each independently a C₁-C₅₀ hydrocarbyl group which may contain a heteroatom,
R⁸¹ is fluorine or a C₁-C₁₀ fluorinated hydrocarbyl group which may contain hydroxy, ether bond or ester bond, R⁸² is hydrogen or a C₁-C₂₀ hydrocarbyl group which may contain hydroxy, ether bond or ester bond, R⁸¹ and R⁸² may bond together to form a ring with the atom to which they are attached.

2. The resist composition of claim 1 wherein the carboxy-containing compound is a polymer comprising repeat units having the formula (6) or a compound having the formula (7): 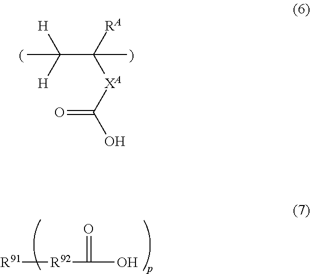
wherein R^{A} is hydrogen, halogen, methyl or trifluoromethyl,
X^{A} is a single bond, phenylene, naphthylene, or *—C(═O)—O—X^{A1}, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone,
p is 1, 2, 3 or 4,
R⁹¹ is a C₁-C₄₀ p-valent hydrocarbon group or C₂-C₄₀ p-valent heterocyclic group; when p=2, R⁹¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R⁹² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R⁹² may be identical or different.

3. The resist composition of claim 2 wherein the polymer comprising repeat units having formula (6) is free of an acid labile group.

4. A laminate comprising a substrate and a resist film formed thereon from the resist composition of claim 1.

5. The laminate of claim 4, further comprising an underlying film between the substrate and the resist film.

6. The laminate of claim 4 wherein the resist film is formed by a ligand exchange between the hypervalent iodine compound and the carboxy-containing compound.

7. A pattern forming process comprising the steps of applying the resist composition of claim 1 onto a substrate or a substrate having an underlying film deposited thereon to form a resist film thereon, exposing the resist film to i-line, KrF excimer laser, ArF excimer laser, EB or EUV, and developing the exposed resist film in a developer.
